(19) United States
(12) Patent Application Publication
(10) Pub. No.: US 2007/0059551 A1
(43) Pub. Date: Mar. 15, 2007

(54) Composition for organic electroluminescent element, method for manufacturing organic electroluminescent element, and organic electroluminescent element

(75) Inventor: Kazuki Yamazaki, Kanagawa (JP)

Correspondence Address: BIRCH STEWART KOLASCH & BIRCH, PO BOX 747, FALLS CHURCH, VA, 22040-0747, US

(73) Assignee: FUJI PHOTO FILM CO., LTD.

(21) Appl. No.: 11/518,303

(22) Filed: Sep. 11, 2006

(30) Foreign Application Priority Data
Sep. 14, 2005 (JP) 2005-267556
Sep. 14, 2005 (JP) 2005-267557
Feb. 23, 2006 (JP) 2006-047240

(51) Int. Cl. H01L 51/54; H01L 51/56; C09K 11/06

(52) U.S. Cl. 428/690; 428/917; 313/504; 257/E51.044; 252/301.16; 252/301.35; 427/66

(57) ABSTRACT

A composition for an organic electroluminescent element used for forming a pattern by an ink jet method, the composition having at least one metal complex having a tridentate or higher-dentate ligand. Also provided are a method for manufacturing an organic electroluminescent element including forming an organic compound layer by discharging the composition for an organic electroluminescent element in a pattern with an ink jet apparatus, a method for manufacturing an organic electroluminescent element including using a transfer material having an organic compound layer containing a metal complex having a tridentate or higher-dentate ligand, and organic electroluminescent elements manufactured by these methods.

### CROSS-REFERENCE TO RELATED APPLICATION

This application claims priority under 35 USC 119 from Japanese patent Application Nos. 2005-267556, 2005-267557, and 2006-047240, the disclosures of which are incorporated by reference herein.

### BACKGROUND OF THE INVENTION

1. Field of the Invention

The invention relates to a composition for an organic electroluminescent element, a method for manufacturing an organic electroluminescent element, and an organic electroluminescent element.

2. Description of the Related Art

Nowadays, research and developments concerning various display elements are actively conducted. Among them, an organic electroluminescent element (hereinafter occasionally referred to as “an organic EL element” or “a luminescent element”) attracts attention because the organic luminescent element enables high-luminance luminescence at low voltage. Because the organic EL element has advantages such as easier production and capability to form a thinner and lighter luminescent element compared to other luminescent elements, use as a thin display element has been researched and developed. In recent years, a high-performance organic EL element has been obtained which is comparable to a light-emitting diode (LED) even in respects of the luminance, the luminous efficiency, the durability, and the like. The organic EL element is promising particularly as an element that realizes a cheep and large area full-color display element.

In the production of organic EL elements, a thin film pattern, which is an organic compound layer (an organic layer) disposed between a pair of electrodes, can be formed by the vacuum deposition method, the spin coating method, the printing method, the ink jet method, and the like.

Organic layers of organic EL elements are typically manufactured by the deposition method. Japanese Patent Application Laid-Open (JP-A) Nos. 9-167684 and 2000-195665 have proposed methods in which an organic compound layer is uniformly formed on a temporary substrate of mica or a film in advance by the deposition method, then the substrate and the organic layer are brought into proximity, followed by heating and deposition. However, these methods have a problem in that the manufacturing efficiency is not good because the deposition method is used. Furthermore, because only a low molecular organic compound can be used for organic electroluminescence (EL) due to adoption of the deposition method, there is a problem in that the bending resistance and the durability of film strength and the like are insufficient when used in a flexible display and the like. The problem is apparent particularly when applied to a large area.

A polymer-type organic EL element that uses a luminescent thin film containing a low molecular compound dispersed in a binder resin, is also known. These polymer-type elements are advantageous also in making a large area display, and are expected to be applied to a flexible display. However, because the deposition method cannot be adapted for forming an organic luminescent thin film, the thin film is formed directly on the substrate by a wet process.

However, the wet process has problems in that the uniformity in the thickness of the organic thin film becomes insufficient due to the surface tension of the solution, and that each organic compound layer dissolves at the interface when organic layers are stacked. For this reason, the organic electroluminescent element obtained by this method has had a problem in that the luminous efficiency and the durability of the element are inferior.

The following International Publication No. WO 00/41893 pamphlet has proposed a thermal transfer method with a laser using a donor sheet having an organic thin film and a photothermal conversion layer. However, the thermal transfer as described in the literature has a problem in that the gas is entrapped at the adhesion interface of the organic layer and the element function is deteriorated. Furthermore, there is also a problem in that the luminous efficiency and durability of the organic EL element, and the uniformity of the luminescent surface vary depending on the condition of the interface of the organic layer.

Furthermore, when an organic thin film pattern is formed by a patterned thermal writing that uses a heating head and a laser used in the print technology field, the temperature distribution is generated on the periphery of the pattern by thermal diffusion property and the outline of the organic thin film pattern is not cut finely from the donor side. For this reason, there are problems in that the variation in the luminescent amount occurs, defects happen by electric failure and thin film fragments, and the durability is deteriorated. Furthermore, there is a problem of decrease in the yield caused by the malalignment of the substrate relative to the heating head or the laser.

The ink jet method has advantages such as ability to make highly accurate pattern, applicability to formation of a large area pattern, and capability of price reduction due to lack of necessity to use an expensive vacuum equipment. The ink jet method is particularly suitable for forming a polymer-based organic compound layer. Various methods for manufacturing the organic EL element involving the ink jet method have been disclosed (see, for example, Japanese Patent Application Laid Open (JP-A) Nos. 11-40358 and 11-54270, and the first pamphlet of International Publication No. WO 03/026359A1).

However, there is a problem in that the composition used in the manufacture of the organic EL element using the ink jet method has poor storability over time and that the composition may deteriorate when held in an ink jet device or the like for a long time. Manufacturing of the element using the deteriorated composition leads to the decrease in the element performance such as the luminous efficiency and the driving durability, and thus stable manufacture of the element is made difficult. A composition with excellent storability for an organic electroluminescent element has not been provided yet.

The method for manufacturing an organic EL element, which uses a transfer material to form the organic layer, has been proposed (for example, see JP-A No. 2004-79317). According to this manufacturing method, a luminescent element excellent in luminous efficiency, luminance, and durability can be easily manufactured by using a transfer material for forming the organic layer. However, there are needs for further improvement in the stability upon transfer of a transfer layer (an organic layer) from the transfer material to the substrate under heat or pressure, or in the stability of the transfer material over time.

### SUMMARY OF THE INVENTION

The invention has been made in consideration of the above-mentioned situation, and provides a composition for an organic electroluminescent element, a method for manufacturing an organic electroluminescent element, and an organic electroluminescent element.

A first aspect of the invention is to provide a composition for an organic electroluminescent element capable of forming a pattern by an ink jet method, comprising at least one metal complex having a tridentate or higher-dentate ligand.

A second aspect of the invention is to provide a method for manufacturing an organic electroluminescent element, the method comprising forming a first electrode on a substrate, forming an organic compound layer by discharging the composition of the first aspect in a pattern onto the side of the substrate that has the first electrode thereon using an ink jet apparatus, and forming a second electrode on the organic compound layer.

A third aspect of the invention is to provide a method for manufacturing an organic electroluminescent element, the method comprising forming a first electrode on a substrate, superposing a transfer material having an organic compound layer containing a metal complex having a tridentate or higher-dentate ligand provided on a temporary support, on the side of the substrate that has the first electrode thereon, applying heat and/or pressure thereto, peeling away the temporary support so as to transfer the organic compound layer onto the side of the substrate that has the first electrode thereon, and forming a second electrode on the organic compound layer.

### DESCRIPTION OF THE INVENTION

In the following, the invention will be described in detail.

[Composition for an Organic Electroluminescent Element]

The composition according to the invention for an organic electroluminescent element (hereinafter referred to as “composition for an organic EL element”) is a composition for an organic EL element capable of forming a pattern by an ink jet method, and contains at least one metal complex having a tridentate or higher-dentate ligand.

The metal complex having a tridentate or higher-dentate ligand in the invention is a metal complex excellent in stability in liquid.

Since the composition for an organic EL element according to the invention uses a metal complex having a tridentate of more ligand, the deterioration of the composition for an organic EL element with the passage of time can be effectively suppressed. An organic EL element that has high luminous efficiency, high luminance, and excellent durability can be manufactured stably and easily by applying this composition for an organic EL element to the manufacture of an organic EL element involving the ink jet method.

In the following, each component of the composition for an organic EL element according to the invention will be described.

[Metal Complex Having a Tridentate or Higher-Dentate Ligand]

First, the metal complex having a tridentate or higher-dentate ligand according to the invention will be described in detail.

In the metal complex according to the invention, the atoms coordinating to the metal ion are not particularly limited. An oxygen atom, a nitrogen atom, a carbon atom, a sulfur atom, or a phosphorus atom is preferable, an oxygen atom, a nitrogen atom, or a carbon atom is more preferable, and a nitrogen atom or a carbon atom is still more preferable.

The metal ion in the metal complex in the invention is not particularly limited. From the viewpoint of the improvement in the luminous efficiency, the improvement in durability and the decrease in the driving voltage, transition metal ions and rare-earth metal ions are preferable; an iridium ion, a platinum ion, a gold ion, a rhenium ion, a tungsten ion, a rhodium ion, a ruthenium ion, an osmium ion, a palladium ion, a silver ion, a copper ion, a cobalt ion, a zinc ion, a nickel ion, a lead ion, an aluminum ion, a gallium ion, and rare-earth metal ions (for example, an europium ion, a gadolinium ion, and a terbium ion) are more preferable; an iridium ion, a platinum ion, a gold ion, a rhenium ion, a tungsten ion, a palladium ion, a zinc ion, an aluminum ion, a gallium ion, an europium ion, a gadolinium ion, and a terbium ion are still more preferable. When the metal complex is used as a luminescent material, an iridium ion, a platinum ion, a rhenium ion, a tungsten ion, an europium ion, a gadolinium ion, and a terbium ion are particularly preferable.

When the metal complex in the invention is used as a charge transport material or a host material in a luminescent layer, an iridium ion, a platinum ion, a palladium ion, a zinc ion, an aluminum ion, and a gallium ion are particularly preferable.

As metal complexes having a tridentate or higher-dentate ligand in the invention, metal complexes having a ligand of tridentate to hexadentate are preferable from the viewpoint of the improvement in the luminous efficiency and the improvement in durability. In the case of metal ions which easily form a hexa-coordinate type complex, such as an iridium ion, metal complexes having a tridentate, a quadridentate, or a hexadentate ligand are preferable. In the case of metal ions which easily form a tetra-coordinate type complex, such as a platinum ion, metal complexes having a tridentate or a quadridentate ligand are more preferable, and metal complexes having a quadridentate ligand are still more preferable.

The ligand of the metal complex in the invention is preferably chain or circular from the viewpoint of the improvement in the luminous efficiency and the improvement in durability, and preferably has at least one nitrogen-containing heterocycle (for example, a pyridine ring, a quinoline ring, a pyrimidine ring, a pyrazine ring, a pyrrole ring, an imidazole ring, a pyrazole ring, an oxazole ring, a thiazole ring, an oxadiazole ring, a thiadiazole ring, and a triazole ring) which coordinates to the center metal (for example, M¹¹ in the case of a compound represented by the after-mentioned formula (I) with nitrogen. The nitrogen-containing heterocycle is preferably a nitrogen-containing six-membered heterocycle or a nitrogen-containing five-membered heterocycle. The heterocycles described above may form one or more condensed rings with other rings.

The expression “the ligand of a metal complex is chain” means that the ligand of the metal complex does not take a cyclic structure (for example, a terpyridyl ligand). Furthermore, the expression “the ligand of a metal complex is circular” means that plural ligands in the metal complex are bonded mutually to form a closed structure (for example, a phthalocyanine ligand or a crown ether ligand).

The metal complex in the invention is preferably a compounds represented by the formula (I), (II), or (III), which will be described in detail later.

The compound represented by Formula (I) will be described first.

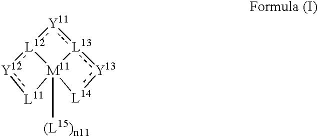

In Formula (I), M¹¹ represents a metal ion; L¹¹ to L¹⁵ each independently represent a ligand coordinated to M¹¹; in no case does an additional atomic group connect L¹¹ and L¹⁴ to form a cyclic ligand; in no case, is L¹⁵ bonded to both L¹¹ and L¹⁴ to form a cyclic ligand; Y¹¹ to Y¹³ each independently represent a connecting group, a single bond, or a double bond; when Y¹¹, Y¹², or Y¹³ represent a connecting group, the bond between L¹¹ and Y¹², the bond between Y¹² and L¹², the bond between L¹² and Y¹¹, the bond between Y¹¹ and L¹³, the bond between L¹³ and Y¹³, and the bond between Y¹³ and L¹⁴ are each independently a single bond or a double bond; and n¹¹ represents an integer of 0 to 4. Each bond connecting M¹¹ and each of L¹¹ to L¹⁵ may be selected from a coordinate bond, an ionic bond and a covalent bond.

Hereinafter, details of the compound represented by Formula (I) will be described.

In Formula (I), M¹¹ represents a metal ion. The metal ion is not particularly limited, but is preferably a divalent or trivalent metal ion. Preferable examples of the divalent or trivalent metal ion include a platinum ion, an iridium ion, a rhenium ion, a palladium ion, a rhodium ion, a ruthenium ion, a copper ion, a europium ion, a gadolinium ion, and a terbium ion. More preferable examples thereof include a platinum ion, an iridium ion, and a europium ion. Still more preferable examples thereof include a platinum ion and an iridium ion. Particularly preferable examples thereof include a platinum ion.

In Formula (I), L¹¹, L¹², L¹³, and L¹⁴ each independently represent a moiety coordinating to M¹¹. Preferable examples of the atom coordinating to M¹¹ contained in L¹¹, L¹², L¹³, or L¹⁴ include preferably a nitrogen atom, an oxygen atom, a sulfur atom, a carbon atom, and a phosphorus atom. More preferable examples thereof include a nitrogen atom, an oxygen atom, a sulfur atom, and a carbon atom. Still more preferable examples thereof include a nitrogen atom, an oxygen atom, and a carbon atom.

The bonds between M¹¹ and L¹¹, between M¹¹ and L¹², between M¹¹ and L¹³, between M¹¹ and L¹⁴ each may be independently selected from a covalent bond, an ionic bond, and a coordination bond. In this specification, the terms “ligand” and “coordinate” are used also when the bond between the central metal and the ligand is a bond (an ionic bond or a covalent bond) other than a coordination bond, as well as when the bond between the central metal and the ligand is a coordination bond, for convenience of the explanation.

The entire ligand comprising L¹¹, Y¹², L¹², Y¹¹, L¹³, Y¹³, and L¹⁴ is preferably an anionic ligand. The term “anionic ligand” used herein refers to a ligand having at least one anion bonded to the metal. The number of anions in the anionic ligand is preferably 1 to 3, more preferably from 1 or 2, and still more preferably 2.

When the moiety represented by any of L¹¹, L¹², L¹³, and L¹⁴ coordinates to M¹¹ via a carbon atom, the moiety is not particularly limited, and examples thereof include imino ligands, aromatic carbon ring ligands (e.g., a benzene ligand, a naphthalene ligand, an anthracene ligand, and a phenanthrene ligand), and heterocyclic ligands [e.g., a thiophene ligand, a pyridine ligand, a pyrazine ligand, a pyrimidine ligand, a thiazole ligand, an oxazole ligand, a pyrrole ligand, an imidazole ligand, and a pyrazole ligand, ring-condensation products thereof (e.g., a quinoline ligand and a benzothiazole ligand), and tautomers thereof].

When the moiety represented by any of L¹¹, L¹², L¹³, and L¹⁴ coordinates to M¹¹ via a nitrogen atom, the moiety is not particularly limited, and examples thereof include nitrogen-containing heterocyclic ligands such as a pyridine ligand, a pyrazine ligand, a pyrimidine ligand, a pyridazine ligand, a triazine ligand, a thiazole ligand, an oxazole ligand, a pyrrole ligand, an imidazole ligand, a pyrazole ligand, a triazole ligand, an oxadiazole ligand, and a thiadiazole ligand, and ring-condensation products thereof (e.g., a quinoline ligand, a benzoxazole ligand, and a benzimidazole ligand), and tautomers thereof [in the invention, the following ligands (pyrrole tautomers) are also included in tautomers, in addition to normal isomers: the five-membered heterocyclic ligand of compound (24), the terminal five-membered heterocyclic ligand of compound (64), and the five-membered heterocycle ligand of compound (145), the compounds (24), (64), (145) being shown below as typical examples of the compound represented by formula (I)]; amino ligands such as alkylamino ligands (preferably having 2 to 30 carbon atoms, more preferably 2 to 20 carbon atoms, and particularly preferably 2 to 10 carbon atoms, such as methylamino), arylamino ligands (e.g., and phenylamino), acylamino ligands (preferably having 2 to 30 carbon atoms, more preferably 2 to 20 carbon atoms, and particularly preferably 2 to 10 carbon atoms, such as acetylamino and benzoylamino), alkoxycarbonylamino ligands (preferably having 2 to 30 carbon atoms, more preferably 2 to 20 carbon atoms, and particularly preferably 2 to 12 carbon atoms, such as methoxycarbonylamino), aryloxycarbonylamino ligands (preferably having 7 to 30 carbon atoms, more preferably 7 to 20 carbon atoms, and particularly preferably 7 to 12 carbon atoms, such as phenyloxycarbonylamino), sulfonylamino ligands (preferably having 1 to 30 carbon atoms, more preferably 1 to 20 carbon atoms, and particularly preferably 1 to 12 carbon atoms, such as methanesulfonylamino and benzenesulfonylamino), and imino ligands. These ligands may be substituted.

When the moiety represented by any of L¹¹, L¹², L¹³, and L¹⁴ coordinates to M¹¹ via an oxygen atom, the moiety is not particularly limited, and examples thereof include alkoxy ligands (preferably having 1 to 30 carbon atoms, more preferably 1 to 20 carbon atoms, and particularly preferably 1 to 10 carbon atoms, such as methoxy, ethoxy, butoxy, and 2-ethylhexyloxy), aryloxy ligands (preferably having 6 to 30 carbon atoms, more preferably 6 to 20 carbon atoms, and particularly preferably 6 to 12 carbon atoms, such as phenyloxy, 1-naphthyloxy, and 2-naphthyloxy), heterocyclic oxy ligands (preferably having 1 to 30 carbon atoms, more preferably 1 to 20 carbon atoms, and particularly preferably 1 to 12 carbon atoms, such as pyridyloxy, pyrazyloxy, pyrimidyloxy, and quinolyloxy), acyloxy ligands (preferably having 2 to 30 carbon atoms, more preferably 2 to 20 carbon atoms, and particularly preferably 2 to 10 carbon atoms, such as acetoxy and benzoyloxy), silyloxy ligands (preferably having 3 to 40 carbon atoms, more preferably 3 to 30 carbon atoms, and particularly preferably 3 to 24 carbon atoms, such as trimethylsilyloxy and triphenylsilyloxy), carbonyl ligands (e.g., ketone ligands, ester ligands, and amido ligands), and ether ligands (e.g., dialkylether ligands, diarylether ligands, and furyl ligands).

When the moiety represented by any of L¹¹, L¹², L¹³, and L¹⁴ coordinates to M¹¹ via a sulfur atom, the moiety is not particularly limited, and examples thereof include alkylthio ligands (preferably having 1 to 30 carbon atoms, more preferably 1 to 20 carbon atoms, and particularly preferably 1 to 12 carbon atoms, such as methylthio and ethylthio), arylthio ligands (preferably having 6 to 30 carbon atoms, more preferably 6 to 20 carbon atoms, and particularly preferably 6 to 12 carbon atoms, such as phenylthio), heterocyclic thio ligands (preferably having 1 to 30 carbon atoms, more preferably 1 to 20 carbon atoms, and particularly preferably 1 to 12 carbon atoms, such as pyridylthio, 2-benzimidazolylthio, 2-benzoxazolylthio, and 2-benzothiazolylthio), thiocarbonyl ligands (e.g., thioketone ligands and thioester ligands), and thioether ligands (e.g., dialkylthioether ligands, diarylthioether ligands, and thiofuryl ligands). These substitution ligands may respectively have a substitutent.

When the moiety represented by any of L¹¹, L¹², L¹³, and L¹⁴ coordinates to M¹¹ via a phosphorus atom, the moiety is not particularly limited, and examples thereof include dialkylphosphino groups, diarylphosphino groups, trialkylphosphine groups, triarylphosphine groups, phosphinine groups and the like. These groups each may have a substituent.

In a preferable embodiment, L¹¹ and L¹⁴ each independently represent a moiety selected from an aromatic carbon ring ligand, an alkyloxy ligand, an aryloxy ligand, an ether ligand, an alkylthio ligand, an arylthio ligand, an alkylamino ligand, an arylamino ligand, an acylamino ligand, or a nitrogen-containing heterocyclic ligand [e.g., a pyridine ligand, a pyrazine ligand, a pyrimidine ligand, a pyridazine ligand, a triazine ligand, a thiazole ligand, an oxazole ligand, a pyrrole ligand, an imidazole ligand, a pyrazole ligand, a triazole ligand, an oxadiazole ligand, a thiadiazole ligand, or a condensed ring ligand containing one or more of the above ligands (e.g., a quinoline ligand, a benzoxazole ligand, or a benzimidazole ligand), or a tautomer of any of the above ligands]; more preferably, an aromatic carbon ring ligand, an aryloxy ligand, an arylthio ligand, an arylamino ligand, a pyridine ligand, a pyrazine ligand, an imidazole ligand, a condensed ring ligand containing one or more of the above ligands (e.g., a quinoline ligand, a quinoxaline ligand, or a benzimidazole ligand), or a tautomer of any of the above ligands; still more preferably, an aromatic carbon ring ligand or an aryloxy ligand, an arylthio ligand, or an arylamino ligand; and particularly preferably, an aromatic carbon ring ligand or an aryloxy ligand.

In a preferable embodiment, L¹² and L¹³ each independently represent a moiety forming a coordination bond with M¹¹. The moiety forming a coordination bond with M¹¹ is preferably a pyridine, pyrazine, pyrimidine, triazine, thiazole, oxazole, pyrrole or triazole ring, a condensed ring containing one or more of the above rings (e.g., a quinoline ring, a benzoxazole ring, a benzimidazole ring, an indolenine ring), or a tautomer of any of the above rings; more preferably a pyridine, pyrazine, pyrimidine, or pyrrole ring, a condensed ring containing one or more of the above rings (e.g., a quinoline ring, a benzopyrrole ring), or a tautomer of any of the above rings; still more preferably a pyridine, pyrazine or pyrimidine ring, or a condensed ring containing one or more of the above rings (e.g., quinoline ring); particularly preferably a pyridine ring or a condensed ring containing a pyridine ring (e.g., a quinoline ring).

In Formula (I), L¹⁵ represents a ligand coordinating to M¹¹. L¹⁵ is preferably a monodentate to tetradentate ligand and more preferably a monodentate to tetradentate anionic ligand. The monodentate to tetradentate anionic ligand is not particularly limited, but is preferably a halogen ligand, a 1,3-diketone ligand (e.g., an acetylacetone ligand), a monoanionic bidentate ligand containing a pyridine ligand [e.g., a picolinic acid ligand or a 2-(2-hydroxyphenyl)-pyridine ligand], or a tetradentate ligand L¹¹, Y¹², L¹², Y¹¹, L¹³, Y¹³, and L¹⁴ can form; more preferably, a 1,3-diketone ligand (e.g., an acetylacetone ligand), a monoanionic bidentate ligand containing a pyridine ligand [e.g., a picolinic acid ligand or a 2-(2-hydroxyphenyl)-pyridine ligand], or a tetradentate ligand L¹¹, Y¹², L¹², Y¹¹, L¹³, Y¹³, and L¹⁴ can form; still more preferably, a 1,3-diketone ligand (e.g., an acetylacetone ligand) or a monoanionic bidentate ligand containing a pyridine ligand [e.g., a picolinic acid ligand or a 2-(2-hydroxyphenyl)-pyridine ligand); and particularly preferably, a 1,3-diketone ligand (e.g., an acetylacetone ligand). The number of coordination sites and the number of ligands do not exceed the valency of the metal. L¹⁵ does not bind to both L¹¹ and L¹⁴ to form a cyclic ligand.

In Formula (I), Y¹¹, Y¹² and Y¹³ each independently represent a connecting group or a single or double bond. The connecting group is not particularly limited, and preferable examples thereof include connecting groups containing atoms selected from carbon atoms, nitrogen atoms, oxygen atoms, sulfur atoms, silicon atoms, and phosphorus atoms. Specific examples of such connecting groups include the following groups:

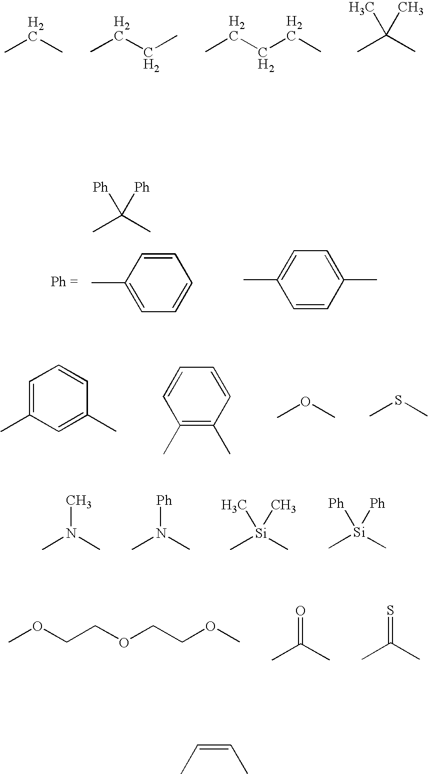

When Y¹¹ is a connecting group, the bond between L¹² and Y¹¹ and the bond between Y¹¹ and L¹³ are each independently a single or double bond. When Y¹² is a connecting group, the bond between L¹¹ and Y¹² and the bond between Y¹² and L¹² are each independently a single or double bond. When Y¹³ is a connecting group, the bond between L¹³ and Y¹³ and the bond between Y¹³ and L¹⁴ are each independently a single or double bond.

Preferably, Y¹¹, Y¹², and Y¹³ each independently represent a single bond, a double bond, a carbonyl connecting group, an alkylene connecting group, or an alkenylene group. Y¹¹ is more preferably a single bond or an alkylene group, and still more preferably an alkylene group. Each of Y¹² and Y¹³ is more preferably a single bond or an alkenylene group and still more preferably a single bond.

The ring formed by Y¹², L¹¹, L¹², and M¹¹, the ring formed by Y¹¹, L¹², L¹³, and M¹¹, and the ring formed by Y¹³, L¹³, L¹⁴, and M¹¹ are each preferably a four- to ten-membered ring, more preferably a five- to seven-membered ring, and still more preferably a five- to six-membered ring.

In Formula (I), n¹¹ represents an integer of 0 to 4. When M¹¹ is a tetravalent metal, n¹¹ is 0. When M¹¹ is a hexavalent metal, n¹¹ is preferably 1 or 2 and more preferably 1. When M¹¹ is a hexavalent metal and n¹¹ is 1, L¹⁵ represents a bidentate ligand. When M¹¹ is a hexavalent metal and n¹¹ is 2, L¹⁵ represents a monodentate ligand. When M¹¹ is an octavalent metal, n¹¹ is preferably from 1 to 4, more preferably, 1 or 2, and still more preferably 1. When M¹¹ is an octavalent metal and n¹¹ is 1, L¹⁵ represents a tetradentate ligand. When M¹¹ is an octavalent metal and n¹¹ is 2, L¹⁵ represents a bidentate ligand. When n¹¹ is two or greater, there are plural L¹⁵'s, and the L¹⁵'s may be the same as or different from each other.

Preferable embodiments of the compound represented by Formula (I) include compounds represented by the following Formulae (1), (2), (3) or (4).

Firstly, explanation of the compound represented by Formula (1) is provided.

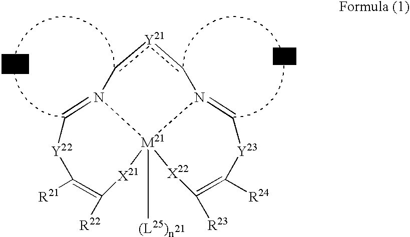

In Formula (1), M²¹ represents a metal ion; and Y²¹ represents a connecting group or a single or double bond. Y²³ and Y²³ each represent a single bond or a connecting group. Q²¹ and Q²² each represent an atomic group forming a nitrogen-containing heterocycle, and the bond between Y²¹ and the ring containing Q²¹ and the bond between Y²¹ and the ring containing Q²² are each a single or double bond. X²¹ and X²² each independently represent an oxygen atom, a sulfur atom, or a substituted or unsubstituted nitrogen atom. R²¹, R²², R²³, and R²⁴ each independently represent a hydrogen atom or a substituent. R²¹ and R²² may bind to each other to form a ring, and R²³ and R²⁴ may bind to each other to form a ring. L²⁵ represents a ligand coordinating to M²¹, and n²¹ represents an integer of 0 to 4.

The compound represented by formula (1) will be described in detail.

In Formula (1), the definition of M²¹ is the same as the definition of M¹¹ in Formula (I), and their preferable ranges are also the same.

Q²¹ and Q²² each independently represent an atomic group forming a nitrogen-containing heterocycle (ring containing a nitrogen atom coordinating to M²¹). The nitrogen-containing heterocycles formed by Q²¹ and Q²² are not particularly limited, and may be selected, for example, from a pyridine ring, a pyrazine ring, a pyrimidine ring, a triazine ring, a thiazole ring, an oxazole ring, a pyrrole ring, and a triazole ring, and condensed rings containing one or more of the above rings (e.g., a quinoline ring, a benzoxazole ring, a benzimidazole ring, and an indolenine ring), and tautomers thereof.

The nitrogen-containing heterocycle formed by Q²¹ or Q²² is preferably selected from a pyridine ring, a pyrazine ring, a pyrimidine ring, a pyridazine ring, a triazine ring, a pyrazol ring, an imidazol ring, an oxazol ring, a pyrrol ring, a benzazol ring, and condensed rings containing one or more of the above rings (e.g., a quinoline ring, a benzoxazole ring, a benzimidazole ring, and an indolenine ring), and tautomers thereof, more preferably selected from a pyridine ring, a pyrazine ring, a pyrimidine ring, an imidazol ring, a pyrrol ring, and condensed rings containing one or more of the above rings (e.g., a quinoline ring), and tautomers thereof, still more preferably a pyridine ring, or a condensed ring containing the pyridine ring (e.g., a quinoline ring), and particularly preferably a pyridine ring.

X²¹ and X²² each independently represent an oxygen atom, a sulfur atom, or a substituted or unsubstituted nitrogen atom. X²¹ and X²² are each preferably an oxygen atom, a sulfur atom, or a substituted nitrogen atom, more preferably an oxygen atom or a sulfur atom, and particularly preferably an oxygen atom.

The definition of Y²¹ is the same as that of Y¹¹ in Formula (I), and their preferable ranges are also the same.

Y²² and Y²³ each independently represent a single bond or a connecting group, preferably a single bond. The connecting group is not particularly limited, and examples thereof include a carbonyl connecting group, a thiocarbonyl connecting group, an alkylene group, an alkenylene group, an arylene group, a heteroarylene group, connecting groups which connects moieties via an oxygen atom, connecting groups which connects moieties via a nitrogen atom, and connecting groups comprising combinations of connecting groups selected from the above.

The connecting group represented by Y²² or Y²³ is preferably a carbonyl connecting group, an alkylene connecting group, or an alkenylene connecting group, more preferably a carbonyl connecting group or an alkenylene connecting group, and still more preferably a carbonyl connecting group.

R²¹, R²², R²³, and R²⁴ each independently represent a hydrogen atom or a substituent. The substituent is not particularly limited, and examples thereof include alkyl groups (preferably having 1 to 30 carbon atoms, more preferably 1 to 20 carbon atoms, and particularly preferably 1 to 10 carbon atoms, and examples thereof include a methyl group, an ethyl group, an iso-propyl group, a tert-butyl group, a n-octyl group, a n-decyl group, a n-hexadecyl group, a cyclopropyl group, a cyclopentyl group, and a cyclohexyl group), alkenyl groups (preferably having 2 to 30 carbon atoms, more preferably 2 to 20 carbon atoms, and particularly preferably 2 to 10 carbon atoms, and examples thereof include a vinyl group, an allyl group, a 2-butenyl group, and a 3-pentenyl group), alkynyl groups (preferably having 2 to 30 carbon atoms, more preferably 2 to 20 carbon atoms, and particularly preferably 2 to 10 carbon atoms, and examples thereof include a propargyl group and a 3-pentynyl group), aryl groups (preferably having 6 to 30 carbon atoms, more preferably 6 to 20 carbon atoms, and particularly preferably 6 to 12 carbon atoms, and examples thereof include a phenyl group, a p-methylphenyl group, a naphthyl group, and an anthranyl group), amino groups (preferably having 0 to 30 carbon atoms, more preferably 0 to 20 carbon atoms, and particularly preferably 0 to 10 carbon atoms, and examples thereof include an amino group, a, methylamino group, a dimethylamino group, a diethylamino group, a dibenzylamino group, a diphenylamino group, and a ditolylamino group),

alkoxy groups (preferably having 1 to 30 carbon atoms, more preferably 1 to 20 carbon atoms, and particularly preferably 1 to 10 carbon atoms, and examples thereof include a methoxy group, a ethoxy group, a butoxy group, and a 2-ethylhexyloxy group), aryloxy groups (preferably having 6 to 30 carbon atoms, more preferably 6 to 20 carbon atoms, and particularly preferably 6 to 12 carbon atoms, and examples thereof include a phenyloxy group, a 1-naphthyloxy group, and a 2-naphthyloxy group), heterocyclic oxy groups (preferably having 1 to 30 carbon atoms, more preferably 1 to 20 carbon atoms, and particularly preferably 1 to 12 carbon atoms, and examples thereof include a pyridyloxy group, a pyrazyloxy group, a pyrimidyloxy group, and a quinolyloxy group), acyl groups (preferably having 1 to 30 carbon atoms, more preferably 1 to 20 carbon atoms, and particularly preferably 1 to 12 carbon atoms, and examples thereof include a acetyl group, a benzoyl group, a formyl group, and a pivaloyl group), alkoxycarbonyl groups (preferably having 2 to 30 carbon atoms, more preferably 2 to 20 carbon atoms, and particularly preferably 2 to 12 carbon atoms, and examples thereof include a methoxycarbonyl group and an ethoxycarbonyl group), aryloxycarbonyl groups (preferably having 7 to 30 carbon atoms, more preferably 7 to 20 carbon atoms, and particularly preferably 7 to 12 carbon atoms, and examples thereof include a phenyloxycarbonyl group),

acyloxy groups (preferably having 2 to 30 carbon atoms, more preferably 2 to 20 carbon atoms, and particularly preferably 2 to 10 carbon atoms, and examples thereof include an acetoxy group and a benzoyloxy group), acylamino groups (preferably having 2 to 30 carbon atoms, more preferably 2 to 20 carbon atoms, and particularly preferably 2 to 10 carbon atoms, and examples thereof include an acetylamino group and a benzoylamino group), alkoxycarbonylamino groups (preferably having 2 to 30 carbon atoms, more preferably 2 to 20 carbon atoms, and particularly preferably 2 to 12 carbon atoms, and examples thereof include a methoxycarbonylamino group), aryloxycarbonylamino groups (preferably having 7 to 30 carbon atoms, more preferably 7 to 20 carbon atoms, and particularly preferably 7 to 12 carbon atoms, and examples thereof include a phenyloxycarbonylamino group), sulfonylamino groups (preferably having 1 to 30 carbon atoms, more preferably 1 to 20 carbon atoms, and particularly preferably 1 to 12 carbon atoms, and examples thereof include a methanesulfonylamino group and a benzenesulfonylamino group), sulfamoyl groups (preferably having 0 to 30 carbon atoms, more preferably 0 to 20 carbon atoms, and particularly preferably 0 to 12 carbon atoms, and examples thereof include a sulfamoyl group, a methylsulfamoyl group, a dimethylsulfamoyl group, and a phenylsulfamoyl group),

carbamoyl groups (preferably having 1 to 30 carbon atoms, more preferably 1 to 20 carbon atoms, and particularly preferably 1 to 12 carbon atoms, and examples thereof include a carbamoyl group, a methylcarbamoyl group, a diethylcarbamoyl group, and a phenylcarbamoyl group), alkylthio groups (preferably having 1 to 30 carbon atoms, more preferably 1 to 20 carbon atoms, and particularly preferably 1 to 12 carbon atoms, and examples thereof include a methylthio group and an ethylthio group), arylthio groups (preferably having 6 to 30 carbon atoms, more preferably 6 to 20 carbon atoms, and particularly preferably 6 to 12 carbon atoms, and examples thereof include a phenylthio group), heterocyclic thio groups (preferably having 1 to 30 carbon atoms, more preferably 1 to 20 carbon atoms, and particularly preferably 1 to 12 carbon atoms, and examples thereof include a pyridylthio group, a 2-benzimidazolylthio group, a 2-benzoxazolylthio group, and a 2-benzothiazolylthio group), sulfonyl groups (preferably having 1 to 30 carbon atoms, more preferably 1 to 20 carbon atoms, and particularly preferably 1 to 12 carbon atoms, and examples thereof include a mesyl group and a tosyl group), sulfinyl groups (preferably having 1 to 30 carbon atoms, more preferably 1 to 20 carbon atoms, and particularly preferably 1 to 12 carbon atoms, and examples thereof include a methanesulfinyl group and a benzenesulfinyl group), ureido groups (preferably having 1 to 30 carbon atoms, more preferably 1 to 20 carbon atoms, and particularly preferably 1 to 12 carbon atoms, and examples thereof include a ureido group, a methylureido group, and a phenylureido group),

phosphoric amide groups (preferably having 1 to 30 carbon atoms, more preferably 1 to 20 carbon atoms, and particularly preferably 1 to 12 carbon atoms, and examples thereof include a diethylphosphoric amide group and a phenylphosphoric amide group), a hydroxy group, a mercapto group, halogen atoms (such as fluorine, chlorine, bromine, or iodine), a cyano group, a sulfo group, a carboxyl group, a nitro group, a hydroxamic acid group, sulfino groups, hydrazino groups, imino groups, heterocyclic groups (preferably having 1 to 30 carbon atoms and more preferably 1 to 12 carbon atoms; the heteroatom(s) may be selected from nitrogen, oxygen, and sulfur atoms), and examples thereof include an imidazolyl group, a pyridyl group, a quinolyl group, a furyl group, a thienyl group, a piperidyl group, a morpholino group, a benzoxazolyl group, a benzimidazolyl group, a benzothiazolyl group, a carbazolyl group, and an azepinyl group), silyl groups (preferably having 3 to 40 carbon atoms, more preferably 3 to 30 carbon atoms, and particularly preferably 3 to 24 carbon atoms, and examples thereof include a trimethylsilyl group and a triphenylsilyl group), and silyloxy groups (preferably having 3 to 40 carbon atoms, more preferably 3 to 30 carbon atoms, and particularly preferably 3 to 24 carbon atoms, and examples thereof include a trimethylsilyloxy group and a triphenylsilyloxy group). These substituents may have a substitutent(s).

In a preferable embodiment, R²¹, R²², R²³, and R²⁴ are each independently selected from alkyl groups or aryl groups. In another preferable embodiment, R²¹ and R²² are groups that bind to each other to form a ring structure (e.g., a benzo-condensed ring or a pyridine-condensed ring), and/or R²³ and R²⁴ are groups that bind to each other to form a ring structure or ring structures (e.g., a benzo-condensed ring or a pyridine-condensed ring). In a more preferable embodiment, R²¹ and R²² are groups that bind to each other to form a ring structure (e.g., a benzo-condensed ring or a pyridine-condensed ring), and/or R²³ and R²⁴ are groups that bind to each other to form a ring structure or ring structures (e.g., a benzo-condensed ring or a pyridine-condensed ring).

The definition of L²⁵ is the same as that of L¹⁵ in Formula (I), and their preferable ranges are also the same.

The definition of n²¹ is the same as that of n¹¹ in Formula (I), and their preferable ranges are also the same.

In Formula (1), examples of preferable embodiments are described below:

(1) the rings formed by Q²¹ and Q²² are pyridine rings, and Y²¹ is a connecting group;

(2) the rings formed by Q²¹ and Q²² are pyridine rings, Y²¹ is a single or double bond, and X²¹ and X²² are selected from sulfur atoms, substituted nitrogen atoms, and unsubstituted nitrogen atom;

(3) the rings formed by Q²¹ and Q²² are each a five-membered nitrogen-containing heterocycle, or a nitrogen-containing six-membered ring containing two or more nitrogen atoms.

Preferable examples of compounds represented by Formula (1) are compounds represented by the following Formula (I-A).

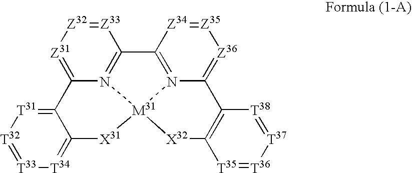

The compound represented by Formula (I-A) will be described below.

In Formula (I-A), the definition of M³¹ is the same as that of M¹¹ in Formula (I), and their preferable ranges are also the same.

Z³¹, Z³², Z³³, Z³⁴, Z³⁵, and Z³⁶ each independently represent a substituted or unsubstituted carbon or nitrogen atom, and preferably a substituted or unsubstituted carbon atom. The substituent on the carbon may be selected from the substituents described as examples of R²¹ in Formula (1). Z³¹ and Z³² may be bonded to each other via a connecting group to form a condensed ring (e.g., a benzo-condensed ring or a pyridine-condensed ring). Z³² and Z³³ may be bonded to each other via a connecting group to form a condensed ring (e.g., a benzo-condensed ring or a pyridine-condensed ring). Z³³ and Z³⁴ may be bonded to each other via a connecting group to form a condensed ring (e.g., a benzo-condensed ring or a pyridine-condensed ring). Z³⁴ and Z³⁵ may be bonded to each other via a connecting group to form a condensed ring (e.g., a benzo-condensed ring or a pyridine-condensed ring). Z³⁵ and Z³⁶ may be bonded to each other via a connecting group to form a condensed ring (e.g., a benzo-condensed ring or a pyridine-condensed ring). Z³¹ and T³¹ may be bonded to each other via a connecting group to form a condensed ring (e.g., a benzo-condensed ring or a pyridine-condensed ring). Z³⁶ and T³⁸ may be bonded to each other via a connecting group to form a condensed ring (e.g., a benzo-condensed ring or a pyridine-condensed ring).

The substituent on the carbon is preferably an alkyl group, an alkoxy group, an alkylamino group, an aryl group, a group capable of forming a condensed ring (e.g., a benzo-condensed ring or a pyridine-condensed ring), or a halogen atom, more preferably an alkylamino group, an aryl group, or a group capable of forming a condensed ring (e.g., a benzo-condensed ring or a pyridine-condensed ring), still more preferably an aryl group or a group capable of forming a condensed ring (e.g., a benzo-condensed ring or a pyridine-condensed ring), and particularly preferably a group capable of forming a condensed ring (e.g., a benzo-condensed ring or a pyridine-condensed ring).

T³¹, T³², T³³, T³⁴, T³⁵, T³⁶, T³⁷, and T³⁸ each independently represent a substituted or unsubstituted carbon or nitrogen atom, and more preferably a substituted or unsubstituted carbon atom. Examples of the substituents on the carbon include the groups described as examples of R²¹ in formula (1); T³¹ and T³² may be bonded to each other via a connecting group to form a condensed ring (e.g., a benzo-condensed ring). T³² and T³³ may be bonded to each other via a connecting group to form a condensed ring (e.g., a benzo-condensed ring). T³³ and T³⁴ may be bonded to each other via a connecting group to form a condensed ring (e.g., a benzo-condensed ring). T³⁵ and T³⁶ may be bonded to each other via a connecting group to form a condensed ring (e.g., a benzo-condensed ring). T³⁶ and T³⁷ may be bonded to each other via a connecting group to form a condensed ring (e.g., a benzo-condensed ring). T³⁷ and T³⁸ may be bonded to each other via a connecting group to form a condensed ring (e.g., a benzo-condensed ring).

The substituent on the carbon is preferably an alkyl group, an alkoxy group, an alkylamino group, an aryl group, a group capable of forming a condensed ring (e.g., a benzo-condensed ring or a pyridine-condensed ring), or a halogen atom; more preferably an aryl group, a group capable of forming a condensed ring (e.g., a benzo-condensed ring or pyridine-condensed ring), or a halogen atom; still more preferably an aryl group or a halogen atom, and particularly preferably an aryl group.

The definitions and preferable ranges of X³¹ and X³² are the same as the definitions and preferable ranges of X²¹ and X²² in Formula (1), respectively.

The compound represented by Formula (2) will be described below.

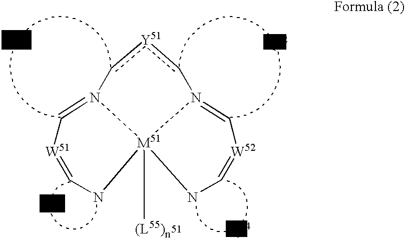

In Formula (2), the definition of M⁵¹ is the same as that of M¹¹ in Formula (I), and their preferable ranges are also the same.

The definitions of Q⁵¹ and Q⁵² are the same as the definitions of Q²¹ and Q²² in Formula (1), and their preferable ranges are also the same.

Q⁵³ and Q⁵⁴ each independently represent a group forming a nitrogen-containing heterocycle (ring containing a nitrogen atom coordinating to M⁵¹). The nitrogen-containing heterocycles formed by Q⁵³ and Q⁵⁴ are not particularly limited, and are preferably selected from tautomers of pyrrole compounds, tautomers of imidazole compounds (e.g., the five-membered heterocyclic ligand contained in the compound (29) shown below as a specific example of the compound represented by Formula (I)), tautomers of thiazole compounds (e.g., the five-membered heterocyclic ligand contained in the compound (30) shown below as a specific example of the compound represented by Formula (I)), and tautomers of oxazole compounds (e.g., the five-membered heterocyclic ligand contained in the compound (31) shown below as a specific example of the compound represented by Formula (I)), more preferably selected from tautomers of pyrrole, imidazole, and thiazole compounds; still more preferably selected from tautomers of pyrrole and imidazole compounds; and particularly preferably selected from tautomers of pyrrole compounds.

The definition of Y⁵¹ is the same as that of Y¹¹ in Formula (I), and their preferable range are also the same.

The definition of L⁵⁵ is the same as that of L¹⁵ in Formula (I), and their preferable ranges are also the same.

The definition of n⁵¹ is the same as that of n¹¹, and their preferable ranges are also the same.

W⁵¹ and W⁵² each independently represent a substituted or unsubstituted carbon or nitrogen atom, more preferably an unsubstituted carbon or nitrogen atom, and still more preferably an unsubstituted carbon atom.

The compound represented by Formula (3) will be described below.

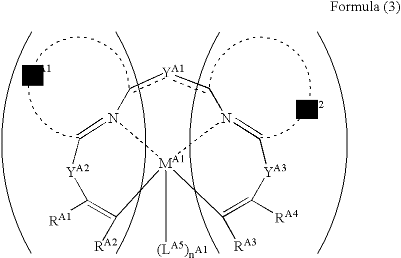

In Formula (3), the definitions and preferable ranges of M^{A1}, Q^{A1}, Q^{A2}, Y^{A1}, Y^{A2}, Y^{A3}, R^{A1}, R^{A2}, R^{A3}, R^{A4}, L^{A5}, and n^{A1} are the same as the definitions and preferable ranges of M²¹, Q²¹, Q²², Y²¹, Y²², Y²³, R²¹, R²², R²³, R²⁴, L²⁵ and n²¹ in Formula (1) respectively.

Preferable examples of compounds represented by Formula (3) are compounds represented by the following Formula (3-A) or (3-B).

The compound represented by Formula (3-A) will be described first.

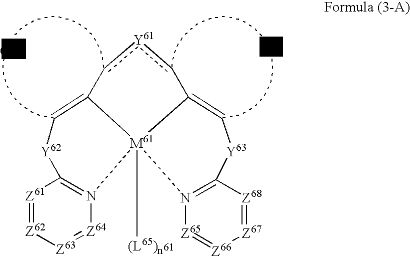

In Formula (3-A), the definitions of M⁶¹ is the same as that of M¹¹ in Formula (I), and their preferable ranges are also the same.

Q⁶¹ and Q⁶² each independently represent a ring-forming group. The rings formed by Q⁶¹ and Q⁶² are not particularly limited, and examples thereof include a benzene ring, a pyridine ring, a pyridazine ring, a pyrimidine ring, a thiophene ring, an isothiazole ring, a furan ring, an isoxazole ring, and condensed rings thereof.

Each of the rings formed by Q⁶¹ and Q⁶² is preferably a benzene ring, a pyridine ring, a thiophene ring, a thiazole ring, or a condensed ring containing one or more of the above rings; more preferably a benzene ring, a pyridine ring, or a condensed ring containing one or more of the above rings; and still more preferably a benzene ring or a condensed ring containing a benzene ring.

The definition of Y⁶¹ is the same as that of Y¹¹ in Formula (I), and their preferable ranges are also the same.

Y⁶² and Y⁶³ each independently represent a connecting group or a single bond. The connecting group is not particularly limited, and examples thereof include a carbonyl connecting group, a thiocarbonyl connecting group, alkylene groups, alkenylene groups, arylene groups, heteroarylene groups, a connecting group which connects moieties via an oxygen or nitrogen atom, and connecting groups comprising combinations of connecting groups selected from the above.

Y⁶² and Y⁶³ are each independently selected, preferably from a single bond, a carbonyl connecting group, an alkylene connecting group, and an alkenylene group, more preferably from a single bond and an alkenylene group, and still more preferably from a single bond.

The definition of L⁶⁵ is the same as that of L¹⁵ in Formula (I), and their preferable ranges are also the same.

The definition of n⁶¹ is the same as the definition of n¹¹ in Formula (I), and their preferable ranges are also the same.

Z⁶¹, Z⁶², Z⁶³, Z⁶⁴, Z⁶⁵, Z⁶⁶, Z⁶⁷, and Z⁶⁸ each independently represent a substituted or unsubstituted carbon or nitrogen atom, and preferably a substituted or unsubstituted carbon atom. Examples of the substituent on the carbon include the groups described as examples of R²¹ in Formula (1). Z⁶¹ and Z⁶² may be bonded to each other via a connecting group to form a condensed ring (e.g., a benzo-condensed ring or a pyridine-condensed ring) Z⁶² and Z⁶³ may be bonded to each other via a connecting group to form a condensed ring (e.g., a benzo-condensed ring or a pyridine-condensed ring). Z⁶³ and Z⁶⁴ may be bonded to each other via a connecting group to form a condensed ring (e.g., a benzo-condensed ring or a pyridine-condensed ring). Z⁶⁵ and Z⁶⁶ may be bonded to each other via a connecting group to form a condensed ring (e.g., a benzo-condensed ring or a pyridine-condensed ring). Z⁶⁶ and Z⁶⁷ may be bonded to each other via a connecting group to form a condensed ring (e.g., a benzo-condensed ring or a pyridine-condensed ring). Z⁶⁷ and Z⁶⁸ may be bonded to each other via a connecting group to form a condensed ring (e.g., a benzo-condensed ring or a pyridine-condensed ring). The ring formed by Q⁶¹ may be bonded to Z⁶¹ via a connecting group to form a ring. The ring formed by Q⁶² may be bonded to Z⁶⁸ via a connecting group to form a ring.

The substituent on the carbon is preferably an alkyl group, an alkoxy group, an alkylamino group, an aryl group, a group capable of forming a condensed ring (e.g., benzo-condensed ring or pyridine-condensed ring), or a halogen atom, more preferably an alkylamino group, an aryl group, or a group capable of forming a condensed ring (e.g., benzo-condensed ring or pyridine-condensed ring), still more preferably an aryl group or a group capable of forming a condensed ring (e.g., benzo-condensed ring or pyridine-condensed ring), and particularly preferably a group capable of forming a condensed ring (e.g., benzo-condensed ring or pyridine-condensed ring).

The compound represented by Formula (3-B) will be described below.

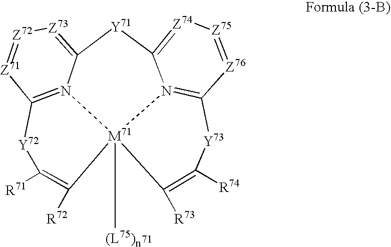

In Formula (3-B), the definition of M⁷¹ is the same as that of M¹¹ in Formula (I), and their preferable ranges are also the same.

The definitions and preferable ranges of Y⁷¹, Y⁷², and Y⁷³ are the same as the definition and preferable range of Y⁶² in Formula (3-A).

The definition of L⁷⁵ is the same as that of L¹⁵ in Formula (I), and their preferable ranges are also the same.

The definition of n⁷¹ is the same as that of n¹¹ in Formula (I), and their preferable ranges are also the same.

Z⁷¹, Z⁷², Z⁷³, Z⁷⁴, Z⁷⁵, and Z⁷⁶ each independently represent a substituted or unsubstituted carbon or nitrogen atom, and more preferably a substituted or unsubstituted carbon atom. Examples of the substituent on the carbon include the groups described as examples of R²¹ in Formula (1). In addition, Z⁷¹ and Z⁷² may be bonded to each other via a connecting group to form a ring (e.g., a benzene ring). Z⁷² and Z⁷³ may be bonded to each other via a connecting group to form a ring (e.g., a benzene ring). Z⁷³ and Z⁷⁴ may be bonded to each other via a connecting group to form a ring (e.g., a benzene ring). Z⁷⁴ and Z⁷⁵ may be bonded to each other via a connecting group to form a ring (e.g., a benzene ring). Z⁷⁵ and Z⁷⁶ may be bonded to each other via a connecting group to form a ring (e.g., a benzene ring). The definitions and preferable ranges of R⁷¹ to R⁷⁴ are the same as the definitions of R²¹ to R²⁴ in Formula (1), respectively. R⁷¹ and R⁷² may be bonded to each other via a connecting group to form a ring (e.g., a benzene ring or a pyridine ring). R⁷³ and R⁷⁴ may be bonded to each other via a connecting group to form a ring (e.g., a benzene ring or a pyridine ring).

Preferable examples of compounds represented by Formula (3-B) include compounds represented by the following formula (3-C).

The compound represented by Formula (3-C) will be described below.

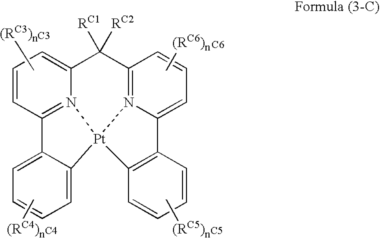

In Formula (3-C), R^{C1} and R^{C2} each independently represent a hydrogen atom or a substituent, and the substituents may be selected from the alkyl groups and aryl groups described as examples of R²¹ to R²⁴ in Formula (1). R^{C3}, R^{C4}, R^{C5}, and R^{C6} each independently represent a hydrogen atom or a substituent, and the substituent may be selected from the substituents described as examples of R²¹ to R²⁴ in Formula (1). Each of n^{C3} and n^{C6} represents an integer of 0 to 3; each of n^{C4} and n^{C5} represents an integer of 0 to 4; when there are plural R^{C3}s, R^{C4}s, R^{C5}s, or R^{C6}s, the plural R^{C3}s, R^{C4}s, R^{C5}s, or R^{C6} s may be the same as each other or different from each other, and may be bonded to each other to form a ring. R^{C3}, R^{C4}, R^{C5}, and R^{C6} each preferably represent an alkyl group, an aryl group, a heteroaryl group, or a halogen atom.

The compound represented by Formula (4) will be described below.

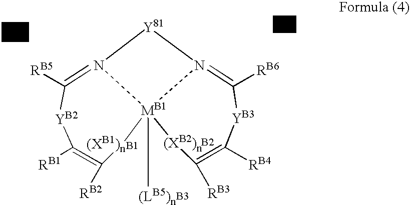

In Formula (4), the definitions and preferable ranges of M^{B1}, Y^{B2}, Y^{B3}, R^{B1}, R^{B2}, R^{B3}, R^{B4}, L^{B5}, n^{B3}, X^{B1}, and X^{B2} are the same as the definitions of M²¹, Y²², Y²³, R²¹, R²², R²³, R²⁴, L²⁵, n²¹, X²¹, and X²² in Formula (1), respectively.

Y^{B1} represents a connecting group whose definition is the same as that of Y²¹ in Formula (1). Y^{B1} is preferably a vinyl group substituted at 1- or 2-position, a phenylene ring, a pyridine ring, a pyrazine ring, a pyrimidine ring, or an alkylene group having 2 to 8 carbons.

R^{B5} and R^{B6} each independently represent a hydrogen atom or a substituent, and the substituent may be selected from the alkyl groups, aryl groups, and heterocyclic groups described as examples of R²¹ to R²⁴ in Formula (1). However, Y^{B1} is not bonded to R^{B5} or R^{B6}. n^{B1} and n^{B2} each independently represent an integer of 0 or 1.

Preferable examples of the compound represented by Formula (4) include compounds represented by the following Formula (4-A).

The compound represented by Formula (4-A) will be described below.

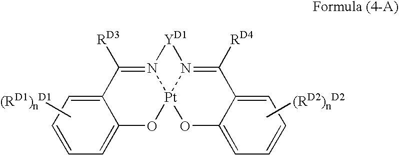

In Formula (4-A), R^{D3} and R^{D4} each independently represent a hydrogen atom or a substituent, and R^{D1} and R^{D2} each represent a substituent. The substituents represented by R^{D1}, R^{D2}, R^{D3}, and R^{D4} may be selected from the substituents described as examples of R^{B5} and R^{B6} in Formula (4), and have the same preferable range as R^{B5} and R^{B6} in Formula (4). n^{D1} and n^{D2} each represent an integer of 0 to 4. When there are plural R^{D1}s, the plural R^{D1}s may be the same as or different from each other or may be bonded to each other to form a ring. When there are plural R^{D2}s, the plural R^{D2}s may be the same as or different from each other or may be bonded to each other to form a ring. Y^{D1} represents a vinyl group substituted at 1- or 2-position, a phenylene ring, a pyridine ring, a pyrazine ring, a pyrimidine ring, or an alkylene group having 1 to 8 carbon atoms.

Preferable examples of the metal complex having a tridentate ligand according to the invention include compounds represented by the following Formula (5).

The compound represented by Formula (5) will be described below.

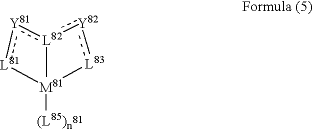

In Formula (5), the definition of M⁸¹ is the same as that of M¹¹ in Formula (I), and their preferable ranges are also the same.

The definitions and preferable ranges of L⁸¹, L⁸², and L⁸³ are the same as the definitions and preferable ranges of L¹¹, L¹², and L¹³ in Formula (I), respectively.

The definitions and preferable ranges of Y⁸¹ and Y⁸² are the same as the definitions and preferable ranges of Y¹¹ and Y¹² in Formula (I), respectively.

L⁸⁵ represents a ligand coordinating to M⁸¹. L⁸⁵ is preferably a mono- to tri-dentate ligand and more preferably a monodentate to tridentate anionic ligand. The mono- to tri-dentate anionic ligand is not particularly limited, but is preferably a halogen ligand or a tridentate ligand L⁸¹, Y⁸¹, L⁸², Y⁸², and L⁸³ can form, and more preferably a tridentate ligand L⁸¹, Y⁸¹, L⁸², Y⁸², and L⁸³ can form. L⁸⁵ is not directly bonded to L⁸¹ or L⁸³. The numbers of coordination sites and ligands do not exceed the valency of the metal.

n⁸¹ represents an integer of 0 to 5. When M⁸¹ is a tetravalent metal, n⁸¹ is 1, and L⁸⁵ represents a monodentate ligand. When M⁸¹ is a hexavalent metal, n⁸¹ is preferably from 1 to 3, more preferably 1 or 3, and still more preferably 1. When M⁸¹ is hexavalent and n⁸¹ is 1, L⁸⁵ represents a tridentate ligand. When M⁸¹ is hexavalent and n⁸¹ is 2, L⁸⁵ represents a monodentate ligand and a bidentate ligand. When M⁸¹ is hexavalent and n⁸¹ is 3, L⁸⁵ represents a monodentate ligand. When M⁸¹ is an octavalent metal, n⁸¹ is preferably from 1 to 5, more preferably 1 or 2, and still more preferably 1. When M⁸¹ is octavalent and n⁸¹ is 1, L⁸⁵ represents a pentadentate ligand. When M⁸¹ is octavalent and n⁸¹ is 2, L⁸⁵ represents a tridentate ligand and a bidentate ligand. When M⁸¹ is octavalent and n⁸¹ is 3, L⁸⁵ represents a tridentate ligand and two monodentate ligands, or represents two bidentate ligands and one monodentate ligand. When M⁸¹ is octavalent and n⁸¹ is 4, L⁸⁵ represents one bidentate ligand and three monodentate ligands. When M⁸¹ is octavalent and n⁸¹ is 5, L⁸⁵ represents five monodentate ligands. When n⁸¹ is two or greater, there are plural L⁸⁵s, and the plural L⁸⁵s may be the same as or different from each other.

In a preferable example of the compound represented by Formula (5), L⁸¹, L⁸², or L⁸³ each represent an aromatic carbon ring containing a carbon atom coordinating to M⁸¹, a heterocycle containing a carbon atom coordinating to M⁸¹, or a nitrogen-containing heterocycle containing a nitrogen atom coordinating to M⁸¹, wherein at least one of L⁸¹, L⁸², and L⁸³ is a nitrogen-containing heterocycle. Examples of the aromatic carbon ring containing a carbon atom coordinating to M⁸¹, heterocycle containing a carbon atom coordinating to M⁸¹, or nitrogen-containing heterocycle containing a nitrogen atom coordinating to M⁸¹ include the examples of ligands (moieties) each containing a nitrogen or carbon atom coordinating to M¹¹ in Formula (I) described in the explanation of Formula (I). Preferable examples thereof are the same as in the description of ligands (moieties) each containing a nitrogen or carbon atom coordinating to M¹¹ in Formula (I). Y⁸¹ and Y⁸² each preferably represent a single bond or a methylene group.

Other preferable examples of compounds represented by Formula (5) include compounds represented by the following Formulae (5-A) and (5-B).

The compound represented by Formula (5-A) will be described below.

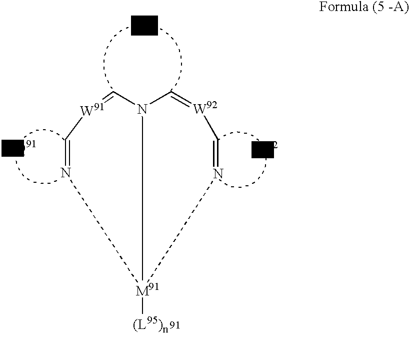

In Formula (5-A), the definition of M⁹¹ is the same as that of M⁸¹ in Formula (5), and their preferable ranges are also the same.

Q⁹¹ and Q⁹² each represent a group forming a nitrogen-containing heterocycle (ring containing a nitrogen atom coordinating to M⁹¹). The nitrogen-containing heterocycles formed by Q⁹¹ and Q⁹² are not particularly limited, and examples thereof include a pyridine ring, a pyrazine ring, a pyrimidine ring, a pyridazine ring, a triazine ring, a thiazole ring, an oxazole ring, a pyrrole ring, a pyrazole ring, a imidazole, a triazole ring, and condensed rings containing one or more of the above rings (e.g., a quinoline ring, a benzoxazole ring, a benzimidazole ring, and an indolenine ring), and tautomers thereof.

Each of the nitrogen-containing heterocycles formed by Q⁹¹ and Q⁹² is preferably a pyridine ring, a pyrazole ring, a thiazole ring, an imidazole ring, a pyrrole ring, a condensed ring containing one or more of the above ring (e.g., a quinoline ring, a benzothiazole ring, a benzimidazole ring, or an indolenine ring), or a tautomer of any of the above rings; more preferably a pyridine ring, a pyrrole ring, a condensed ring containing one or more of these rings (e.g., a quinoline ring), or a tautomer of any of the above rings; still more preferably a pyridine ring or a condensed ring containing a pyridine ring (e.g., a quinoline ring); and particularly preferably a pyridine ring.

Q⁹³ represents a group forming a nitrogen-containing heterocycle (ring containing a nitrogen atom coordinating to M⁹¹). The nitrogen-containing heterocycle formed by Q⁹³ is not particularly limited, but is preferably a pyrrole ring, an imidazole ring, a tautomer of a triazole ring, or a condensed ring containing one or more of the above rings (e.g., benzopyrrole), and more preferably a tautomer of a pyrrole ring or a tautomer of a condensed ring containing a pyrrole ring (e.g., benzopyrrole).

The definitions and preferable ranges of W⁹¹ and W⁹² are the same as the definitions and preferable ranges of W⁵¹ and W⁵² in Formula (2), respectively.

The definition of L⁹⁵ is the same as that of L⁸⁵ in Formula (5), and their preferable ranges are also the same.

The definition of n⁹¹ is the same as that of n⁸¹ in Formula (5), and their preferable ranges are also the same.

The compound represented by Formula (5-B) will be described next.

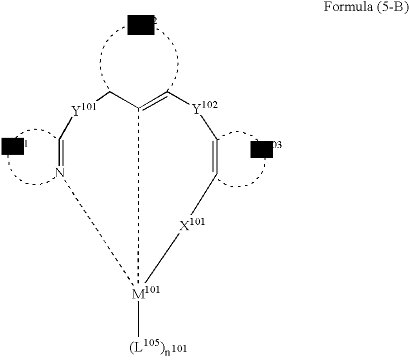

In Formula (5-B), the definition of M¹⁰¹ is the same as that of M⁸¹ in Formula (5), and their preferable ranges are also the same.

The definition of Q¹⁰² is the same as that of Q²¹ in Formula (1), and their preferable ranges are also the same.

The definition of Q¹⁰¹ is the same as that of Q⁹¹ in Formula (5-A), and their preferable ranges are also the same.

Q¹⁰³ represents a group forming an aromatic ring. The aromatic ring formed by Q¹⁰³ is not particularly limited, but is preferably a benzene ring, a furan ring, a thiophene ring, a pyrrole ring, or a condensed ring containing one or more of the above rings (e.g., a naphthalene ring), more preferably a benzene ring or a condensed ring containing a benzene ring (e.g., naphthalene ring), and particularly preferably a benzene ring.

The definitions and preferable ranges of Y¹⁰¹ and Y¹⁰² are the same as the definition and preferable range of Y²² in Formula (1).

The definition of L¹⁰⁵ is the same as that of L⁸⁵ in Formula (5), and their preferable ranges are also the same.

The definition of n¹⁰¹ is the same as that of n⁸¹ in Formula (5), and their preferable ranges are also the same.

The definition of X¹⁰¹ is the same as that of X²¹ in Formula (1), and their preferable ranges are also the same.

Another preferable embodiment of the metal complex containing a tridentate ligand according to the invention is a compound represented by Formula (II) shown below.

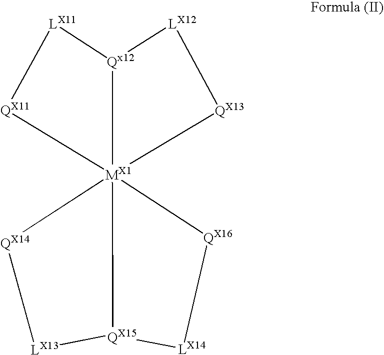

In Formula (II), M^{X1} represents a metal ion. Q^{X11} to Q^{X16} each independently represent an atom coordinating to M^{X1} or an atomic group containing an atom coordinating to M^{X1}. L^{X11} to L^{X14} each independently represent a single bond, a double bond or a connecting group.

Namely, in Formula (II), the atomic group comprising Q^{X11}-L^{X11}-Q^{X12}-L^{X12}-Q^{X13} and the atomic group comprising Q^{X14}-L^{X13}-Q^{X15}-L^{X14}-Q^{X16} each form a tridentate ligand.

In addition, each of the bond between M^{X1} and each of Q^{X11} to Q^{X16} may be a coordination bond, an ionic bond, or a covalent bond.

The compound represented by Formula (II) will be described in detail below.

In Formula (II), M^{X1} represents a metal ion. The metal ion is not particularly limited, but is preferably a monovalent to trivalent metal ion, more preferably a divalent or trivalent metal ion, and still more preferably a trivalent metal ion. Specifically, a platinum ion, an iridium ion, a rhenium ion, a palladium ion, a rhodium ion, a ruthenium ion, a copper ion, a europium ion, a gadolinium, and a terbium ion are preferable. Among these, an iridium ion and a europium ion are more preferable, and an iridium ion is still more preferable.

Q^{X11} to Q^{X16} each represent an atom coordinating to M^{X1} or an atomic group containing an atom coordinating to M^{X1}.

When any of Q^{X11} to Q^{X16} is an atom coordinating to M^{X1}, specific examples of the atom include a carbon atom, a nitrogen atom, an oxygen atom, a silicon atom, a phosphorus atom, and a sulfur atom. Preferable specific examples of the atom include a nitrogen atom, an oxygen atom, a sulfur atom, and a phosphorus atom. More preferable specific examples of the atom include a nitrogen atom and an oxygen atom.

When any of Q^{X11} to Q^{X16} is an atomic group containing a carbon atom coordinating to M^{X1}, examples of the atomic group coordinating to M^{X1} via a carbon atom include imino groups, aromatic hydrocarbon ring groups (such as a benzene ring group or a naphthalene ring group), heterocyclic groups (such as a thiophene group, a pyridine group, a pyrazine group, a pyrimidine group, a pyridazine group, a triazine group, a thiazole group, an oxazole group, a pyrrole group, an imidazole group, a pyrazole group, or a triazole group), condensed rings containing one or more of the above rings, and tautomers thereof.

When any of Q^{X11} to Q^{X16} is an atomic group containing a nitrogen atom coordinating to M^{X1}, examples of the atomic group coordinating to M^{X1} via a nitrogen atom include nitrogen-containing heterocyclic groups, amino groups, and imino groups. Examples of the nitrogen-containing heterocyclic groups include pyridine, pyrazine, pyrimidine, pyridazine, triazine, thiazole, oxazole, pyrrole, imidazole, pyrazole, or triazole. Examples of the amino groups include alkylamino groups [preferably having 2 to 30 carbon atoms, more preferably 2 to 20 carbon atoms, and particularly preferably 2 to 10 carbon atoms, and examples thereof include a methylamino group), arylamino groups (e.g., a phenylamino group)], acylamino groups (preferably having 2 to 30 carbon atoms, more preferably 2 to 20 carbon atoms, and particularly preferably 2 to 10 carbon atoms, and examples thereof include an acetylamino group and a benzoylamino group), alkoxycarbonylamino groups (preferably having 2 to 30 carbon atoms, more preferably 2 to 20 carbon atoms, and particularly preferably 2 to 12 carbon atoms, and examples thereof include a methoxycarbonylamino group), aryloxycarbonylamino groups (preferably having 7 to 30 carbon atoms, more preferably 7 to 20 carbon atoms, and particularly preferably 7 to 12 carbon atoms, and examples thereof include a phenyloxycarbonylamino group), and sulfonylamino groups (preferably having 1 to 30 carbon atoms, more preferably 1 to 20 carbon atoms, and particularly preferably 1 to 12 carbon atoms, and examples thereof include a methanesulfonylamino and benzenesulfonylamino group). These groups may have a substitutent(s).

When any of Q^{X11} to Q^{X16} is an atomic group containing an oxygen atom coordinating to M^{X1}, examples of the atomic groups coordinating to M^{X1} via an oxygen atom include alkoxy groups (preferably having 1 to 30 carbon atoms, more preferably 1 to 20 carbon atoms, and particularly preferably 1 to 10 carbon atoms, and examples thereof include a methoxy group, an ethoxy group, a butoxy group, and a 2-ethylhexyloxy group), aryloxy groups (preferably having 6 to 30 carbon atoms, more preferably 6 to 20 carbon atoms, and particularly preferably 6 to 12 carbon atoms, and examples thereof include a phenyloxy group, a 1-naphthyloxy group, and a 2-naphthyloxy group), heterocyclic oxy groups (preferably having 1 to 30 carbon atoms, more preferably 1 to 20 carbon atoms, and particularly preferably 1 to 12 carbon atoms, and examples thereof include a pyridyloxy group, a pyrazyloxy group, a pyrimidyloxy group, and a quinolyloxy group), acyloxy groups (preferably having 2 to 30 carbon atoms, more preferably 2 to 20 carbon atoms, and particularly preferably 2 to 10 carbon atoms, and examples thereof include an acetoxy group and a benzoyloxy group), silyloxy groups (preferably having 3 to 40 carbon atoms, more preferably 3 to 30 carbon atoms, and particularly preferably 3 to 24 carbon atoms, and examples thereof include a trimethylsilyloxy group and a triphenylsilyloxy), carbonyl groups (e.g., ketone groups, ester groups, and amido groups), and ether groups (e.g., dialkylether groups, diarylether groups, and furyl groups).

When any of Q^{X11} to Q^{X16} is an atomic group containing a silicon atom coordinating to M^{X1}, examples of the atomic group coordinating to M^{X1} via a silicon atom include alkylsilyl groups (preferably having 3 to 30 carbon atoms, and examples thereof include a trimethylsilyl group), and arylsilyl groups (preferably, having 18 to 30 carbon atoms, and examples thereof include a triphenylsilyl group). These groups may have a substituent(s).

When any of Q^{X11} to Q^{X16} is an atomic group containing a sulfur atom coordinating to M^{X1}, examples of the atomic group coordinating to M^{X1} via a sulfur atom include alkylthio groups (preferably having 1 to 30 carbon atoms, more preferably 1 to 20 carbon atoms, and particularly preferably 1 to 12 carbon atoms, and examples thereof include a methylthio group and an ethylthio group), arylthio groups (preferably having 6 to 30 carbon atoms, more preferably 6 to 20 carbon atoms, and particularly preferably 6 to 12 carbon atoms, and examples thereof include a phenylthio group), heterocyclic thio groups (preferably having 1 to 30 carbon atoms, more preferably 1 to 20 carbon atoms, and particularly preferably 1 to 12 carbon atoms, and examples thereof include a pyridylthio group, a 2-benzimidazolylthio group, a 2-benzoxazolylthio group, and a 2-benzothiazolylthio group), thiocarbonyl groups (e.g., a thioketone group and a thioester group), and thioether groups (e.g., a dialkylthioether group, a diarylthioether group, and a thiofuryl group).

When any of Q^{X11} to Q^{X16} is an atomic group containing a phosphorus atom coordinating to M^{X1}, examples of the atomic group coordinating to M^{X1} via a phosphorus atom include dialkylphosphino groups, diarylphosphino groups, trialkyl phosphines, triaryl phosphines, and phosphinine groups. These groups may have a substituent(s).

The atomic groups represented by Q^{X11} to Q^{X16} are each preferably an aromatic hydrocarbon ring group containing a carbon atom coordinating to M^{X1}, an aromatic heterocyclic group containing a carbon atom coordinating to M^{X1}, a nitrogen-containing aromatic heterocyclic group containing a nitrogen atom coordinating to M^{X1}, an alkyloxy group, an aryloxy group, an alkylthio group, an arylthio group, or an dialkylphosphino group, and more preferably an aromatic hydrocarbon ring group containing a carbon atom coordinating to M^{X1}, an aromatic heterocyclic group containing a carbon atom coordinating to M^{X1}, or a nitrogen-containing aromatic heterocyclic group containing a nitrogen atom coordinating to M^{X1}.

The bond between M^{X1} and each of Q^{X11} to Q^{X16} may be a coordination bond or a covalent bond.

In Formula (II), L^{X11} to L^{X14} each represent a single or double bond or a connecting group. The connecting group is not particularly limited, but preferably a connecting group containing one or more atoms selected from carbon, nitrogen, oxygen, sulfur, and silicon. Examples of the connecting group are shown below, however, the scope of thereof is not limited by these.

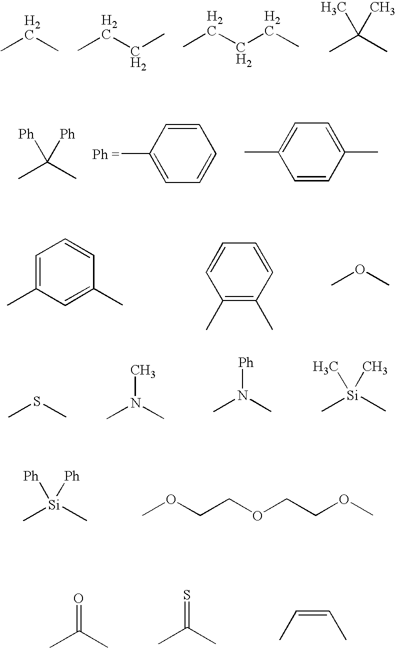

These connecting groups may have a substituent(s), and the substituent may be selected from the examples of the substituents represented by R²¹ to R²⁴ in Formula (1), and the preferable range thereof is also the same as in Formula (1). L^{X11} to L^{X14} are each preferably a single bond, a dimethylmethylene group, or a dimethylsilylene group.

Among compounds represented by Formula (II), compounds represented by the following Formula (X2) are more preferable, and compounds represented by the following Formula (X3) are still more preferable.

The compound represented by Formula (X2) is described first.

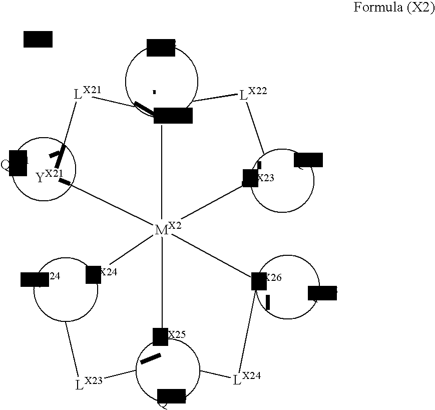

In Formula (X2), M^{X2} represents a metal ion. Y^{X21} to Y^{X26} each represent an atom coordinating to M^{X2}; and Q^{X21} to Q^{X26} each represent an atomic group forming an aromatic ring or an aromatic heterocycle respectively with Y^{X21} to Y^{X26}. L^{X21} to L^{X24} each represent a single or double bond or a connecting group. The bond between M^{X2} and each of Y^{X21} to Y^{X26} may be a coordination bond or a covalent bond.

The compound represented by Formula (X2) will be described below in detail.

In Formula (X2), the definition of M^{X2} is the same as that of M^{X1} in Formula (II), and their preferable ranges are also the same. Y^{X21} to Y^{X26} each represent an atom coordinating to M^{X2}. The bond between M^{X2} and each of Y^{X21} to Y^{X26} may be a coordination bond or a covalent bond. Each of Y^{X21} to Y^{X26} is a carbon atom, a nitrogen atom, an oxygen atom, a sulfur atom, a phosphorus atom, or a silicon atom, and preferably a carbon atom or a nitrogen atom. Q^{X21} to Q^{X26} represent atomic groups forming rings containing Y^{X21} to Y^{X26}, respectively, and the rings are each independently selected from aromatic hydrocarbon rings and aromatic heterocycles. The aromatic hydrocarbon rings and aromatic heterocycles may be selected from a benzene ring, a pyridine ring, a pyrazine ring, a pyrimidine ring, a pyridazine ring, a triazine ring, a pyrrole ring, a pyrazole ring, an imidazole ring, a triazole ring, an oxazole ring, a thiazole ring, an oxadiazole ring, a thiadiazole ring, a thiophene ring, and a furan ring; preferably selected from a benzene ring, a pyridine ring, a pyrazine ring, a pyrimidine ring, a pyrazole ring, an imidazole ring, and a triazole ring; more preferably selected from a benzene ring, a pyridine ring, a pyrazine ring, a pyrazole ring, and a triazole ring; and particularly preferably selected from a benzene ring and a pyridine ring. The aromatic rings may have a condensed ring or a substituent.

The definitions and preferable ranges of L^{X21} to L^{X24} are the same as the definitions and preferable ranges of L^{X11} to L^{X14} in Formula (II), respectively.

Compounds represented by the following Formula (X3) are more preferable examples of the compounds represented by Formula (II).

The compound represented by Formula (X3) will be described below.

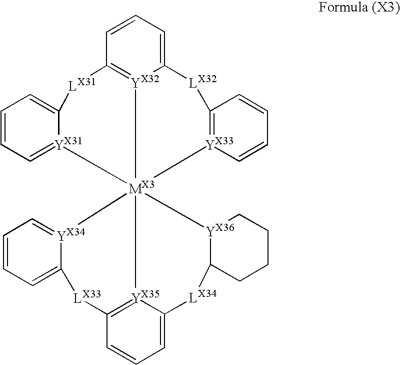

In Formula (X3), M^{X3} represents a metal ion. Y^{X31} to Y^{X36} each represent a carbon atom, a nitrogen atom, or a phosphorus atom. L^{X31} to L^{X34} each represent a single bond, a double bond or a connecting group. The bond between M^{X3} and each of Y^{X31} to Y^{X36} may be a coordination bond or a covalent bond.

The definition of M^{X3} is the same as that of M^{X1} in Formula (II) above, and their preferable ranges are also the same. Y^{X31} to Y^{X36} each represent an atom coordinating to M^{X3}. The bond between M^{X3} and each of Y^{X31} to Y^{X36} may be a coordination bond or a covalent bond. Y^{X31} to Y^{X36} each represent a carbon atom, a nitrogen atom, or a phosphorus atom, and preferably a carbon atom or a nitrogen atom. The definitions and preferable ranges of L^{X31} to L^{X34} are the same as the definitions and preferable ranges of L^{X11} to L^{X14} in Formula (II), respectively.

Specific examples of compounds represented by the Formula (I), (II) or (5) include the compounds (1) to (242) described in JP-A No. 2005-310733 and compounds (243) to (245) (their structures being shown below). The invention is not limited thereto.

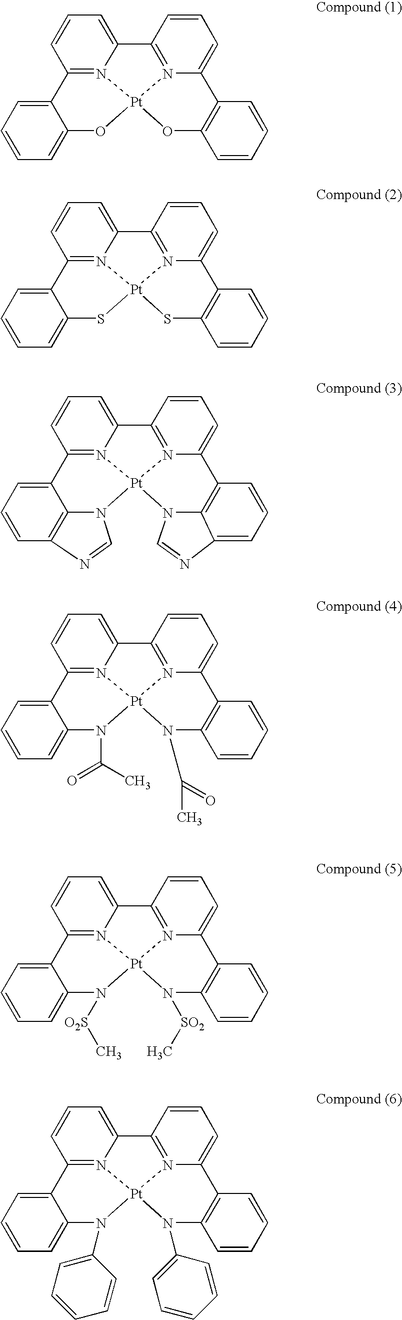

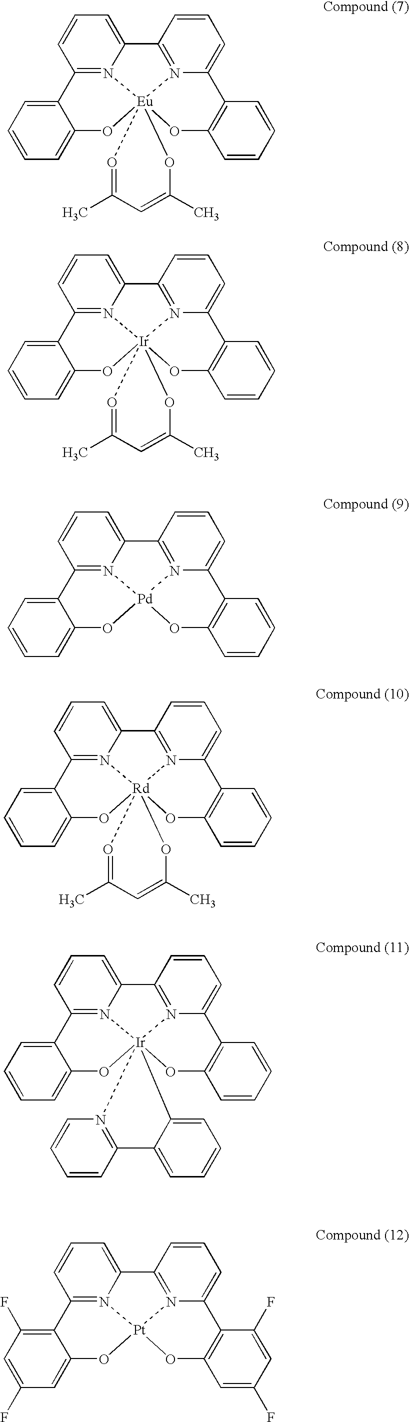

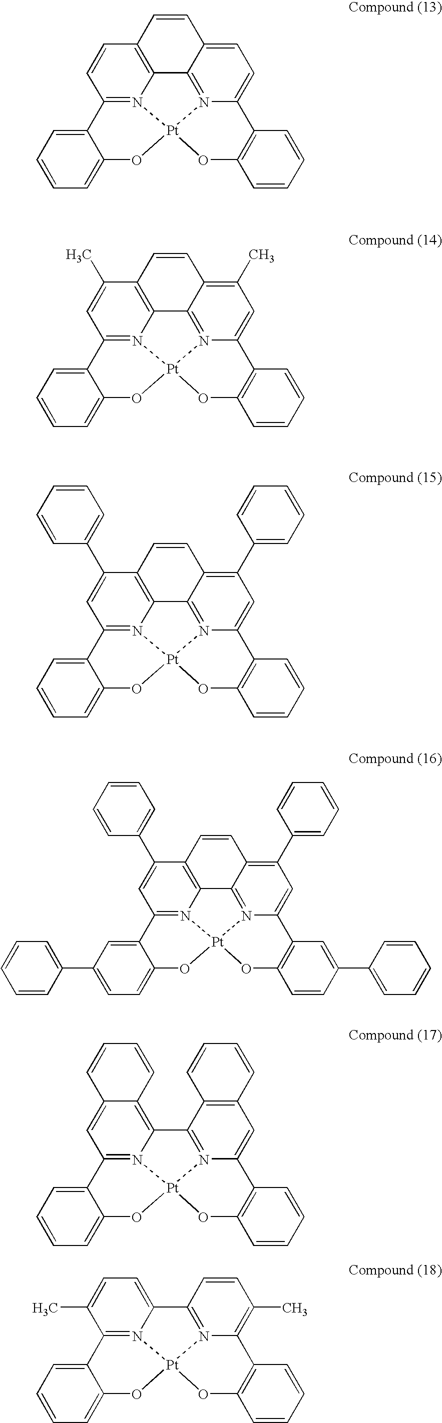

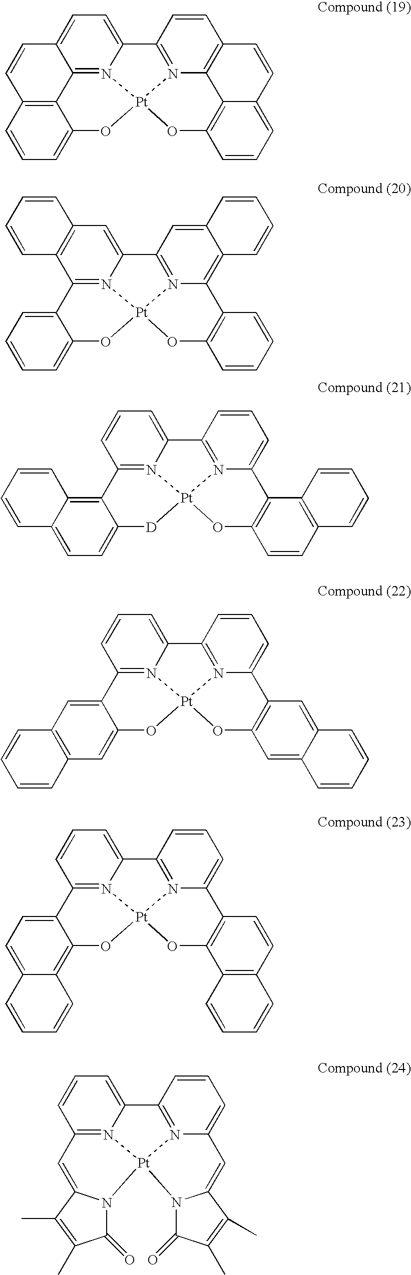

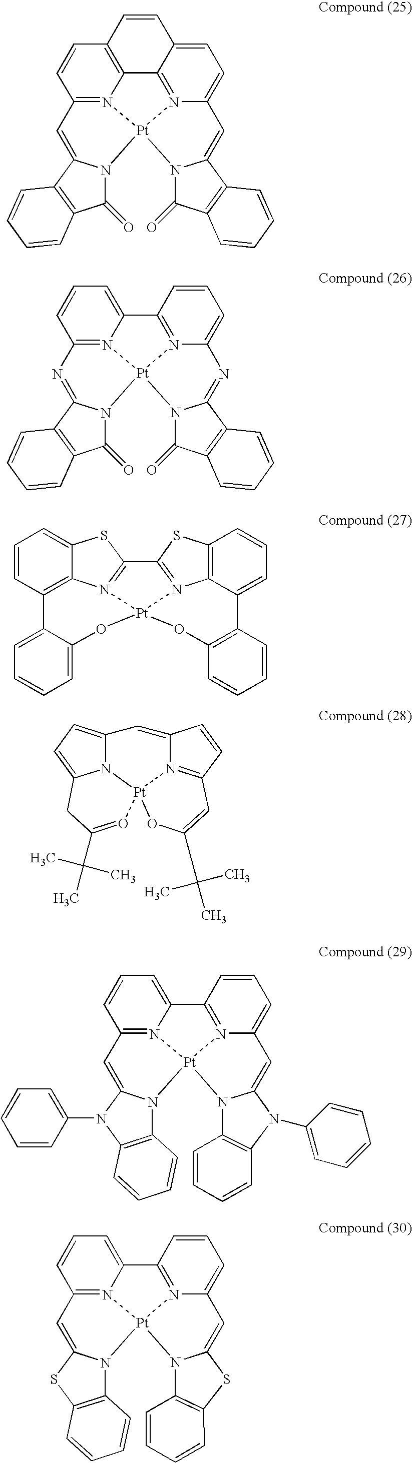

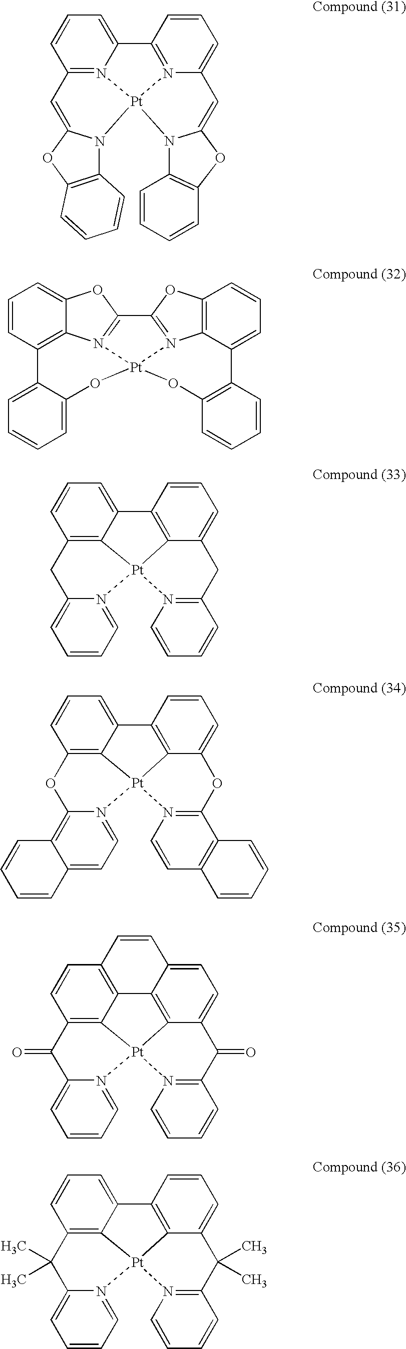

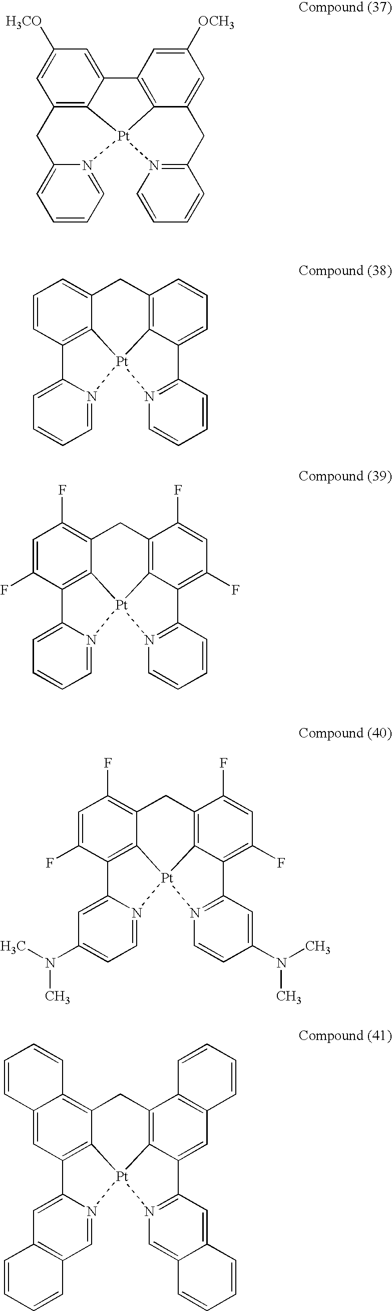

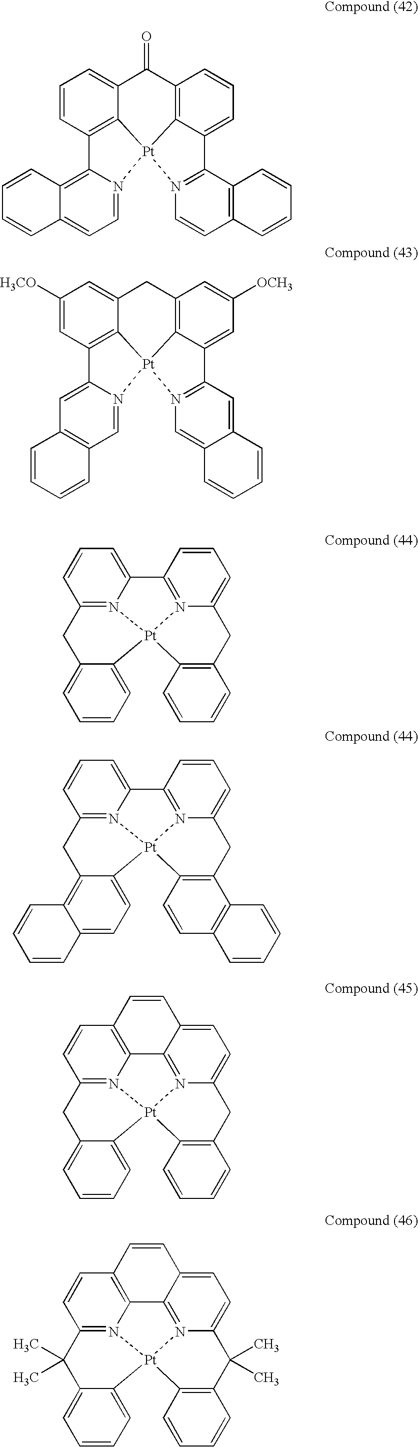

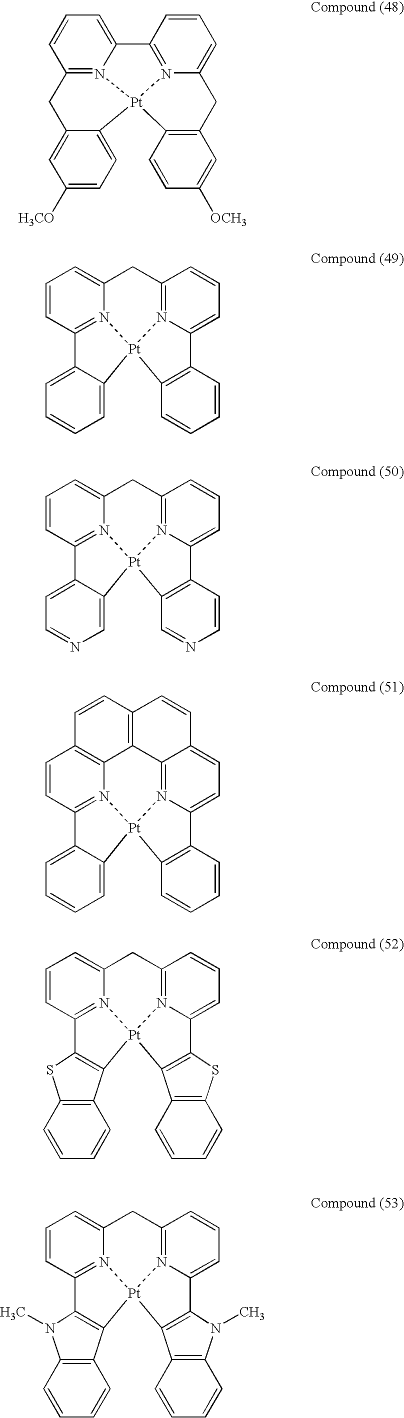

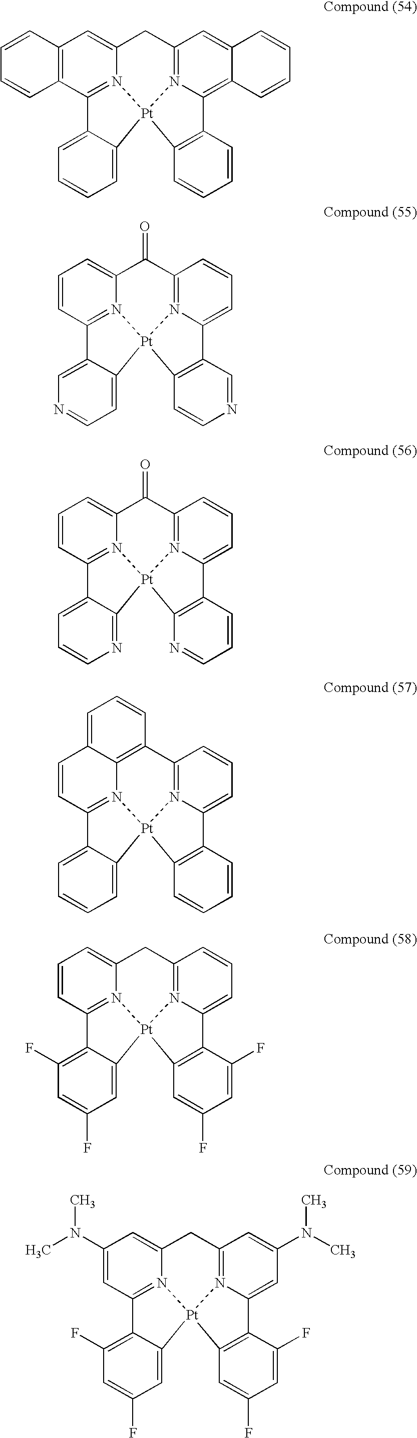

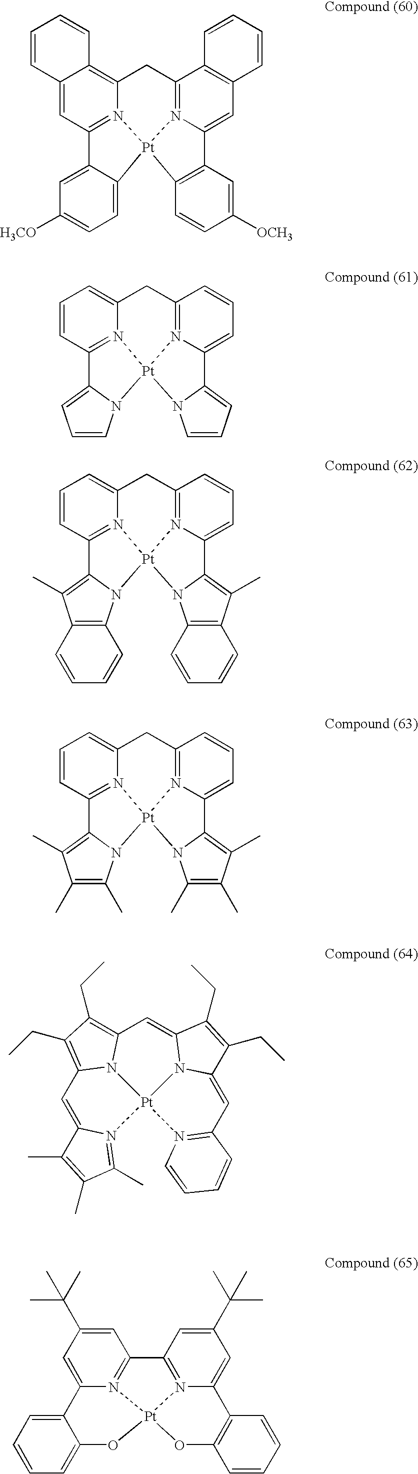

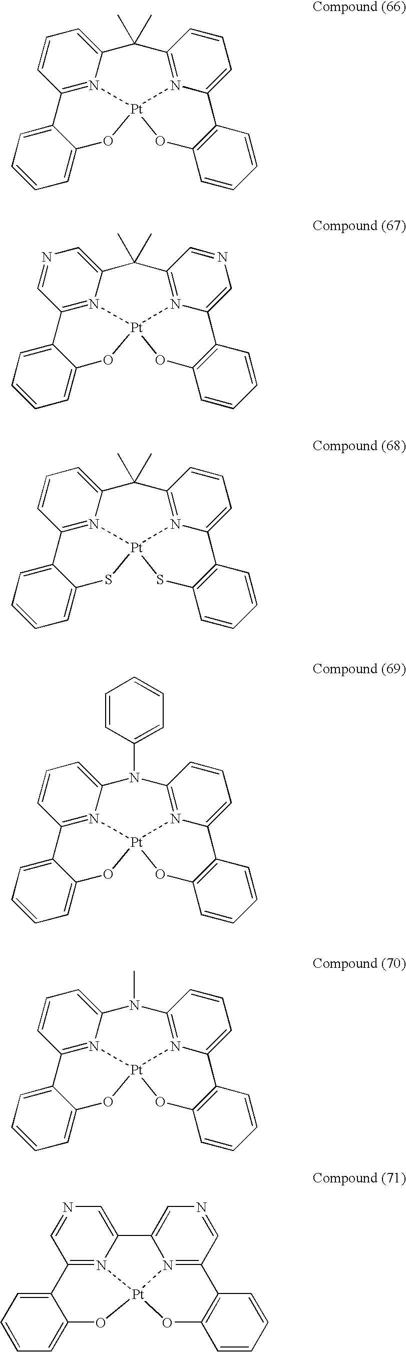

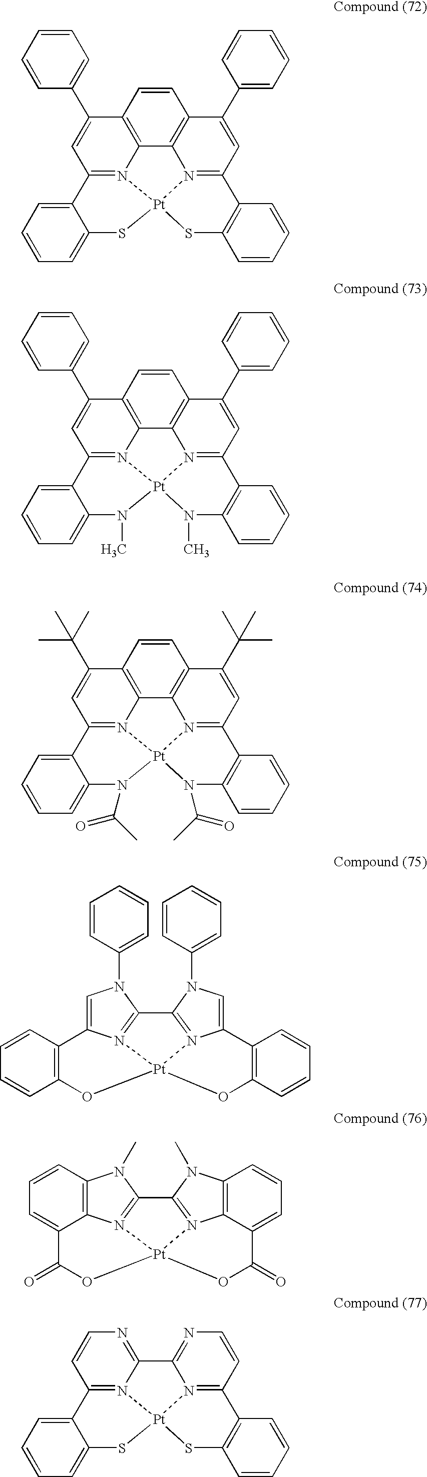

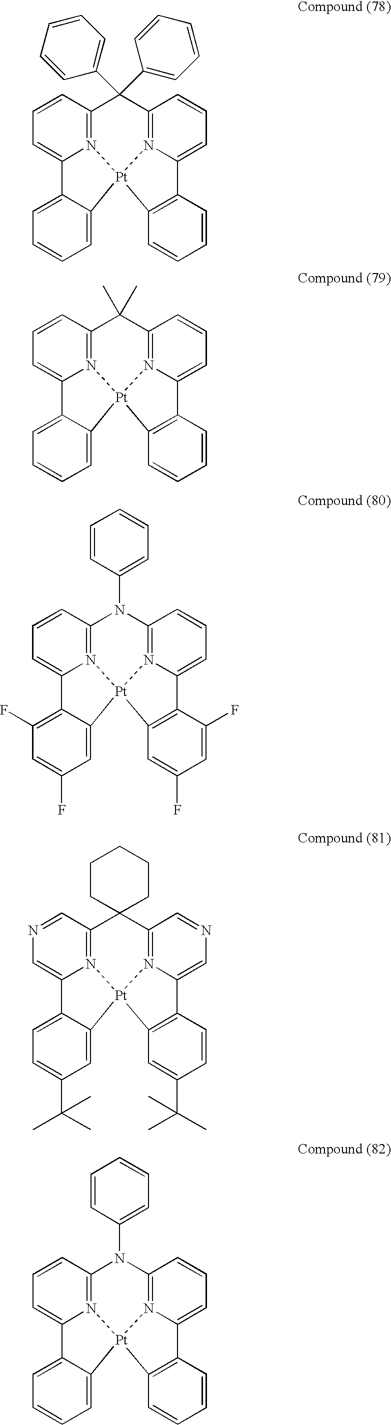

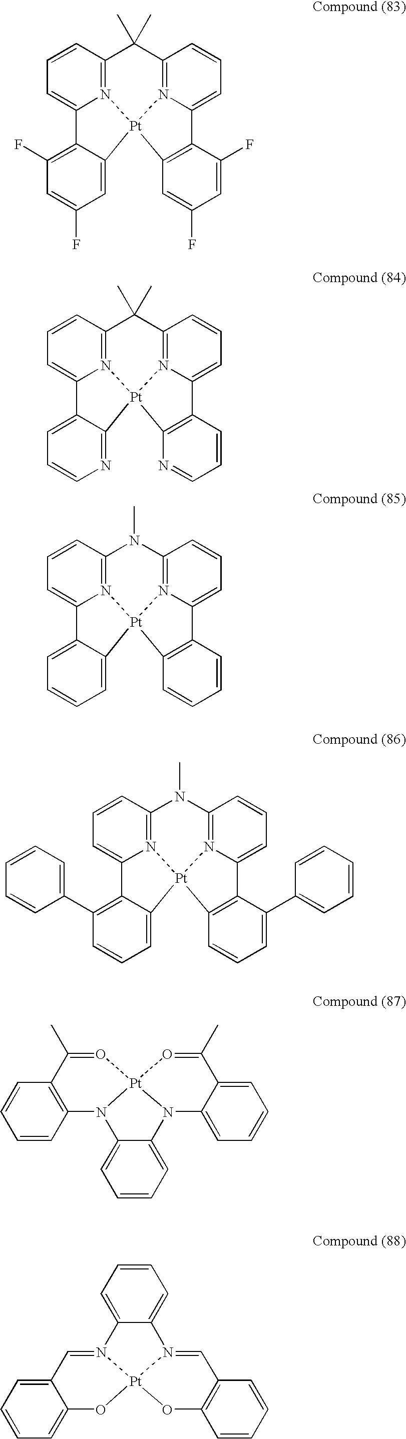

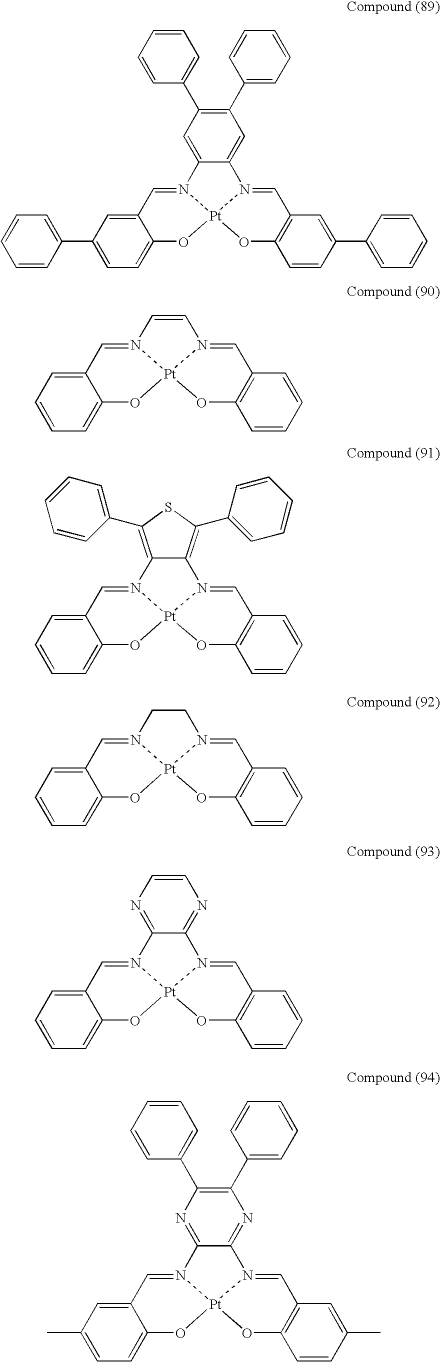

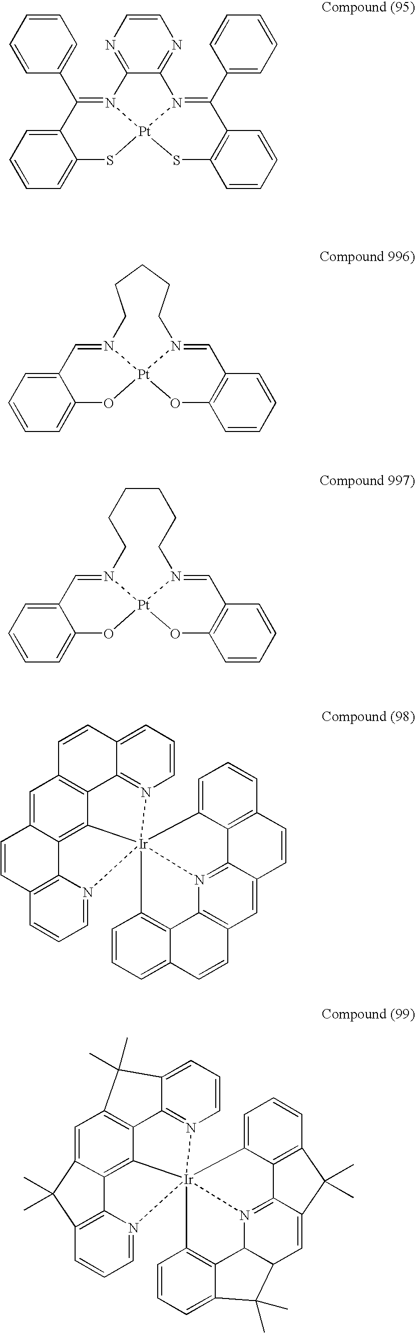

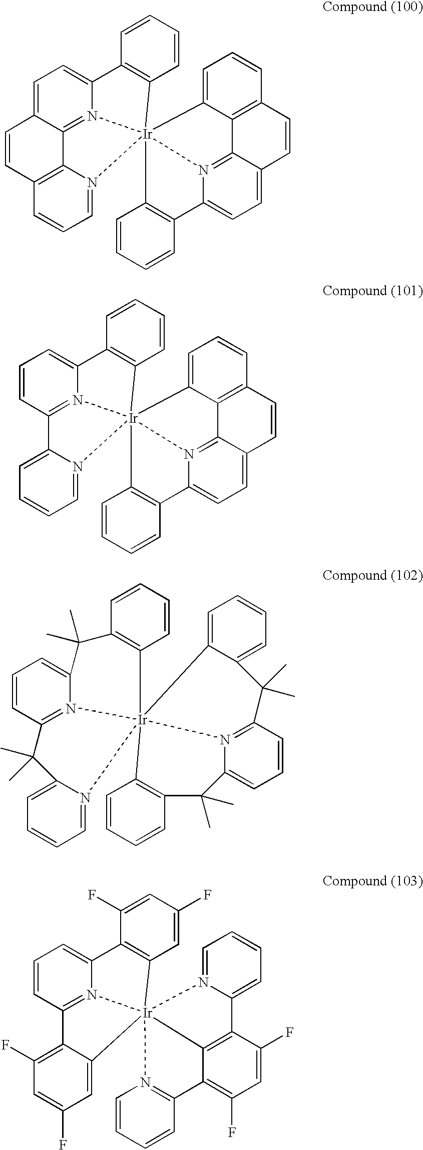

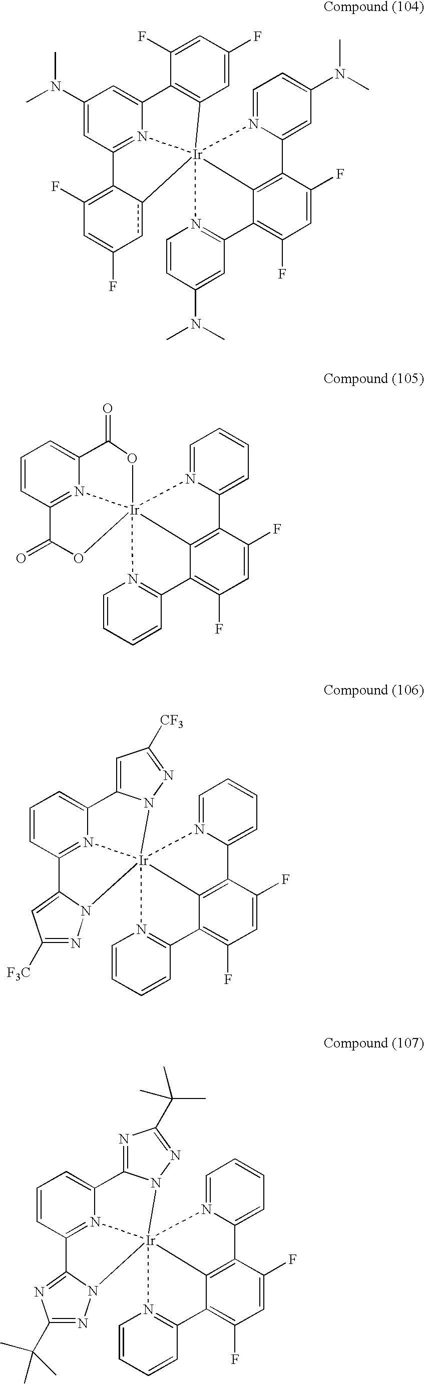

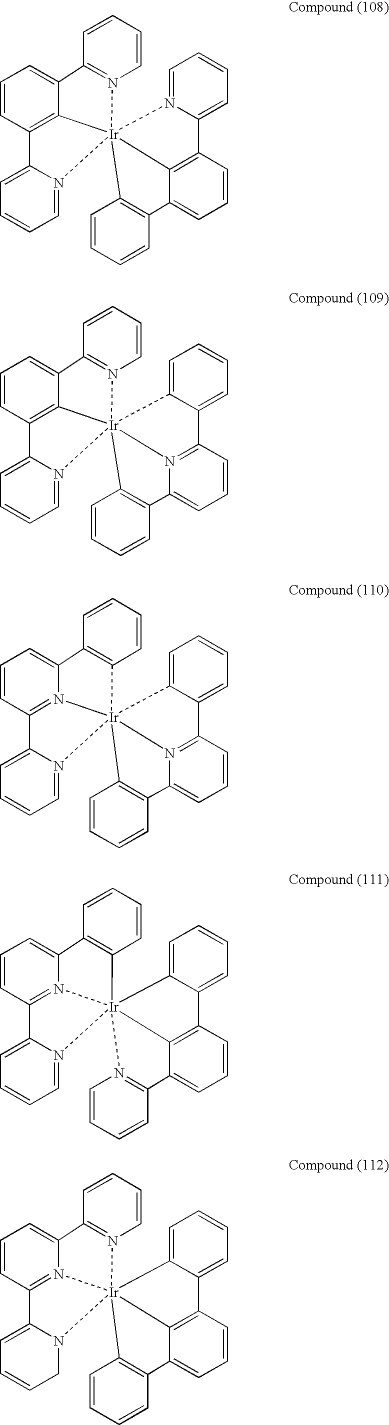

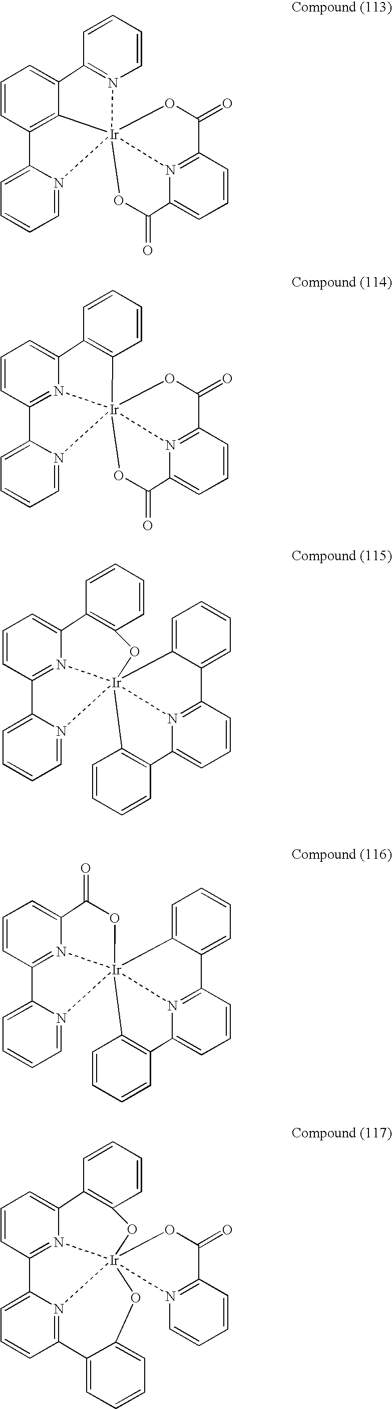

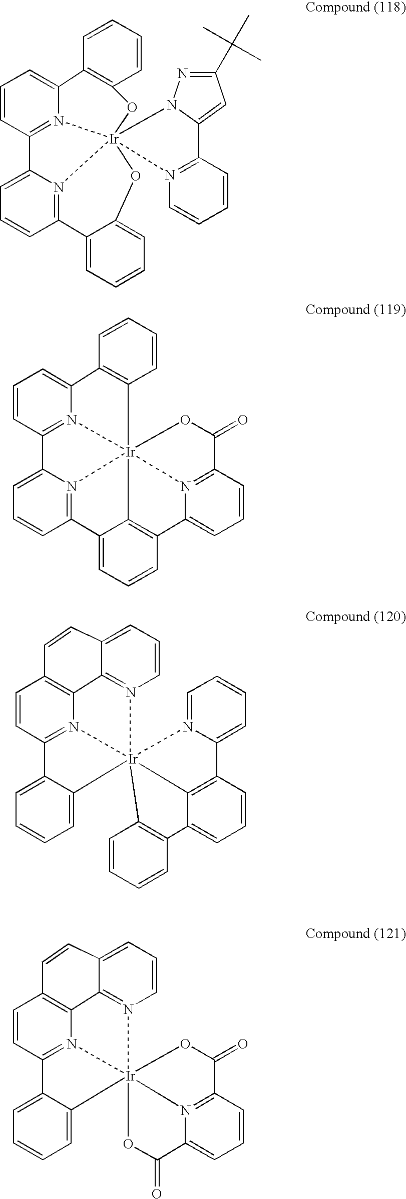

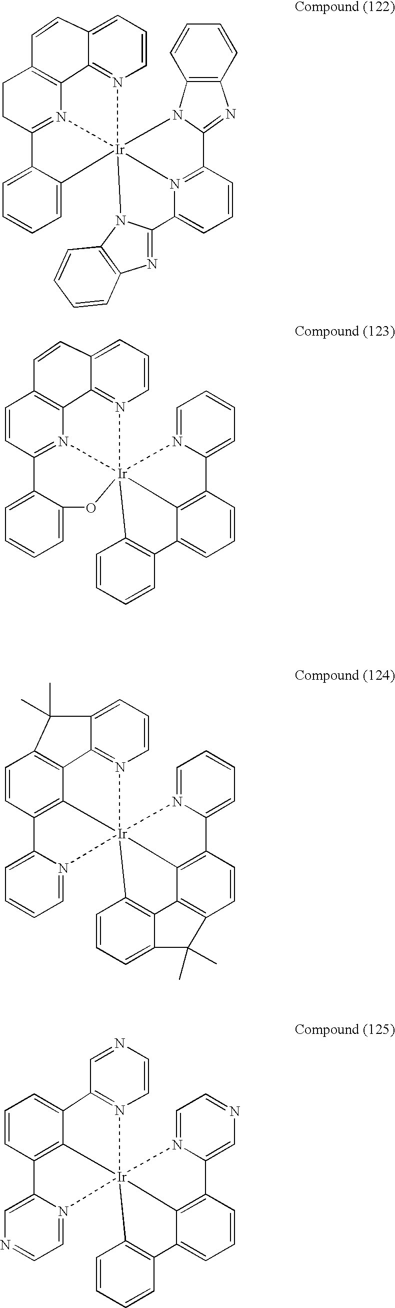

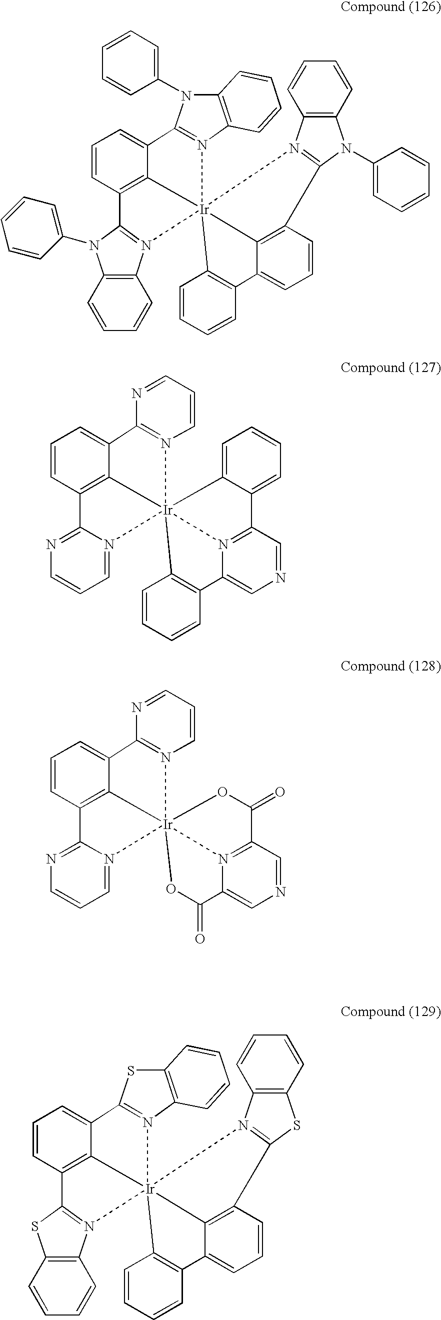

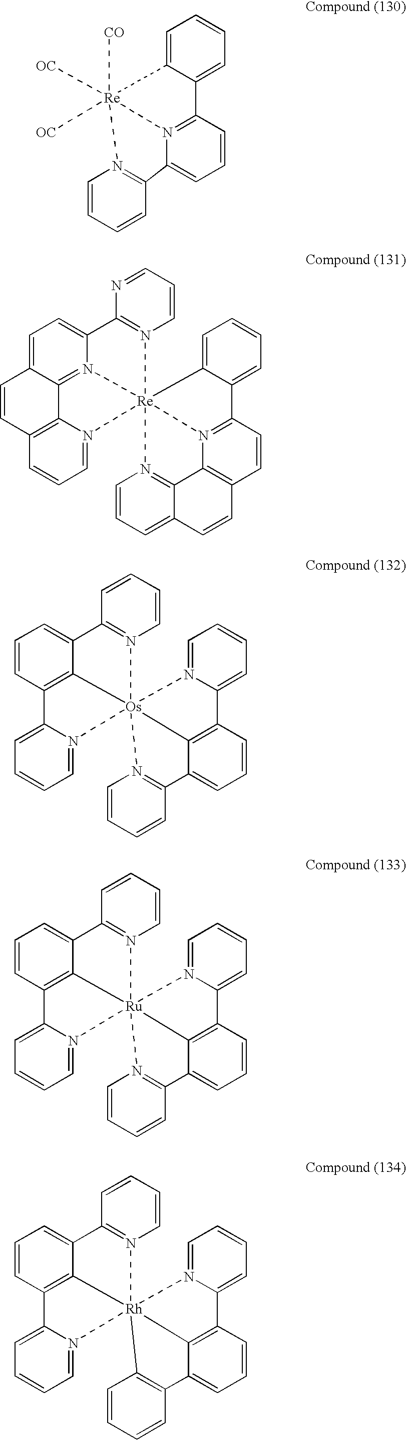

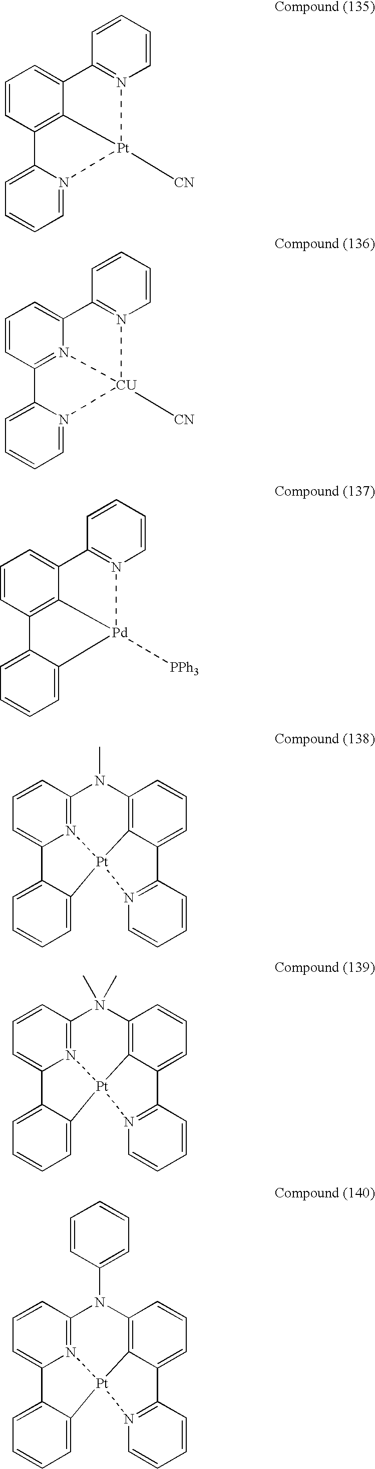

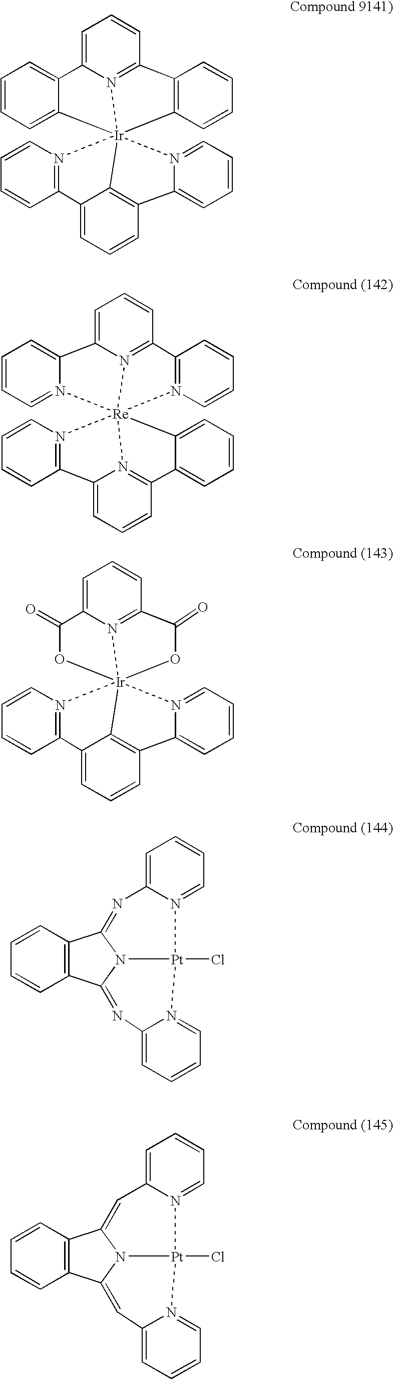

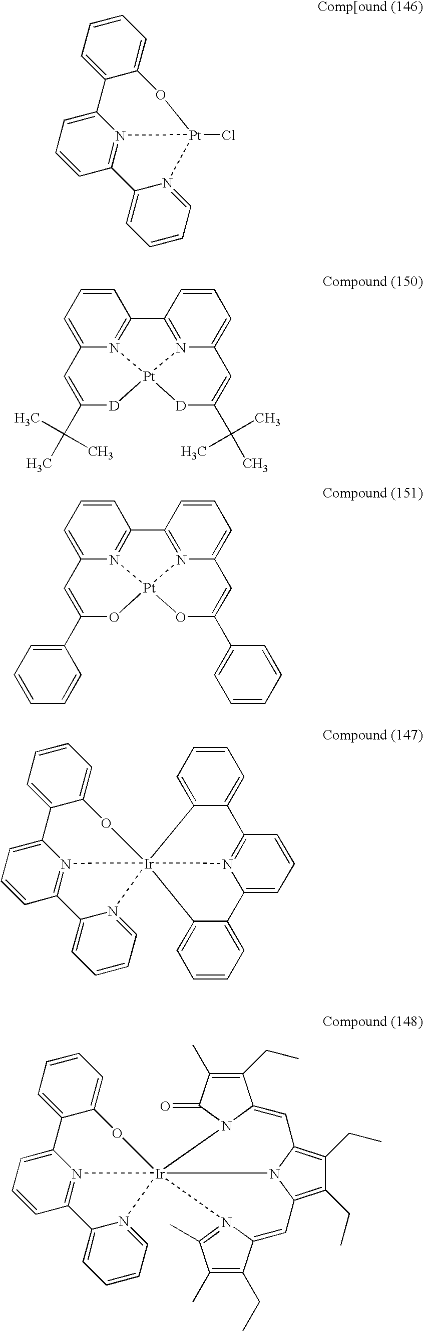

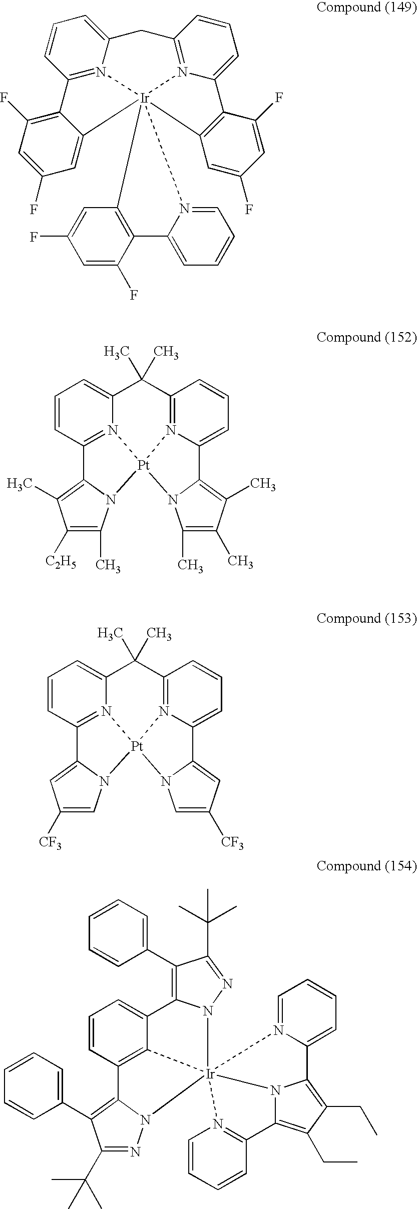

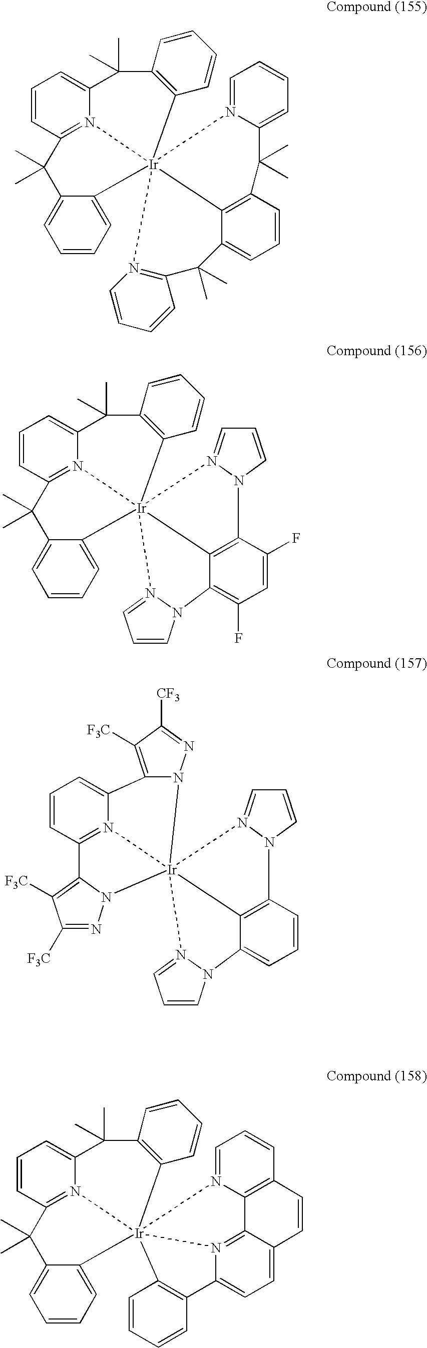

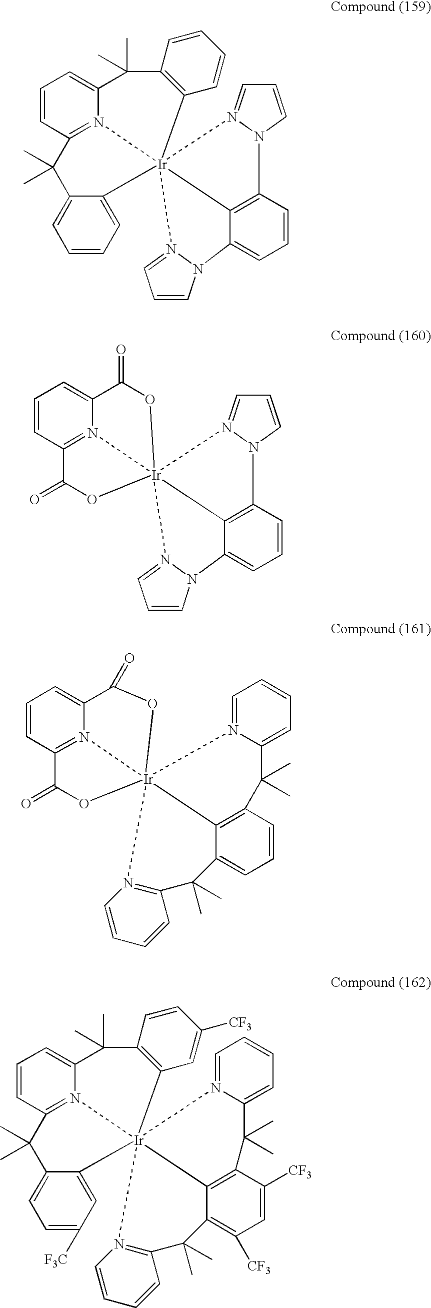

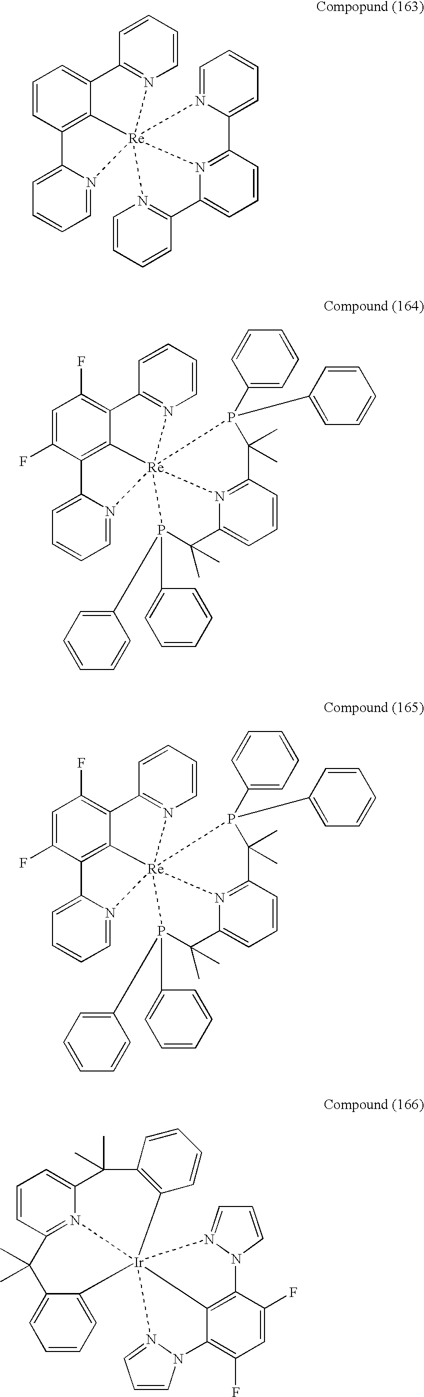

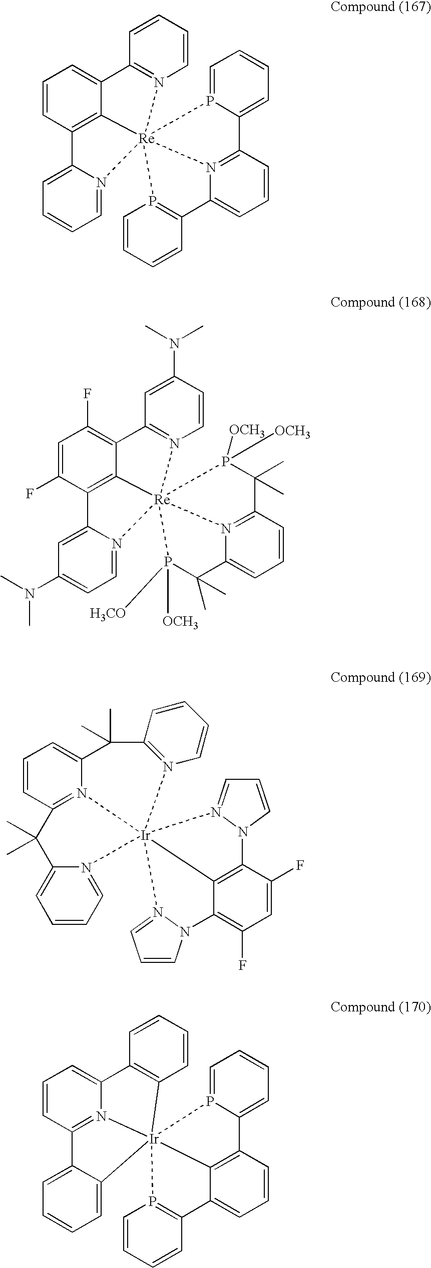

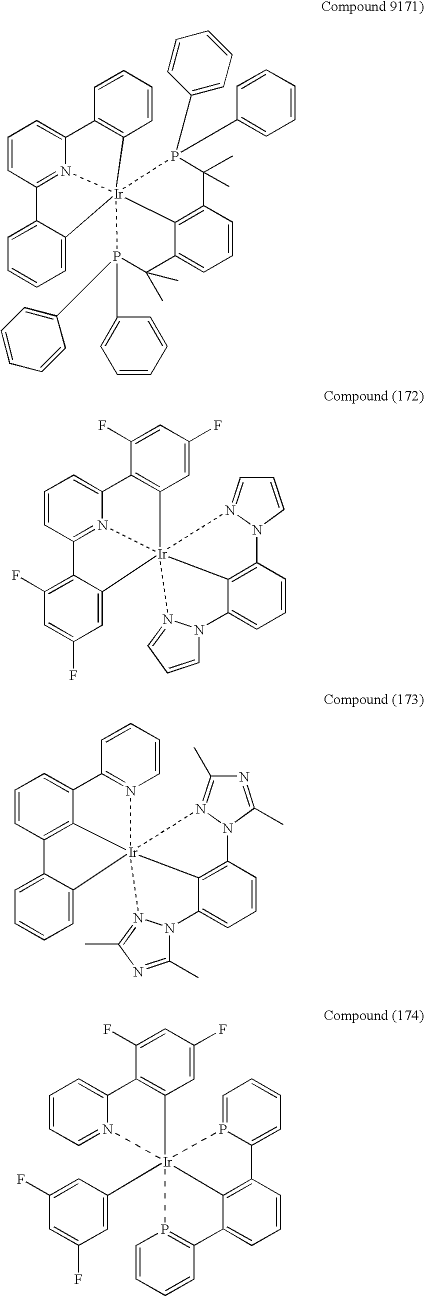

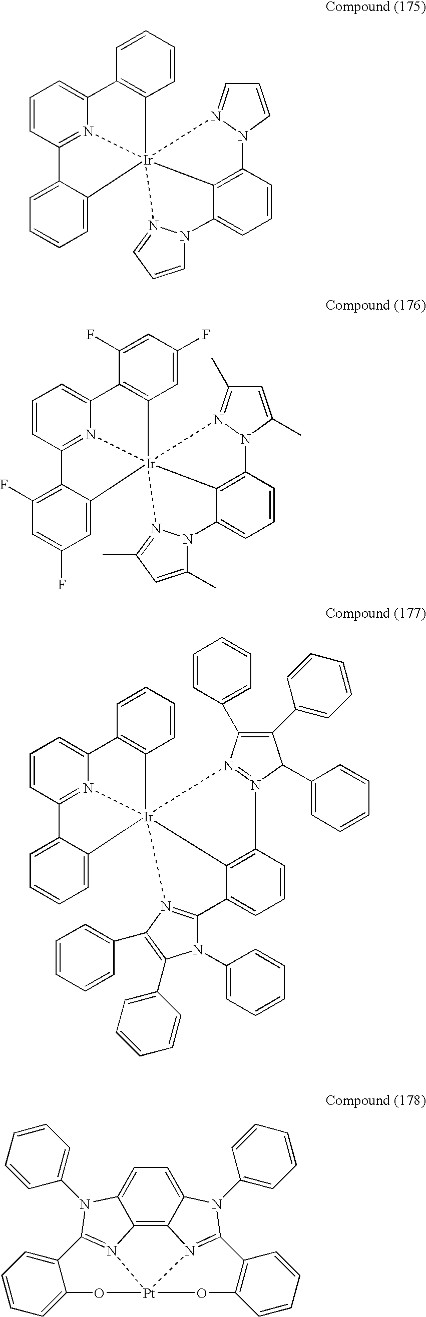

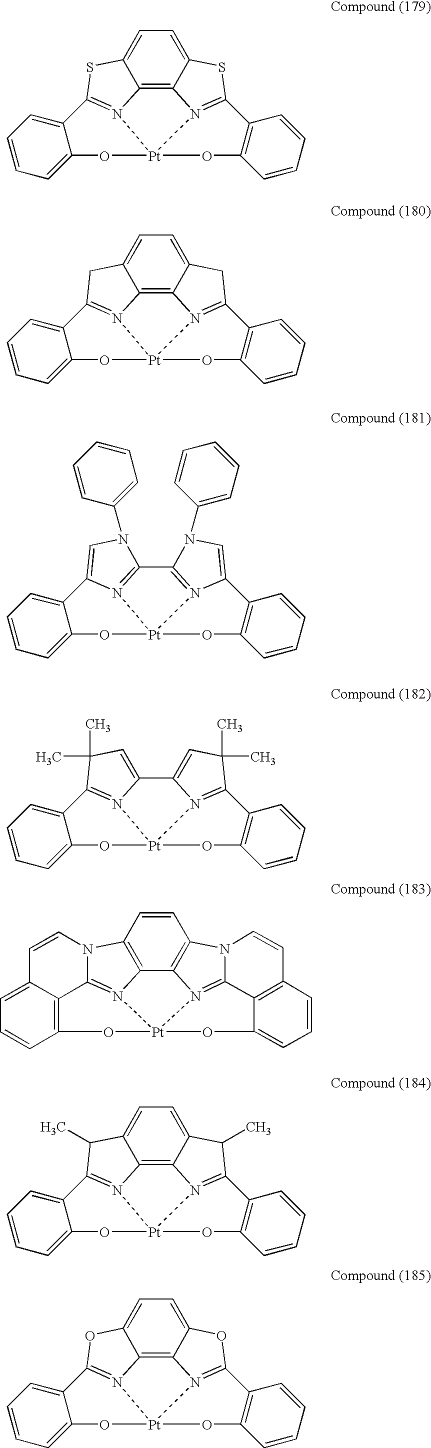

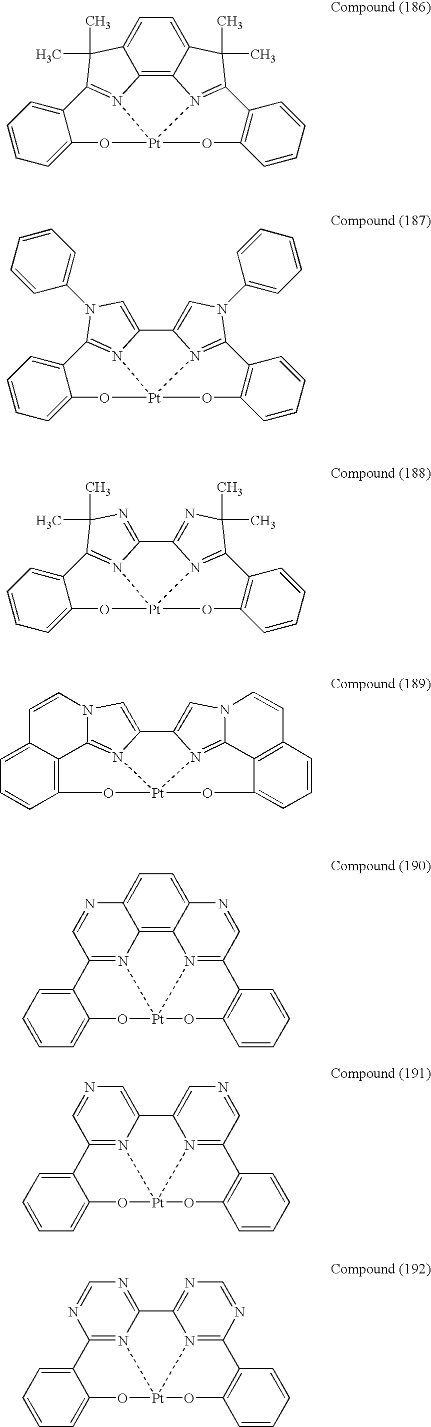

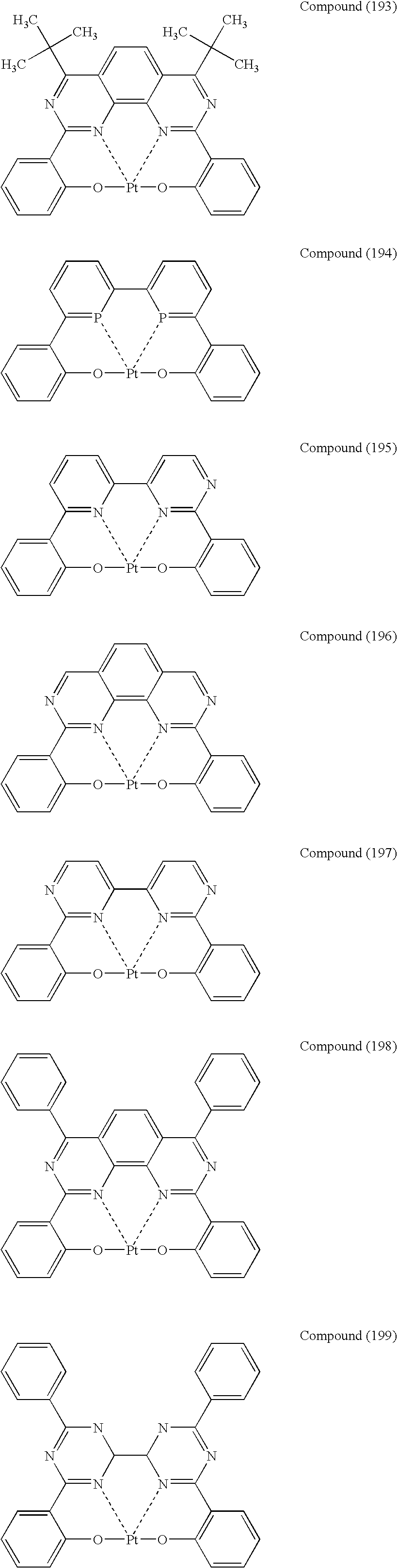

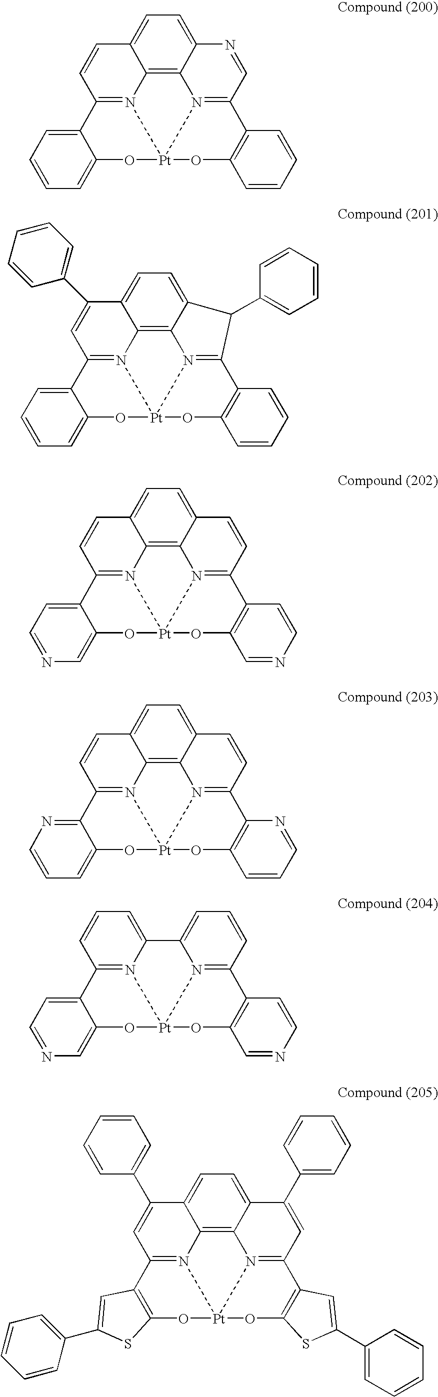

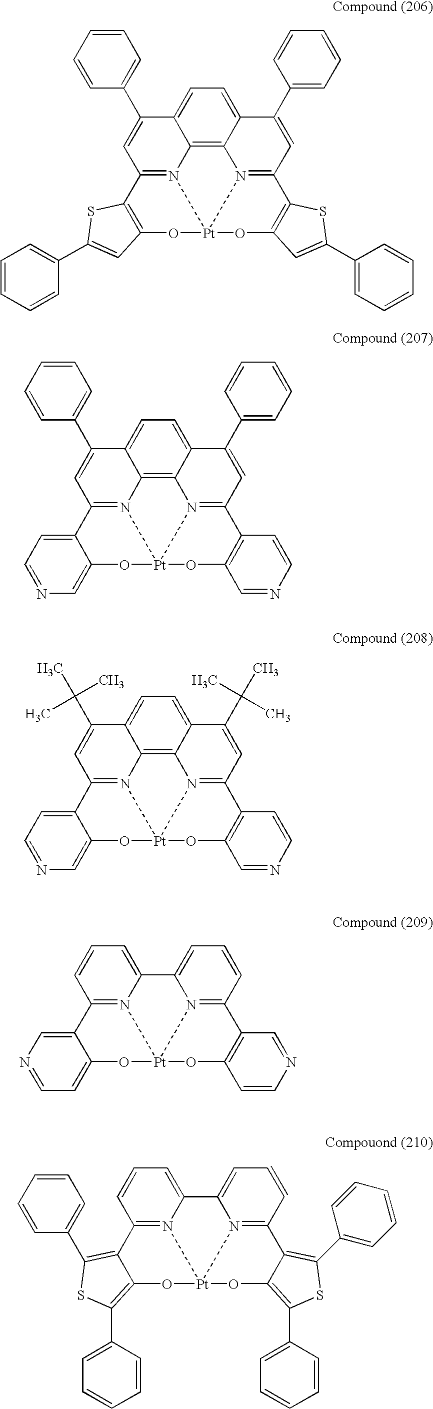

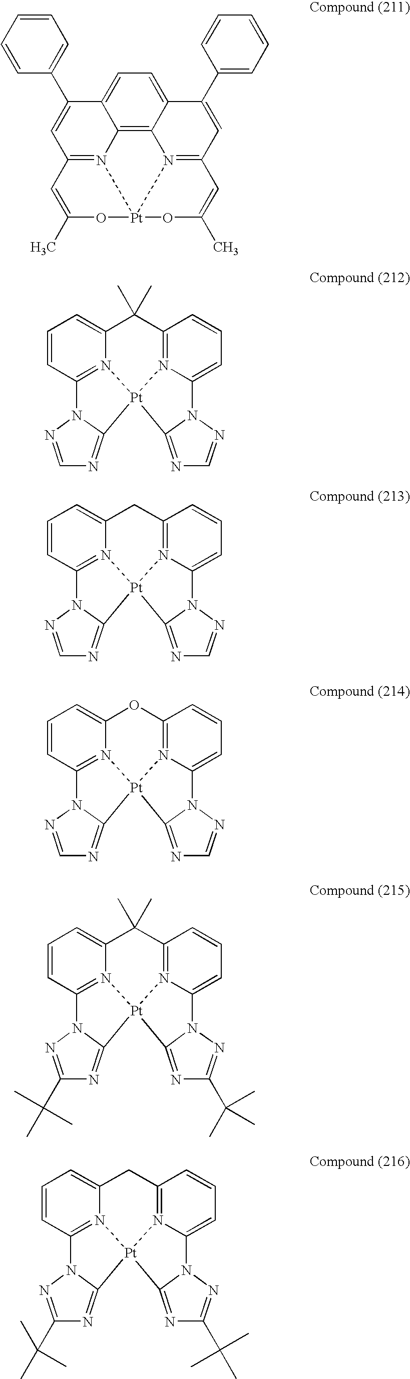

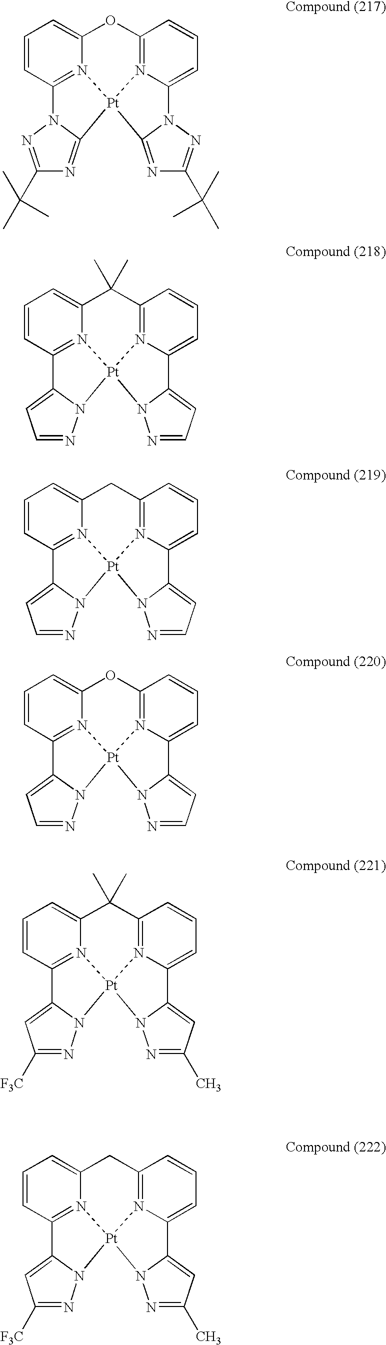

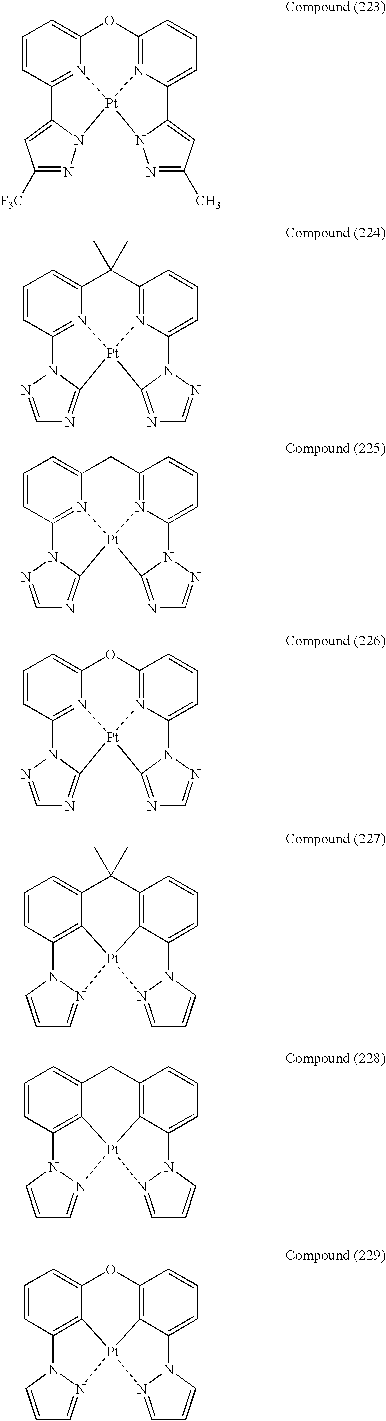

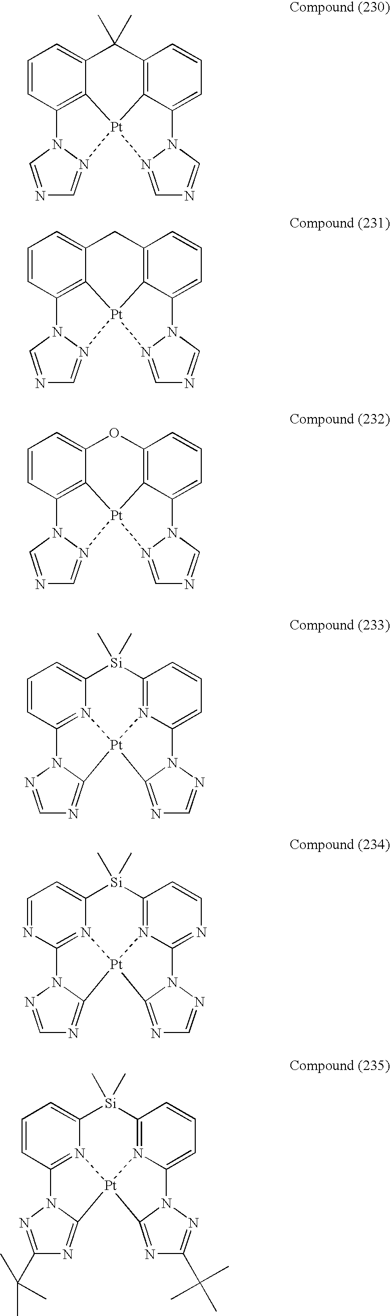

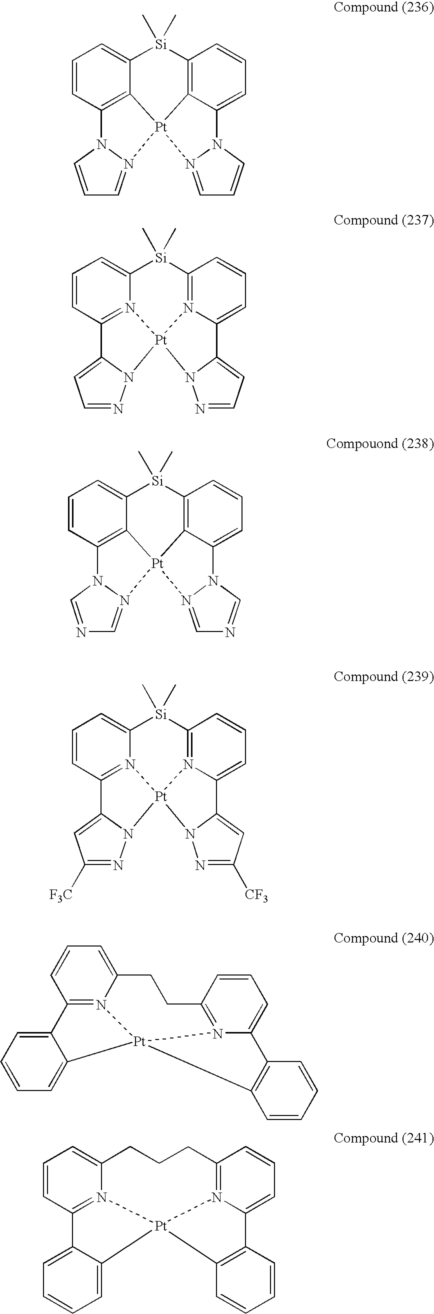

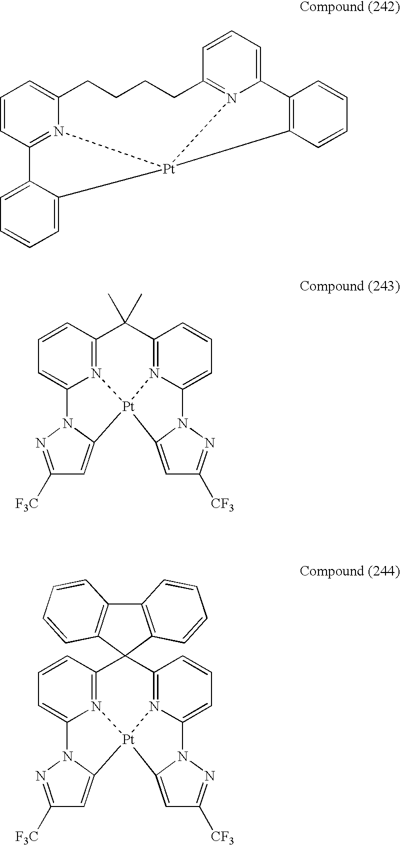

Among compounds represented by the above-mentioned compound examples, other compounds than compounds having a ligand selected from quadridentate ligands containing bipyridyl or phenanthroline in a partial structure thereof, Schiff base type quadridentate ligands, phenylbipyridyl tridentate ligands, diphenylpyridine tridentate ligands, and terpyridine tridentate ligands, are preferable.

Metal complexes in the invention [compounds represented by Formulae (I), (1), (1-A), (2), (3), (3-A), (3-B), (3-C), (4), (4-A), (5), (5-A), (5-B), (II), (X2), and (X3)] can be synthesized by various techniques.

For example, a metal complex can be obtained by a reaction of a ligand (or its dissociated body) and a metal compound in the presence or absence of a solvent (for example, a halogenated solvent, an alcohol solvent, an ether solvent, an ester solvent, a ketone solvent, a nitrile solvent, an amide solvent, a sulfonic solvents, a sulfoxide solvent, or water) in the presence or absence of a base (which may be selected from various inorganic or organic bases, e.g., sodium methoxide, t-butoxy potassium, triethylamine, or potassium carbonate) at room temperature or lower, or under heating (beside the usual heating technique, the technique of heating with a microwave is also effective).

When a metal complex according to the invention is synthesized, the reaction time varies depending on the activity of the reaction raw material, and thus is not particularly limited. The reaction time is preferably from one minute to five days, more preferably from five minutes to three days, and more preferably from ten minutes to one day.

The reaction temperature at synthesis of a metal complex in the invention varies depending on the activity of the reaction, and thus is not particularly limited. The reaction temperature is preferably from 0° C. to 300° C., more preferably from 5° C. to 250° C., and more preferably from 10° C. to 200° C.

Compounds represented by above Formulae (I), (1), (1-A), (2), (3), (3-A), (3-B), (3-C), (4), (4-A), (5), (5-A), (5-B), (II), (X2), and (X3) can be synthesized by appropriately selecting the ligands as partial structures of the desired complex.

For example, the compound represented by the formula (I-A) can be synthesized by adding 6,6′-bis(2-hydroxyphenyl)-2,2′-bipyridyl ligand, its derivative (for example, a 2,9-bis(2-hydroxyphenyl)-1,10-phenanthroline ligand, a 2,9-bis(2-hydroxyphenyl)-4,7-diphenyl-1,10-phenanthroline ligand, or a 6,6′-bis(2-hydroxy-5-tert-butylphenyl)-2,2′-bipyridyl ligand), or the like in an amount of preferably 0.1 to 10 equivalent, more preferably 0.3 to 6 equivalent, and more preferably 0.5 to 4 equivalent relative to the metal compound. In the method for synthesizing the compound represented by the formula (1-A), the reaction solvent, the reaction time, and the reaction temperature are each the same as described above in the method for synthesizing the metal complex according to the invention.

Derivatives of 6,6′-bis(2-hydroxyphenyl)-2,2′-bipyridyl ligand can be synthesized by using various known methods.

For example, a derivative can be synthesized by reacting a 2,2′-bipyridyl derivative (for example, 1,10-phenanthroline) and an anisole derivative (for example, 4-fluoroanisole) by the method described in Journal of Organic Chemistry, 741, 11, (1946). Synthesis can be conducted also by deprotecting a methyl group (by the method described in Journal of Organic Chemistry, 741, 11, (1946), or, for example, by the method of heating in pyridine hydrochloride) after Suzuki coupling reaction using a halogenated 2,2′-bipyridyl derivative (for example, 2,9-dibromo-1,10-phenanthroline) and a 2-methoxy phenylboronate derivative (for example, 2-methoxy-5-fluorophenylboronic acid) or the like as starting materials is carried out. As another alternative, synthesis can be carried out by deprotecting a methyl group (by the method described in Journal of Organic Chemistry, 741, 11, (1946), or, for example, by the method of heating in pyridine hydrochloride) after Suzuki coupling reaction using a 2,2′-bipyridyl boronic acid derivative (for example, 6,6′-bis(4,4,5,5-tetramethyl-1,3,2-dioxabororyl)-2,2′-bipyridyl) and a halogenated anisole derivative (for example, 2-bromo anisole) as starting materials.

In the following, the compounds represented by the following formula (III) will be described.

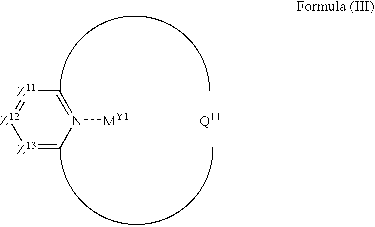

In Formula (III), Q¹¹ represents an atomic group forming a nitrogen-containing heterocycle; Z¹¹, Z¹², and Z¹³ each represent a substituted or unsubstituted carbon or nitrogen atom; and M^{Y1} represents a metal ion that may further have a ligand.

In Formula (III), Q¹¹ represents an atomic group forming a nitrogen-containing heterocycle that contains the two carbon atoms bonded to Q¹¹ and the nitrogen atom directly bonded to the two carbon atoms. The number of atoms constituting the nitrogen-containing heterocycle formed by Q¹¹ is not particularly limited. The cycle of the nitrogen-containing heterocycle contains preferably from 12 to 20 atoms, more preferably from 14 to 16 atoms, and more preferably 16 atoms.

Z¹¹, Z¹², and Z¹³ each independently represent a substituted or unsubstituted carbon or nitrogen atom. As for the combination of Z¹¹, Z¹², and Z¹³, at least one of Z¹¹, Z¹², and Z¹³ is preferably nitrogen.

Examples of the substituent on the carbon atom include alkyl groups (preferably having 1 to 30 carbon atoms, more preferably 1 to 20 carbon atoms, and particularly preferably 1 to 10 carbon atoms, such as methyl, ethyl, iso-propyl, tert-butyl, n-octyl, n-decyl, n-hexadecyl, cyclopropyl, cyclopentyl, and cyclohexyl), alkenyl groups (preferably having 2 to 30 carbon atoms, more preferably 2 to 20 carbon atoms, and particularly preferably 2 to 10 carbon atoms, such as vinyl, allyl, 2-butenyl, and 3-pentenyl), alkynyl groups (preferably having 2 to 30 carbon atoms, more preferably 2 to 20 carbon atoms, and particularly preferably 2 to 10 carbon atoms, such as propargyl and 3-pentynyl),

aryl groups (preferably having 6 to 30 carbon atoms, more preferably 6 to 20 carbon atoms, and particularly preferably 6 to 12 carbon atoms, such as phenyl, p-methylphenyl, naphthyl, and anthranyl), amino groups (preferably having 0 to 30 carbon atoms, more preferably 0 to 20 carbon atoms, and particularly preferably 0 to 10 carbon atoms, such as amino, methylamino, dimethylamino, diethylamino, dibenzylamino, diphenylamino, and ditolylamino), alkoxy groups (preferably having 1 to 30 carbon atoms, more preferably 1 to 20 carbon atoms, and particularly preferably 1 to 10 carbon atoms, such as methoxy, ethoxy, butoxy, and 2-ethylhexyloxy), aryloxy groups (preferably having 6 to 30 carbon atoms, more preferably 6 to 20 carbon atoms, and particularly preferably 6 to 12 carbon atoms, such as phenyloxy, 1-naphthyloxy, and 2-naphthyloxy), heterocyclic oxy groups (preferably having 1 to 30 carbon atoms, more preferably 1 to 20 carbon atoms, and particularly preferably 1 to 12 carbon atoms, such as pyridyloxy, pyrazyloxy, pyrimidyloxy, and quinolyloxy),

acyl groups (preferably having 1 to 30 carbon atoms, more preferably 1 to 20 carbon atoms, and particularly preferably 1 to 12 carbon atoms, such as acetyl, benzoyl, formyl, and pivaloyl), alkoxycarbonyl groups (preferably having 2 to 30 carbon atoms, more preferably 2 to 20 carbon atoms, and particularly preferably 2 to 12 carbon atoms, such as methoxycarbonyl and ethoxycarbonyl), aryloxycarbonyl groups (preferably having 7 to 30 carbon atoms, more preferably 7 to 20 carbon atoms, and particularly preferably 7 to 12 carbon atoms, such as phenyloxycarbonyl), acyloxy groups (preferably having 2 to 30 carbon atoms, more preferably 2 to 20 carbon atoms, and particularly preferably 2 to 10 carbon atoms, such as acetoxy and benzoyloxy), acylamino groups (preferably having 2 to 30 carbon atoms, more preferably 2 to 20 carbon atoms, and particularly preferably 2 to 10 carbon atoms, such as acetylamino and benzoylamino)

alkoxycarbonylamino groups (preferably having 2 to 30 carbon atoms, more preferably 2 to 20 carbon atoms, and particularly preferably 2 to 12 carbon atoms, such as methoxycarbonylamino), aryloxycarbonylamino groups (preferably having 7 to 30 carbon atoms, more preferably 7 to 20 carbon atoms, and particularly preferably 7 to 12 carbon atoms, such as phenyloxycarbonylamino), sulfonylamino groups (preferably having 1 to 30 carbon atoms, more preferably 1 to 20 carbon atoms, and particularly preferably 1 to 12 carbon atoms, such as methanesulfonylamino and benzene sulfonylamino), sulfamoyl groups (preferably having 0 to 30 carbon atoms, more preferably 0 to 20 carbon atoms, and particularly preferably 0 to 12 carbon atoms, such as sulfamoyl, methylsulfamoyl, dimethylsulfamoyl, and phenylsulfamoyl),

carbamoyl groups (preferably having 1 to 30 carbon atoms, more preferably 1 to 20 carbon atoms, and particularly preferably 1 to 12 carbon atoms, such as carbamoyl, methylcarbamoyl, diethylcarbamoyl, and phenylcarbamoyl), alkylthio groups (preferably having 1 to 30 carbon atoms, more preferably 1 to 20 carbon atoms, and particularly preferably 1 to 12 carbon atoms, such as methylthio and ethylthio), arylthio groups (preferably having 6 to 30 carbon atoms, more preferably 6 to 20 carbon atoms, and particularly preferably 6 to 12 carbon atoms, such as phenylthio), heterocyclic thio groups (preferably having 1 to 30 carbon atoms, more preferably 1 to 20 carbon atoms, and particularly preferably 1 to 12 carbon atoms, such as pyridylthio, 2-benzimidazolylthio, 2-benzoxazolylthio, and 2-benzothiazolylthio),

sulfonyl groups (preferably having 1 to 30 carbon atoms, more preferably 1 to 20 carbon atoms, and particularly preferably 1 to 12 carbon atoms, and examples thereof include a mesyl group and a tosyl group), sulfinyl groups (preferably having 1 to 30 carbon atoms, more preferably 1 to 20 carbon atoms, and particularly preferably 1 to 12 carbon atoms, and examples thereof include a methanesulfinyl group and a benzenesulfinyl group), ureido groups (preferably having 1 to 30 carbon atoms, more preferably 1 to 20 carbon atoms, and particularly preferably 1 to 12 carbon atoms, and examples thereof include a ureido group, a methylureido group, and a phenylureido group), phosphoric amide groups (preferably having 1 to 30 carbon atoms, more preferably 1 to 20 carbon atoms, and particularly preferably 1 to 12 carbon atoms, and examples thereof include a diethylphosphoric amide group and a phenylphosphoric amide group), a hydroxy group, a mercapto group, halogen atoms (e.g., fluorine, chlorine, bromine, and iodine),

a cyano group, a sulfo group, a carboxyl group, a nitro group, a hydroxamic acid group, sulfino groups, hydrazino groups, imino groups, heterocyclic groups (preferably having 1 to 30 carbon atoms, and particularly preferably 1 to 12 carbon atoms; the heteroatom(s) may be selected from nitrogen, oxygen and sulfur atoms; examples of the heterocyclic groups include imidazolyl, pyridyl, quinolyl, furyl, thienyl, piperidyl, morpholino, benzoxazolyl, benzimidazolyl, benzothiazolyl, carbazolyl, and azepinyl), silyl groups (preferably having 3 to 40 carbon atoms, more preferably 3 to 30 carbon atoms, and particularly preferably 3 to 24 carbon atoms, and examples thereof include a trimethylsilyl group and a triphenylsilyl group), silyloxy groups (preferably having 3 to 40 carbon atoms, more preferably 3 to 30 carbon atoms, and particularly preferably 3 to 24 carbon atoms, and examples thereof include a trimethylsilyloxy group and a triphenylsilyloxy group), and the like. These substituents may themselves have a substituent.

Among these substituents, the substituent on the carbon atom is preferably an alkyl group, an aryl, a heterocyclic group or a halogen atom, more preferably an aryl group or a halogen atom, and still more preferably a phenyl group or a fluorine atom.

The substituent on the nitrogen atom may be selected from the substituents described as examples of the substituent on the carbon atom, and have the same preferable range as in the case of the substituent on the carbon atom.

In Formula (III), M^{Y1} represents a metal ion that may have an additional ligand. M^{Y1} preferably represents a metal ion having no ligand.

The metal ion represented by M^{Y1} is not particularly limited. It is preferably a divalent or trivalent metal ion. The divalent or trivalent metal ion is preferably a cobalt ion, a magnesium ion, a zinc ion, a palladium ion, a nickel ion, a copper ion, a platinum ion, a lead ion, an aluminum ion, an iridium ion, or a europium ion, more preferably a cobalt ion, a magnesium ion, a zinc ion, a palladium ion, a nickel ion, a copper ion, a platinum ion, or a lead ion, still more preferably a copper ion or a platinum ion, and particularly preferably a platinum ion. M^{Y1} may or may not be bound to an atom contained in Q¹¹, and is preferably bound to an atom contained in Q¹¹.

The additional ligand that M^{Y1} may have is not particularly limited, but is preferably a monodentate or bidentate ligand, and more preferably a bidentate ligand. The coordinating atom is not particularly limited, but preferably an oxygen atom, a sulfur atom, a nitrogen atom, a carbon atom, or a phosphorus atom, more preferably an oxygen atom, a nitrogen atom, or a carbon atom, and still more preferably an oxygen atom or a nitrogen atom.

Preferable examples of compounds represented by Formula (III) include compounds represented by the following Formulae (a) to (j) and the tautomers thereof.

Compounds represented by Formula (III) are more preferably selected from compounds represented by Formula (a) or (b) and tautomers thereof, and still more preferably selected from compounds represented by Formula (b).

Compounds represented by Formula (c) or (g) are also preferable as the compounds represented by Formula (III).

A compound represented by Formula (c) is preferably a compound represented by Formula (d), a tautomer of a compound represented by Formula (d), a compound represented by Formula (e), a tautomer of a compound represented by Formula (e), a compound represented by Formula (f) or a tautomer of a compound represented by Formula (f); more preferably a compound represented by Formula (d), a tautomer of a compound represented by Formula (d), a compound represented by Formula (e), or a tautomer of a compound represented by Formula (e); and still more preferably a compound represented by Formula (d) or a tautomer of a compound represented by Formula (d).

A compound represented by Formula (g) is preferably a compound represented by Formula (h), a tautomer of a compound represented by Formula (h), a compound represented by Formula (i), a tautomer of a compound represented by Formula (i), a compounds represented by Formula (j) or a tautomer of a compounds represented by Formula (j); more preferably a compound represented by Formula (h), a tautomers of a compound represented by Formula (h), a compound represented by Formula (i), or a tautomer of a compound represented by Formula (i); and still more preferably a compound represented by Formula (h) or a tautomer of a compound represented by Formula (h).

Hereinafter, the compounds represented by Formulae (a) to (j) will be described in detail.

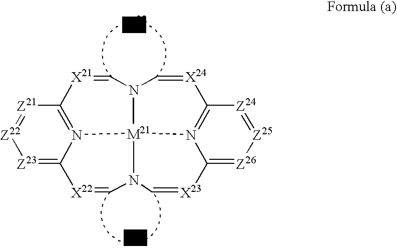

The compound represented by Formula (a) will be described below.

In Formula (a), the definitions and preferable ranges of Z²¹, Z²², Z²³, Z²⁴, Z²⁵, Z²⁶, and M²¹ are the same as the definitions and preferable ranges of corresponding Z¹¹, Z¹², Z¹³, Z¹¹, Z¹², Z¹³, and M^{Y1} in Formula (III), respectively.

Q²¹ and Q²² each represent a group forming a nitrogen-containing heterocycle. Each of the nitrogen-containing heterocycles formed by Q²¹ and Q²² is not particularly limited, but is preferably a pyrrole ring, an imidazole ring, a triazole ring, a condensed ring containing one or more of the above rings (e.g., benzopyrrole), or a tautomer of any of the above rings (e.g., in Formula (b) below, the nitrogen-containing five-membered ring substituted by R⁴³ and R⁴⁴, or by R⁴⁵ and R⁴⁶ is defined as a tautomer of pyrrole), and more preferably a pyrrole ring or a condensed ring containing a pyrrole ring (e.g., benzopyrrole).

X²¹, X²², X²³, and X²⁴ each independently represent a substituted or unsubstituted carbon or nitrogen atom, preferably an unsubstituted carbon or nitrogen atom, and more preferably a nitrogen atom.

The compound represented by Formula (b) will be described below.

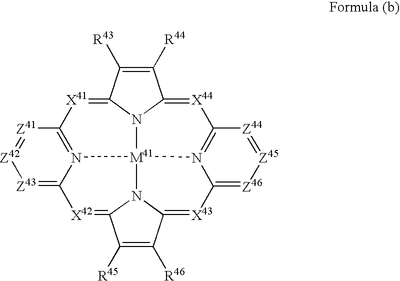

In Formula (b), the definitions and preferable ranges of Z⁴¹, Z⁴², Z⁴³, Z⁴⁴, Z⁴⁵, Z⁴⁶, X⁴¹, X⁴², X⁴³, X⁴⁴, and M⁴¹ are the same as the definitions and preferable ranges of Z²¹, Z²², Z²³, Z²⁴, Z²⁵, Z²⁶, X²¹, X²², X²³, X²⁴, and M²¹ in Formula (a), respectively.

R⁴³, R⁴⁴, R⁴⁵, and R⁴⁶ are each preferably selected from a hydrogen atom or a substituent. The substituent may be selected from the above-described examples of the substituent on the carbon atom represented by Z¹¹ or Z¹² in Formula (III)

R⁴³, R⁴⁴, R⁴⁵, and R⁴⁶ each independently represent a hydrogen atom or a substituent. Examples of the substituent include the groups described above as examples of the substituent on the carbon atom represented by Z¹¹ or Z¹² in Formula (III).

The compound represented by Formula (c) will be described below.

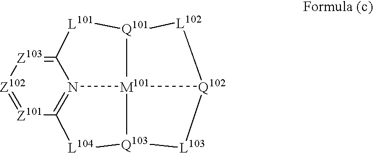

In Formula (c), Z¹⁰¹, Z¹⁰², and Z¹⁰³ each independently represent a substituted or unsubstituted carbon or nitrogen atom. At least one of Z¹⁰¹, Z¹⁰², and Z¹⁰³ is preferably a nitrogen atom.

L¹⁰¹, L¹⁰², L¹⁰³, and L¹⁰⁴ each independently represent a single bond or a connecting group. The connecting group is not particularly limited, and examples thereof include a carbonyl connecting group, an alkylene group, an alkenylene group, an arylene group, a heteroarylene group, a nitrogen-containing heterocycle connecting group, a connecting group which connects moieties via an oxygen atom, an amino connecting group, an imino connecting group, a carbonyl connecting group, and connecting groups comprising combinations thereof.

L¹⁰¹, L¹⁰², L¹⁰³, and L¹⁰⁴ are each preferably a single bond, an alkylene group, an alkenylene group, an amino connecting group, or an imino connecting group, more preferably a single bond, an alkylene connecting group, an alkenylene connecting group, or an imino connecting group, and still more preferably a single bond or an alkylene connecting group.

Q¹⁰¹ and Q¹⁰³ each independently represent a group containing a carbon atom coordinating to M¹⁰¹, a group containing a nitrogen atom coordinating to M¹⁰¹, a group containing a phosphorus atom coordinating to M¹⁰¹, a group containing an oxygen atom coordinating to M¹⁰¹, or a group containing a sulfur atom coordinating to M¹⁰¹.

The group containing a carbon atom coordinating to M¹⁰¹ is preferably an aryl group containing a coordinating carbon atom, a five-membered ring heteroaryl group containing a coordinating carbon atom, or a six-membered ring heteroaryl group containing a coordinating carbon atom; more preferably, an aryl group containing a coordinating carbon atom, a nitrogen-containing five-membered ring heteroaryl group containing a coordinating carbon atom, or a nitrogen-containing six-membered ring heteroaryl group containing a coordinating carbon atom; and still more preferably, an aryl group containing a coordinating carbon atom.

The group containing a nitrogen atom coordinating to M¹⁰¹ is preferably a nitrogen-containing five-membered ring heteroaryl group containing a coordinating nitrogen atom or a nitrogen-containing six-membered ring heteroaryl group containing a coordinating nitrogen atom, and more preferably a nitrogen-containing six-membered ring heteroaryl group containing a coordinating nitrogen atom.

The group containing a phosphorus atom coordinating to M¹⁰¹ is preferably an alkyl phosphine group containing a coordinating phosphorus atom, an aryl phosphine group containing a coordinating phosphorus atom, an alkoxyphosphine group containing a coordinating phosphorus atom, an aryloxyphosphine group containing a coordinating phosphorus atom, a heteroaryloxyphosphine group containing a coordinating phosphorus atom, a phosphinine group containing a coordinating phosphorus atom, or a phosphor group containing a coordinating phosphorus atom; more preferably, an alkyl phosphine group containing a coordinating phosphorus atom or an aryl phosphine group containing a coordinating phosphorus atom.

The group containing an oxygen atom coordinating to M¹⁰¹ is preferably an oxy group or a carbonyl group containing a coordinating oxygen atom, and more preferably an oxy group.

The group containing a sulfur atom coordinating to M¹⁰¹ is preferably a sulfide group, a thiophene group, or a thiazole group, and more preferably a thiophene group.

Each of Q¹⁰¹ and Q¹⁰³ is preferably a group containing a carbon atom coordinating to M¹⁰¹, a group containing a nitrogen atom coordinating to M¹⁰¹, or a group containing a an oxygen atom coordinating to M¹⁰¹; more preferably a group containing a carbon atom coordinating to M¹⁰¹ or a group containing a nitrogen atom coordinating to M¹⁰¹; and still more preferably a group containing a carbon atom coordinating to M¹⁰¹.

Q¹⁰² represents a group containing a nitrogen atom coordinating to M¹⁰¹, a group containing a phosphorus atom coordinating to M¹⁰¹, a group containing an oxygen atom coordinating to M¹⁰¹ or a group containing a sulfur atom coordinating to M¹⁰¹, and preferably a group containing a nitrogen atom coordinating to M¹⁰¹.

The definition of M¹⁰¹ is the same as that of M¹¹ in Formula (I), and their preferable ranges are also the same.

The compound represented by Formula (d) will be described below.

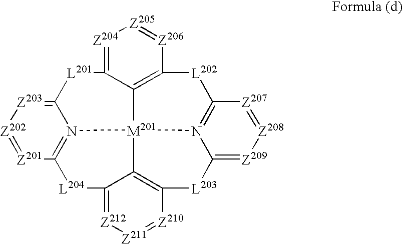

In Formula (d), the definitions and preferable ranges Z²⁰¹, Z²⁰², Z²⁰³, Z²⁰⁷, Z²⁰⁸, Z²⁰⁹, L²⁰¹, L²⁰², L²⁰³, L²⁰⁴, and M²⁰¹ are the same as the definitions and preferable ranges Z¹⁰¹, Z¹⁰², Z¹⁰³, Z¹⁰¹, Z¹⁰², Z¹⁰³, L¹⁰¹, L¹⁰², L¹⁰³, L¹⁰⁴, and M¹⁰¹ in Formula (c), respectively. Z²⁰⁴, Z²⁰⁵, Z²⁰⁶, Z²¹⁰, Z²¹¹, and Z²¹² each represent a substituted or unsubstituted carbon or a substituted or unsubstituted nitrogen atom, and preferably a substituted or unsubstituted carbon atom.

The compound represented by Formula (e) will be described below.

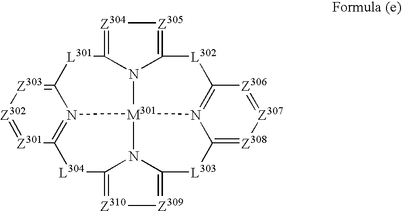

In Formula (e), the definitions and preferable ranges of Z³⁰¹, Z³⁰², Z³⁰³, Z³⁰⁴, Z³⁰⁵, Z³⁰⁶, Z³⁰⁷, Z³⁰⁸, Z³⁰⁹, Z³¹⁰, L³⁰¹, L³⁰², L³⁰³, L³⁰⁴, and M³⁰¹ are the same as the definitions and preferable ranges of corresponding Z²⁰¹, Z²⁰², Z²⁰³, Z²⁰⁴, Z²⁰⁶, Z²⁰⁷, Z²⁰⁸, Z²⁰⁹, Z²¹⁰, Z²¹², L¹⁰¹, L¹⁰², L¹⁰³, L¹⁰⁴, and M¹⁰¹ in formulae (d) and (c), respectively.

The compound represented by Formula (f) will be described below.

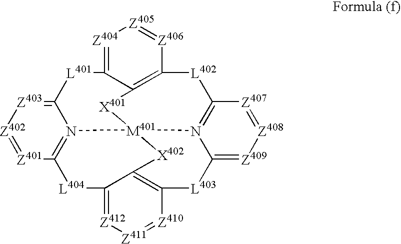

In Formula (f), the definitions and preferable ranges of Z⁴⁰¹, Z⁴⁰², Z⁴⁰³, Z⁴⁰⁴, Z⁴⁰⁵, Z⁴⁰⁶, Z⁴⁰⁷, Z⁴⁰⁸, Z⁴⁰⁹, Z⁴¹⁰, Z⁴¹¹, Z⁴¹², L⁴⁰¹, L⁴⁰², L⁴⁰³, L⁴⁰⁴, and M⁴⁰¹ are the same as the definitions and preferable ranges of corresponding Z²⁰¹, Z²⁰², Z²⁰³, Z²⁰⁴, Z²⁰⁵, Z²⁰⁶, Z²⁰⁷, Z²⁰⁸, Z²⁰⁹, Z²¹⁰, Z²¹¹, Z²¹², L¹⁰¹, L¹⁰², L¹⁰³, L¹⁰⁴, and M¹⁰¹ in formulae (d) and (c), respectively. X⁴⁰¹ and X⁴⁰² each represent an oxygen atom or a substituted or unsubstituted nitrogen or a sulfur atom, preferably an oxygen atom or a substituted nitrogen atom, and more preferably an oxygen atom.

The compound represented by Formula (g) will be described below.

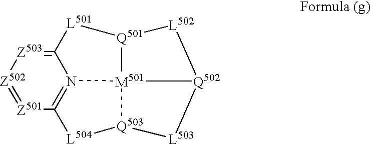

In Formula (g), the definitions and preferable ranges of Z⁵⁰¹, Z⁵⁰², Z⁵⁰³, L⁵⁰¹, L⁵⁰², L⁵⁰³, L⁵⁰⁴, Q⁵⁰¹, Q⁵⁰², Q⁵⁰³, and M⁵⁰¹ are the same as the definitions and preferable ranges of corresponding Z¹⁰¹, Z¹⁰², Z¹⁰³, L¹⁰¹, L¹⁰², L¹⁰³, L¹⁰⁴, Q¹⁰¹, Q¹⁰³, Q¹⁰², and M¹⁰¹ in Formula (c), respectively.

The compound represented by Formula (h) will be described below.

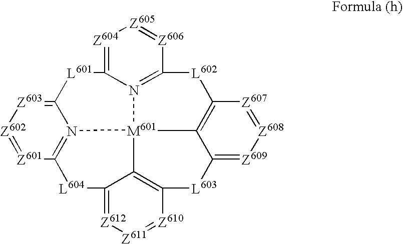

In Formula (h), the definitions and preferable ranges of Z⁶⁰¹, Z⁶⁰², Z⁶⁰³, Z⁶⁰⁴, Z⁶⁰⁵, Z⁶⁰⁶, Z⁶⁰⁷, Z⁶⁰⁸, Z⁶⁰⁹, Z⁶¹⁰, Z⁶¹¹, Z⁶¹², L⁶⁰¹, L⁶⁰², L⁶⁰³, L⁶⁰⁴, and M⁶⁰¹ are the same as the definitions and preferable ranges of corresponding Z²⁰¹, Z²⁰², Z²⁰³, Z²⁰⁷, Z²⁰⁸, Z²⁰⁹, Z²⁰⁴, Z²⁰⁵, Z²⁰⁶, Z²¹⁰, Z²¹¹, Z²¹², L¹⁰¹, L¹⁰², L¹⁰³, L¹⁰⁴, and M¹⁰¹ in Formulae (d) and (c), respectively.

The compound represented by Formula (i) will be described below.

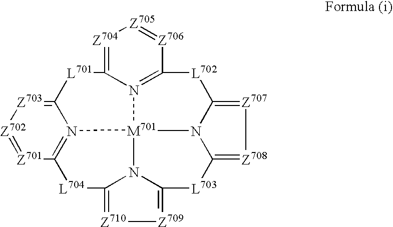

In Formula (i), the definitions and preferable ranges of Z⁷⁰¹, Z⁷⁰², Z⁷⁰³, Z⁷⁰⁴, Z⁷⁰⁵, Z⁷⁰⁶, Z⁷⁰⁷, Z⁷⁰⁸, Z⁷⁰⁹, Z⁷¹⁰, L⁷⁰¹, L⁷⁰², L⁷⁰³, L⁷⁰⁴, and M⁷⁰¹ are the same as the definitions and preferable ranges of corresponding Z²⁰¹, Z²⁰², Z²⁰³, Z²⁰⁷, Z²⁰⁸, Z²⁰⁹, Z²⁰⁴, Z²⁰⁶, Z²¹⁰, Z²¹², L¹⁰¹, L¹⁰², L¹⁰³, L¹⁰⁴, and M¹⁰¹ in Formulae (d) and (c), respectively.

The compound represented by Formula (j) will be described below.

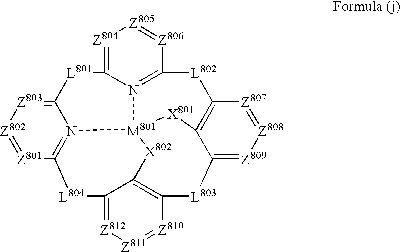

In Formula (j), the definitions and preferable ranges of Z⁸⁰¹, Z⁸⁰², Z⁸⁰³, Z⁸⁰⁴, Z⁸⁰⁵, Z⁸⁰⁶, Z⁸⁰⁷, Z⁸⁰⁸, Z⁸⁰⁹, Z⁸¹⁰, Z⁸¹¹, Z⁸¹², L⁸⁰¹, L⁸⁰², L⁸⁰³, L⁸⁰⁴, M⁸⁰¹, X⁸⁰¹, and X⁸⁰² are the same as the definitions and preferable ranges of corresponding Z²⁰¹, Z²⁰², Z²⁰³, Z²⁰⁷, Z²⁰⁸, Z²⁰⁹, Z²⁰⁴, Z²⁰⁵, Z²⁰⁶, Z²¹⁰, Z²¹¹, Z²¹², L¹⁰¹, L¹⁰², L¹⁰³, L¹⁰⁴, M¹⁰¹, X⁴⁰¹ and X⁴⁰² in Formulae (d), (c), and (f), respectively.

Specific examples of compounds represented by Formula (III) include compounds (2) to (8), compounds (15) to (20), compound (27) to (32), compounds (36) to (38), compounds (42) to (44), compounds (50) to (52), and compounds (57) to (154) described in Japanese Patent Application No. 2004-88575, the disclosure of which is incorporated herein by reference. The structures of the above compounds are shown below, however, the scope of the invention is not limited thereto.

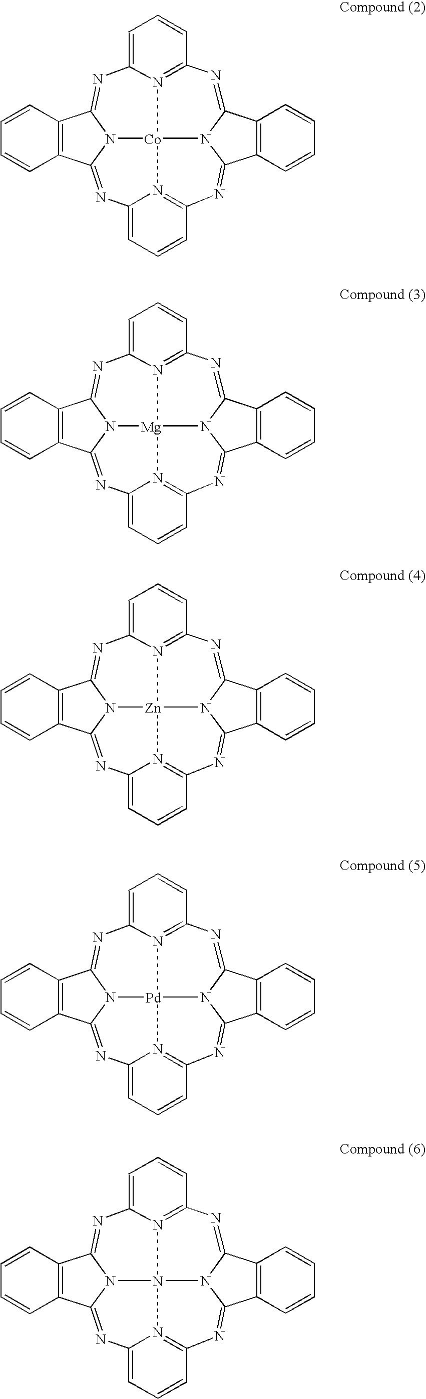

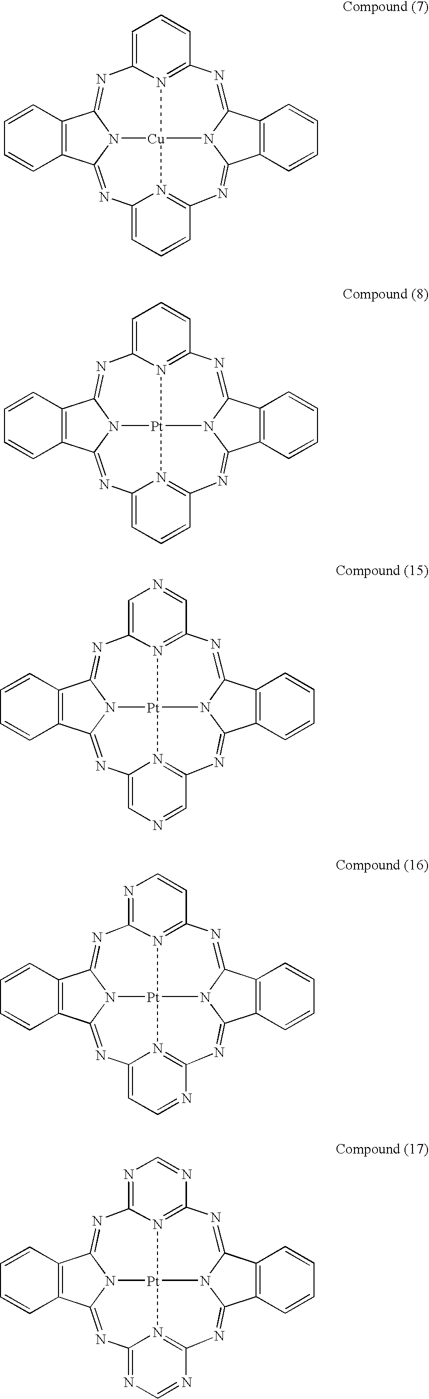

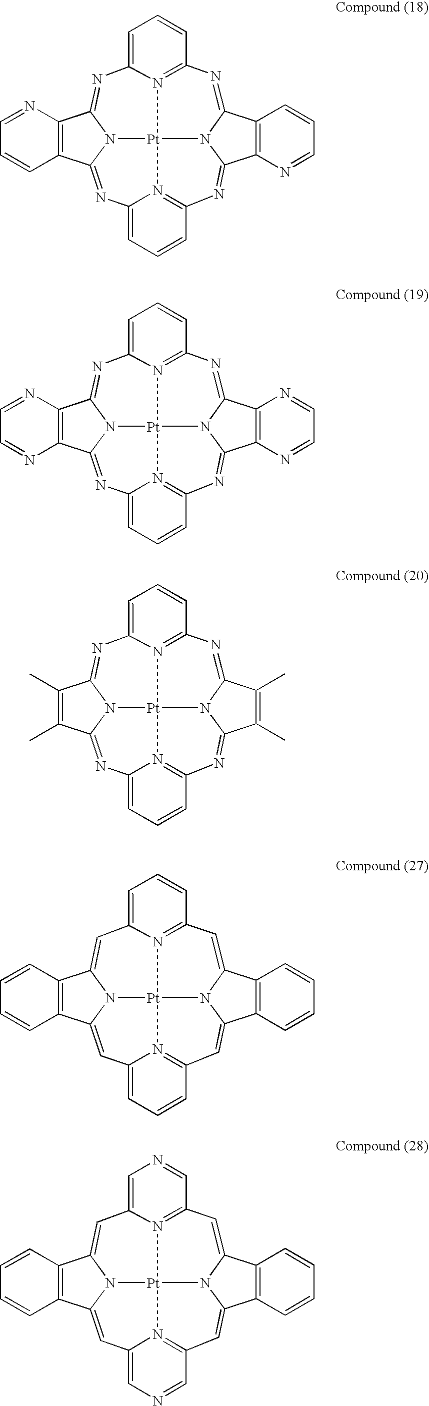

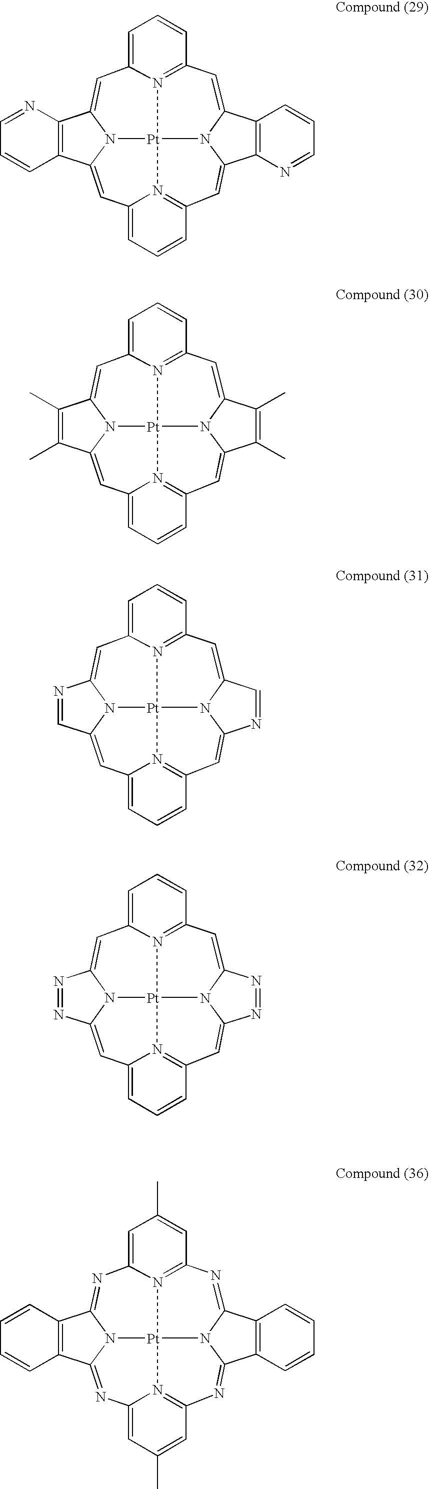

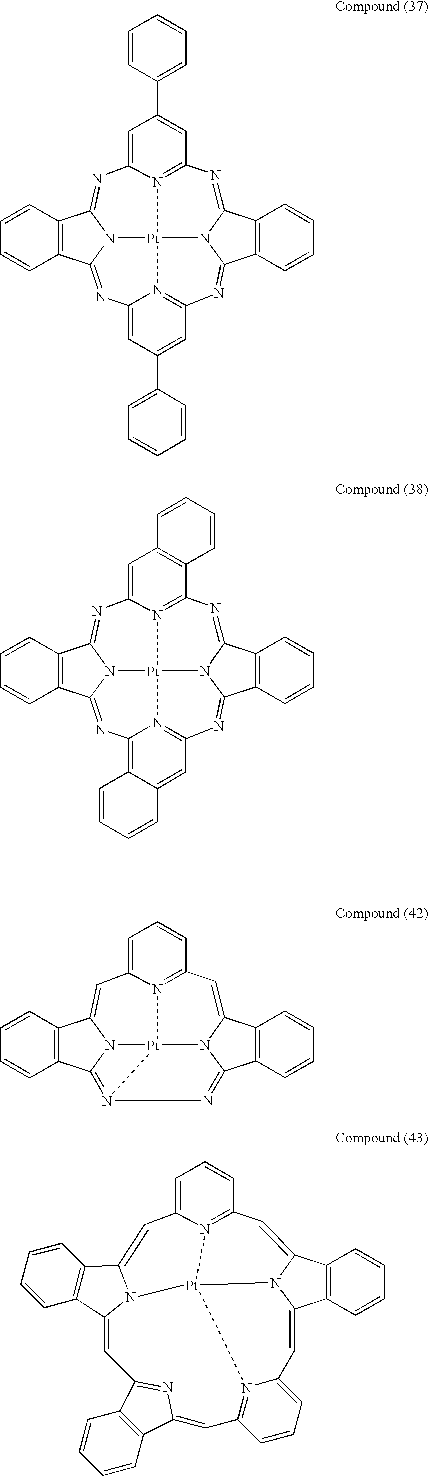

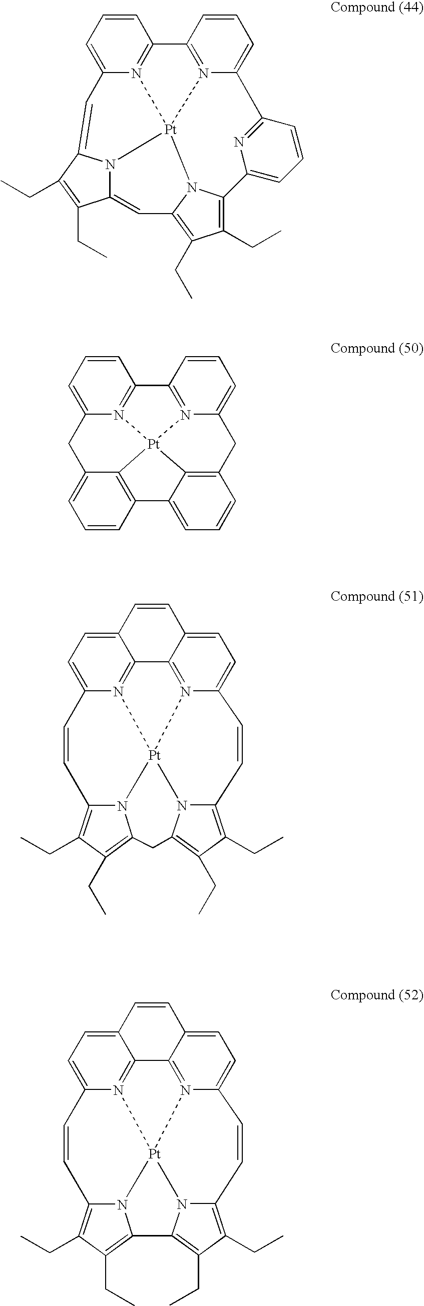

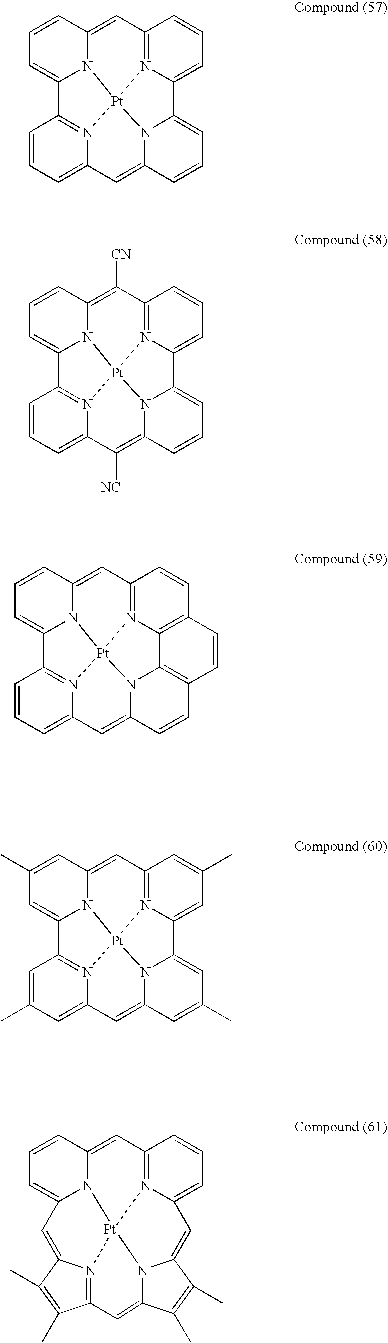

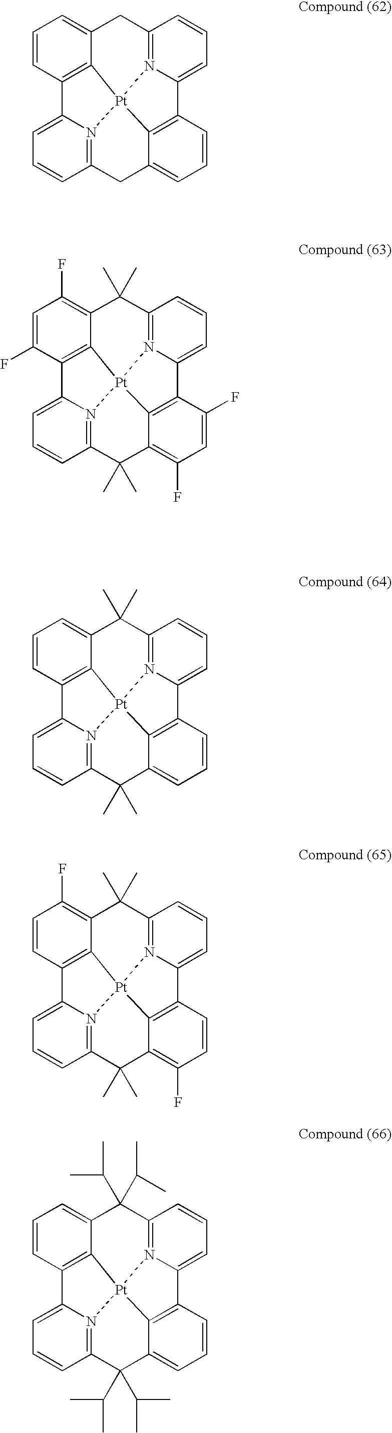

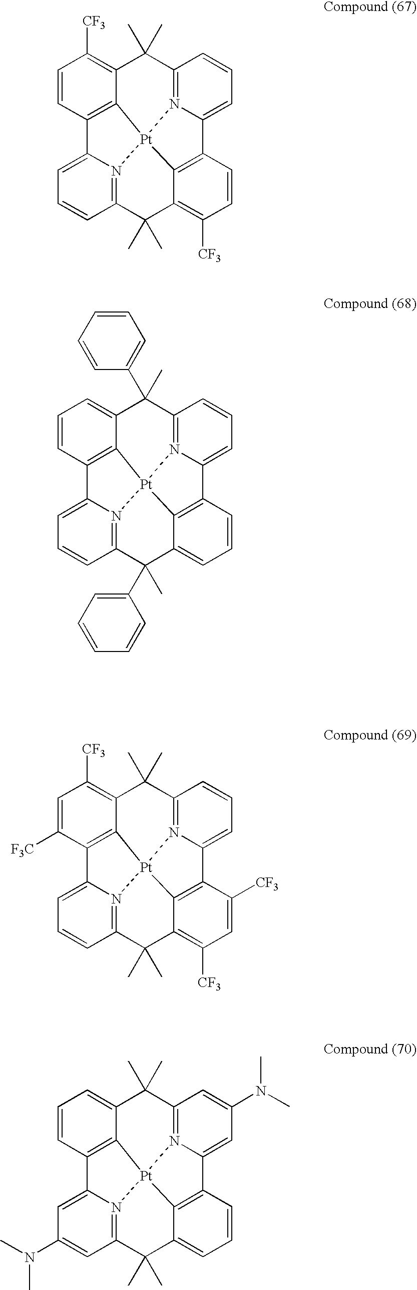

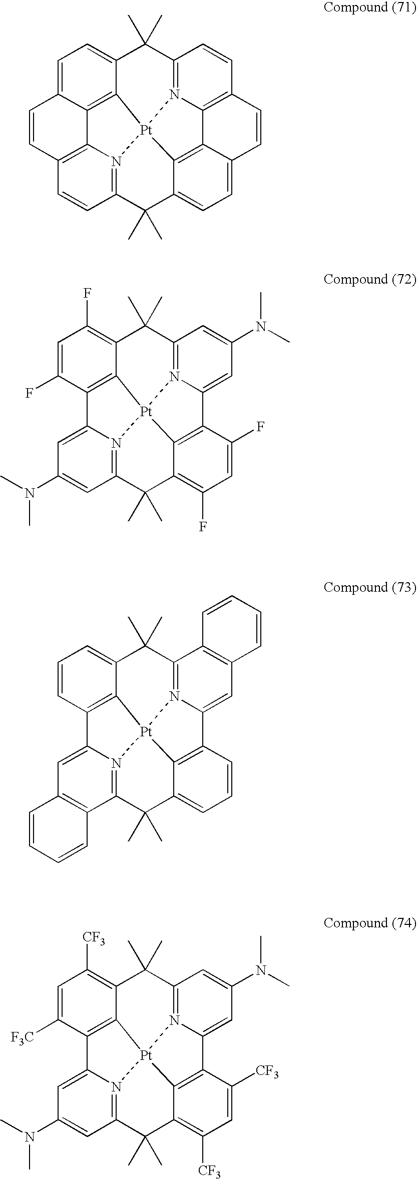

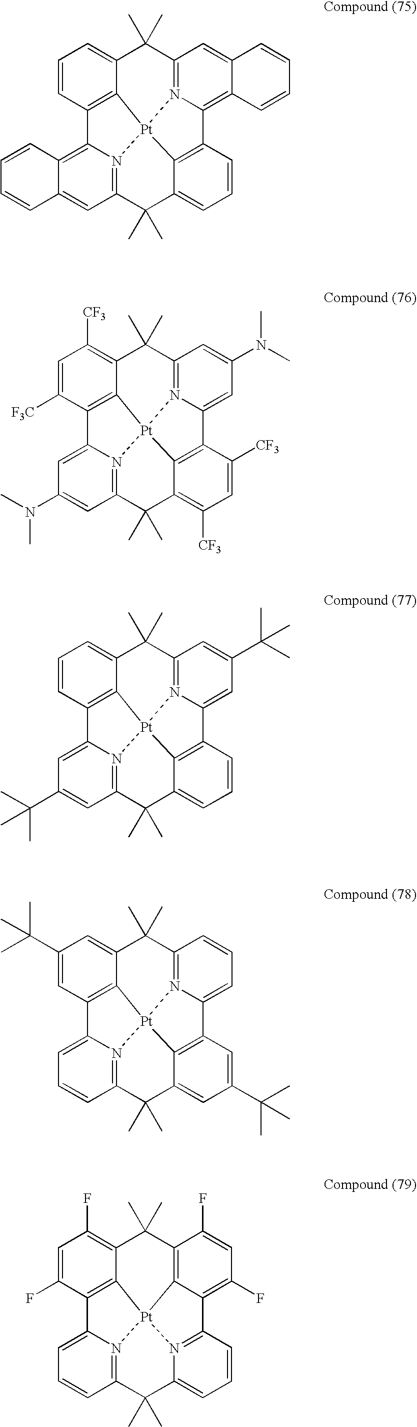

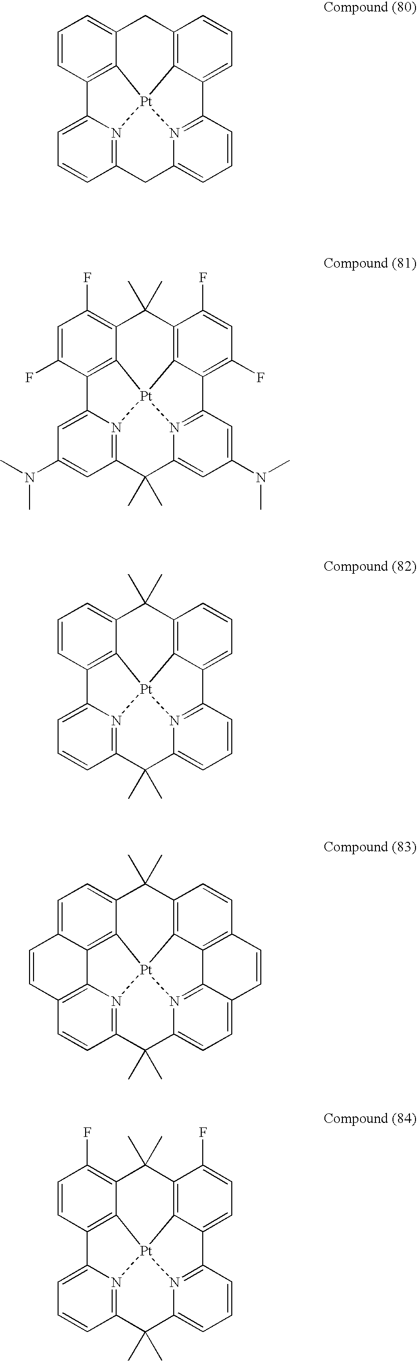

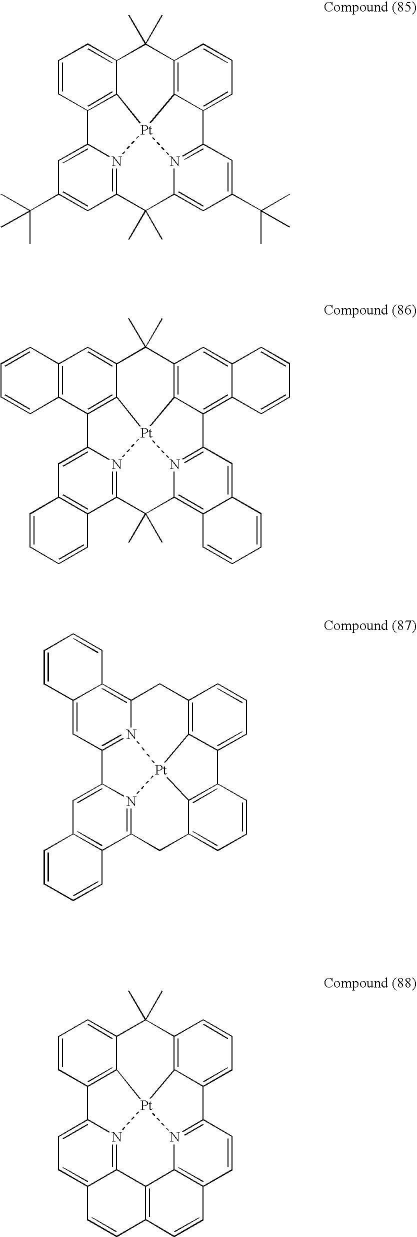

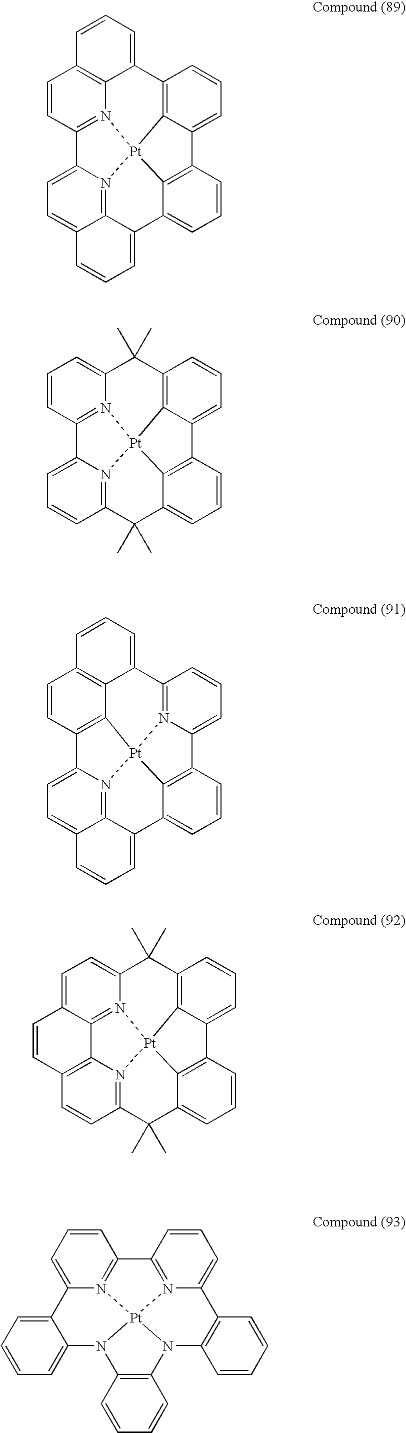

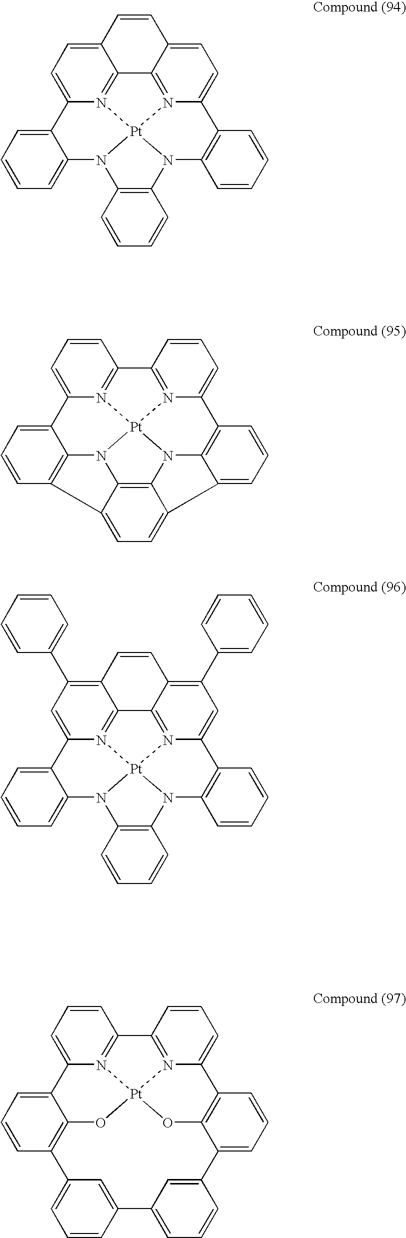

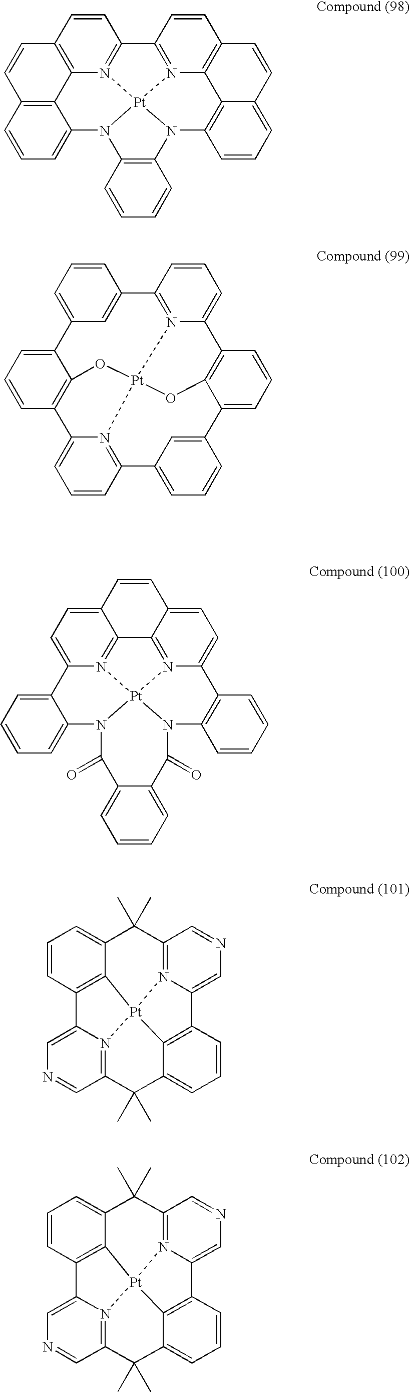

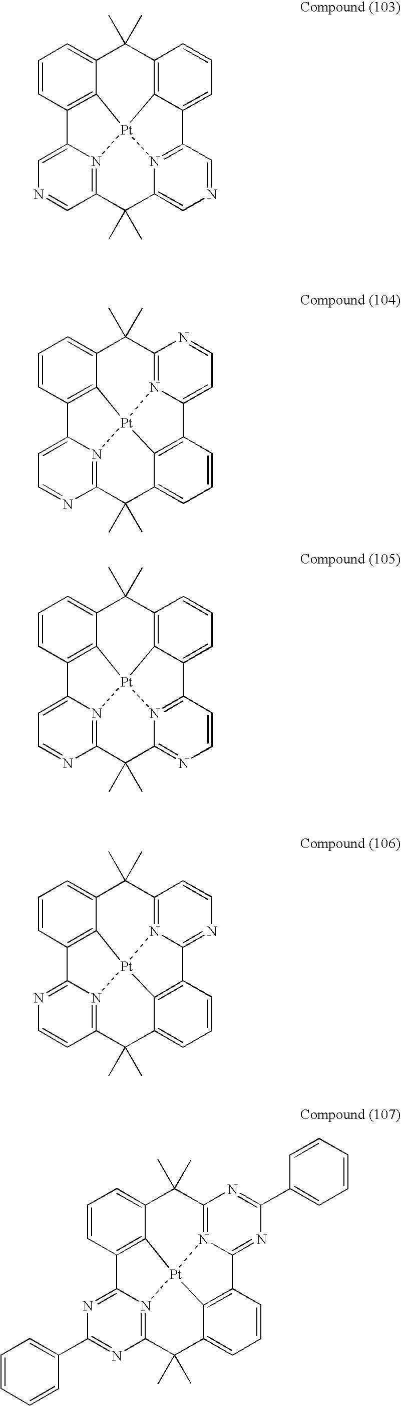

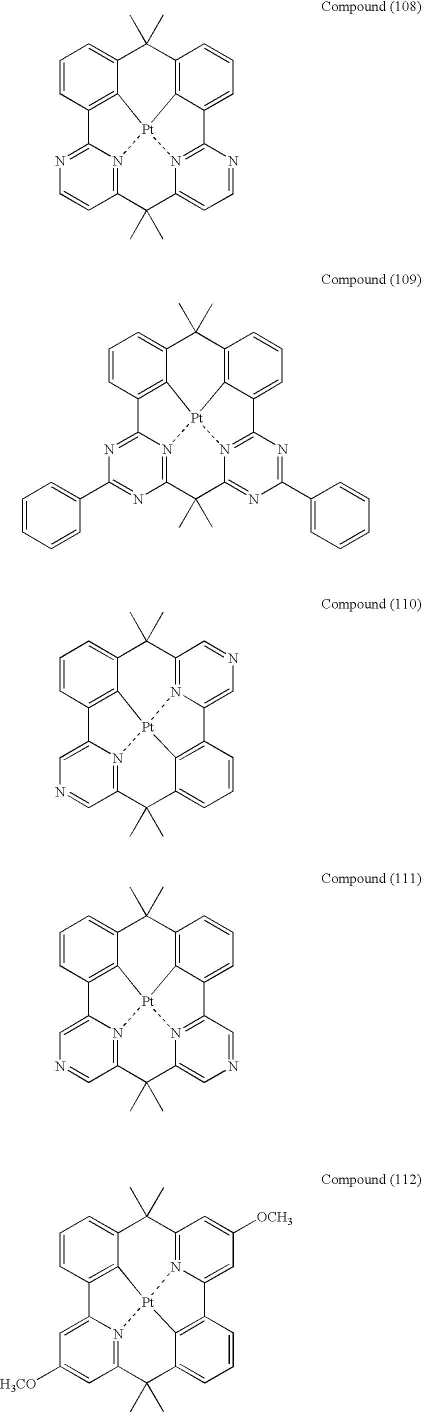

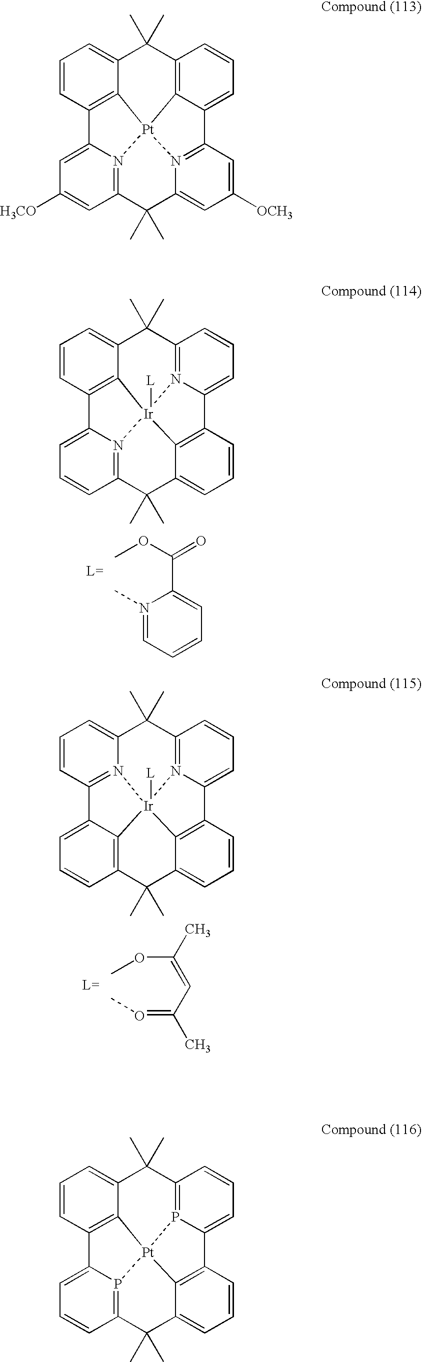

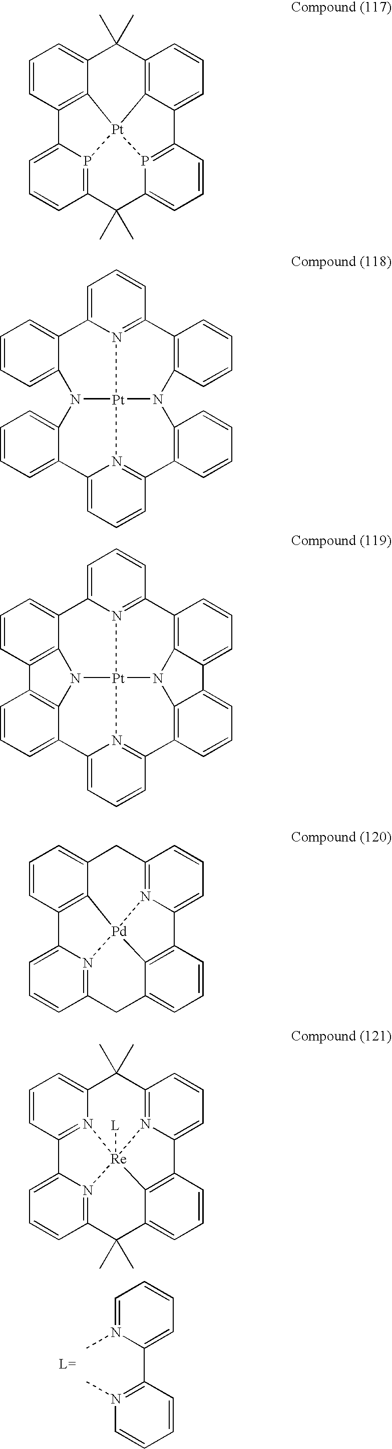

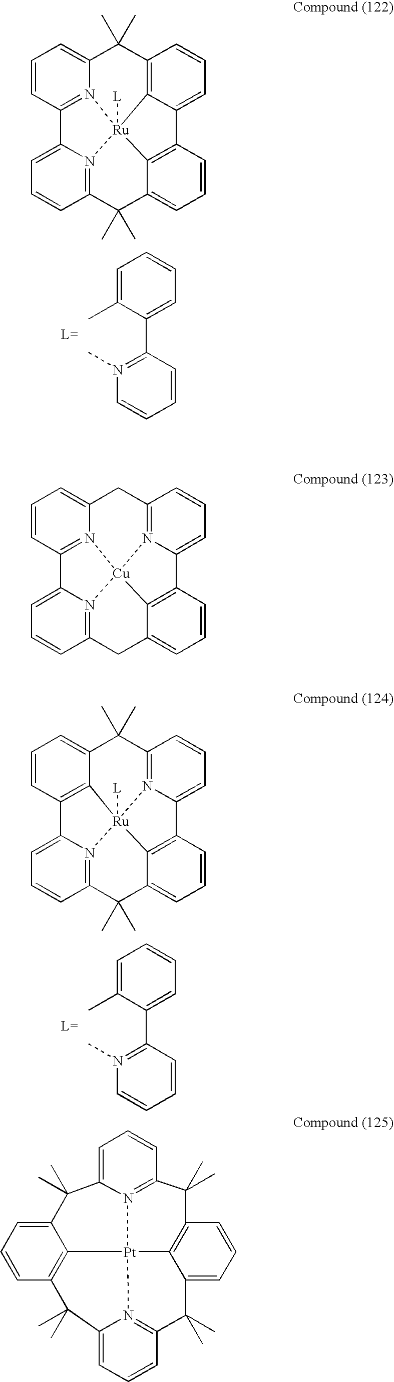

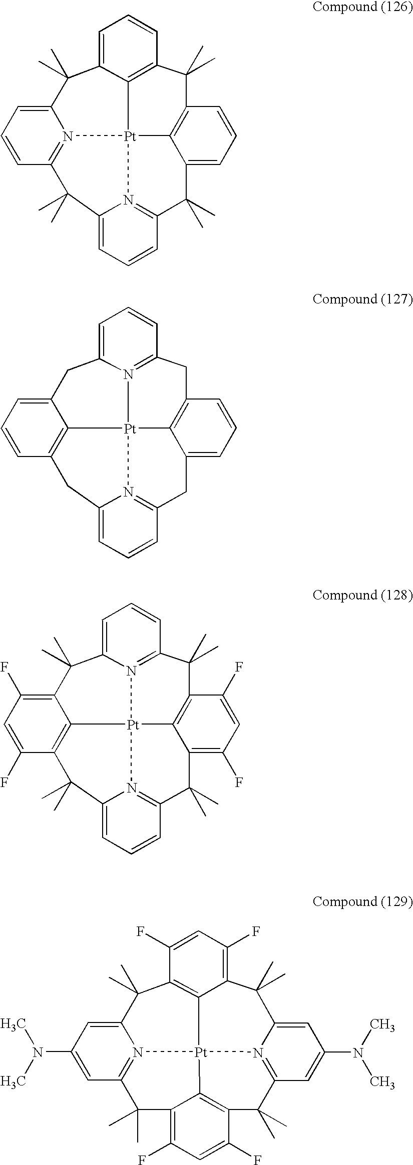

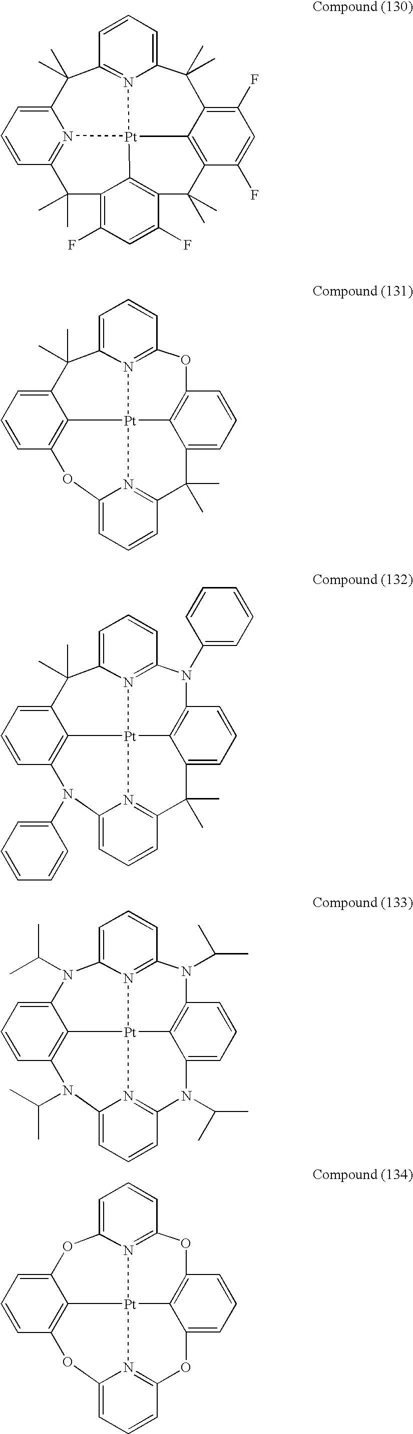

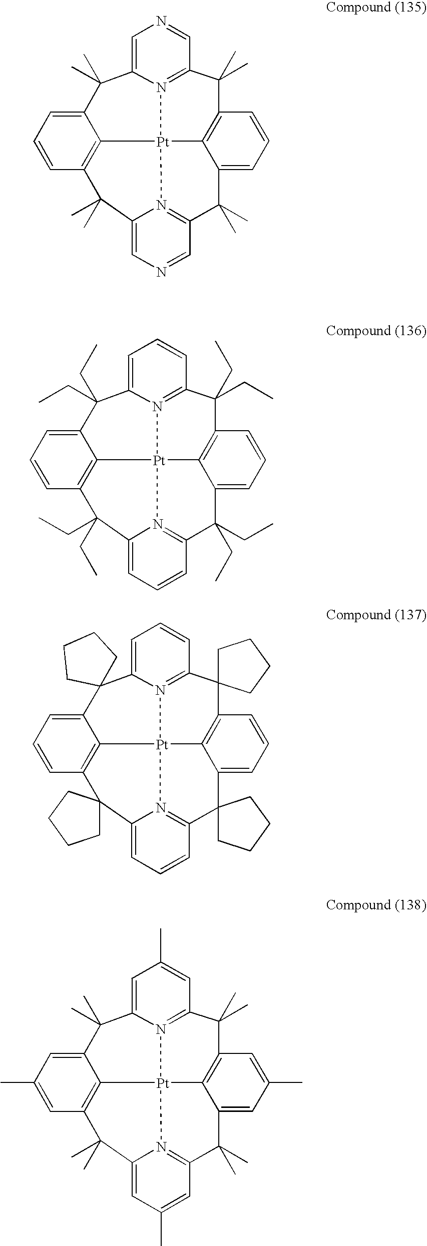

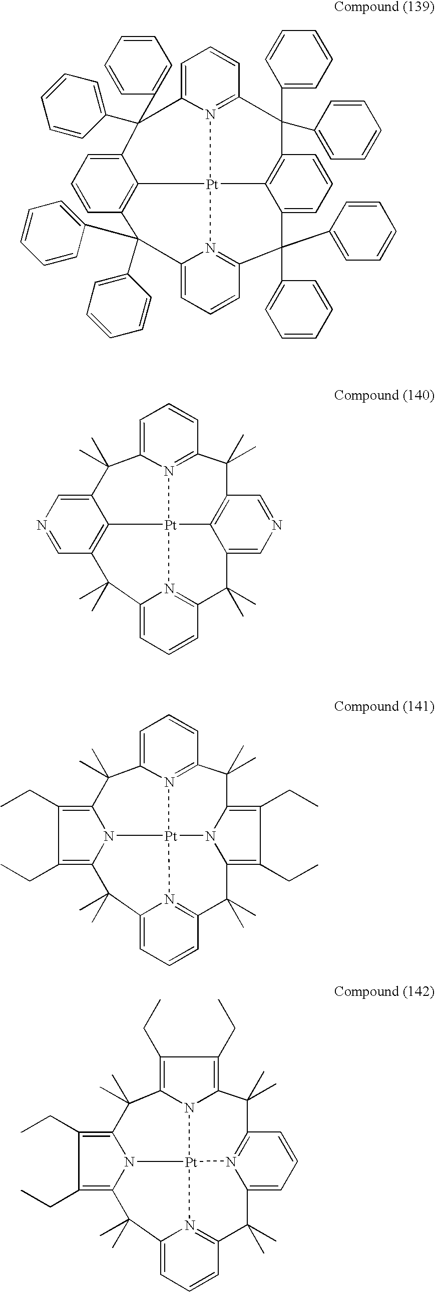

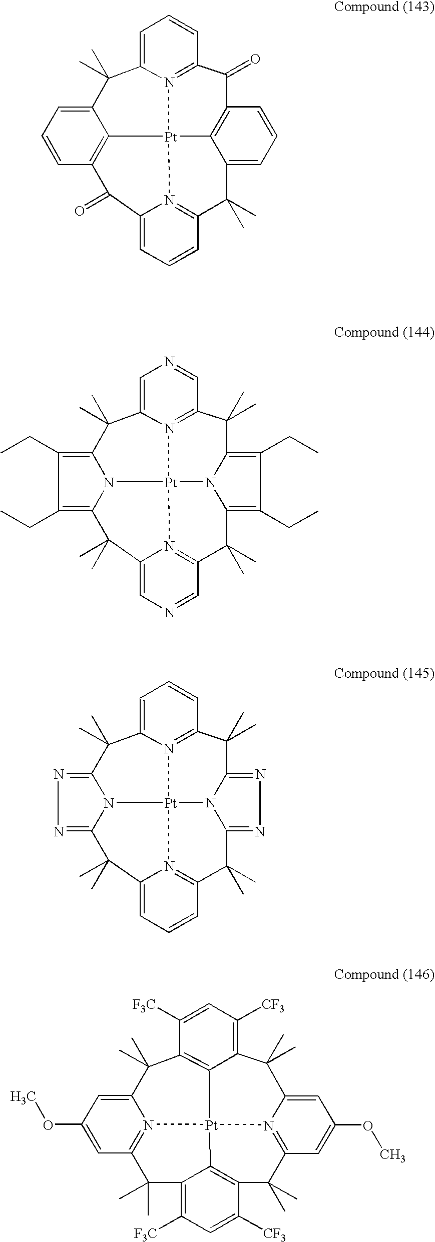

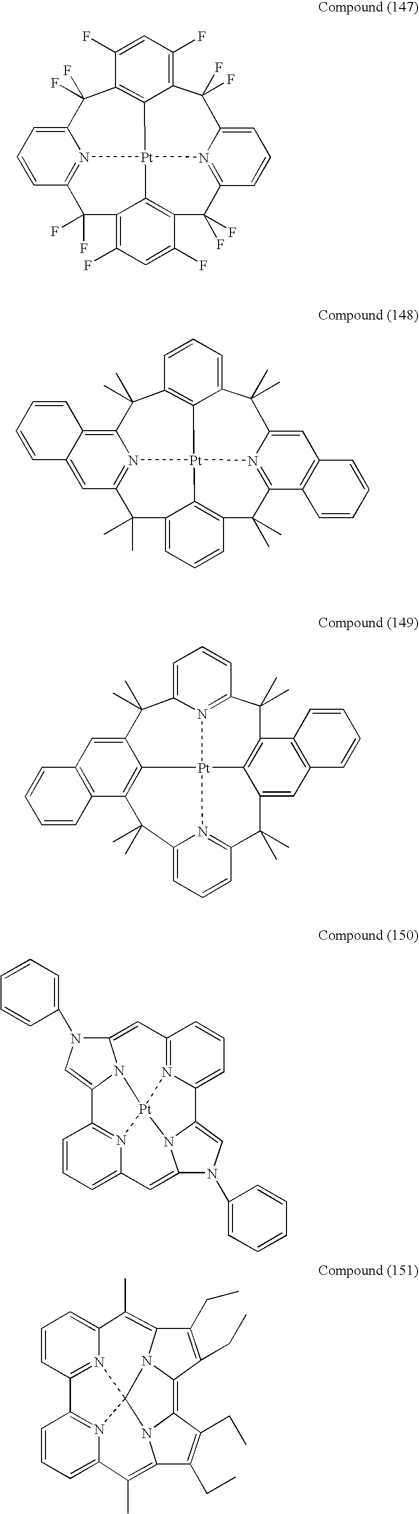

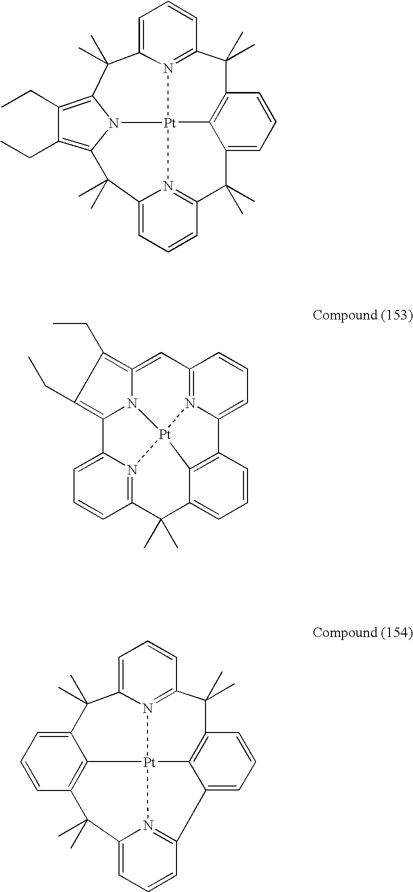

Preferable examples of the metal complex usable in the invention further include compounds represented by Formula (A-1), (B-1), (C-1), (D-1), (E-1), or (F-1) described below.

Formula (A-1) is described below.

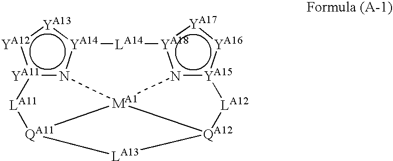

In Formula (A-1), M^{A1} represents a metal ion. Y^{A11}, Y^{A14}, Y^{A15} and Y^{A18} each independently represent a carbon atom or a nitrogen atom. Y^{A12}, Y^{A13}, Y^{A16} and Y^{A17} each independently represent a substituted or unsubstituted carbon atom, a substituted or unsubstituted nitrogen atom, an oxygen atom or a sulfur atom. L^{A11}, L^{A12}, L^{A13} and L^{A14} each represent a connecting group, and may have the same structure as each other or different structure from each other. Q^{A11} and Q^{A12} each independently represent a partial structure containing an atom bonded to M^{A1}.

The compound represented by Formula (A-1) will be described in detail.

M^{A1} represents a metal ion. The metal ion is not particularly limited. It is preferably a divalent metal ion, more preferably Pt²⁺, Pd²⁺, Cu²⁺, Ni²⁺, Co²⁺, Zn²⁺, Mg²⁺ or Pb²⁺, still more preferably Pt²⁺ or Cu²⁺, and further more preferably Pt²⁺.

Y^{A11}, Y^{A14}, Y^{A15} and Y^{A18} each independently represent a carbon atom or a nitrogen atom. Each of Y^{A11}, Y^{A14}, Y^{A15} and Y^{A18} is preferably a carbon atom.

Y^{A12}, Y^{A13}, Y^{A16} and Y^{A17} each independently represent a substituted or unsubstituted carbon atom, a substituted or unsubstituted nitrogen atom, an oxygen atom or a sulfur atom. Each of Y^{A12}, Y^{A13}, Y^{A16} and Y^{A17} is preferably a substituted or unsubstituted carbon atom or a substituted or unsubstituted nitrogen atom.

L^{A11}, L^{A12}, L^{A13} and L^{A14} each independently represent a divalent connecting group. The divalent connecting group represented by L^{A11}, L^{A12}, L^{A13} or L^{A14} may be, for example, a single bond or a connecting group formed of atoms selected from carbon, nitrogen, silicon, sulfur, oxygen, germanium, phosphorus and the like, more preferably a single bond, a substituted or unsubstituted carbon atom, a substituted or unsubstituted nitrogen atom, a substituted silicon atom, an oxygen atom, a sulfur atom, a divalent aromatic hydrocarbon cyclic group or a divalent aromatic heterocyclic group, still more preferably a single bond, a substituted or unsubstituted carbon atom, a substituted or unsubstituted nitrogen atom, a substituted silicon atom, a divalent aromatic hydrocarbon cyclic group or a divalent aromatic heterocyclic group, and further more preferably a single bond or a substituted or unsubstituted methylene group. Examples of the divalent connecting group represented by L^{A11}, L^{A12}, L^{A13} or L^{A14} include the following groups:

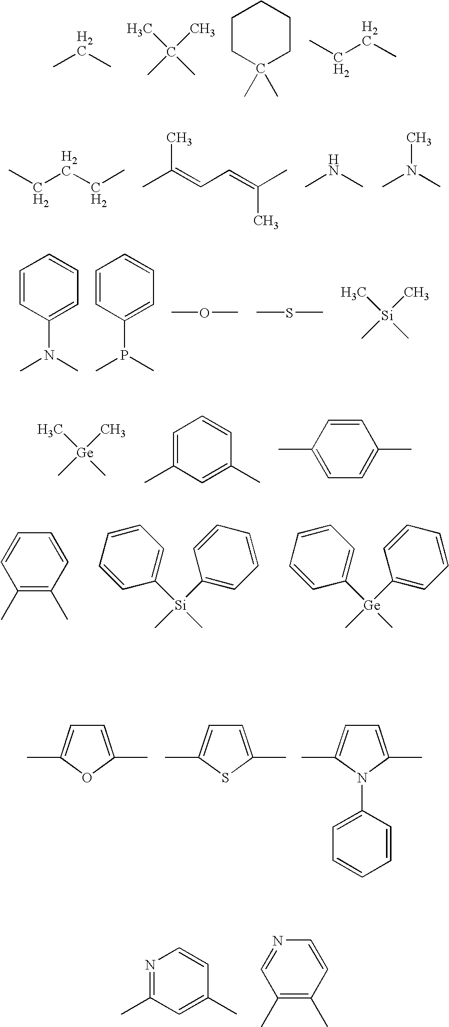

The divalent connecting group represented by L^{A11}, L^{A12}, L^{A13} or L^{A14} may further have a substituent. The substituent which can be introduced into the divalent connecting group may be, for example, an alkyl group (preferably those having 1 to 30 carbon atoms, more preferably those having 1 to 20 carbon atoms, particularly preferably those having 1 to 10 carbon atoms, and examples thereof include a methyl group, an ethyl group, an iso-propyl group, a tert-butyl group, a n-octyl group, a n-decyl group, a n-hexadecyl group, a cyclopropyl group, a cyclopentyl group, and a cyclohexyl group), an alkenyl group (preferably those having 2 to 30 carbon atoms, more preferably those having 2 to 20 carbon atoms, particularly preferably those having 2 to 10 carbon atoms, and examples thereof include a vinyl group, an allyl group, a 2-butenyl group, and a 3-pentenyl group), an alkynyl group (preferably those having 2 to 30 carbon atoms, more preferably those having 2 to 20 carbon atoms, particularly preferably those having 2 to 10 carbon atoms, and examples thereof include a propargyl group and a 3-pentynyl group),

an aryl group (preferably those having 6 to 30 carbon atoms, more preferably those having 6 to 20 carbon atoms, particularly preferably those having 6 to 12 carbon atoms, and examples thereof include a phenyl group, a p-methylphenyl group, a naphthyl group, and an anthranyl group), an amino group preferably those having 0 to 30 carbon atoms, more preferably those having 0 to 20 carbon atoms, particularly preferably those having 0 to 10 carbon atoms, and examples thereof include an amino group, a methylamino group, a dimethylamino group, a diethylamino group, a dibenzylamino group, a diphenylamino group, and a ditolylamino group), an alkoxy group (preferably those having 1 to 30 carbon atoms, more preferably those having 1 to 20 carbon atoms, particularly preferably those having 1 to 10 carbon atoms, and examples thereof include a methoxy group, an ethoxy group, a butoxy group, and a 2-ethylhexyloxy group), an aryloxy group (preferably those having 6 to 30 carbon atoms, more preferably those having 6 to 20 carbon atoms, particularly preferably those having 6 to 12 carbon atoms, and examples thereof include a phenyloxy group, a 1-naphthyloxy group, and a 2-naphthyloxy group),

a heterocyclic oxy group (preferably those having 1 to 30 carbon atoms, more preferably those having 1 to 20 carbon atoms, particularly preferably those having 1 to 12 carbon atoms, and examples thereof include a pyridyloxy group, a pyrazyloxy group, a pyrimidyloxy group, and a quinolyloxy group), an acyl group (preferably those having 1 to 30 carbon atoms, more preferably those having 1 to 20 carbon atoms, particularly preferably those having 1 to 12 carbon atoms, and examples thereof include an acetyl group, a benzoyl group, a formyl group, and a pivaloyl group), an alkoxycarbonyl group (preferably those having 2 to 30 carbon atoms, more preferably those having 2 to 20 carbon atoms, particularly preferably those having 2 to 12 carbon atoms, and examples thereof include a methoxycarbonyl group, and an ethoxycarbonyl group), an aryloxycarbonyl group (preferably those having 7 to 30 carbon atoms, more preferably those having 7 to 20 carbon atoms, particularly preferably those having 7 to 12 carbon atoms, and examples thereof include a phenyloxycarbonyl group),

an acyloxy group (preferably those having 2 to 30 carbon atoms, more preferably those having 2 to 20 carbon atoms, particularly preferably those having 2 to 10 carbon atoms, and examples thereof include an acetoxy group, and a benzoyloxy group), an acylamino group (preferably those having 2 to 30 carbon atoms, more preferably those having 2 to 20 carbon atoms, particularly preferably those having 2 to 10 carbon atoms, and examples thereof include an acetylamino group, and a benzoylamino group), an alkoxycarbonylamino group (preferably those having 2 to 30 carbon atoms, more preferably those having 2 to 20 carbon atoms, particularly preferably those having 2 to 12 carbon atoms, and examples thereof include a methoxycarbonylamino group), an aryloxycarbonylamino group (preferably those having 7 to 30 carbon atoms, more preferably those having 7 to 20 carbon atoms, particularly preferably those having 7 to 12 carbon atoms, and examples thereof include a phenyloxycarbonylamino group),

a sulfonylamino group (preferably those having 1 to 30 carbon atoms, more preferably those having 1 to 20 carbon atoms, particularly preferably those having 1 to 12 carbon atoms, and examples thereof include a methanesulfonylamino group and a benzenesulfonylamino group), a sulfamoyl group (preferably those having 0 to 30 carbon atoms, more preferably those having 0 to 20 carbon atoms, particularly preferably those having 0 to 12 carbon atoms, and examples thereof include a sulfamoyl group, a methylsulfamoyl group, a dimethylsulfamoyl group, and a phenylsulfamoyl group), a carbamoyl group (preferably those having 1 to 30 carbon atoms, more preferably those having 1 to 20 carbon atoms, particularly preferably those having 1 to 12 carbon atoms, and examples thereof include a carbamoyl group, a methylcarbamoyl group, a diethylcarbamoyl group, and a phenylcarbamoyl group),

an alkylthio group (preferably those having 1 to 30 carbon atoms, more preferably those having 1 to 20 carbon atoms, particularly preferably those having 1 to 12 carbon atoms, and examples thereof include a methylthio group and an ethylthio group), an arylthio group (preferably those having 6 to 30 carbon atoms, more preferably those having 6 to 20 carbon atoms, particularly preferably those having 6 to 12 carbon atoms, and examples thereof include a phenylthio group), a heterocyclic thio group (preferably those having 1 to 30 carbon atoms, more preferably those having 1 to 20 carbon atoms, particularly preferably those having 1 to 12 carbon atoms, and examples thereof include a pyridylthio group, a 2-benzimidazolylthio group, a 2-benzoxazolylthio group, and a 2-benzthiazolylthio group), a sulfonyl group (preferably those having 1 to 30 carbon atoms, more preferably those having 1 to 20 carbon atoms, particularly preferably those having 1 to 12 carbon atoms, and examples thereof include a mesyl group and a tosyl group), a sulfinyl group (preferably those having 1 to 30 carbon atoms, more preferably those having 1 to 20 carbon atoms, particularly preferably those having 1 to 12 carbon atoms, and examples thereof include a methanesulfinyl group and a benzenesulfinyl group),

a ureido group (preferably those having 1 to 30 carbon atoms, more preferably those having 1 to 20 carbon atoms, particularly preferably those having 1 to 12 carbon atoms, and examples thereof include a ureido group, a methylureido group, and a phenylureido group), a phosphoric amide group (preferably those having 1 to 30 carbon atoms, more preferably those having 1 to 20 carbon atoms, particularly preferably those having 1 to 12 carbon atoms, and examples thereof include a diethylphosphoric amide group and a phenylphosphoric amide group), a hydroxy group, a mercapto group, a halogen atom (and examples thereof include a fluorine atom, chlorine atom, bromine atom, iodine atom), a cyano group, a sulfo group, a carboxyl group, a nitro group, a hydroxamic acid group, a sulfino group, a hydrazino group, an imino group,

a heterocyclic group (preferably those having 1 to 30 carbon atoms, more preferably those having 1 to 12 carbon atoms, containing a heteroatom such as a nitrogen atom, an oxygen atom or a sulfur atom; specific examples thereof include an imidazolyl group, a pyridyl group, a quinolyl group, a furyl group, a thienyl group, a piperidyl group, a morpholino group, a benzoxazolyl group, a benzimidazolyl group, a benzthiazolyl group, a carbazolyl group, and an azepinyl group), a silyl group (preferably those having 3 to 40 carbon atoms, more preferably those having 3 to 30 carbon atoms, particularly preferably those having 3 to 24 carbon atoms, and examples thereof include a trimethylsilyl group and a triphenylsilyl group) or a silyloxy group (preferably those having 3 to 40 carbon atoms, more preferably those having 3 to 30 carbon atoms, particularly preferably those having 3 to 24 carbon atoms, and examples thereof include a trimethylsilyloxy group and a triphenylsilyloxy group).

These substituents may themselves have a substituent. The substituent which can be introduced to these substituents is preferably selected from an alkyl group, an aryl group, a heterocyclic group, a halogen atom and a silyl group, more preferably selected from an alkyl group, an aryl group, a heterocyclic group and a halogen atom, and still more preferably selected from an alkyl group, an aryl group, an aromatic heterocyclic group and a fluorine atom.

Q^{A11} and Q^{A12} each independently represent a partial structure containing an atom covalently bonded to M^{A1}. Q^{A11} and Q^{A12} each independently preferably represent a group having a carbon atom bonded to M^{A1}, a group having a nitrogen atom bonded to M^{A1}, a group having a silicon atom bonded to M^{A1}, a group having a phosphorus atom bonded to M^{A1}, a group having an oxygen atom bonded to M^{A1} or a group having a sulfur atom bonded to M^{A1}, more preferably a group having a carbon, nitrogen, oxygen, or sulfur atom bonded to M^{A1}, still more preferably a group having a carbon or nitrogen atom bonded to M^{A1}, and further more preferably a group having a carbon atom bonded to M^{A1}.

The group bonded to M^{A1} via a carbon atom is preferably an aryl group having a carbon atom bonded to M^{A1}, a 5-membered cyclic heteroaryl group having a carbon atom bonded to M^{A1} or a 6-membered cyclic heteroaryl group having a carbon atom bonded to M^{A1}, more preferably an aryl group having a carbon atom bonded to M^{A1}, a nitrogen-containing 5-membered cyclic heteroaryl group having a carbon atom bonded to M^{A1} or a nitrogen-containing 6-membered cyclic heteroaryl group having a carbon atom bonded to M^{A1}, and still more preferably an aryl group having a carbon atom bonded to M^{A1}.

The group bonded to M^{A1} via a nitrogen atom is preferably a substituted amino group or a nitrogen-containing 5-membered cyclic heteroaryl group having a nitrogen atom bonded to M^{A1}, more preferably a nitrogen-containing 5-membered cyclic heteroaryl group having a nitrogen atom bonded to M^{A1}.

The group bonded to M^{A1} via a phosphorus atom is preferably a substituted phosphino group. The group having a silicon atom bonded to M^{A1} is preferably a substituted silyl group. The group having an oxygen atom bonded to M^{A1} is preferably an oxy group, and the group having a sulfur atom bonded to M^{A1} is preferably a sulfide group.

The compound represented by Formula (A-1) is more preferably a compound represented by the following Formula (A-2), (A-3) or (A-4).

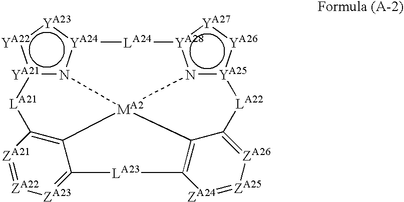

In Formula (A-2), M^{A2} represents a metal ion Y^{A21}, Y^{A24}, Y^{A25} and Y^{A28} each independently represent a carbon atom or a nitrogen atom. Y^{A22}, Y^{A23}, Y^{A26} and Y^{A27} each independently represent a substituted or unsubstituted carbon atom, a substituted or unsubstituted nitrogen atom, an oxygen atom or a sulfur atom. L^{A21}, L^{A22}, L^{A23} and L^{A24} each independently represent a connecting group. Z^{A21}, Z^{A22}, Z^{A24}, Z^{A25} and Z^{A26} each independently represent a nitrogen atom or a substituted or unsubstituted carbon atom.

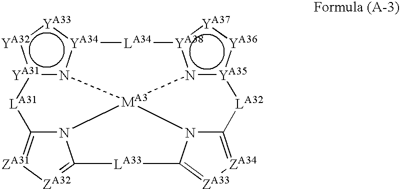

In Formula (A-3), M^{A3} represents a metal ion. Y^{A31}, Y^{A34}, Y^{A35} and Y^{A38} each independently represent a carbon atom or a nitrogen atom. Y^{A32}, Y^{A33}, Y^{A36} and Y^{A37} each independently represent a substituted or unsubstituted carbon atom, a substituted or unsubstituted nitrogen atom, an oxygen atom or a sulfur atom. L^{A31}, L^{A32}, L^{A33} and L^{A34} each independently represent a connecting group. Z^{A31}, Z^{A32} Z^{A33} and Z^{A34} each independently represent a nitrogen atom or a substituted or unsubstituted carbon atom.

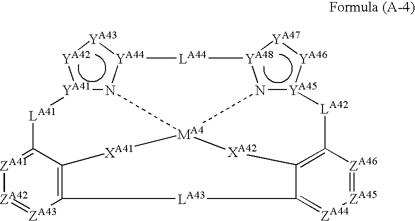

In Formula (A-4), M^{A4} represents a metal ion Y^{A41}, Y^{A44}, Y^{A45} and Y^{A48} each independently represent a carbon atom or a nitrogen atom. Y^{A42}, Y^{A43}, Y^{A46} and Y^{A47} each independently represent a substituted or unsubstituted carbon atom, a substituted or unsubstituted nitrogen atom, an oxygen atom or a sulfur atom. L^{A41}, L^{A42}, L^{A43} and L^{A44} each independently represent a connecting group. Z^{A41}, Z^{A42}, Z^{A43}, Z^{A44}, Z^{A45} and Z^{A46} each independently represent a nitrogen atom or a substituted or unsubstituted carbon atom. X^{A41} and X^{A42} each independently represent an oxygen atom, a sulfur atom or a substituted or unsubstituted nitrogen atom.

The compound represented by Formula (A-2) will be described in detail.

M^{A2}, Y^{A21}, Y^{A24}, Y^{A25}, Y^{A28}, Y^{A22}, Y^{A23}, Y^{A26}, Y^{A27}, L^{A21}, L^{A22}, L^{A23} and L^{A24} have the same definitions as corresponding M^{A1}, Y^{A11}, Y^{A14}, Y^{A15}, Y^{A18}, Y^{A12}, Y^{A13}, Y^{A16}, Y^{A17}, L^{A11}, L^{A12}, L^{A13} and L^{A14} in Formula (A-1) respectively, and their preferable examples are also the same.

Z^{A21}, Z^{A22}, Z^{A23}, Z^{A24}, Z^{A25} and Z^{A26} each independently represent a nitrogen atom or a substituted or unsubstituted carbon atom. Z^{A21}, Z^{A22}, Z^{A23}, Z^{A24}, Z^{A25} and Z^{A26} each independently represent preferably a substituted or unsubstituted carbon atom, and more preferably an unsubstituted carbon atom. When the carbon atom is substituted, the substituent may be selected from the above-mentioned examples of the substituent on the divalent connecting group represented by L^{A11}, L^{A12}, L^{A13} or L^{A14} in Formula (A-1)

The compound represented by Formula (A-3) will be described in detail.

M^{A3}, Y^{A31}, Y^{A34}, Y^{A35}, Y^{A38}, Y^{A32}, Y^{A33}, Y^{A36}, Y^{A37}, L^{A31}, L^{A32}, L^{A33} and L^{A34} have the same definitions as corresponding M^{A1}, Y^{A11}, Y^{A14}, Y^{A15}, Y^{A18}, Y^{A12}, Y^{A13}, Y^{A16}, Y^{A17}, L^{A11}, L^{A12}, L^{A13} and L^{A14} in Formula (A-1) respectively, and their preferable examples are also the same.

Z^{A31}, Z^{A32}, Z^{A33} and Z^{A34} each independently represent a nitrogen atom or a substituted or unsubstituted carbon atom. Each of Z^{A31}, Z^{A32}, Z^{A33} and Z^{A34} is preferably a substituted or unsubstituted carbon atom, and more preferably an unsubstituted carbon atom. When the carbon atom is substituted, the substituent may be selected from the above-mentioned examples of the substituent on the divalent connecting group represented by L^{A11}, L^{A12}, L^{A13} or L^{A14} in Formula (A-1).

The compound represented by Formula (A-4) will be described in detail.

M^{A4}, Y^{A41}, Y^{A44}, Y^{A45}, Y^{A48}, Y^{A42}, Y^{A43}, Y^{A46}, Y^{A47}, L^{A41}, L^{A42}, L^{A43} and L^{A44} have the same definitions as corresponding M^{A1}, Y^{A11}, Y^{A14}, Y^{A15}, Y^{A18}, Y^{A12}, Y^{A13}, Y^{A16}, Y^{A17}, L^{A11}, L^{A12}, L^{A13} and L^{A14} in Formula (A-1) respectively, and their preferable examples are also the same.

Z^{A41}, Z^{A42}, Z^{A43}, Z^{A44}, Z^{A45} and Z^{A46} each independently represent a nitrogen atom or a substituted or unsubstituted carbon atom. Each of Z^{A41}, Z^{A42}, Z^{A43}, Z^{A44}, Z^{A45} and Z^{A46} is preferably a substituted or unsubstituted carbon atom, and more preferably an unsubstituted carbon atom. When the carbon atom is substituted, the substituent may be selected from the above-mentioned examples of the substituent on the divalent connecting group represented by L^{A11}, L^{A12}, L^{A13} or L^{A14} in Formula (A-1).

X^{A41} and X^{A42} each independently represent an oxygen atom, a sulfur atom or a substituted or unsubstituted nitrogen atom. Each of X^{A41} and X^{A42} is preferably an oxygen atom or a sulfur atom, and more preferably an oxygen atom.

Specific examples of the compound represented by Formula (A-1) are shown below. However, the specific examples should not be construed as limiting the invention.

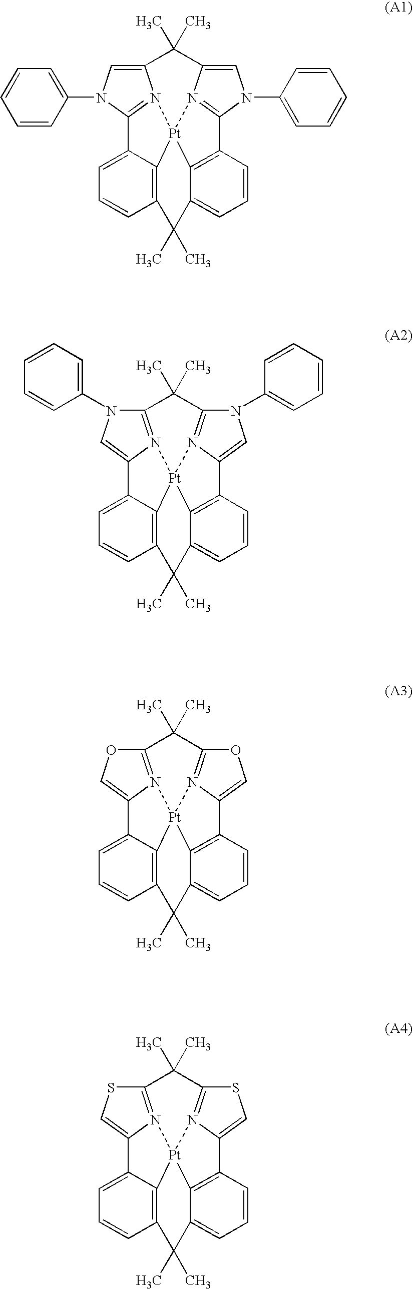

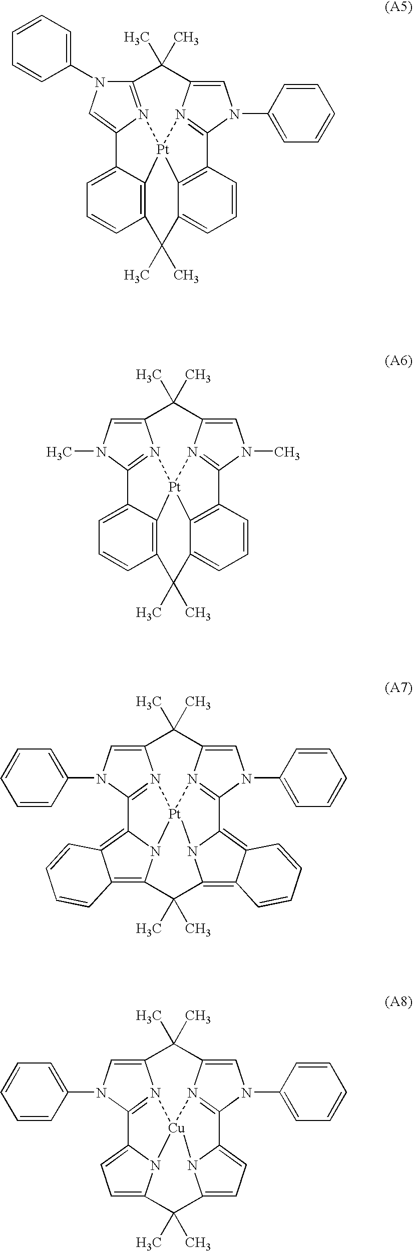

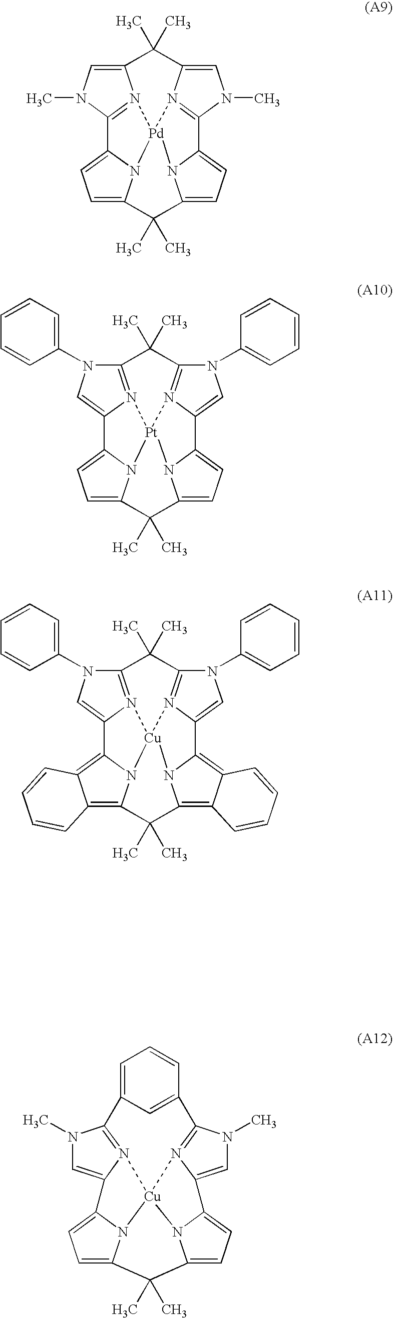

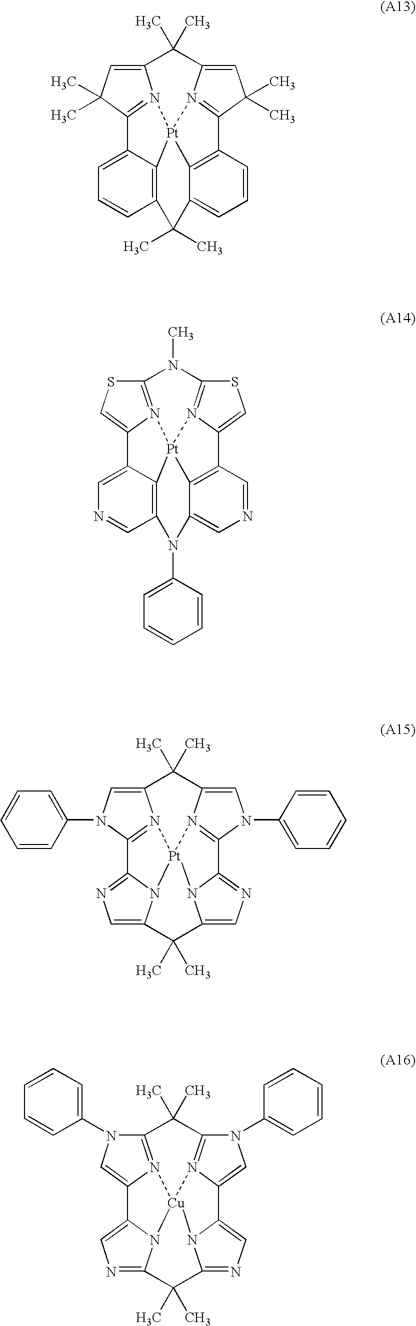

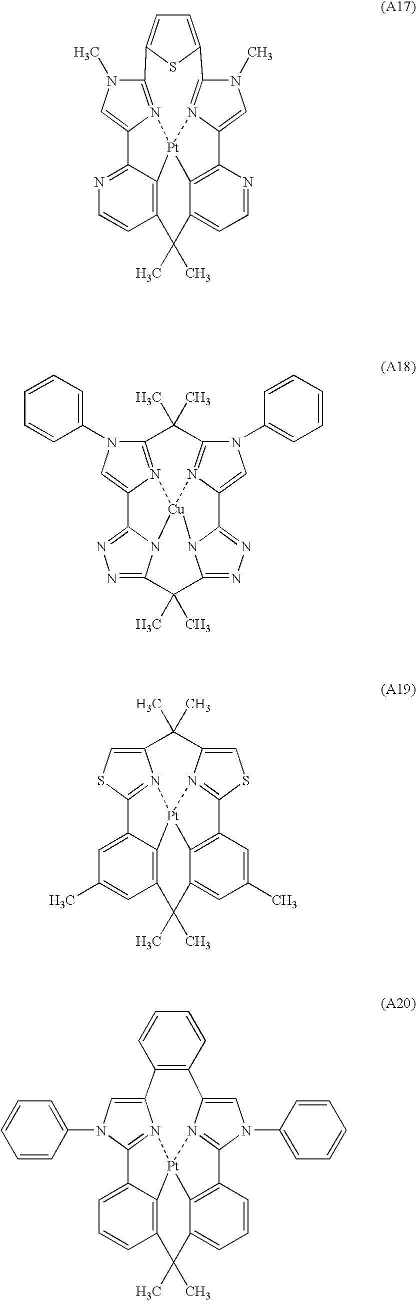

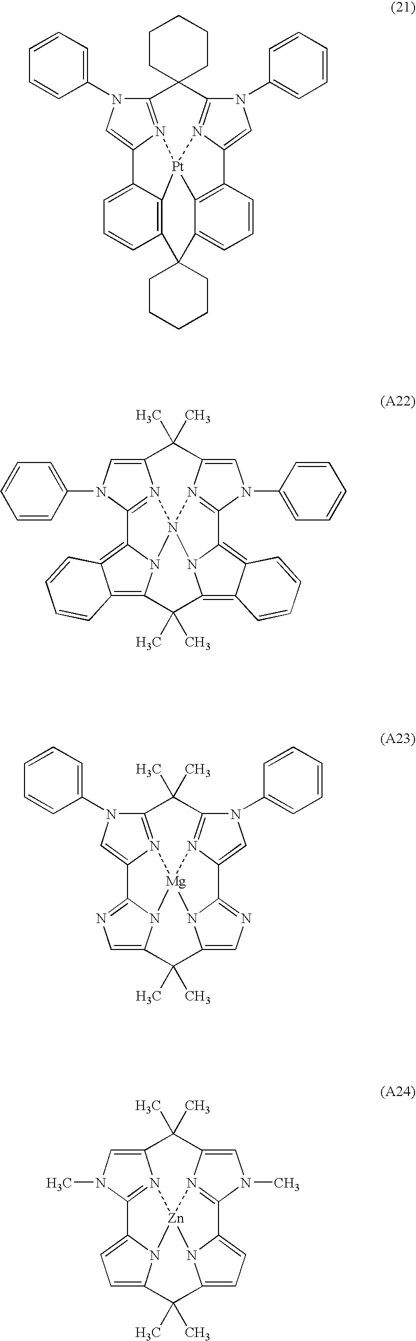

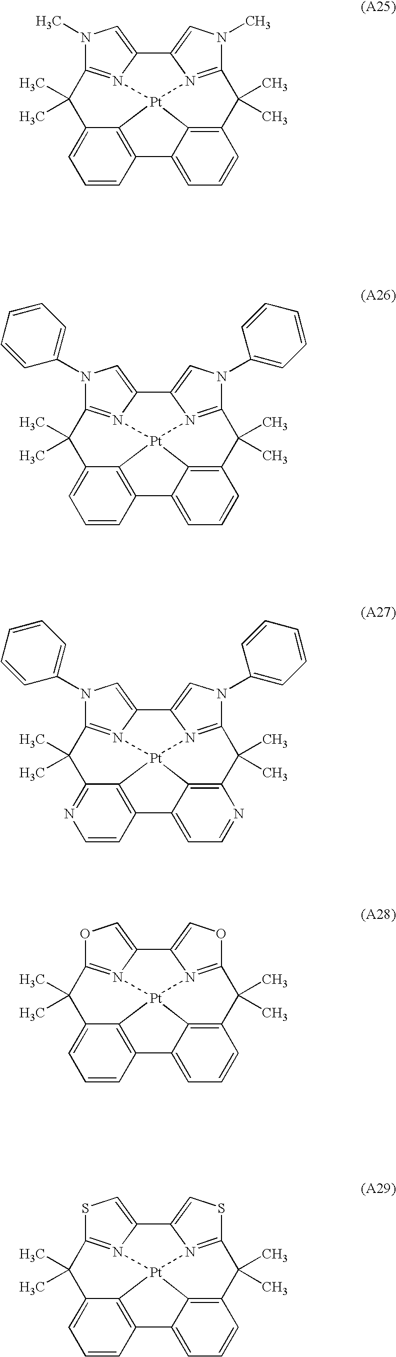

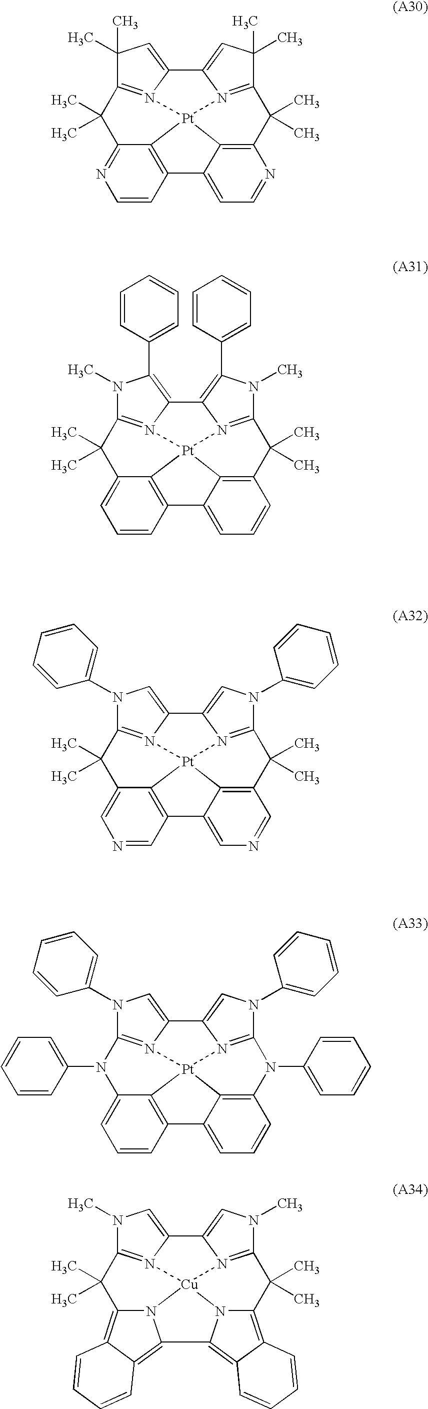

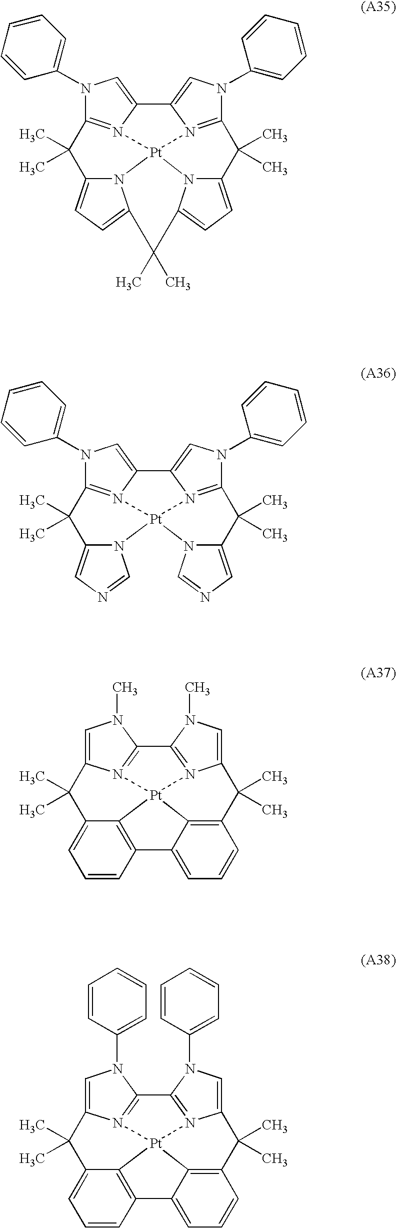

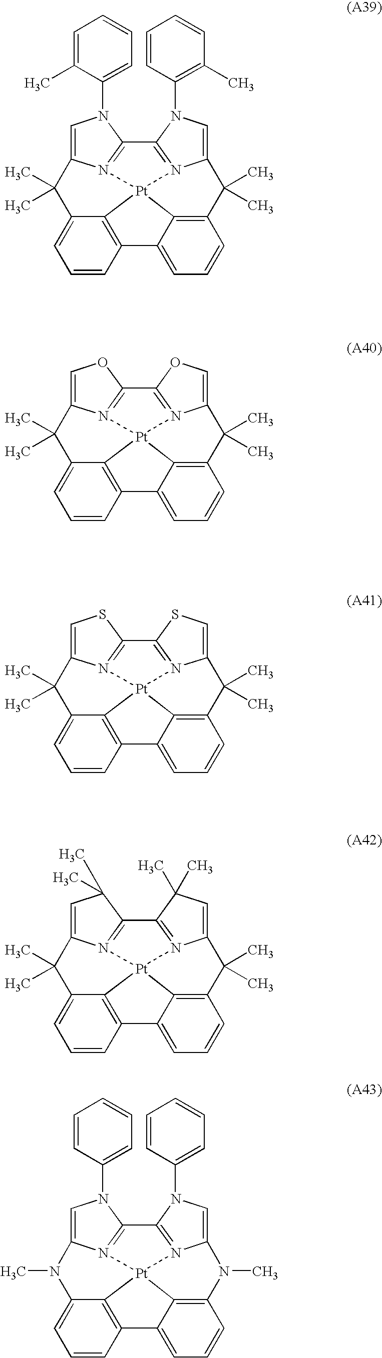

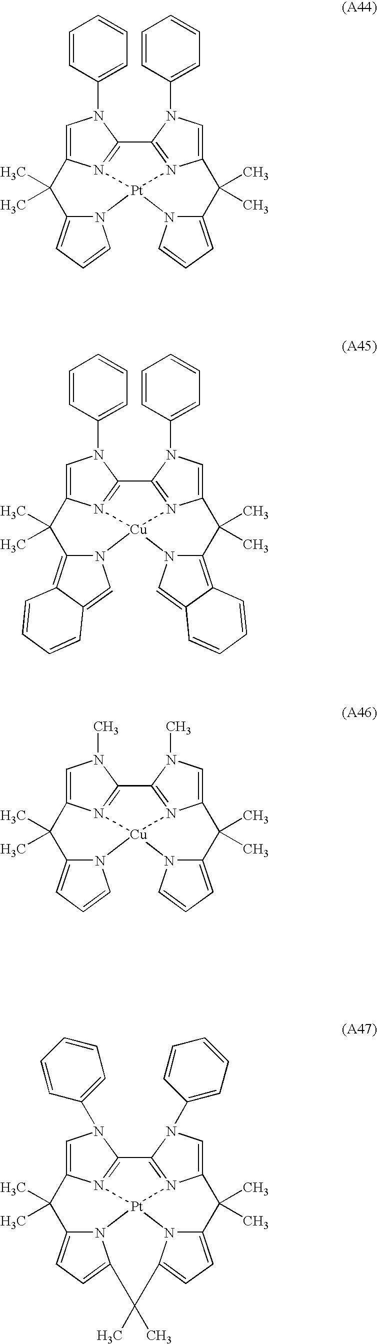

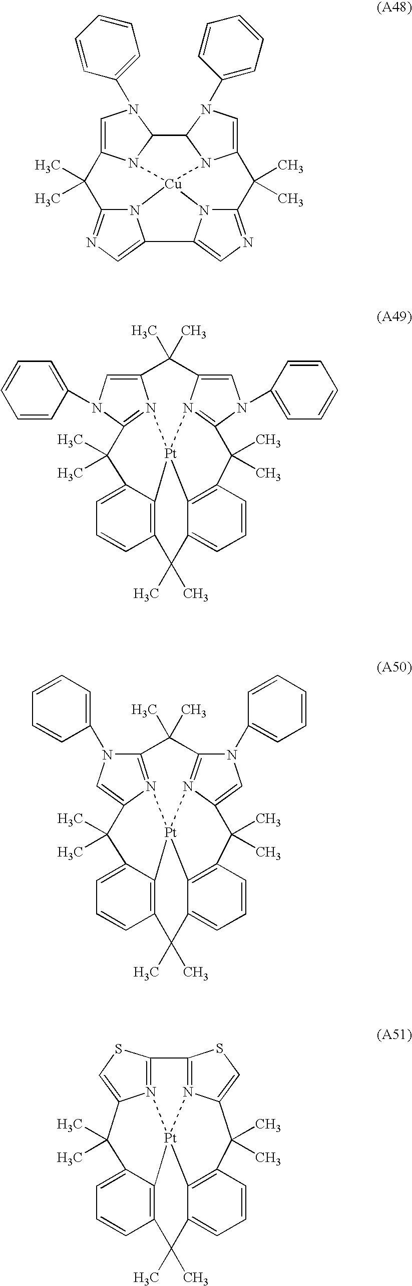

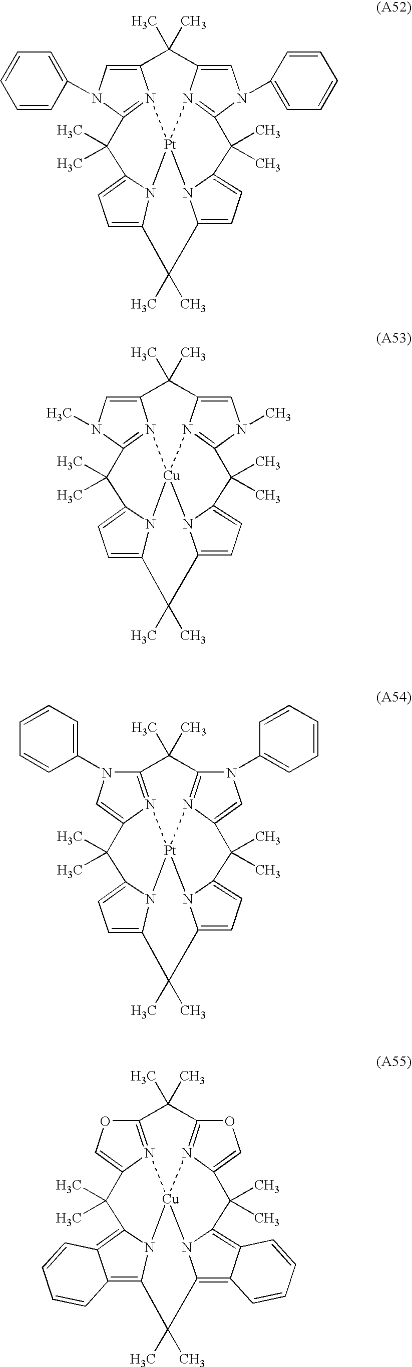

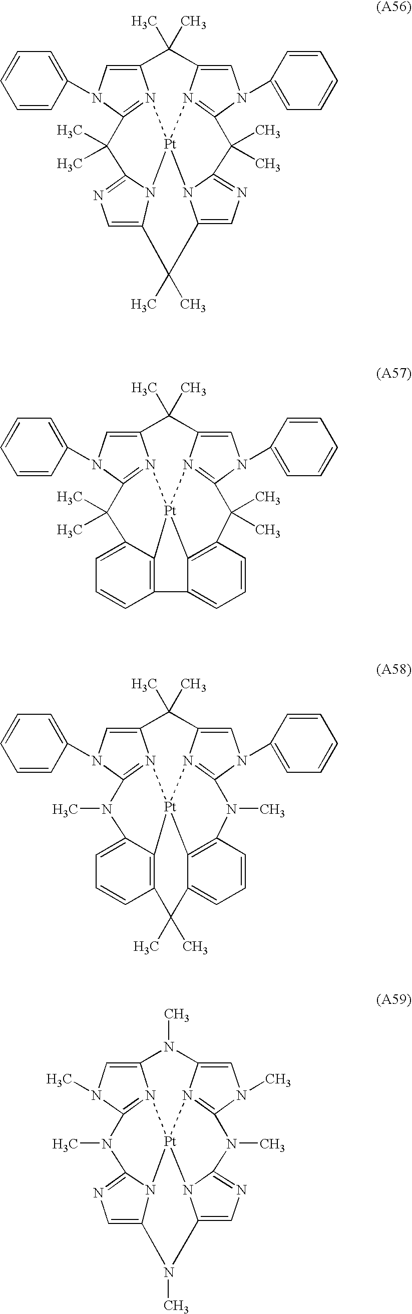

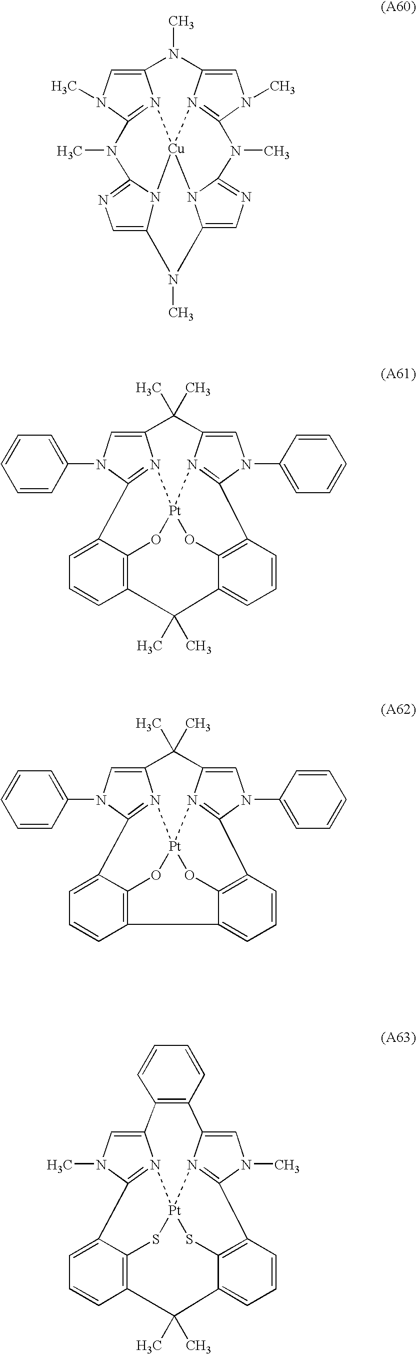

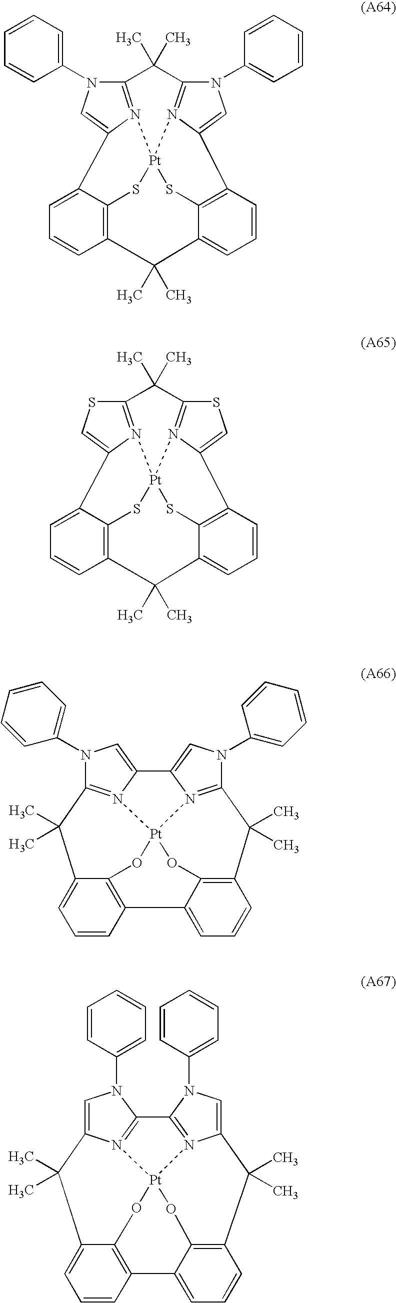

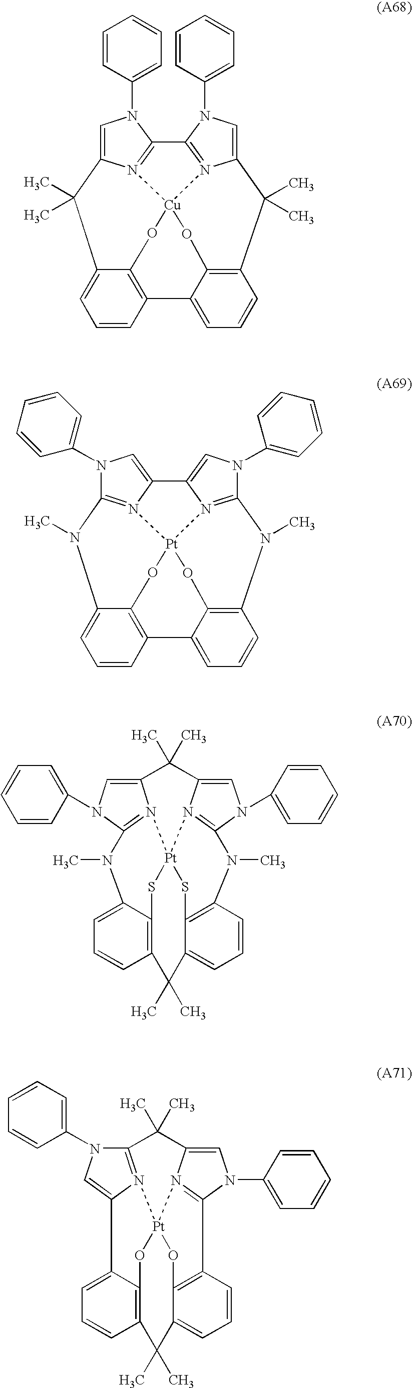

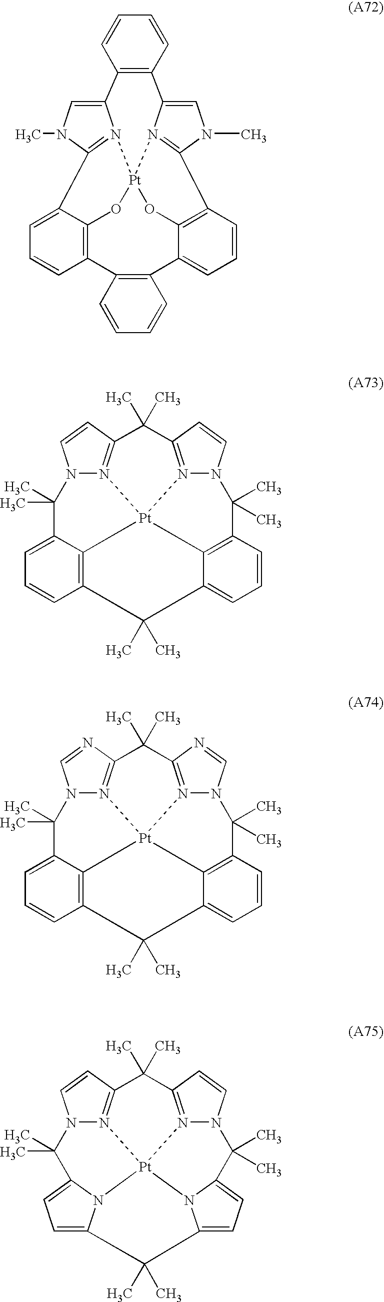

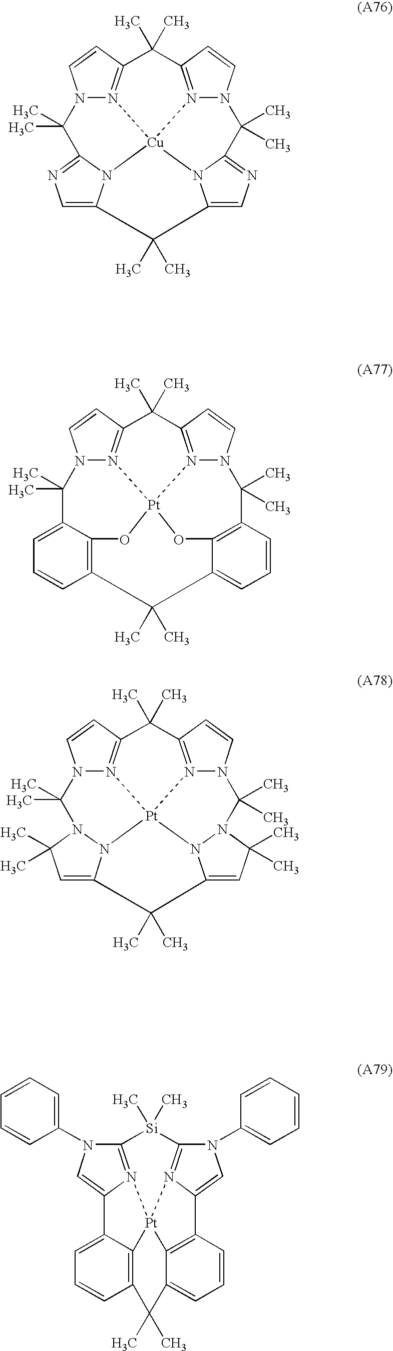

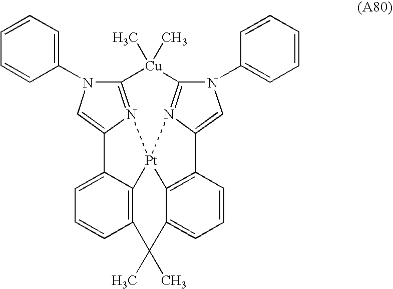

Compounds represented by Formula (B-1) shown below are also preferable as metal complexes usable in the invention.

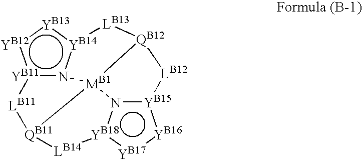

In Formula (B-1), M^{B1} represents a metal ion. Y^{B11}, Y^{B14}, Y^{B15} and Y^{B18} each on atom or a nitrogen atom. Y^{B12}, Y^{B13}, Y^{B16} and Y^{B17} each independently represent a substituted or unsubstituted carbon atom, a substituted or unsubstituted nitrogen atom, an oxygen atom or a sulfur atom. L^{B11}, L^{B12}, L^{B13} and L^{B14} each independently represent a connecting group. Q^{B11} and Q^{B12} each independently represent a partial structure containing an atom bonded to M^{B1}.

The compound represented by Formula (B-1) will be described in detail.

In Formula (B-1), M^{B1}, Y^{B11}, Y^{B14}, Y^{B15}, Y^{B18} Y^{B12}, Y^{B13}, Y^{B16}, Y^{B17}, L^{B11}, L^{B12}, L^{B13}, L^{B14}, Q^{B11} and Q^{B12} have the same definitions as corresponding M^{A1}, Y^{A11}, Y^{A14}, Y^{A15}, Y^{A18} Y^{A12}, Y^{A13}, Y^{A16}, Y^{A17}, L^{A11}, L^{A12}, L^{A13}, L^{A14}, Q^{A11} and Q^{A12} in Formula (A-1) respectively, and their preferable examples are also the same.

More preferable examples of the compound represented by Formula (B-1) include compounds represented by the following Formula (B-2), (B-3) or (B-4).

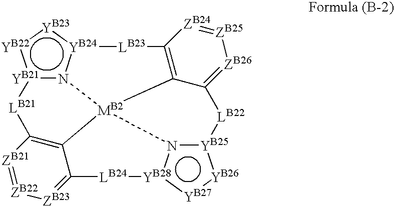

In Formula (B-2), M^{B2} represents a metal ion. Y^{B21}, Y^{B24}, Y^{B25} and Y^{B28} each independently represent a carbon atom or a nitrogen atom. Y^{B22}, Y^{B23}, Y^{B26} and Y^{B27} each independently represent a substituted or unsubstituted carbon atom, a substituted or unsubstituted nitrogen atom, an oxygen atom or a sulfur atom. L^{B21}, L^{B22}, L^{B23} and L^{B24} each independently represent a connecting group. Z^{B21}, Z^{B22}, Z^{B23}, Z^{B24}, Z^{B25} and Z^{B26} each independently represent a nitrogen atom or a substituted or unsubstituted carbon atom.

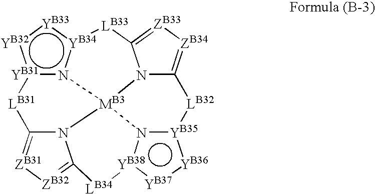

In Formula (B-3), M^{B3} represents a metal ion. Y^{B31}, Y^{B34}, Y^{B35} and Y^{B38} each independently represent a carbon atom or a nitrogen atom. Y^{B32}, Y^{B33}, Y^{B36} and Y^{B37} each independently represent a substituted or unsubstituted carbon atom, a substituted or unsubstituted nitrogen atom, an oxygen atom or a sulfur atom. L^{B31}, L^{B32}, L^{B33} and L^{B34} each independently represent a connecting group. Z^{B31}, Z^{B32}, Z^{B33} and Z^{B34} each independently represent a nitrogen atom or a substituted or unsubstituted carbon atom.

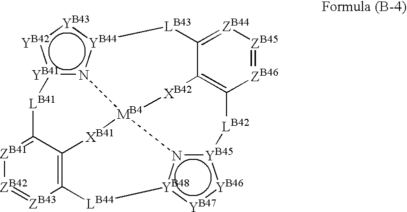

In Formula (B-4), M^{B4} represents a metal ion. Y^{B41}, Y^{B44}, Y^{B45} and Y^{B48} each independently represent a carbon atom or a nitrogen atom. Y^{B42}, Y^{B43}, Y^{B46} and Y^{B47} each independently represent a substituted or unsubstituted carbon atom, a substituted or unsubstituted nitrogen atom, an oxygen atom or a sulfur atom. L^{B41}, L^{B42}, L^{B43} and L^{B44} each independently represent a connecting group. Z^{B41}, Z^{B42}, Z^{B43}, Z^{B44}, Z^{B45} and Z^{B46} each independently represent a nitrogen atom or a substituted or unsubstituted carbon atom. X^{B41} and X^{B42} each independently represent an oxygen atom, a sulfur atom or a substituted or unsubstituted nitrogen atom.

The compound represented by Formula (B-2) will be described in detail.

In Formula (B-2), M^{B2}, Y^{B21}, Y^{B24}, Y^{B25}, Y^{B28}, Y^{B22}, Y^{B23}, Y^{B26}, Y^{B27}, L^{B21}, L^{B22}, L^{B23} and L^{B24} have the same definitions as corresponding M^{B1}, Y^{B11}, Y^{B14}, Y^{B15}, Y^{B18}, Y^{B12}, Y^{B13}, Y^{B16}, Y^{B17}, L^{B11}, L^{B12}, L^{B13} and L^{B14} in Formula (B-1) respectively, and their preferable examples are also the same.

Z^{B21}, Z^{B22}, Z^{B23}, Z^{B24}, Z^{B25} and Z^{B26} each independently represent a nitrogen atom or a substituted or unsubstituted carbon atom. Each of Z^{B21}, Z^{B22}, Z^{B23}, Z^{B24}, Z^{B25} and Z^{B26} is preferably a substituted or unsubstituted carbon atom, and more preferably an unsubstituted carbon atom. When the carbon atom is substituted, the substituent may be selected from the above-mentioned examples of the substituent on the divalent connecting group represented by L^{A11}, L^{A12}, L^{A13} or L^{A14} in Formula (A-1).

The compound represented by Formula (B-3) will be described in detail.

In Formula (B-3), M^{B3}, Y^{B31}, Y^{B34}, Y^{B35}, Y^{B38}, Y^{B32}, Y^{B33}, Y^{B36}, Y^{B37}, L^{B31}, L^{B32}, L^{B33} and L^{B34} have the same definitions as corresponding M^{B1}, Y^{B11}, Y^{B14}, Y^{B15}, Y^{B18}, Y^{B12}, Y^{B13}, Y^{B16}, Y^{B17}, L^{B11}, L^{B12}, L^{B13} and L^{B14} in Formula (B-1) respectively, and their preferable examples are also the same.

Z^{B31}, Z^{B32}, Z^{B33} and Z^{B34} each independently represent a nitrogen atom or a substituted or unsubstituted carbon atom. Each of Z^{B31}, Z^{B32}, Z^{B33} and Z^{B34} is preferably a substituted or unsubstituted carbon atom, and more preferably an unsubstituted carbon atom. When the carbon atom is substituted, the substituent may be selected from the above-mentioned examples of the substituent on the divalent connecting group represented by L^{A11}, L^{A12}, L^{A13} or L^{A14} in Formula (A-1)

The compound represented by Formula (B-4) will be described in detail.

In Formula (B-4), M^{B4}, Y^{B41}, Y^{B44}, Y^{B45}, Y^{B48}, Y^{B42}, Y^{B43}, Y^{B46}, Y^{B47}, L^{B41}, L^{B42}, L^{B43} and L^{B44} have the same definitions as corresponding M^{B1}, Y^{B11}, Y^{B14}, Y^{B15}, Y^{B18}, Y^{B12}, Y^{B13}, Y^{B16}, Y^{B17}, L^{B11}, L^{B12}, L^{B13} and L^{B14} in Formula (B-1) respectively, and their preferable examples are also the same.

Z^{B41}, Z^{B42}, Z^{B43}, Z^{B44}, Z^{B45} and Z^{B46} each independently represent a nitrogen atom or a substituted or unsubstituted carbon atom. Each of Z^{B41}, Z^{B42}, Z^{B43}, Z^{B44}, Z^{B45} and Z^{B46} is preferably a substituted or unsubstituted carbon atom, and more preferably an unsubstituted carbon atom. When the carbon atom is substituted, the substituent may be selected from the above-mentioned examples of the substituent on the divalent connecting group represented by L^{A11}, L^{A12}, L^{A13} or L^{A14} in Formula (A-1).

X^{B41} and X^{B42} each independently represent an oxygen atom, a sulfur atom or a substituted or unsubstituted nitrogen atom. Each of X^{B41} and X^{B42} is preferably an oxygen atom or a sulfur atom, and more preferably an oxygen atom.

Specific examples of the compounds represented by Formula (B-1) are illustrated below, but the invention is not limited thereto.

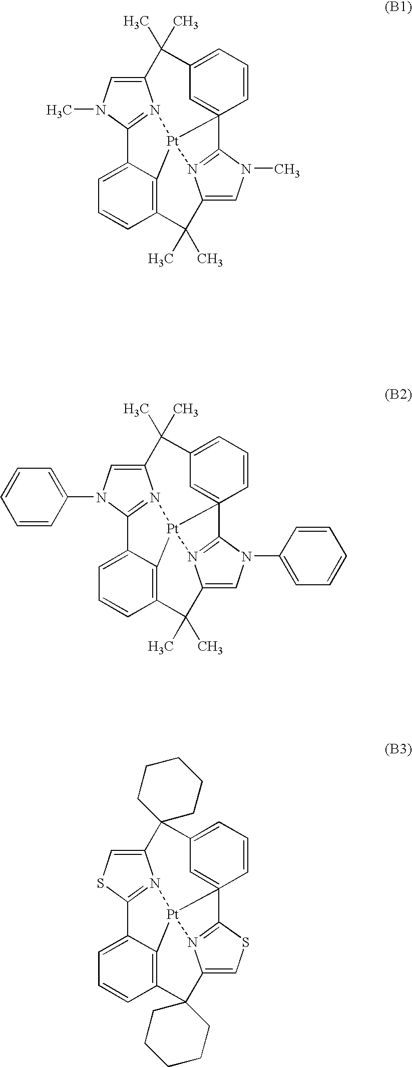

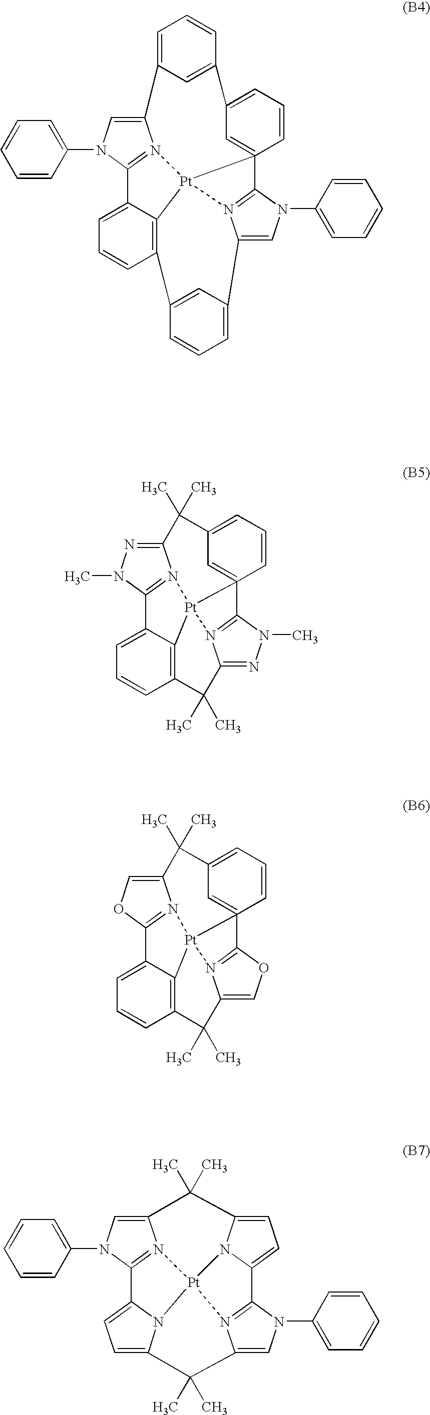

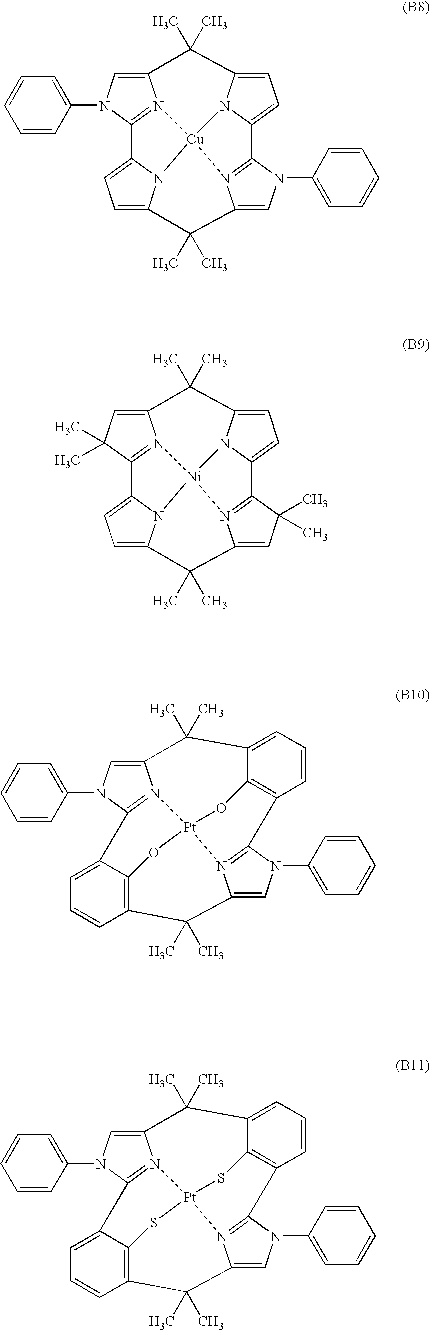

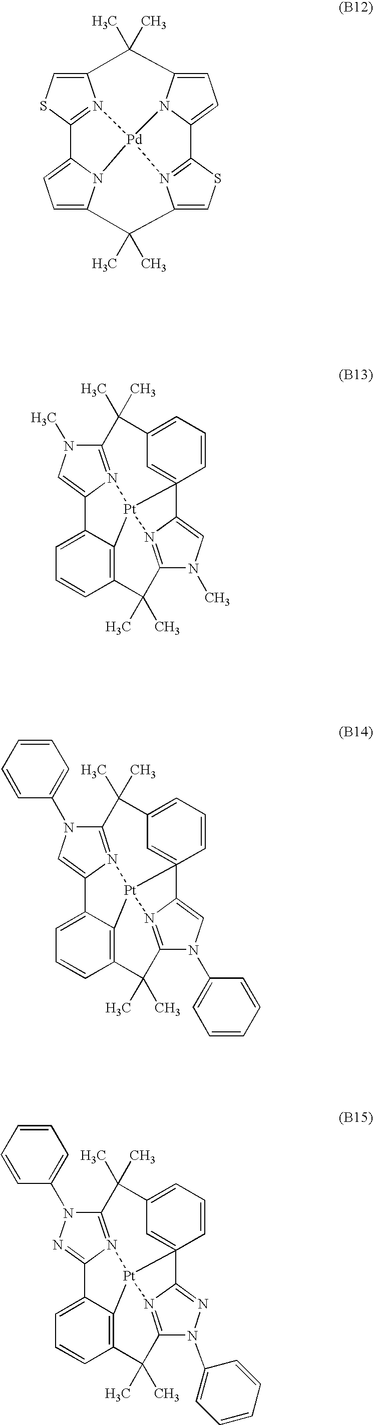

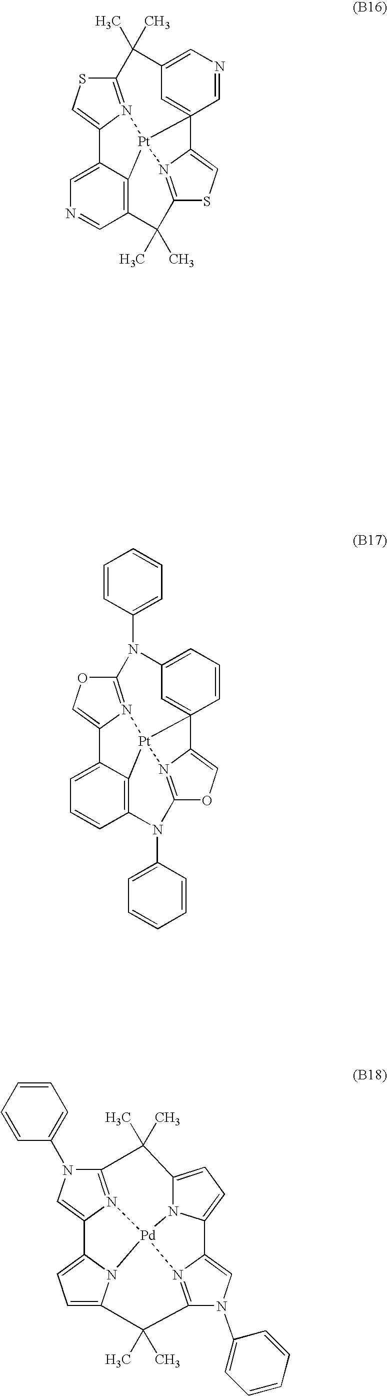

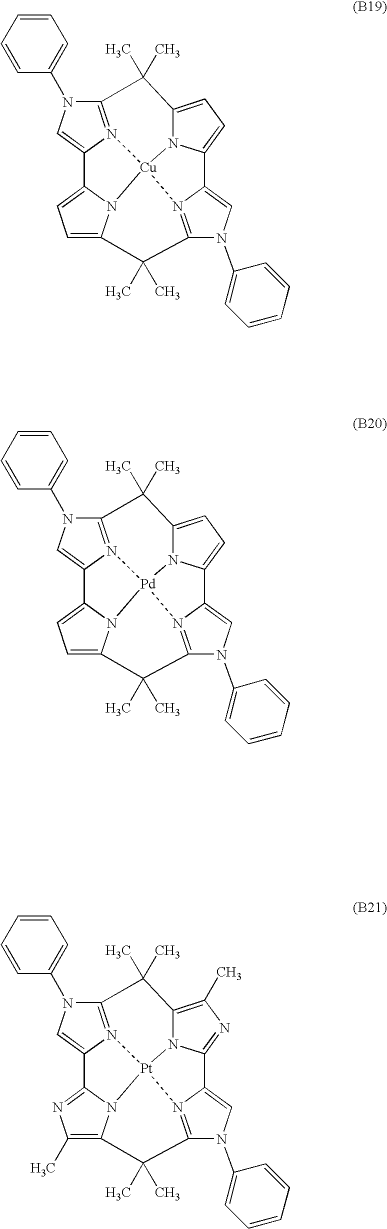

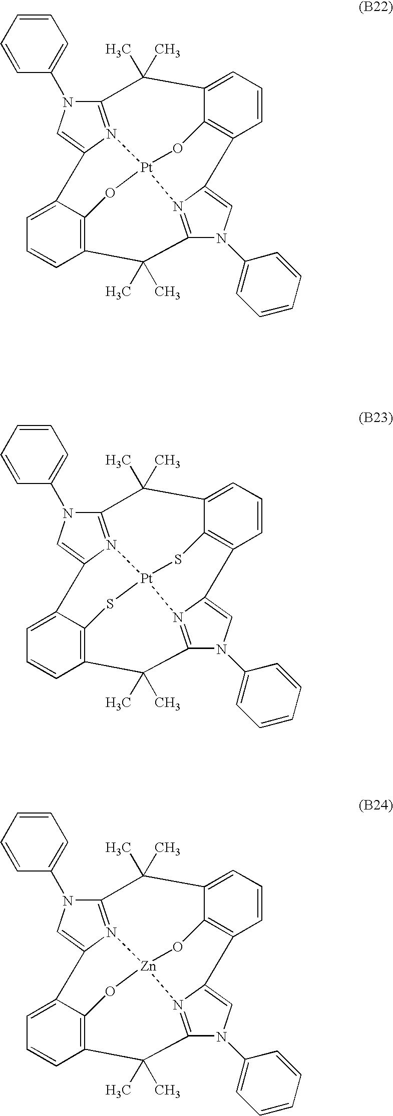

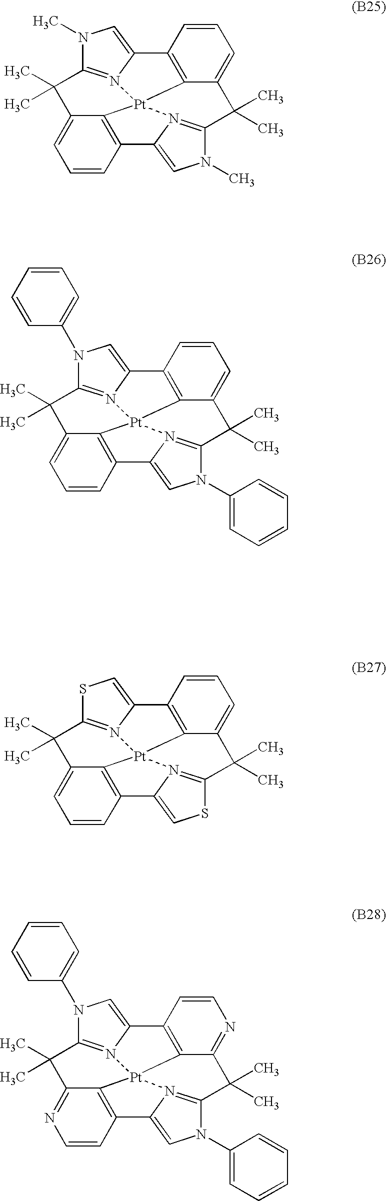

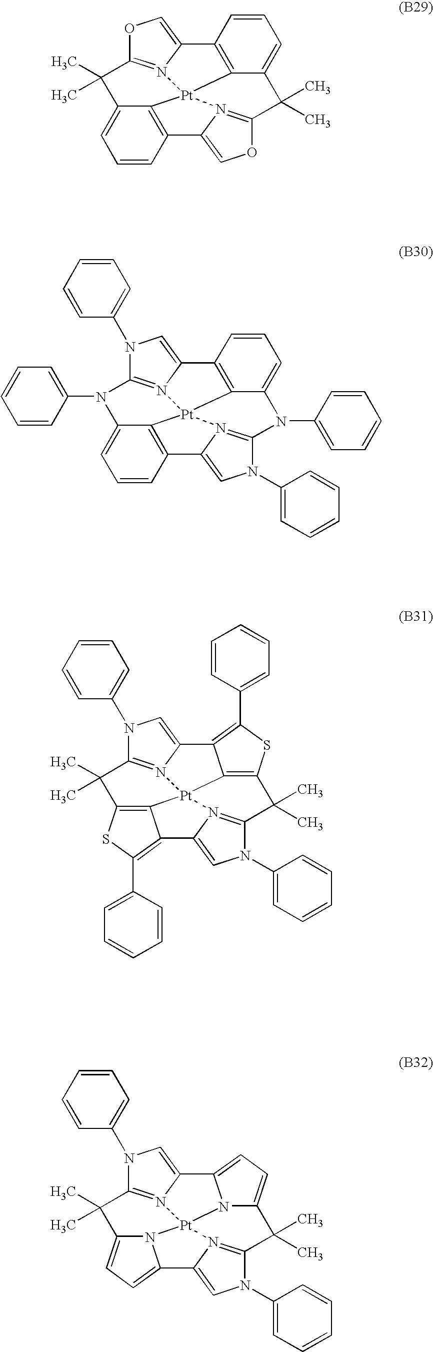

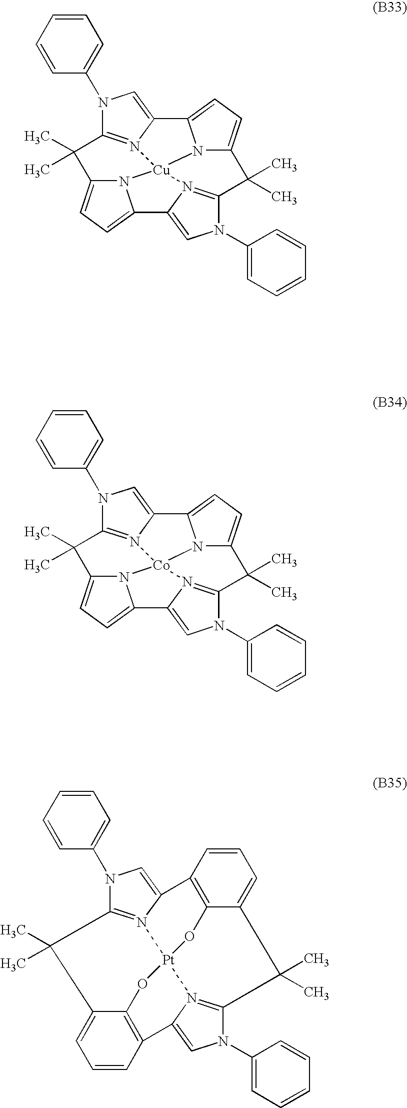

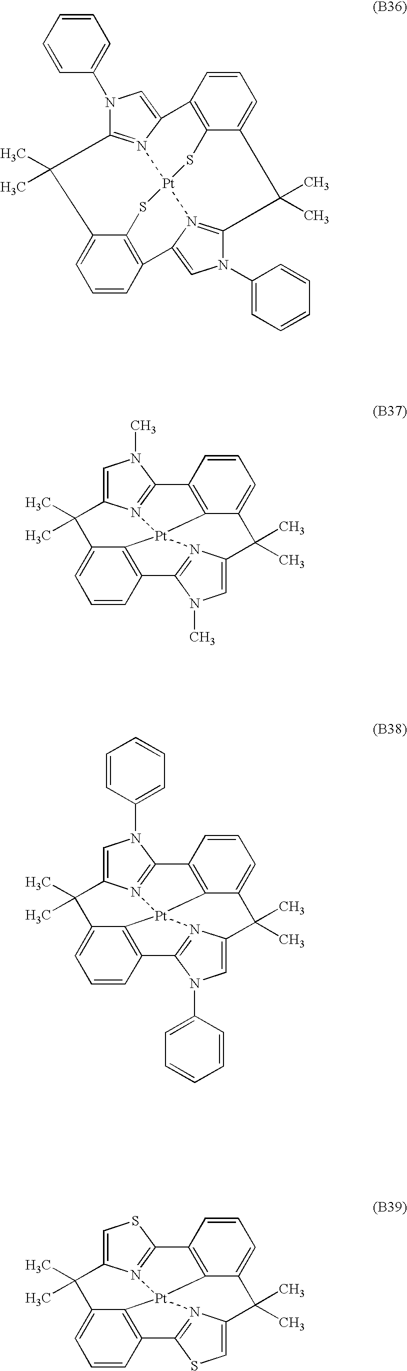

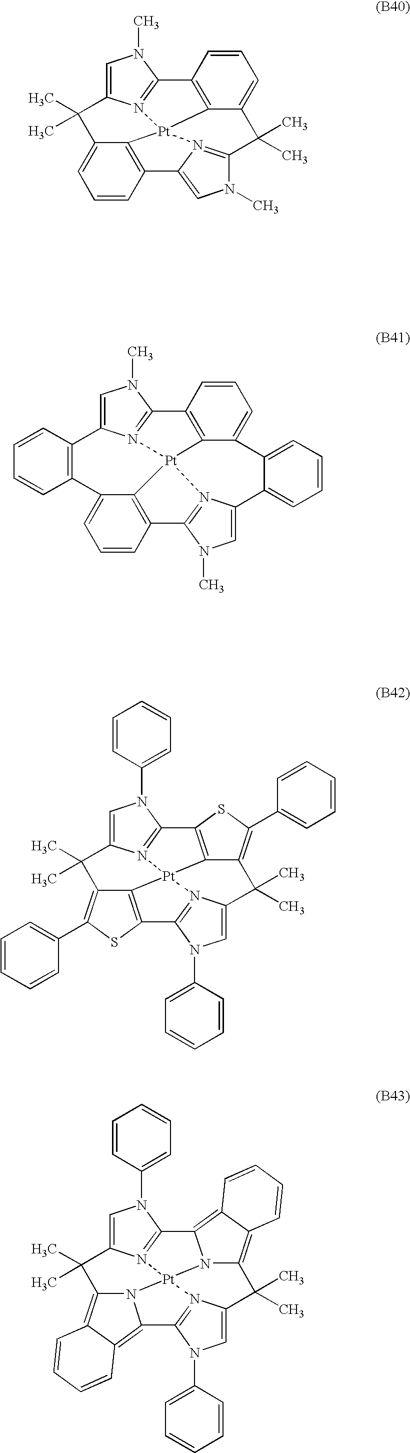

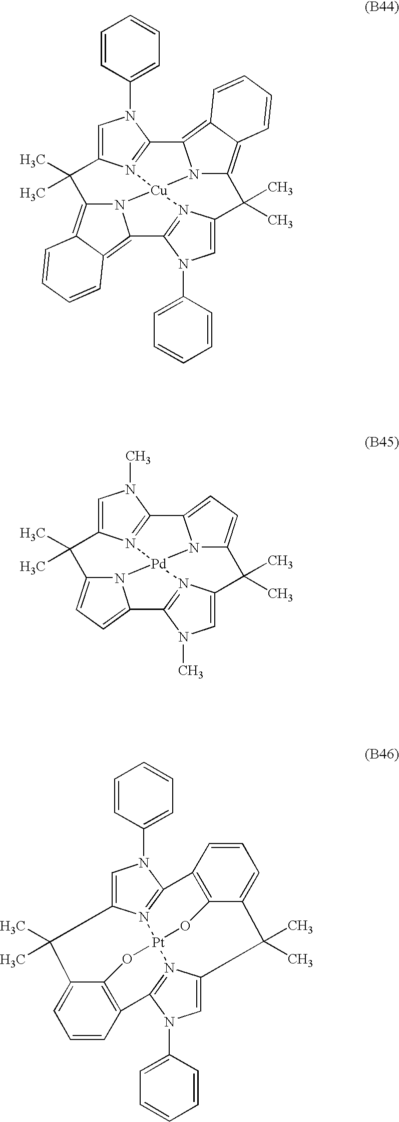

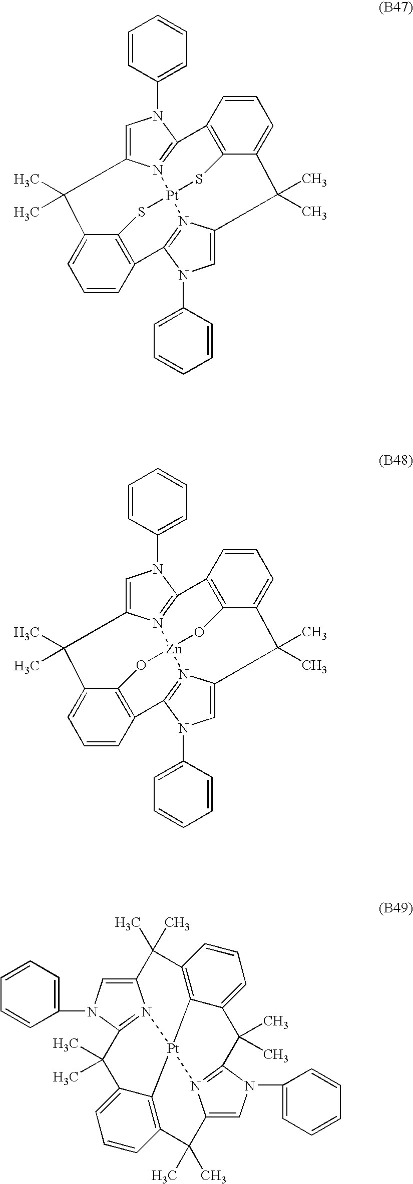

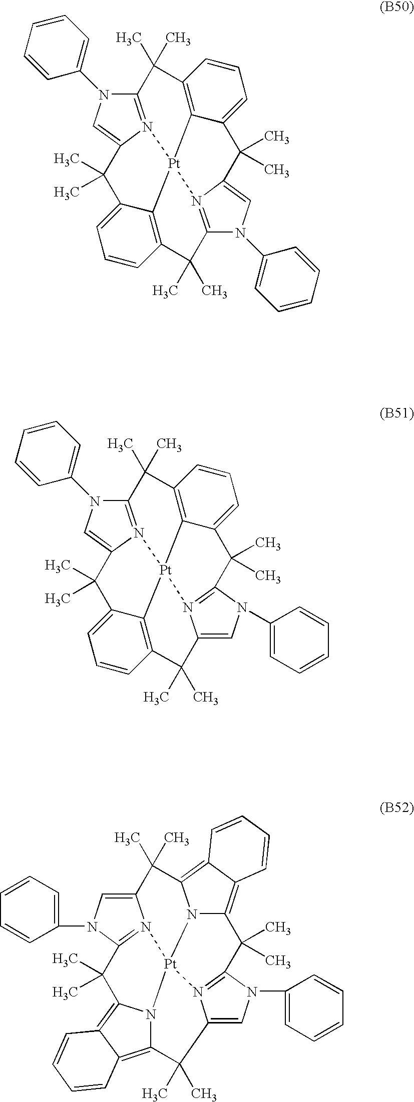

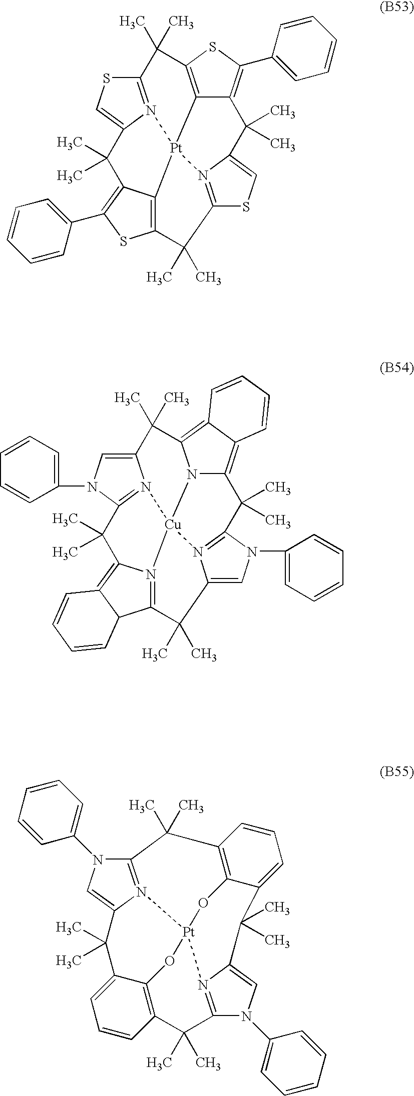

An example of preferable metal complexes usable in the invention is a compound represented by the following Formula (C-1).

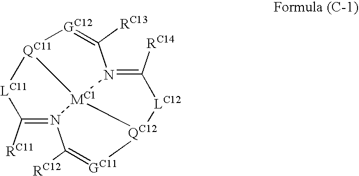

In Formula (C-1), M^{C1} represents a metal ion. R^{C11} and R^{C12} each independently represent a hydrogen atom or a substituent. When R^{C11} and R^{C12} represent substituents, the substituents may be bonded to each other to form a 5-membered ring. R^{C13} and R^{C14} each independently represent a hydrogen atom or a substituent. When R^{C13} and R^{C14} represent substituents, the substituents may be bonded to each other to form a 5-membered ring. G^{C11} and G^{C12} each independently represent a nitrogen atom or a substituted or unsubstituted carbon atom. L^{C11} and L^{C12} each independently represent a connecting group. Q^{C11} and Q^{C12} each independently represent a partial structure containing an atom covalently bonded to M^{C1}.

Formula (C-1) will be described in detail.

In Formula (C-1), M^{C1}, L^{C11}, L^{C12}, Q^{C11} and Q^{C12} have the same definitions as corresponding M^{A1}, L^{A1}, L^{A12}, Q^{A11} and Q^{A12} in Formula (A-1) respectively, and their preferable examples are also the same.

G^{C11} and G^{C12} each independently represent a nitrogen atom or a substituted or unsubstituted carbon atom, preferably a nitrogen atom or an unsubstituted carbon atom, and more preferably a nitrogen atom.

R^{C11} and R^{C12} each independently represent a hydrogen atom or a substituent. R^{C11} and R^{C12} may be bonded to each other to form a 5-membered ring. R^{C13} and R^{C14} each independently represent a hydrogen atom or a substituent. R^{C13} and R^{C14} may be bonded to each other to form a 5-membered ring.

The substituent represented by R^{C11}, R^{C12}, R^{C13} or R^{C14} may be, for example, an alkyl group (preferably having 1 to 30 carbon atoms, more preferably having 1 to 20 carbon atoms, particularly preferably having 1 to 10 carbon atoms; and examples thereof include a methyl group, an ethyl group, an iso-propyl group, a tert-butyl group, a n-octyl group, a n-decyl group, a n-hexadecyl group, a cyclopropyl group, a cyclopentyl group, a cyclohexyl group, etc.), an alkenyl group (preferably having 2 to 30 carbon atoms, more preferably having 2 to 20 carbon atoms, particularly preferably having 2 to 10 carbon atoms; and examples thereof include a vinyl group, an allyl group, a 2-butenyl group, and a 3-pentenyl group), an alkynyl group (preferably having 2 to 30 carbon atoms, more preferably having 2 to 20 carbon atoms, particularly preferably having 2 to 10 carbon atoms; and examples thereof include a propargyl group and a 3-pentynyl group),

an aryl group (preferably having 6 to 30 carbon atoms, more preferably having 6 to 20 carbon atoms, particularly preferably having 6 to 12 carbon atoms; and examples thereof include phenyl, p-methylphenyl, naphthyl, anthranyl, etc.), an amino group (preferably having 0 to 30 carbon atoms, more preferably having 0 to 20 carbon atoms, particularly preferably having 0 to 10 carbon atoms; and examples thereof include an amino group, a methylamino group, a dimethylamino group, a diethylamino group, a dibenzylamino group, a diphenylamino group, and a ditolylamino group), an alkoxy group (preferably having 1 to 30 carbon atoms, more preferably having 1 to 20 carbon atoms, particularly preferably having 1 to 10 carbon atoms; and examples thereof include a methoxy group, an ethoxy group, a butoxy group, and a 2-ethylhexyloxy group), an aryloxy group (preferably a having 6 to 30 carbon atoms, more preferably having 6 to 20 carbon atoms, particularly preferably having 6 to 12 carbon atoms; and examples thereof include a phenyloxy group, a 1-naphthyloxy group, and a 2-naphthyloxy group),

a heterocyclic oxy group (preferably having 1 to 30 carbon atoms, more preferably having 1 to 20 carbon atoms, particularly preferably having 1 to 12 carbon atoms; and examples thereof include a pyridyloxy group, a pyrazyloxy group, a pyrimidyloxy group, and a quinolyloxy group), an acyl group (preferably having 1 to 30 carbon atoms, more preferably having 1 to 20 carbon atoms, particularly preferably having 1 to 12 carbon atoms; and examples thereof include an acetyl group, a benzoyl group, a formyl group, and a pivaloyl group), an alkoxycarbonyl group (preferably having 2 to 30 carbon atoms, more preferably having 2 to 20 carbon atoms, particularly preferably having 2 to 12 carbon atoms; and examples thereof include a methoxycarbonyl group and an ethoxycarbonyl group), an aryloxycarbonyl group (preferably having 7 to 30 carbon atoms, more preferably having 7 to 20 carbon atoms, particularly preferably having 7 to 12 carbon atoms; and examples thereof include a phenyloxycarbonyl group),

an acyloxy group (preferably having 2 to 30 carbon atoms, more preferably having 2 to 20 carbon atoms, particularly preferably having 2 to 10 carbon atoms; and examples thereof include an acetoxy group and a benzoyloxy group), an acylamino group (preferably having 2 to 30 carbon atoms, more preferably having 2 to 20 carbon atoms, particularly preferably having 2 to 10 carbon atoms; and examples thereof include an acetylamino group and a benzoylamino group), an alkoxycarbonylamino group (preferably having 2 to 30 carbon atoms, more preferably having 2 to 20 carbon atoms, particularly preferably having 2 to 12 carbon atoms; and examples thereof include a methoxycarbonylamino group), an aryloxycarbonylamino group (preferably having 7 to 30 carbon atoms, more preferably having 7 to 20 carbon atoms, particularly preferably having 7 to 12 carbon atoms; and examples thereof include a phenyloxycarbonylamino group),

an alkylthio group (preferably having 1 to 30 carbon atoms, more preferably having 1 to 20 carbon atoms, particularly preferably having 1 to 12 carbon atoms; and examples thereof include a methylthio group and an ethylthio group), an arylthio group (preferably having 6 to 30 carbon atoms, more preferably having 6 to 20 carbon atoms, particularly preferably having 6 to 12 carbon atoms; and examples thereof include a phenylthio group), a heterocyclic thio group (preferably having 1 to 30 carbon atoms, more preferably having 1 to 20 carbon atoms, particularly preferably having 1 to 12 carbon atoms; and examples thereof include a pyridylthio group, a 2-benzimidazolylthio group, a 2-benzoxazolylthio group, and a 2-benzthiazolylthio group), a halogen atom (such as a fluorine atom, chlorine atom, bromine atom, iodine atom), a cyano group,

a heterocyclic group (preferably having 1 to 30 carbon atoms, more preferably having 1 to 12 carbon atoms, and containing a heteroatom such as a nitrogen atom, an oxygen atom or a sulfur atom; examples include an imidazolyl group, a pyridyl group, a quinolyl group, a furyl group, a thienyl group, a, piperidyl group, a morpholino group, a benzoxazolyl group, a benzimidazolyl group, a benzthiazolyl group, a carbazolyl group, and an azepinyl group), a silyl group (preferably having 3 to 40 carbon atoms, more preferably having 3 to 30 carbon atoms, particularly preferably having 3 to 24 carbon atoms; and examples thereof include a trimethylsilyl group, and a triphenylsilyl group) or a silyloxy group (preferably having 3 to 40 carbon atoms, more preferably having 3 to 30 carbon atoms, particularly preferably having 3 to 24 carbon atoms; and examples thereof include a trimethylsilyloxy group and a triphenylsilyloxy group).

The substituent represented by R^{C11}, R^{C12}, R^{C13} or R^{C14} is preferably an alkyl group, an aryl group, or such a group that R^{C11} and R^{C12}, or R^{C13} and R^{C14}, are bonded to each other to form a 5-membered ring. In a particularly preferable embodiment, R^{C11} and R^{C12}, or R^{C13} and R^{C14}, are bonded to each other to form a 5-membered ring.

The compound represented by Formula (C-1) is more preferably a compound represented by Formula (C-2).

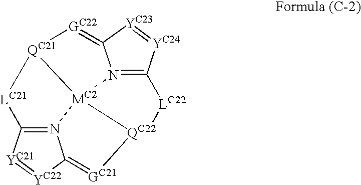

In Formula (C-2), M^{C2} represents a metal ion.

Y^{C21}, Y^{C22}, Y^{C23} and Y^{C24} each independently represent a nitrogen atom or a substituted or unsubstituted carbon atom. G^{C21} and G^{C22} each independently represent a nitrogen atom or a substituted or unsubstituted carbon atom. L^{C21} and L^{C22} each independently represent a connecting group. Q^{C21} and Q^{C22} each independently represent a partial structure containing an atom bonded to M^{C2}.

Formula (C-2) will be described in detail.

In Formula (C-2), M^{C2}, L^{C21}, L^{C22}, Q^{C21}, Q^{C22}, G^{C21} and G^{C22} have the same definitions as corresponding M^{C1}, L^{C11}, L^{C12}, Q^{C11}, Q^{C12}, G^{C11} and G^{C12} in Formula (C-1) respectively, and their preferable examples are also the same.

Y^{C21}, Y^{C22}, Y^{C23} and Y^{C24} each independently represent a nitrogen atom or a substituted or unsubstituted carbon atom, preferably a substituted or unsubstituted carbon atom, and more preferably an unsubstituted carbon atom.

The compound represented by Formula (C-2) is more preferably a compound represented by the following Formula (C-3), (C-4) or (C-5).

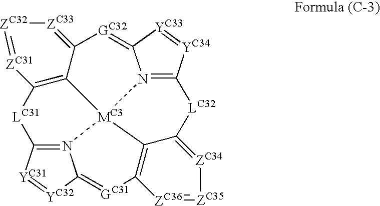

In Formula (C-3), M^{C3} represents a metal ion.

Y^{C31}, Y^{C32}, Y^{C33} and Y^{C34} each independently represent a nitrogen atom or a substituted or unsubstituted carbon atom. G^{C31} and G^{C32} each independently represent a nitrogen atom or a substituted or unsubstituted carbon atom. L^{C31} and L^{C32} each independently represent a connecting group. Z^{C31}, Z^{C32}, Z^{C33}, Z^{C34}, Z^{C35} and Z^{C36} each independently represent a nitrogen atom or a substituted or unsubstituted carbon atom.

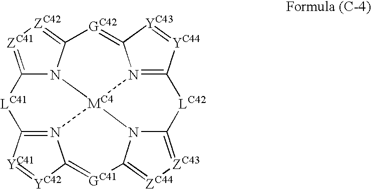

In Formula (C-4), M^{C4} represents a metal ion.

Y^{C41}, Y^{C42}, Y^{C43} and Y^{C44} each independently represent a nitrogen atom or a substituted or unsubstituted carbon atom. G^{C41} and G^{C42} each independently represent a nitrogen atom or a substituted or unsubstituted carbon atom. L^{C41} and L^{C42} each independently represent a connecting group. Z^{C41}, Z^{C42}, Z^{C43} and Z^{C44} each independently represent a nitrogen atom or a substituted or unsubstituted carbon atom.

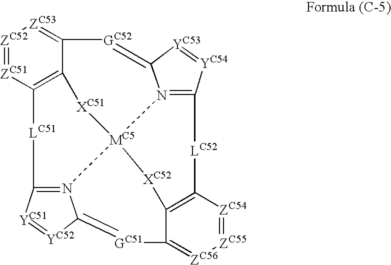

In Formula (C-5), M^{C5} represents a metal ion.

Y^{C51}, Y^{C52}, Y^{C53} and Y^{C54} each independently represent a nitrogen atom or a substituted or unsubstituted carbon atom. G^{C51} and G^{C52} each independently represent a nitrogen atom or a substituted or unsubstituted carbon atom. L^{C51} and L^{C52} each independently represent a connecting group. Z^{C51}, Z^{C52}, Z^{C53}, Z^{C54}, Z^{C55} and Z^{C56} each independently represent a nitrogen atom or a substituted or unsubstituted carbon atom. X^{C51} and X^{C52} each independently represent an oxygen atom, a sulfur atom or a substituted or unsubstituted nitrogen atom.

The compound represented by Formula (C-3) will be described in detail.

In Formula (C-3), M^{C3}, L^{C31}, L^{C32}, G^{C31} and G^{C32} have the same definitions as corresponding M^{C1}, L^{C11}, L^{C12}, G^{C11} and G^{C12} in Formula (C-1) respectively, and their preferable examples are also the same.

Z^{C31}, Z^{C32}, Z^{C33}, Z^{C34}, Z^{C35} and Z^{C36} each independently represent a nitrogen atom or a substituted or unsubstituted carbon atom. Each of Z^{C31}, Z^{C32}, Z^{C33}, Z^{C34}, Z^{C35} and Z^{C36} is preferably a substituted or unsubstituted carbon atom, and more preferably an unsubstituted carbon atom.

The compound represented by Formula (C-4) is described in more detail.

In Formula (C-4), M^{C4}, L^{C41}, L^{C42}, G^{C41} and G^{C42} have the same definitions as corresponding M^{C1}, L^{C11}, L^{C12}, G^{C11} and G^{C12} in Formula (C-1) respectively, and their preferable examples are also the same.

Z^{C41}, Z^{C42}, Z^{C43}, and Z^{C44} each independently represent a nitrogen atom or a substituted or unsubstituted carbon atom. Each of Z^{C41}, Z^{C42}, Z^{C43} and Z^{C44} is preferably a substituted or unsubstituted carbon atom, and more preferably an unsubstituted carbon atom.

The compound represented by Formula (C-5) is described in more detail.

M^{C5}, L^{C51}, L^{C52}, G^{C51} and G^{C52} have the same definitions as corresponding M^{C1}, L^{C11}, L^{C12}, G^{C11} and G^{C12} in Formula (C-1) respectively, and their preferable examples are also the same.

Z^{C51}, Z^{C52}, Z^{C53}, Z^{C54}, Z^{C55} and Z^{C56} each independently represent a nitrogen atom or a substituted or unsubstituted carbon atom. Each of Z^{C51}, Z^{C52}, Z^{C53}, Z^{C54}, Z^{C55} and Z^{C56} is preferably a substituted or unsubstituted carbon atom, and more preferably an unsubstituted carbon atom.

X^{C51} and X^{C52} each independently represent an oxygen atom, a sulfur atom or a substituted or unsubstituted nitrogen atom. Each of X^{C51} and X^{C52} is preferably an oxygen atom or a sulfur atom, and more preferably an oxygen atom.

Specific examples of the compounds represented by Formula (C-1) are illustrated below, however, the invention is not limited thereto.

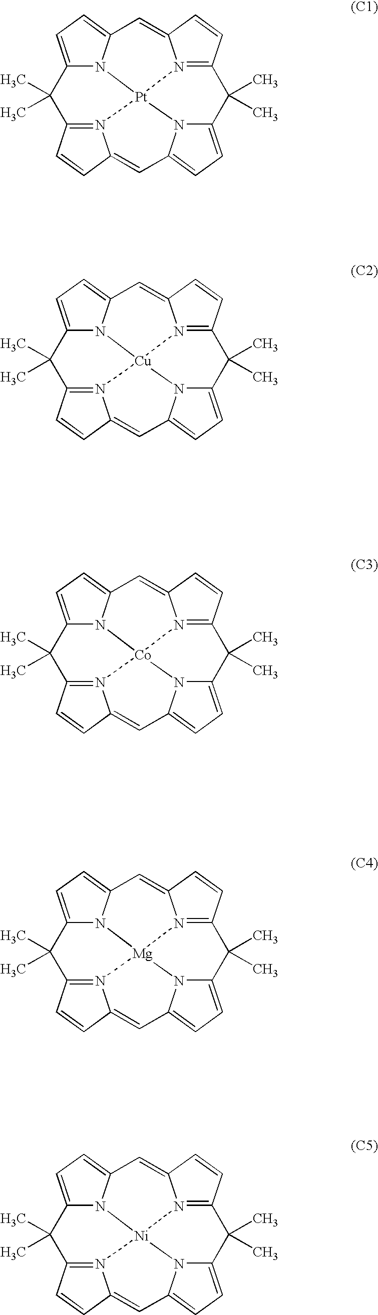

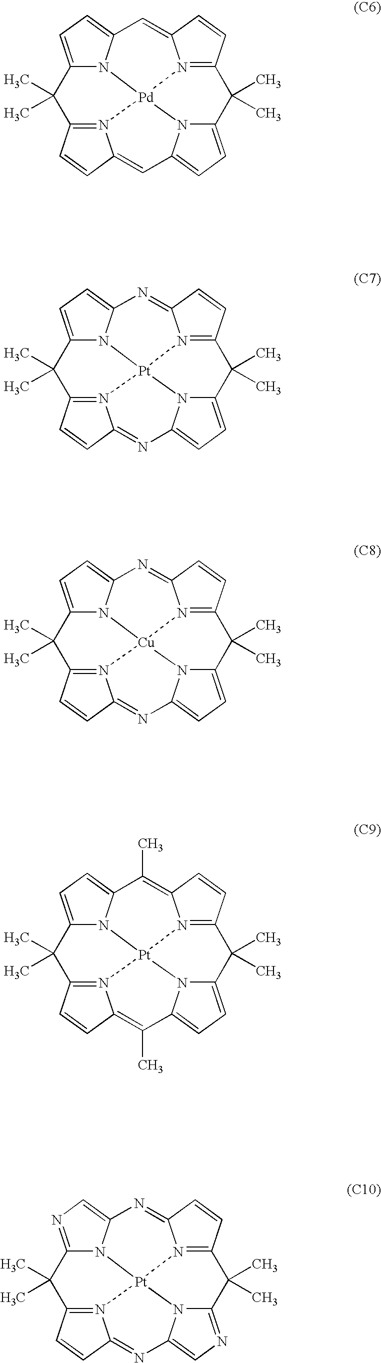

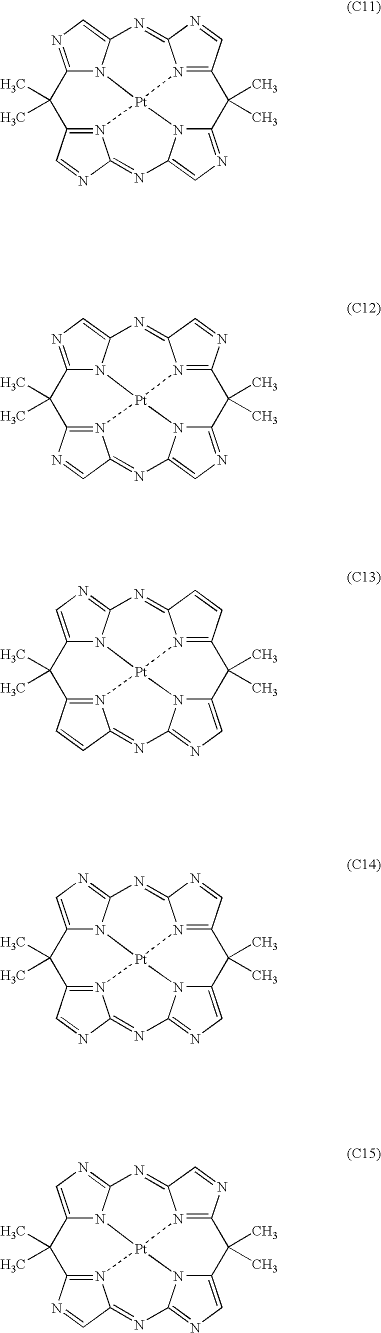

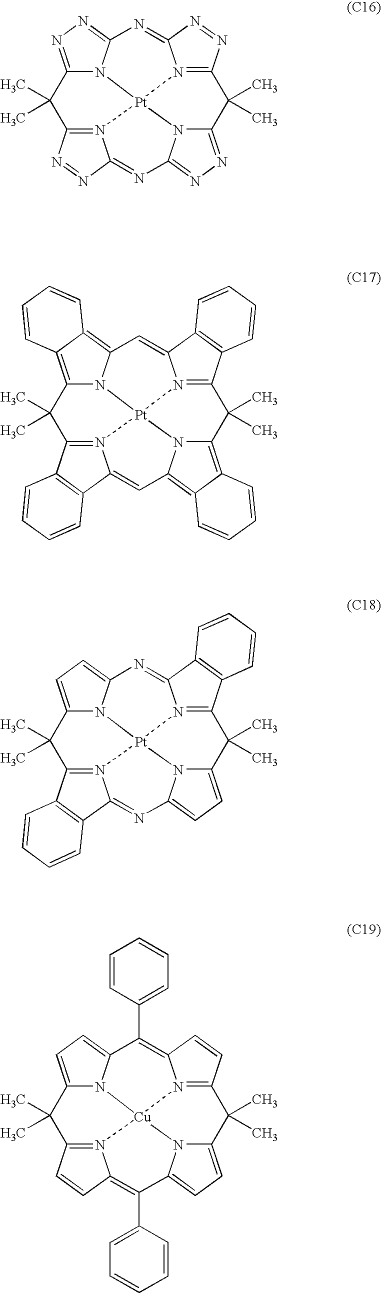

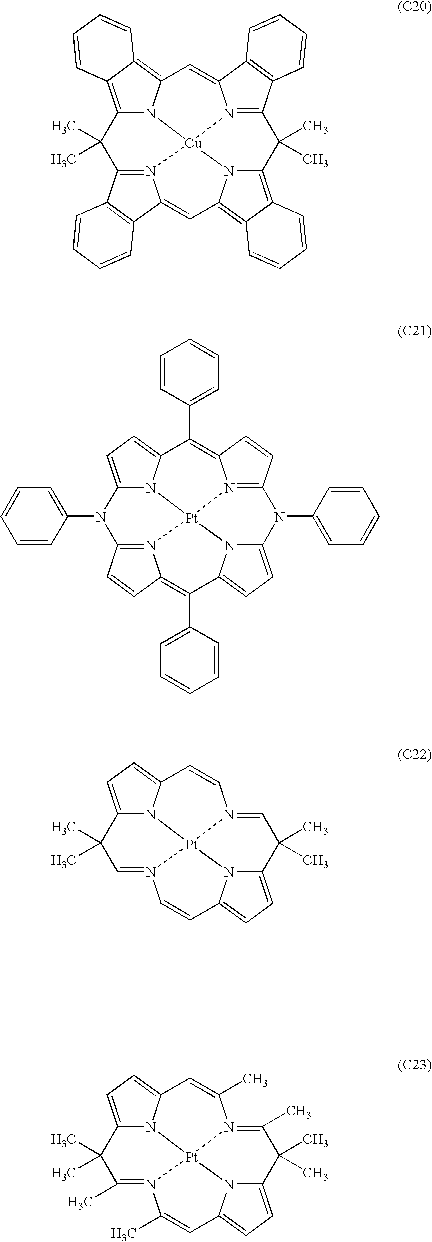

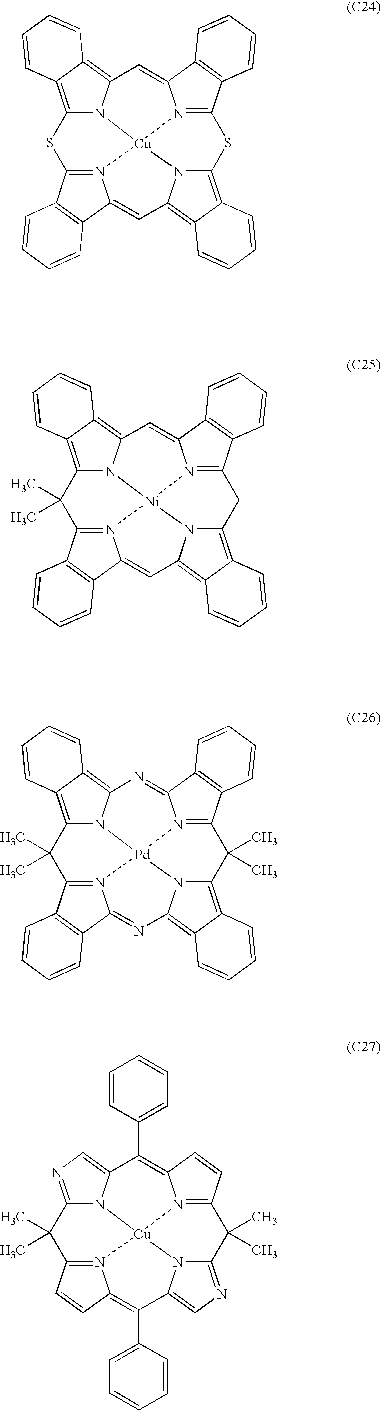

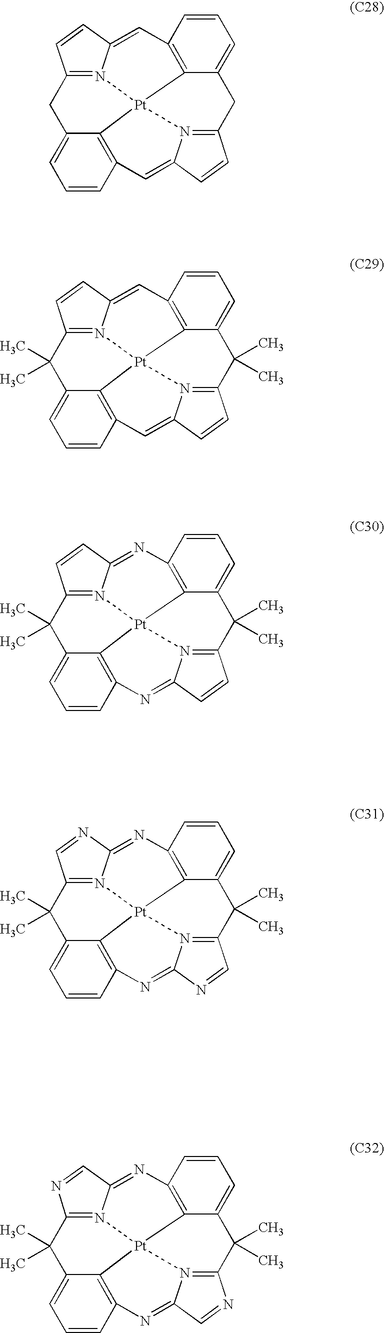

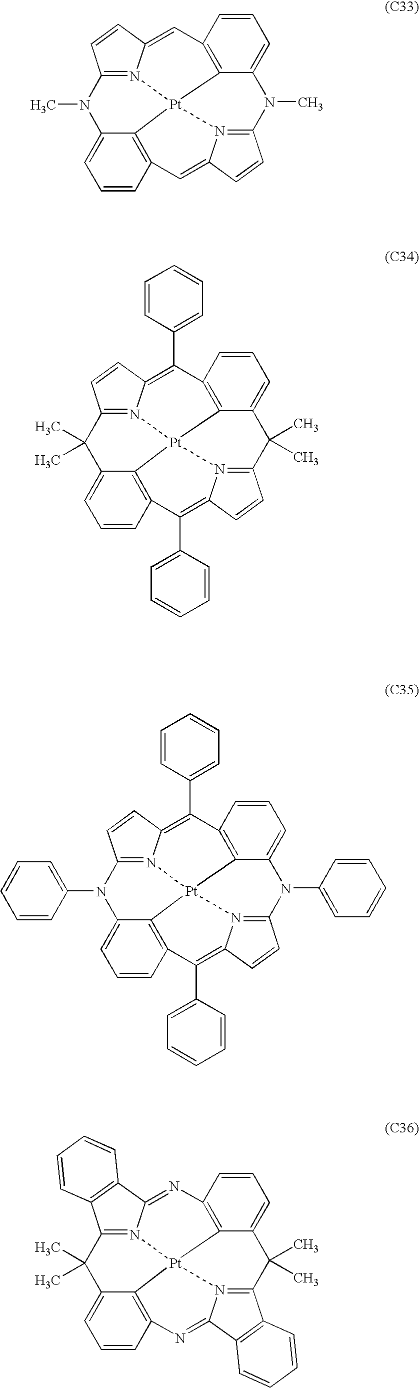

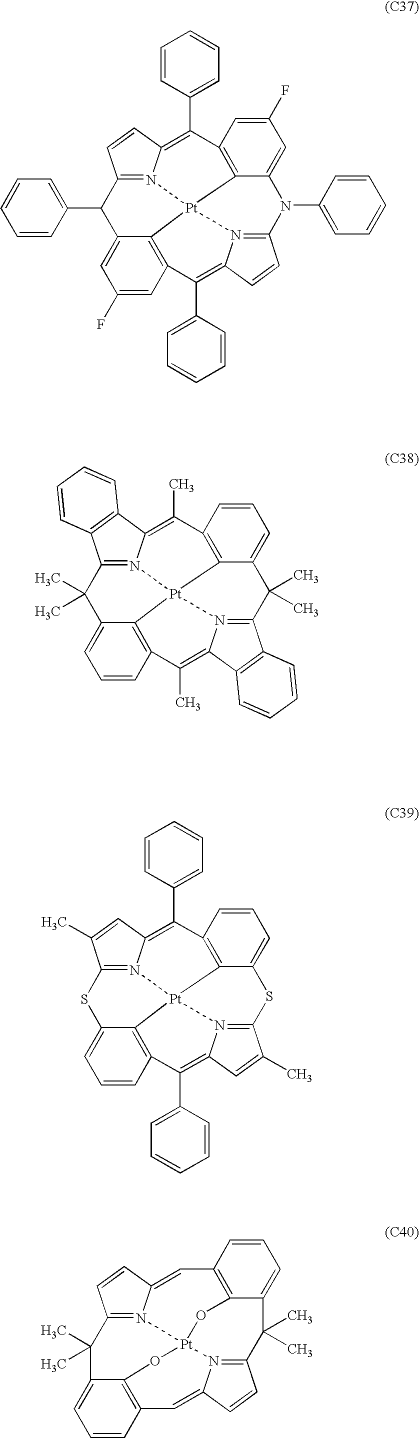

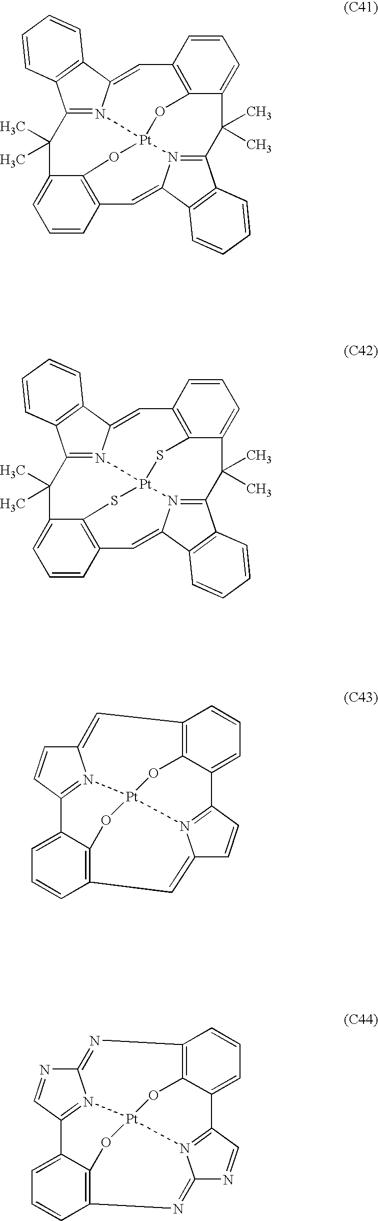

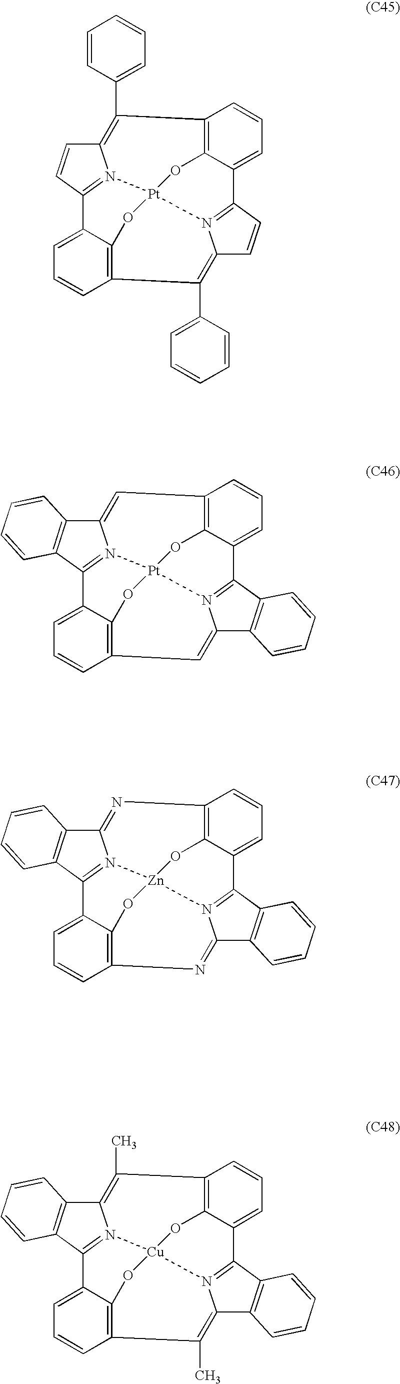

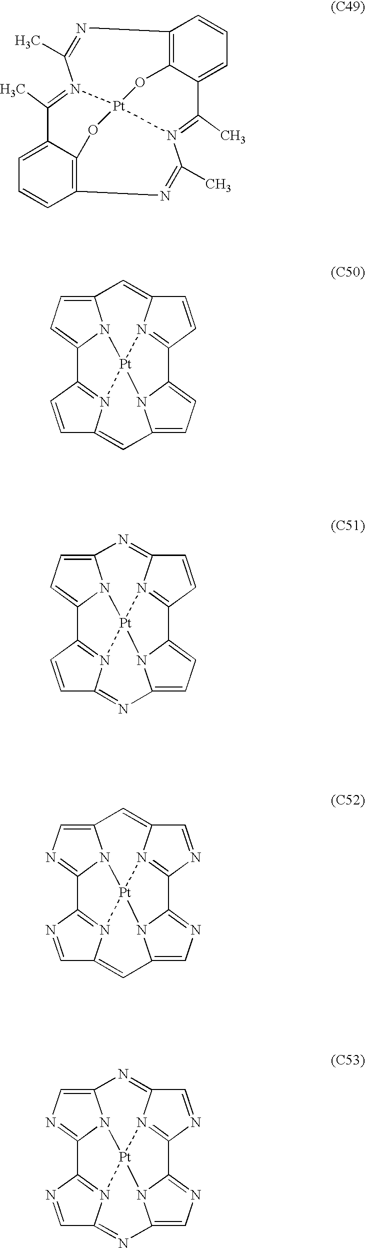

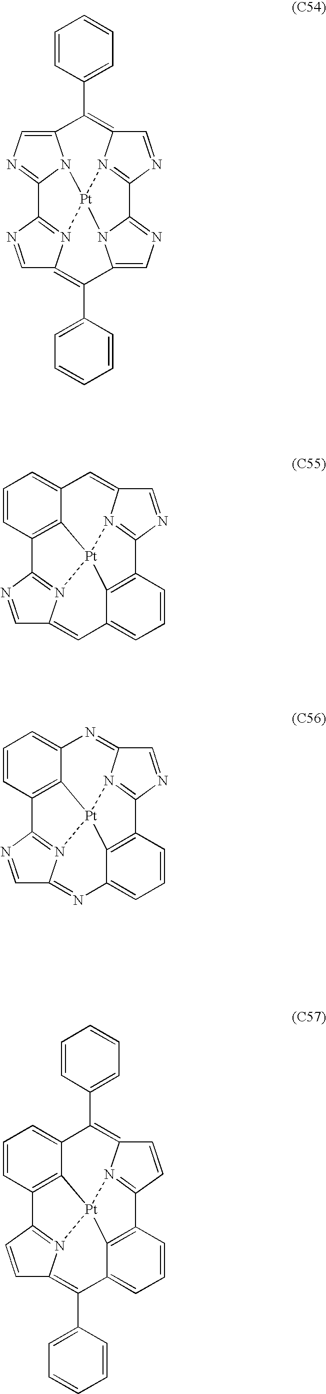

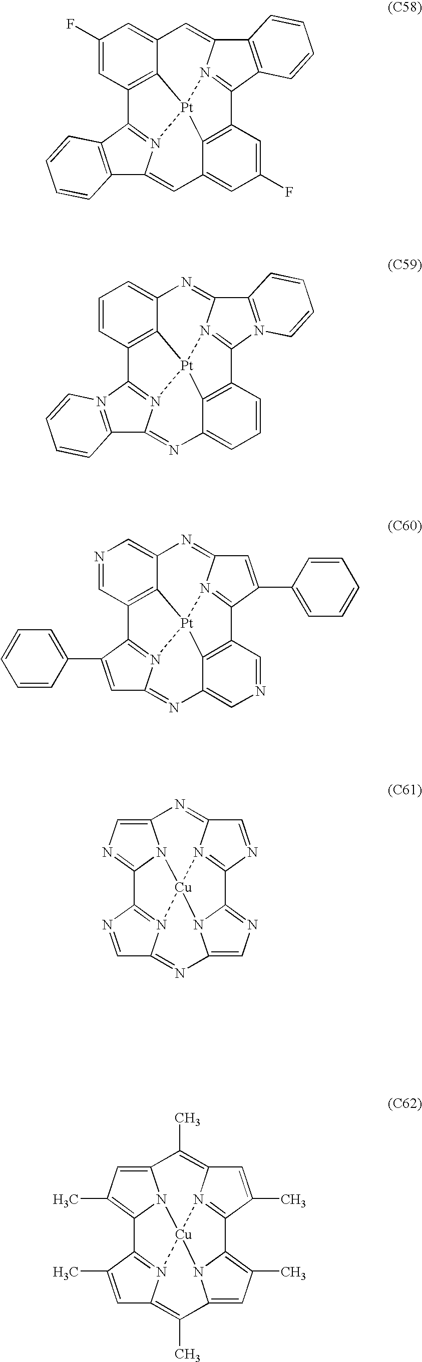

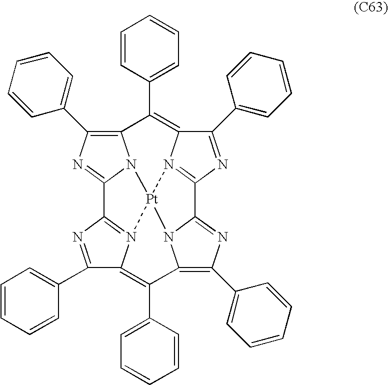

An example of preferable metal complexes usable in the invention is a compound represented by the following Formula (D-1).

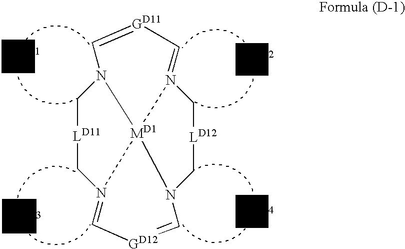

In Formula (D-1), M^{D1} represents a metal ion.

G^{D11} and G^{D12} each independently represent a nitrogen atom or a substituted or unsubstituted carbon atom. J^{D11}, J^{D12}, J^{D13} and J^{D14} each independently represent an atomic group necessary for forming a 5-membered ring. L^{D11} and L^{D12} each independently represent a connecting group.

Formula (D-1) will be described in detail.

In Formula (D-1), M^{D1}, L^{D11} and L^{D12} have the same definitions as corresponding M^{A1}, L^{A11} and L^{A12} in Formula (A-1) respectively, and their preferable examples are also the same.

G^{D11} and G^{D12} have the same definitions as corresponding G^{C11} and G^{C12} in Formula (C-1) respectively, and their preferable examples are also the same.

J^{D11}, J^{D12}, J^{D13} and J^{D14} each independently represent an atomic group necessary for forming a nitrogen-containing 5-membered heterocycle containing the atomic group.

The compound represented by Formula (D-1) is more preferably a compound represented by the following Formula (D-2), (D-3) or (D-4).

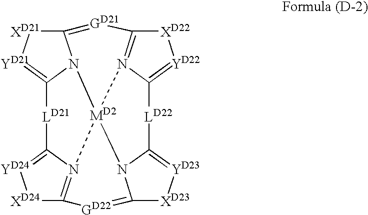

In Formula (D-2), M^{D2} represents a metal ion.

G^{D21} and G^{D22} each independently represent a nitrogen atom or a substituted or unsubstituted carbon atom.

Y^{D21}, Y^{D22}, Y^{D23} and Y^{D24} each independently represent a nitrogen atom or a substituted or unsubstituted carbon atom.

X^{D21}, X^{D22}, X^{D23} and X^{D24} each independently represent an oxygen atom, a sulfur atom, —NR^{D21}— or —C(R^{D22})R^{D23}—.

R^{D21}, R^{D22} and R^{D23} each independently represent a hydrogen atom or a substituent. L^{D21} and L^{D22} each independently represent a connecting group.

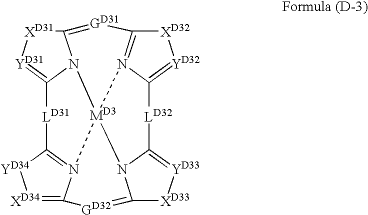

In Formula (D-3), M^{D3} represents a metal ion.

G^{D31} and G^{D32} each independently represent a nitrogen atom or a substituted or unsubstituted carbon atom.

Y^{D31}, Y^{D32}, Y^{D33} and Y^{D34} each independently represent a nitrogen atom or a substituted or unsubstituted carbon atom.

X^{D31}, X^{D32}, X^{D33} and X^{D34} each independently represent an oxygen atom, a sulfur atom, —NR^{D31}— or —C(R^{D32})R^{D33}—.

R^{D31}, R^{D32} and R^{D33} each independently represent a hydrogen atom or a substituent. L^{D31} and L^{D32} each independently represent a connecting group.

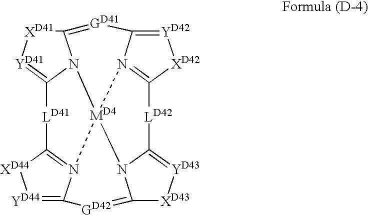

In Formula (D-4), M^{D4} represents a metal ion.

G^{D41} and G^{D42} each independently represent a nitrogen atom or a substituted or unsubstituted carbon atom.

Y^{D41}, Y^{D42}, Y^{D43} and Y^{D44} each independently represent a nitrogen atom or a substituted or unsubstituted carbon atom.

X^{D41}, X^{D42}, X^{D43} and X^{D44} each independently represent an oxygen atom, a sulfur atom, —NR^{D41}— or —C(R^{D42})R^{D43}—. R^{D41}, R^{D42} and R^{D43} each independently represent a hydrogen atom or a substituent. L^{D41} and L^{D42} each independently represent a connecting group.

Formula (D-2) will be described in detail.

In Formula (D-2), M^{D2}, L^{D21}, L^{D22}, G^{D21} and G^{D22} have the same definitions as corresponding M^{D1}, L^{D11}, L^{D12}, G^{D11} and G^{D12} in Formula (D-1) respectively, and their preferable examples are also the same.

Y^{D21}, Y^{D22}, Y^{D23} and Y^{D24} each independently represent a nitrogen atom or a substituted or unsubstituted carbon atom, preferably a substituted or unsubstituted carbon atom, and more preferably an unsubstituted carbon atom.

X^{D21}, X^{D22}, X^{D23} and X^{D24} each independently represent an oxygen atom, a sulfur atom, —NR^{D21}— or —C(R^{D22})R^{D23}—, preferably a sulfur atom, —NR^{D21}— or —C(R^{D22})R^{D23}—, more preferably —NR^{D21}— or —C(R^{D22})R^{D23}—, and further more preferably —NR^{D21}—.

R^{D21}, R^{D22} and R^{D23} each independently represent a hydrogen atom or a substituent. The substituent represented by R^{D21}, R^{D22} or R^{D23} may be, for example, an alkyl group (preferably those having 1 to 20 carbon atoms, more preferably those having 1 to 12 carbon atoms, particularly preferably those having 1 to 8 carbon atoms, and examples thereof include a methyl group, an ethyl group, an iso-propyl group, a tert-butyl group, a n-octyl group, a n-decyl group, a n-hexadecyl group, a cyclopropyl group, a cyclopentyl group, and a cyclohexyl group), an alkenyl group (preferably those having 2 to 20 carbon atoms, more preferably those having 2 to 12 carbon atoms, particularly preferably those having 2 to 8 carbon atoms, and examples thereof include a vinyl group, an allyl group, a 2-butenyl group, and a 3-pentenyl group), an alkynyl group (preferably those having 2 to 20 carbon atoms, more preferably those having 2 to 12 carbon atoms, particularly preferably those having 2 to 8 carbon atoms, and examples thereof include a propargyl group and a 3-pentynyl group),

an aryl group (preferably those having 6 to 30 carbon atoms, more preferably those having 6 to 20 carbon atoms, particularly preferably those having 6 to 12 carbon atoms group, and examples thereof include a phenyl group, a p-methylphenyl group, and a naphthyl group), a substituted carbonyl group (preferably those having 1 to 20 carbon atoms, more preferably those having 1 to 16 carbon atoms, particularly preferably those having 1 to 12 carbon atoms group, and examples thereof include a acetyl group, a benzoyl group, a methoxycarbonyl group, a phenyloxycarbonyl group, a dimethylaminocarbonyl group, and a phenylaminocarbonyl group), a substituted sulfonyl group (preferably those having 1 to 20 carbon atoms, more preferably those having 1 to 16 carbon atoms, particularly preferably those having 1 to 12 carbon atoms group, and examples thereof include a mesyl group and a tosyl group), or

a heterocyclic group (including an aliphatic heterocyclic group and aromatic heterocyclic group, preferably those having 1 to 50 carbon atoms, more preferably those having 1 to 30 carbon atoms, more preferably those having 2 to 12 carbon atoms, preferably containing an oxygen atom, a sulfur atom or a nitrogen atom, and examples thereof include an imidazolyl group, a pyridyl group, a furyl group, a piperidyl group, a morpholino group, a benzoxazolyl group, and a triazolyl group). Each of R^{D21}, R^{D22} and R^{D23} is preferably an alkyl group, aryl group or aromatic heterocyclic group, more preferably an alkyl or aryl group, and still more preferably an aryl group.

Formula (D-3) will be described in detail.

In Formula (D-3), M^{D3}, L^{D31}, L^{D32}, G^{D31} and G^{D32} have the same definitions as corresponding M^{D1}, L^{D11}, L^{D12}, G^{D11} and G^{D12} in Formula (D-1) respectively, and their preferable examples are also the same.

X^{D31}, X^{D32}, X^{D33} and X^{D34} have the same definitions as corresponding X^{D21}, X^{D22}, X^{D23} and X^{D24} in Formula (D-2) respectively, and their preferable examples are also the same.

Y^{D31}, Y^{D32}, Y^{D33} and Y^{D34} have the same definitions as corresponding Y^{D21}, Y^{D22}, Y^{D23} and Y^{D24} in Formula (D-2) respectively, and their preferable examples are also the same.

Formula (D-4) will be described in detail.

In Formula (D-4), M^{D4}, L^{D41}, L^{D42}, G^{D41} and G^{D42} have the same definitions as corresponding M^{D1}, L^{D11}, L^{D12}, G^{D11} and G^{D12} in Formula (D-1) respectively, and their preferable examples are also the same.

X^{D41}, X^{D42}, X^{D43} and X^{D44} have the same definitions as corresponding X^{D21}, X^{D22}, X^{D23} and X^{D24} in Formula (D-2) respectively, and their preferable examples are also the same. Y^{D41}, Y^{D42}, Y^{D43} and Y^{D44} have the same definitions as corresponding Y^{D21}, Y^{D22}, Y^{D23} and Y^{D24} in Formula (D-2) respectively, and their preferable examples are also the same.

Specific examples of the compounds represented by Formula (D-1) are illustrated below, but the invention is not limited thereto.

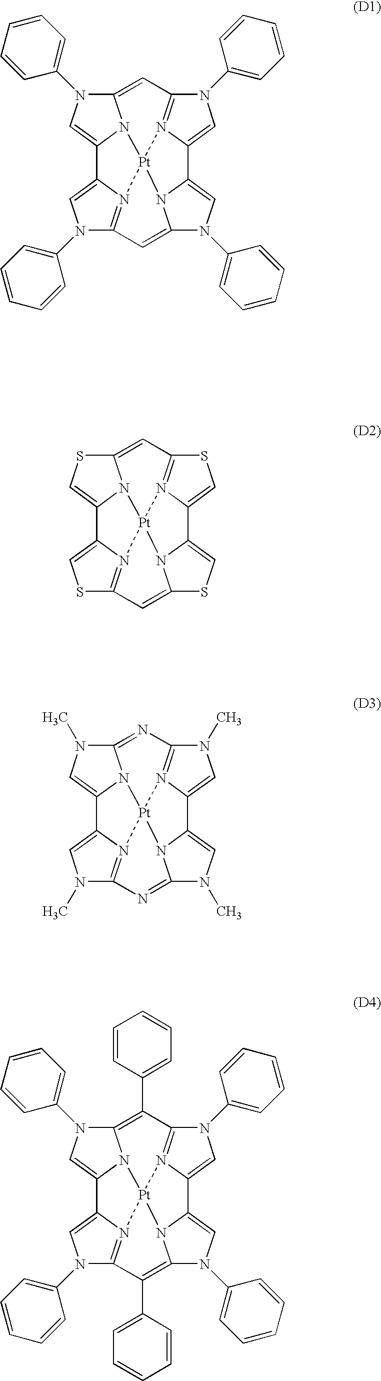

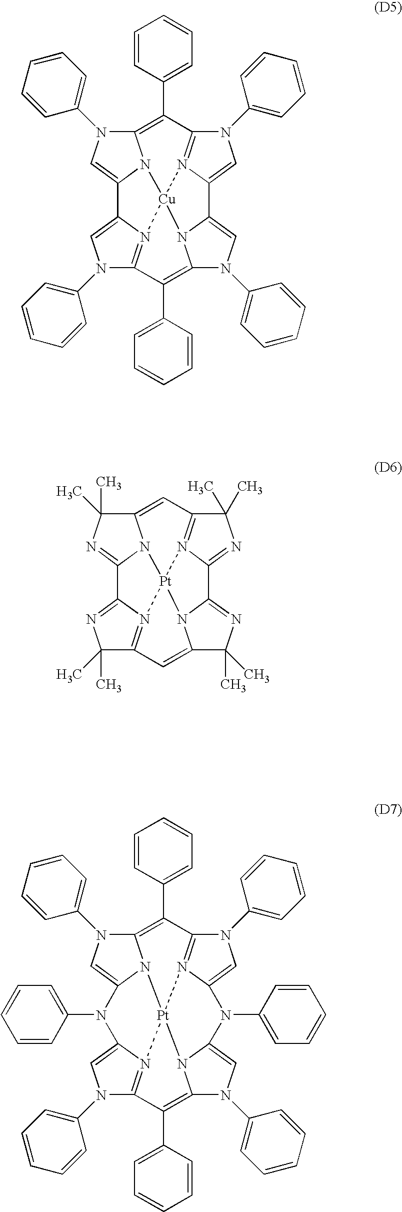

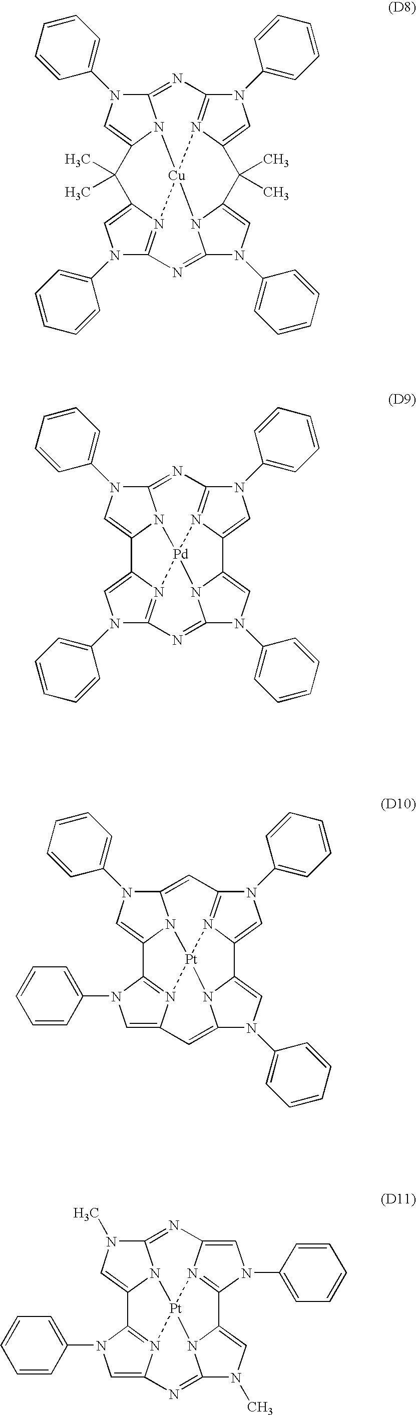

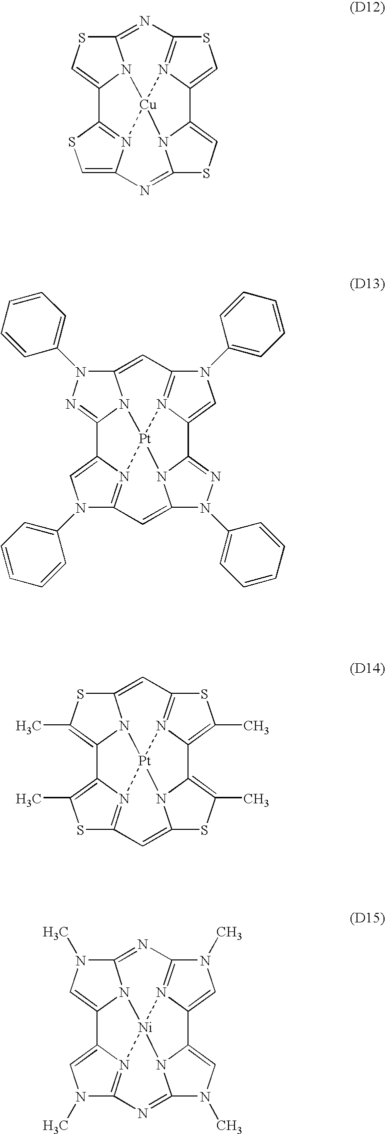

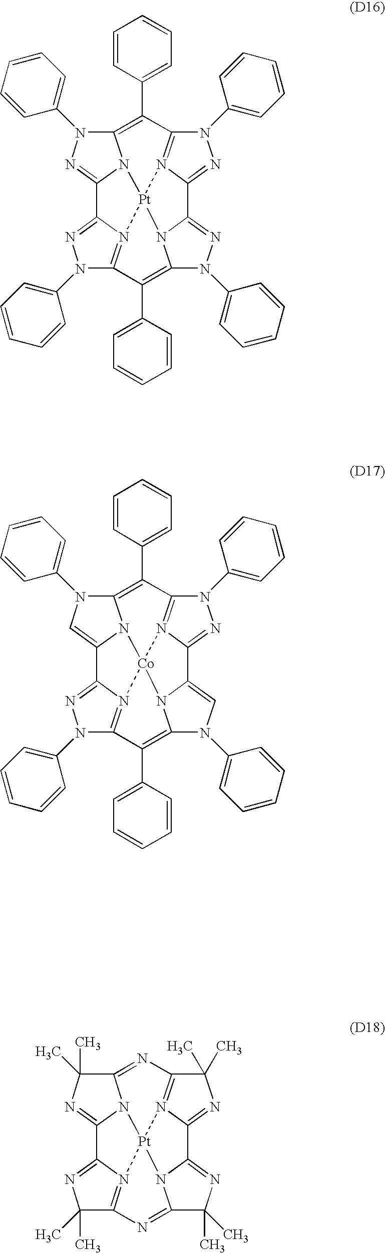

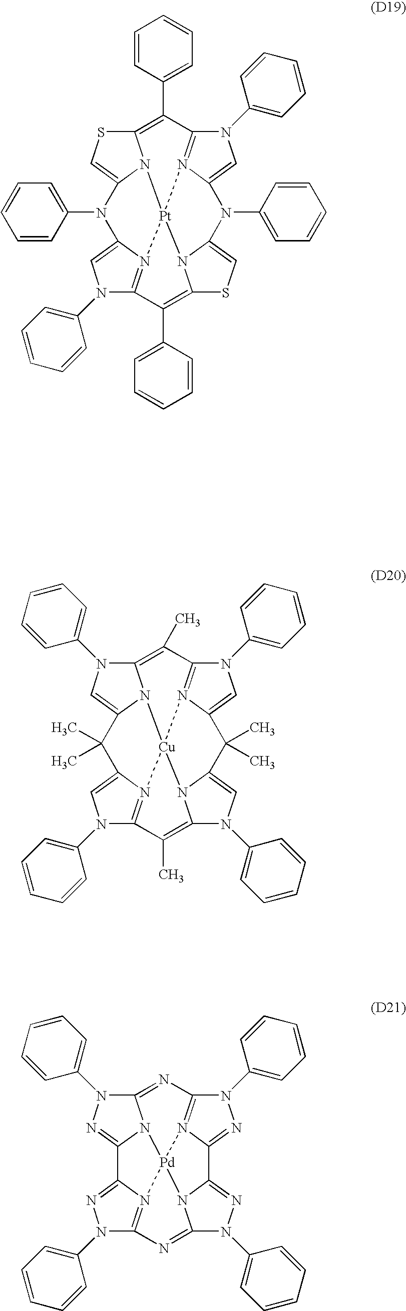

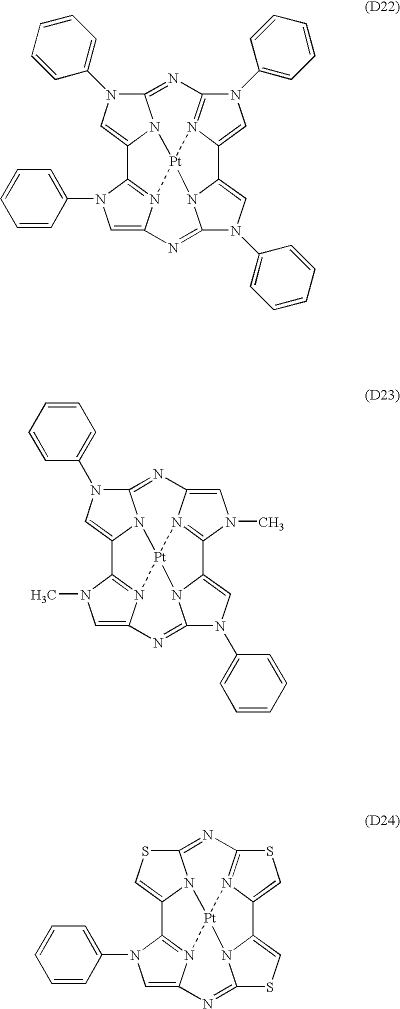

An example of preferable metal complexes usable in the invention is a compound represented by the following Formula (E-1).

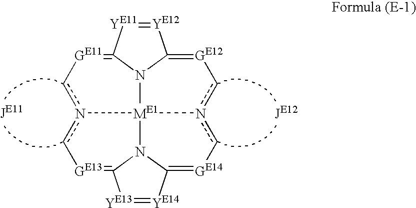

In Formula (E-1), M^{E1} represents a metal ion. J^{E11} and J^{E12} each independently represent an atomic group necessary for forming a 5-membered ring. G^{E11}, G^{E12}, G^{E13} and G^{E14} each independently represent a nitrogen atom or a substituted or unsubstituted carbon atom. Y^{E11}, Y^{E12}, Y^{E13} and Y^{E14} each independently represent a nitrogen atom or a substituted or unsubstituted carbon atom.

Formula (E-1) will be described in detail.

In Formula (E-1), M^{E1} has the same definition as M^{A1} in Formula (A-1), and its preferable examples are also the same. G^{E11}, G^{E12}, G^{E13} and G^{E14} have the same definition as G^{C11} and G^{C12} in Formula (C-1), and their preferable examples are also the same.

J^{E11} and J^{E12} have the same definition as J^{D11} to J^{D14} in Formula (D-1), and their preferable examples are also the same. Y^{E11}, Y^{E12}, Y^{E13} and Y^{E14} have the same definitions as corresponding Y^{C21} to Y^{C24} in Formula (C-2) respectively, and their preferable examples are also the same.

The compound represented by Formula (E-1) is more preferably a compound represented by the following Formula (E-2) or (E-3).

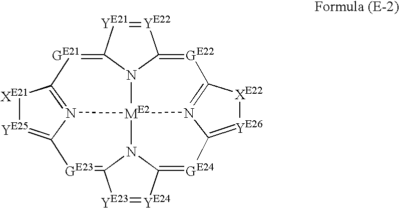

In Formula (E-2), M^{E2} represents a metal ion. G^{E21}, G^{E22}, G^{E23} and G^{E24} each independently represent a nitrogen atom or a substituted or unsubstituted carbon atom. Y^{E21}, Y^{E22}, Y^{E23}, Y^{E24}, Y^{E25} and Y^{E26} each independently represent a nitrogen atom or a substituted or unsubstituted carbon atom.

X^{E21} and X^{E22} each independently represent an oxygen atom, a sulfur atom, —NR^{E21}— or —C(R^{E22})R^{E23}—. R^{E21}, R^{E22} and R^{E23} each independently represent a hydrogen atom or a substituent.

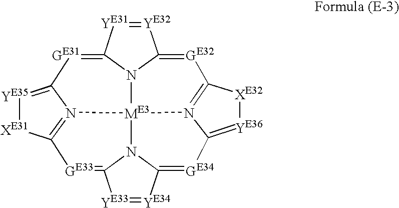

In Formula (E-3), M^{E3} represents a metal ion. G^{E31}, G^{E32}, G^{E33} and G^{E34} each independently represent a nitrogen atom or a substituted or unsubstituted carbon atom. Y^{E31}, Y^{E32}, Y^{E33}, Y^{E34}, Y^{E35} and Y^{E36} each independently represent a nitrogen atom or a substituted or unsubstituted carbon atom. X^{E31} and X^{E32} each independently represent an oxygen atom, a sulfur atom, —NR^{E31}— or —C(R^{E32})R^{E33}—. R^{E31}, R^{E32} and R^{E33} each independently represent a hydrogen atom or a substituent.

Formula (E-2) will be described in detail.

In Formula (E-2), M^{E2}, G^{E21}, G^{E22}, G^{E23}, G^{E24}, Y^{E21}, Y^{E22}, Y^{E23} and Y^{E24} have the same definitions as corresponding M^{E1}, G^{E11}, G^{E12}, G^{E13}, G^{E14}, Y^{E11}, Y^{E12}, Y^{E13} and Y^{E14} in Formula (E-1) respectively, and their preferable examples are also the same. X^{E21} and X^{E22} have the same definitions corresponding X^{D21} and X^{D22} in Formula (D-2) respectively, and their preferable examples are also the same.

Formula (E-3) will be described in detail.

In Formula (E-3), M^{E3}, G^{E31}, G^{E32}, G^{E33}, G^{E34}, Y^{E31}, Y^{E32}, Y^{E33} and Y^{E34} have the same definitions as corresponding M^{E1}, G^{E11}, G^{E12}, G^{E13}, G^{E14}, Y^{E11}, Y^{E12}, Y^{E13} and Y^{E14} in Formula (E-1) respectively, and their preferable examples are also the same. X^{E31} and X^{E32} have the same definitions as corresponding X^{E21} and X^{E22} in Formula (E-2) respectively, and their preferable examples are also the same.

Specific examples of the compounds represented by Formula (E-1) are illustrated below, but the invention is not limited thereto.

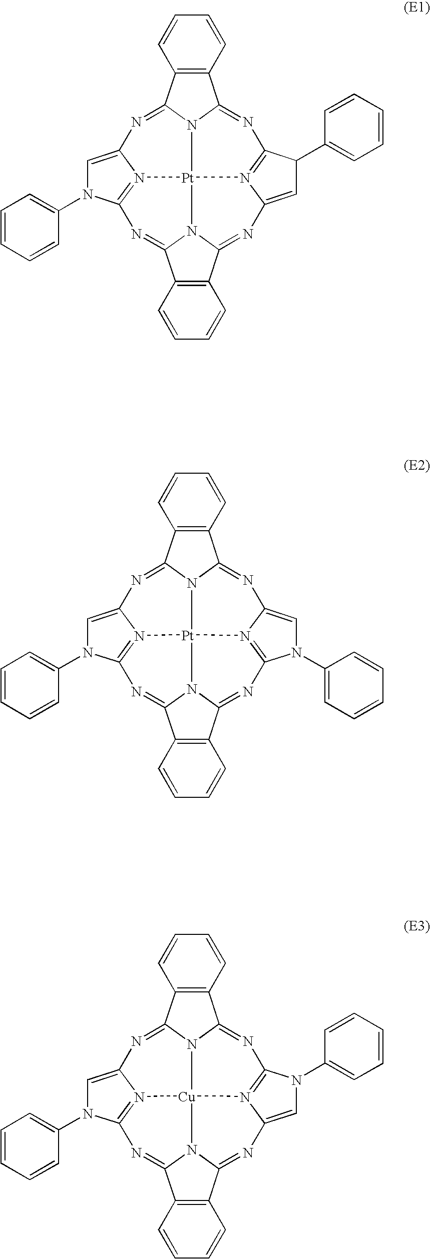

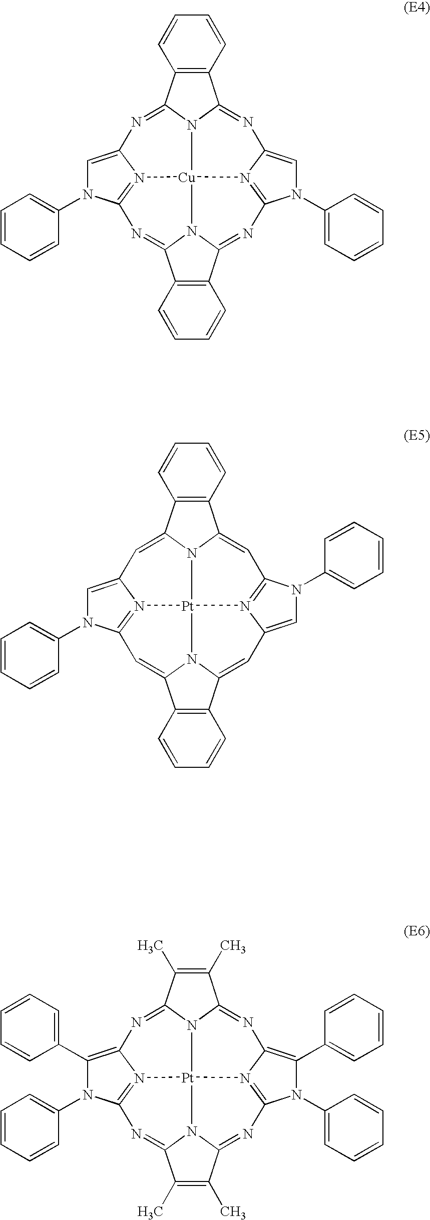

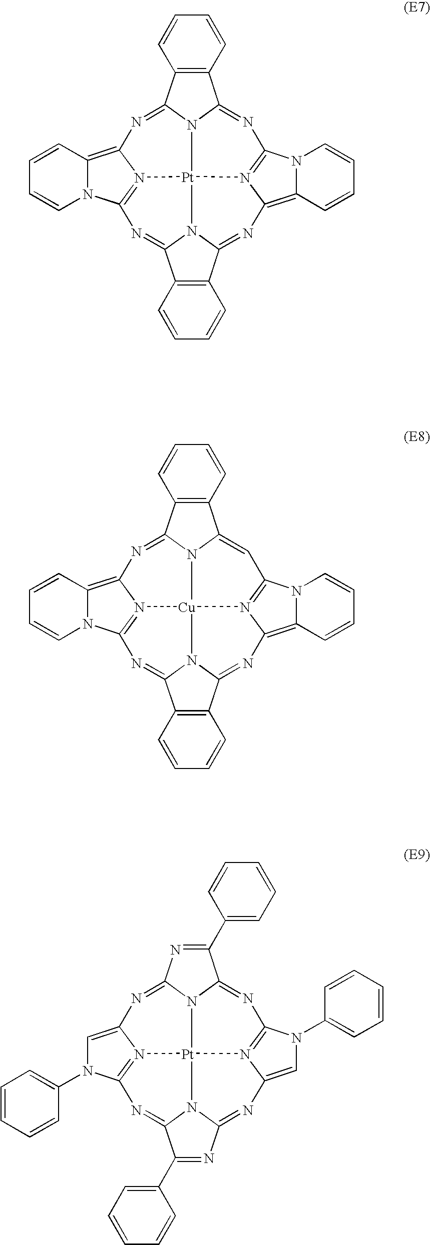

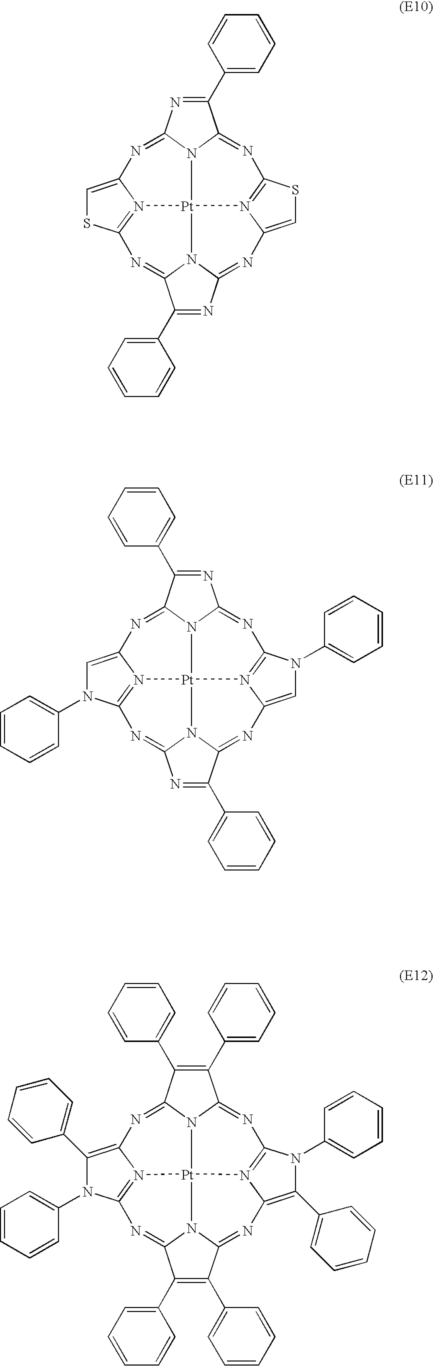

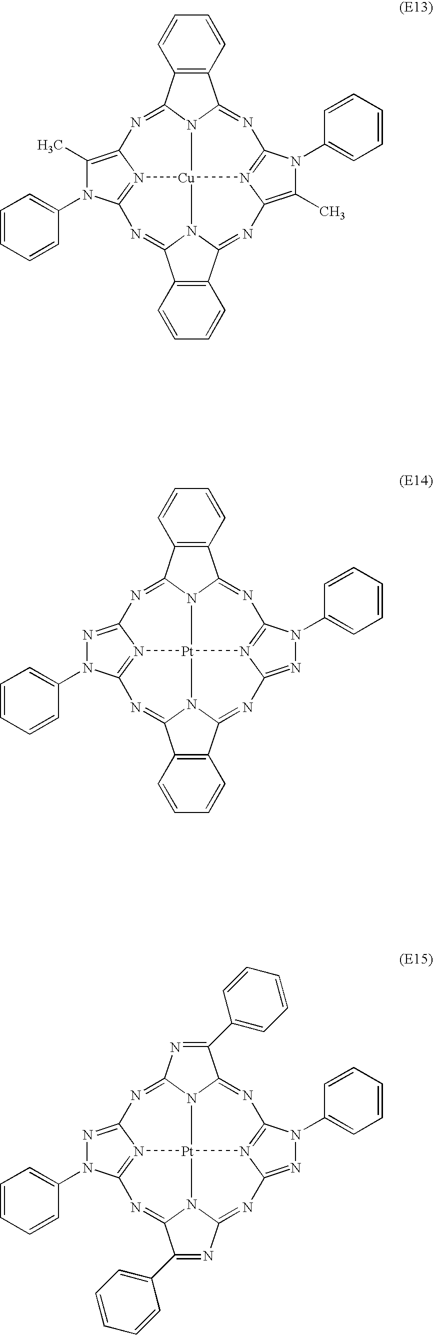

An example of metal complexes usable in the invention is a compound represented by the following Formula (F-1).

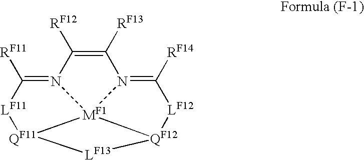

In Formula (F-1), M^{F1} represents a metal ion. L^{F11}, L^{F12} and L^{F13} each independently represent a connecting group. R^{F11}, R^{F12}, R^{F13} and R^{F14} each independently represent a hydrogen atom or a substituent. R^{F11} and R^{F12} may, if possible, be bonded to each other to form a 5-membered ring. R^{F12} and R^{F13} may, if possible, be bonded to each other to form a ring. R^{F13} and R^{F14} may, if possible, be bonded to each other to form a 5-membered ring. Q^{F11} and Q^{F12} each independently represent a partial structure containing an atom bonded to M^{F1}.

The compound represented by Formula (F-1) will be described in detail.

In Formula (F-1), M^{F1}, L^{F11}, L^{F12}, L^{F13}, Q^{F11} and Q^{F12} have the same definitions as corresponding M^{A1}, L^{A11}, L^{A12}, L^{A13}, Q^{A11} and Q^{A12} in Formula (A-1) respectively, and their preferable examples are also the same. R^{F11}, R^{F12}, R^{F13} and R^{F14} each independently represent a hydrogen atom or a substituent. R^{F11} and R^{F12} may, if possible, be bonded to each other to form a 5-membered ring. R^{F12} and R^{F13} may, if possible, be bonded to each other to form a ring. R^{F13} and R^{F14} may, if possible, be bonded to each other to form a 5-membered ring. The substituent represented by R^{F11}, R^{F12}, R^{F13} or R^{F14} may be selected from the above-mentioned examples of the substituent represented by R^{C11} to R^{C14} in Formula (C-1). In a preferable embodiment, R^{F11} and R^{F12} are bonded to each other to form a 5-membered ring, and R^{F13} and R^{F14} are bonded to each other to form a 5-membered ring. In another preferable embodiment, R^{F12} and R^{F13} are bonded to each other to form an aromatic ring.

The compound represented by Formula (F-1) is more preferably a compound represented by Formula (F-2), (F-3) or (F-4).

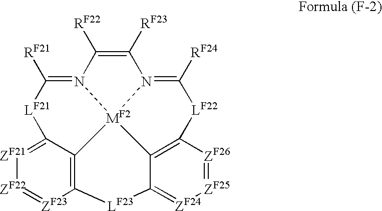

In Formula (F-2), M^{F2} represents a metal ion. L^{F21}, L^{F22} and L^{F23} each independently represent a connecting group. R^{F21}, R^{F22}, R^{F23} and R^{F24} each independently represent a substituent. R^{F21} and R^{F22} may, if possible, be bonded to each other to form a 5-membered ring. R^{F22} and R^{F23} may, if possible, be bonded to each other to form a ring. R^{F23} and R^{F24} may, if possible, be bonded to each other to form a 5-membered ring. Z^{F21}, Z^{F22}, Z^{F23}, Z^{F24}, Z^{F25} and Z^{F26} each independently represent a nitrogen atom or a substituted or unsubstituted carbon atom.

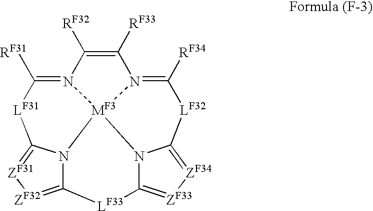

In Formula (F-3), M^{F3} represents a metal ion. L^{F31}, L^{F32} and L^{F33} each independently represent a connecting group. R^{F31}, R^{F32}, R^{F33} and R^{F34} each independently represent a substituent. R^{F31} and R^{F32} may, if possible, be bonded to each other to form a 5-membered ring. R^{F32} and R^{F33} may, if possible, be bonded to each other to form a ring. R^{F33} and R^{F34} may, if possible, be bonded to each other to form a 5-membered ring. Z^{F31}, Z^{F32}, Z^{F33} and Z^{F34} each independently represent a nitrogen atom or a substituted or unsubstituted carbon atom.

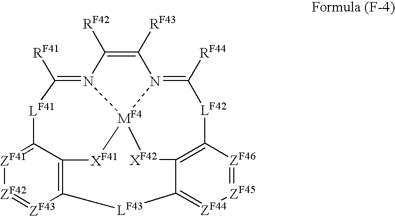

In Formula (F-4), M^{F4} represents a metal ion. L^{F41}, L^{F42} and L^{F43} each independently represent a connecting group. R^{F41}, R^{F42}, R^{F43} and R^{F44} each independently represent a substituent. R^{F41} and R^{F42} may, if possible, be bonded to each other to form a 5-membered ring. R^{F42} and R^{F43} may, if possible, be bonded to each other to form a ring. R^{F43} and R^{F44} may, if possible, be bonded to each other to form a 5-membered ring. Z^{F41}, Z^{F42}, Z^{F43}, Z^{F44}, Z^{F45} and Z^{F46} each independently represent a nitrogen atom or a substituted or unsubstituted carbon atom. X^{F41} and X^{F42} each independently represent an oxygen atom, a sulfur atom or a substituted or unsubstituted nitrogen atom.

The compound represented by Formula (F-2) will be described in detail.

M^{F2}, L^{F21}, L^{F22}, L^{F23}, R^{F21}, R^{F22}, R^{F23} and R^{F24} have the same definitions as corresponding M^{F1}, L^{F11}, L^{F12}, L^{F13}, R^{F11}, R^{F12}, R^{F13} and R^{F14} in Formula (F-1) respectively, and their preferable examples are also the same.

Z^{F21}, Z^{F22}, Z^{F23}, Z^{F24}, Z^{F25} and Z^{F26} each independently represent a nitrogen atom or a substituted or unsubstituted carbon atom. Each of Z^{F21}, Z^{F22}, Z^{F23}, Z^{F24}, Z^{F25} and Z^{F26} is preferably a substituted or unsubstituted carbon atom, and more preferably an unsubstituted carbon atom. When the carbon atom is substituted, the substituent may be selected from the above-mentioned examples of the substituent on the divalent connecting group represented by L^{A11}, L^{A12}, L^{A13} or L^{A14} in Formula (A-1)

The compound represented by Formula (F-3) will be described in detail.

In Formula (F-3), M^{F3}, L^{F31}, L^{F32}, L^{F33}, R^{F31}, R^{F32}, R^{F33} and R^{F34} have the same definitions as corresponding M^{F1}, L^{F11}, L^{F12}, L^{F13}, R^{F11}, R^{F12}, R^{F13} and R^{F14} in Formula (F-1) respectively, and their preferable examples are also the same. Z^{F31}, Z^{F32}, Z^{F33} and Z^{F34} each independently represent a nitrogen atom or a substituted or unsubstituted carbon atom. Each of Z^{F31}, Z^{F32}, Z^{F33} and Z^{F34} is preferably a substituted or unsubstituted carbon atom, and more preferably an unsubstituted carbon atom. When the carbon atom is substituted, the substituent may be selected from the above-mentioned examples of the substituent on the divalent connecting group represented by L^{A11}, L^{A12}, L^{A13} or L^{A14} in Formula (A-1)

The compound represented by Formula (F-4) will be described in detail.

In Formula (F-4), M^{F4}, L^{F41}, L^{F42}, L^{F43}, R^{F41}, R^{F42}, R^{F43} and R^{F44} have the same definitions as corresponding M^{F1}, L^{F11}, L^{F12}, L^{F13}, R^{F11}, R^{F12}, R^{F13} and R^{F14} in Formula (F-1) respectively, and their preferable examples are also the same.

Z^{F41}, Z^{F42}, Z^{F43}, Z^{F44}, Z^{F45} and Z^{F46} each independently represent a nitrogen atom or a substituted or unsubstituted carbon atom. Each of Z^{F41}, Z^{F42}, Z^{F43}, Z^{F44}, Z^{F45} and Z^{F46} is preferably a substituted or unsubstituted carbon atom, and more preferably an unsubstituted carbon atom. When the carbon atom is substituted, the substituent may be selected from the above-mentioned examples of the substituent on the divalent connecting group represented by L^{A11}, L^{A12}, L^{A13} or L^{A14} in Formula (A-1).

X^{F41} and X^{F42} each independently represent an oxygen atom, a sulfur atom or a substituted or unsubstituted nitrogen atom. Each of X^{F41} and X^{F42} is preferably an oxygen atom or a sulfur atom, and more preferably an oxygen atom.

Specific examples of the compounds represented by Formula (F-1) are illustrated below, but the invention is not limited thereto.

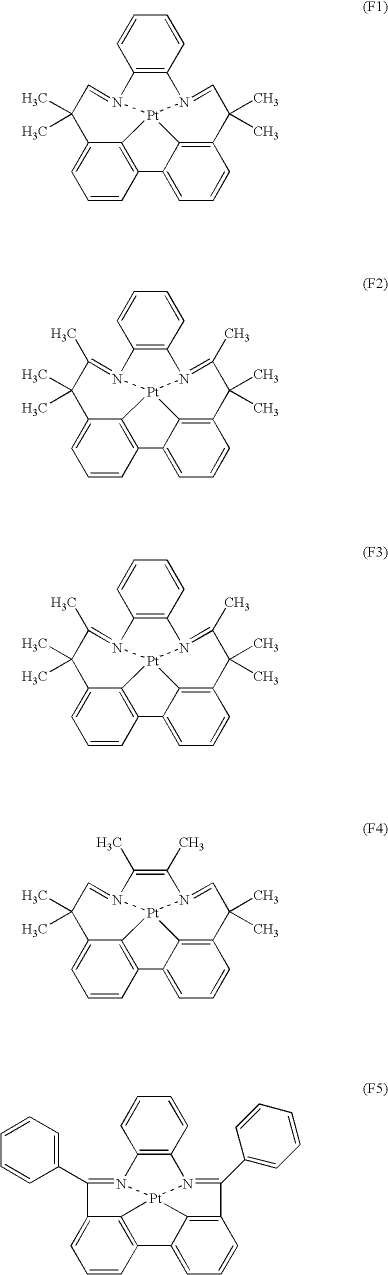

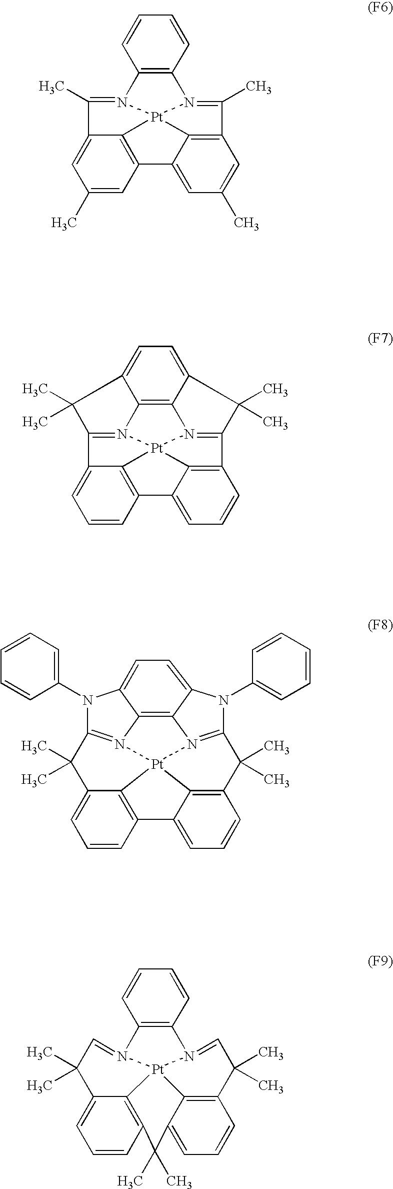

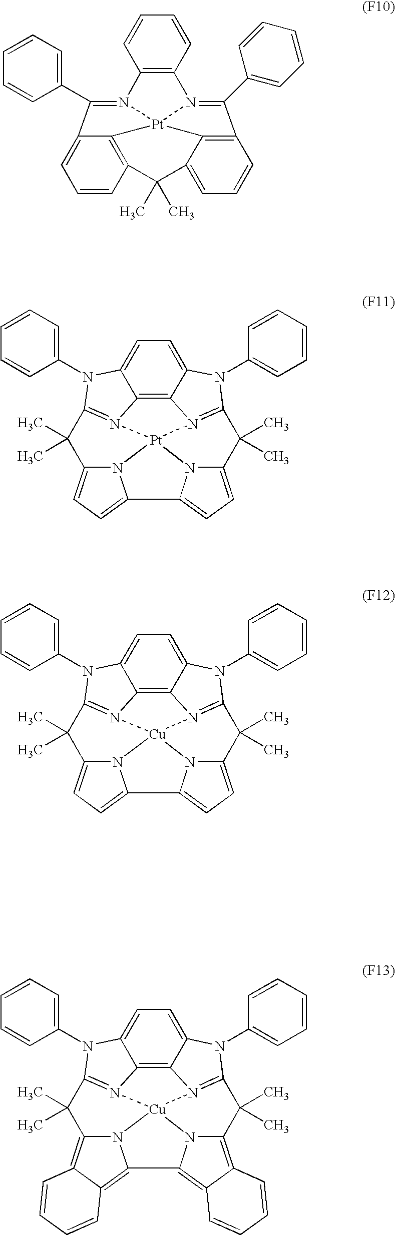

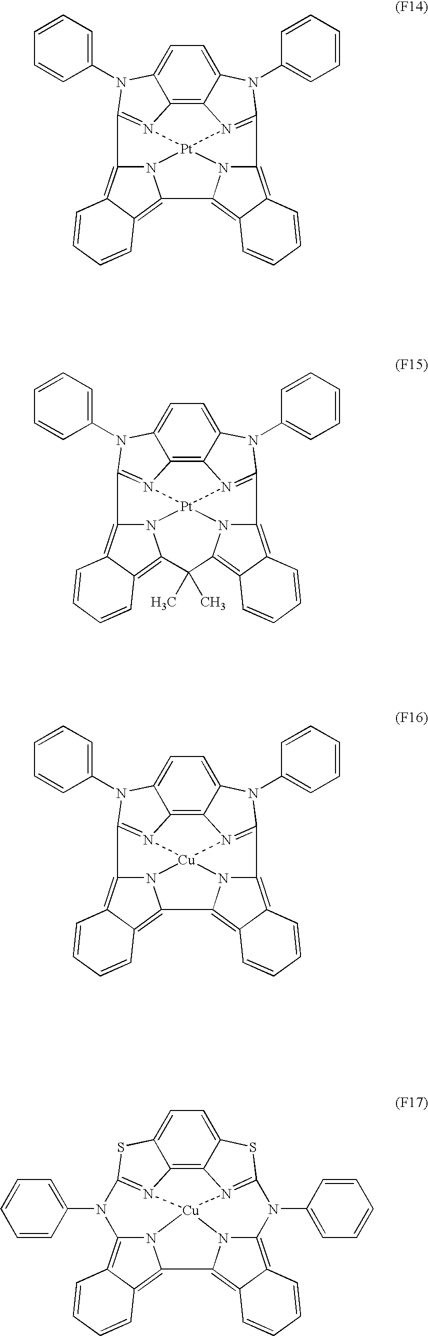

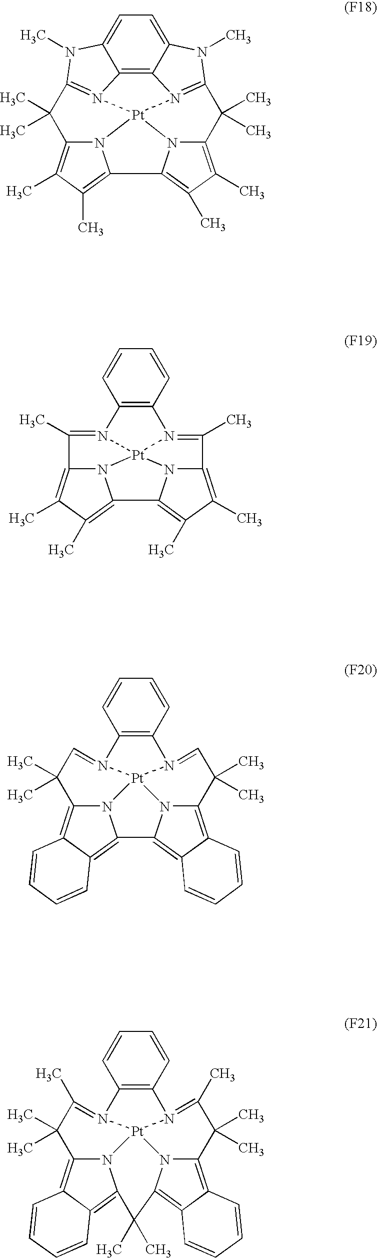

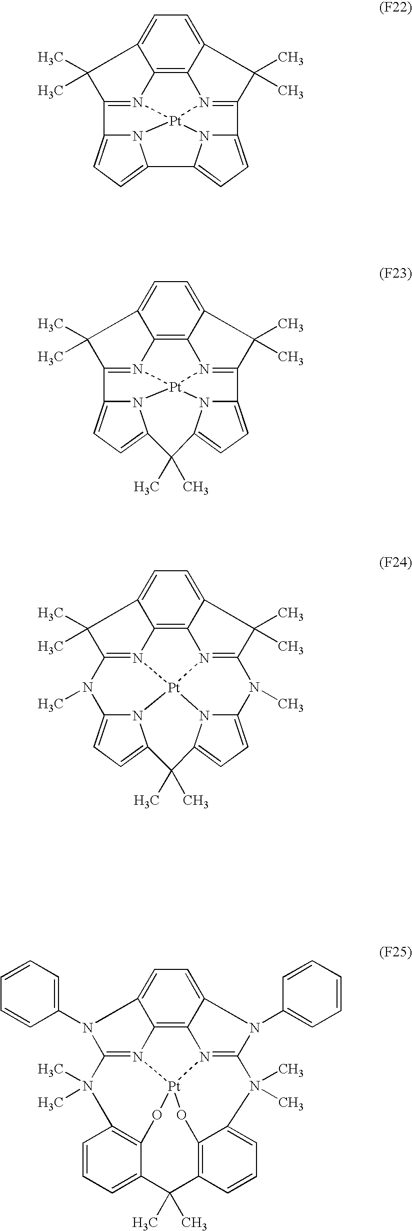

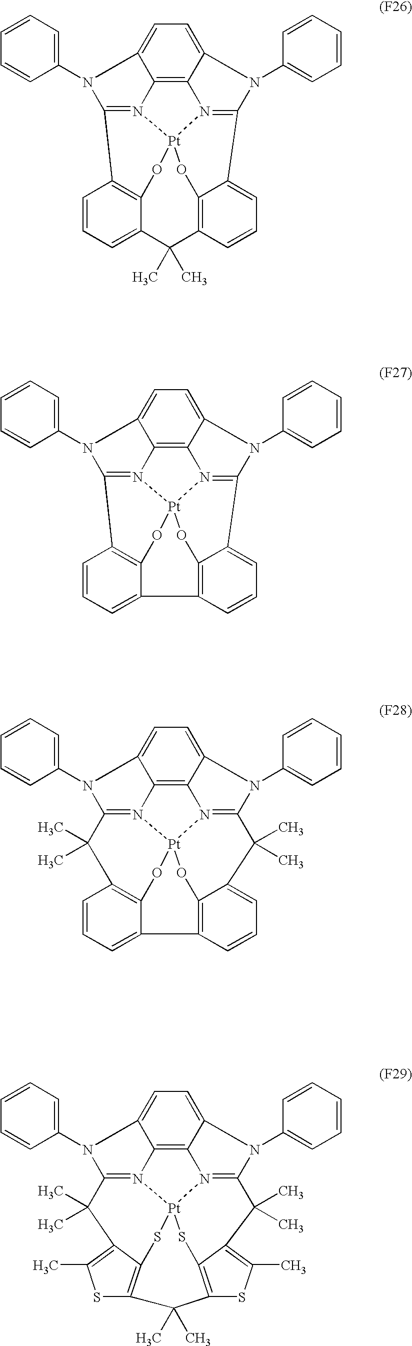

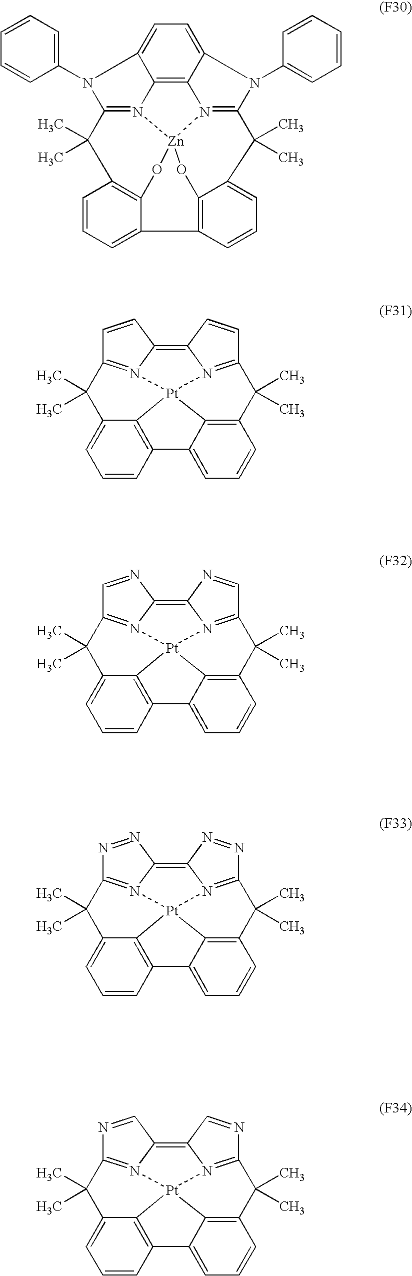

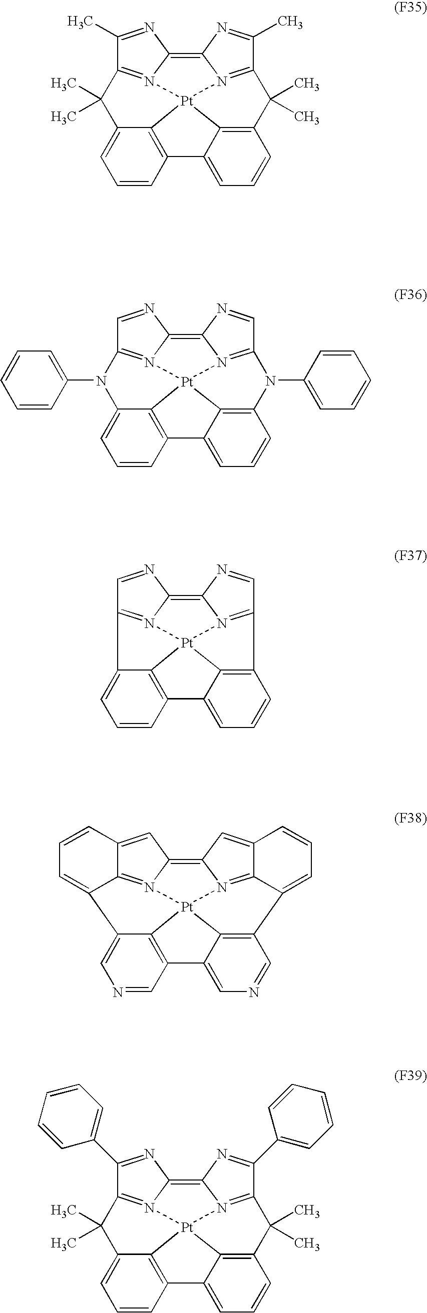

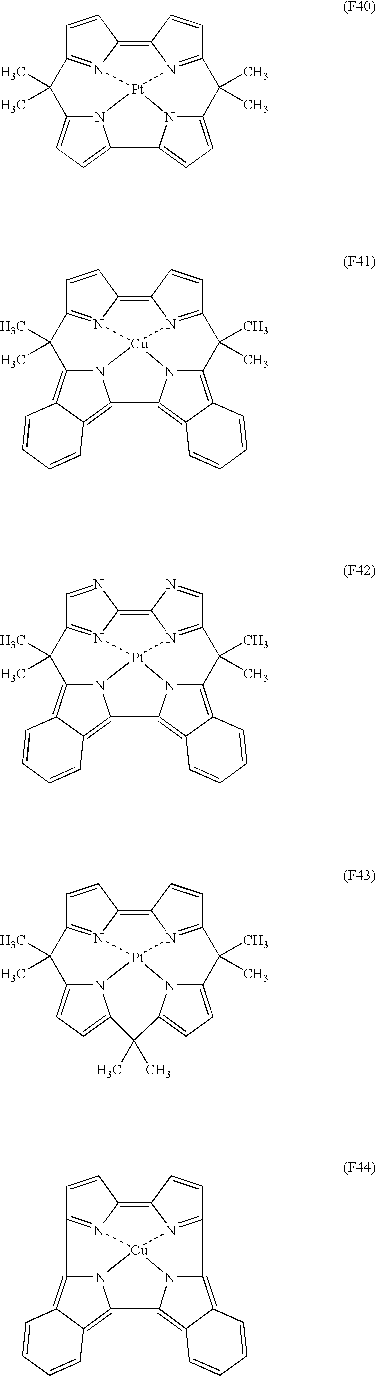

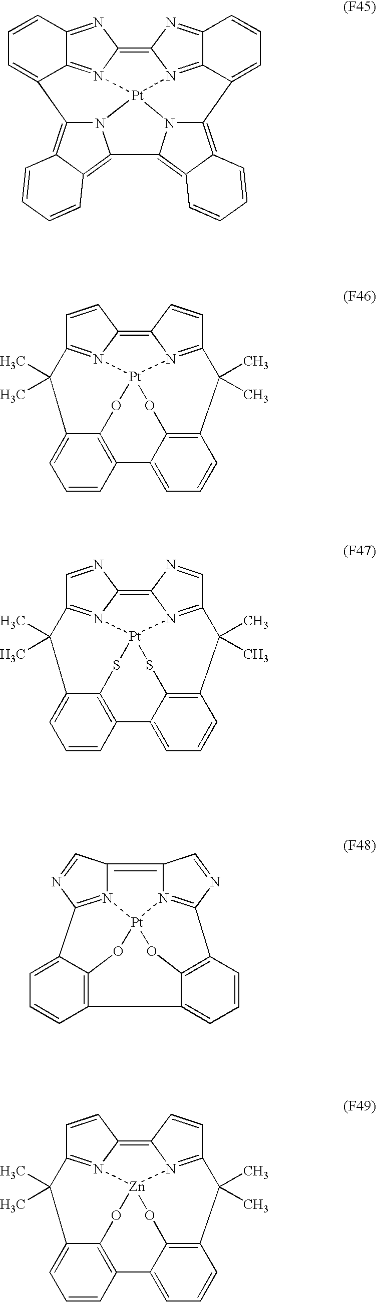

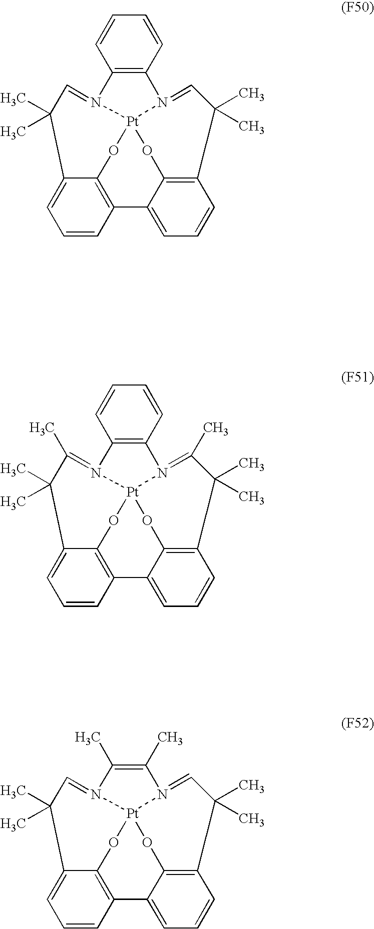

Compounds represented by any one of Formulae (A-1) to (F-1) can be synthesized by known methods.

A single kind of metal complex according to the invention may be contained in the composition for an organic EL element, or two or more kinds of metal complex according to the invention may be used in the composition in combination.

The content of metal complex having a tridentate or higher-dentate ligand in the composition for an organic EL element according to the invention is, for example when the composition is used in a luminescent layer, preferably from 0.1 to 70% by mass relative to the total solid content contained in the composition, and more preferably 1 to 20% by mass relative to the total solid content contained in the composition.

Also when forming other organic compound layers and the like than the luminescent layer, the metal complex according to the invention can be used by being contained in an adequate amount in the composition alone or together with other components described below, in accordance with the constitution of each layer.

[Other Components]

The composition for an organic EL element according to the invention may further contain other components than the metal complex according to the invention, in addition to the metal complex. Such additional components form an organic compound layer together with the metal complex.

Examples of organic compound layers that can be formed by applying the composition for an organic EL element according to the invention include a luminescent layer, a charge transport layer, and a charge injection layer. The additional components may be materials contained in such layers.

The composition for an organic EL element according to the invention is preferably dissolved or dispersed in a solvent, so as to prevent the adherence of the solid content in the organic EL composition and clogging caused thereby at the nozzle entrance for the ink jet, so as to contribute to maintenance of a high contact angle of ink at the nozzle entrance, which prevents the ink curve during flight.

Examples of the solvent include water, alcohols such as methanol, ethanol, 1-methoxy-2-propanol, methoxyethanol, and phenoxyethanol, ketones such as acetone, methyl ethyl ketone, diethyl ketone, n-propyl methyl ketone, and cyclohexanone, ethers such as dibutyl ether, tetrahydrofuran, and dioxane, esters such as ethyl acetate, butyl acetate, ethyl 2-ethylhexanoate, methyl propionate, ethyl propionate, γ-butyrolactone, and diethyl carbonate, amides such as formamide, N,N-dimethylformamide (DMF), and N,N-dimethylacetamide, aliphatic hydrocarbons such as hexane, heptane, octane, and cyclohexane, aromatic hydrocarbons such as benzene, toluene, and xylene, halogenated hydrocarbons such as chloroform, carbon tetrachloride, dichloromethane, and 1,2-dichloroethane, organic solvents such as N-methylpyrrolidone (NMP), dimethylimidazoline (DMI), and dimethylsulfoxide (DMSO), and inorganic solvents. In an embodiment, two or more of these solvents are appropriately mixed, and the mixture is used as the solvent.

Furthermore, the composition preferably contains a lubricant. The lubricant effectively prevents the drying and solidification of the composition at the ink jet nozzle opening. The lubricant may be, for example, a polyhydric alcohol such as glycerin or diethylene glycol. A mixture of two or more lubricants may be used.

The amount of a lubricant to be added is preferably about 5 to 20% by mass relative to the total amount of the composition.

To the composition for an organic EL element, other additives and coated-layer stabilizing materials may be further added, such as stabilizers, viscosity modifiers, antioxidants, pH adjusters, preservatives, resin emulsions, and leveling agents.

The composition for an organic EL element according to the invention is used for pattern formation by an ink jet method.

Here, the pattern formation by an ink jet method refers to a process in which the composition for an organic EL element is dissolved or dispersed in a solvent to form a discharge liquid, and the discharge liquid is discharged from the head of an ink jet apparatus to form pixels of at least one color selected from the three primary colors (e.g., red, green, and blue) and intermediate colors therebetween.

According to this ink jet method, fine patterning can be conducted easily in a short time. Furthermore, because the film thickness can be easily adjusted by increasing or decreasing the discharging amount, the film properties and the coloring performance, such as coloring balance and brightness can be controlled easily and freely.

The viscosity of the composition for an organic EL element according to the invention is preferably from 1 mPa·s to 20 mPa·s, and more preferably from 2 mPa·s to 4 mPa·s. When the viscosity of the composition for an organic EL element is less than 1 mPa·s, the resultant coloring layer does not exhibit sufficient coloring performance in some cases. On the other hand, when the viscosity of the composition for an organic EL element is over 20 mmPa·s, the composition cannot be discharged smoothly from the nozzle opening, and thus, in some cases, patterning is difficult unless the specifications of the device are changed, (for example, enlarging the size of the opening of the nozzle. Furthermore, when the viscosity is high, the solid content in the composition easily precipitates, thus increasing the frequency of occurrence of clogging of the nozzle opening.

Furthermore, the surface tension of the composition for an organic EL element according to the invention may be from 20 mN/m to 70 mN/m, and is preferably from 25 mN/m to 40×10⁻³ N/m. The curve of the flight path is suppressed and the frequency of the flight path curve can be reduced by making the surface tension within this range, as the case of the contact angle mentioned above. When the surface tension is less than 20 mN/m, the wettability of the composition with respect to the constituent material of the nozzle surface is increased; therefore, in some cases, the flight curve occurs and similarly to the case of the contact angle, and the frequency of the flight curve is high. Furthermore, when the surface tension is over 70 mN/m, the meniscus form at the nozzle tip is not stabilized, and the control of the discharging amount and discharge timing of the composition is difficult in some cases.

Furthermore, the composition for an organic EL element according to the invention preferably has a viscosity and a surface tension, at least one of which meets the above-mentioned range. The composition may meet any combination of two or more conditions of the characteristics, or may meet all of the conditions of the characteristics. Such a composition is more suitable for ink jet methods.

Furthermore, the composition for an organic EL element according to the invention may be prepared as a polymer dispersion liquid that contains a polymer for dispersing a metal complex having the above-mentioned tridentate or higher-dentate ligand. When the composition is in the form of a polymer dispersion liquid, each component of an organic compound layer is preferably dispersed in the polymer. By dispersing the components of the organic compound layer in the polymer, the stability of the components of the organic compound layer in the dispersion liquid is improved, so that an organic electroluminescent element with further improved luminous efficiency and durability can be obtained.

Examples of polymers usable for the dispersion include polyvinyl carbazole, polyvinyl chloride, polycarbonate, polystyrene, polymethyl methacrylate, polybutyl methacrylate, polyester, polysulfone, polyphenylene oxide, polybutadiene, hydrocarbon resin, ketone resin, phenoxy resin, polyamide, ethyl cellulose, vinyl acetate, ABS resin, polyurethane, melamine resin, unsaturated polyester, alkyd resin, epoxy resin, silicone resin, polyvinyl butyral, and polyvinyl acetal. Only one polymer may be used, or two or more polymers may be used in combination. A luminescent layer containing a polymer binder can be easily formed on a large area through coating by a wet-film forming method. In particular, the polymers described in, for example, JP-A Nos. 2001-11568, 2002-25779, 2004-152746, can be suitably used.

The polymer dispersion liquid can be prepared as follows: a polymer (for example, PVK) and a metal complex according to the invention are dissolved or dispersed in a solvent (for example, a 1:1 mixture of toluene and chloroform) with a dispersing apparatus under stirring for a necessary time for the dissolution or dispersing. The dispersing apparatus is not particularly limited, and a known device can be used.

[Method for Manufacturing an Organic Electroluminescent Element, and the Organic Electroluminescent Element Manufactured by the Method]

Next, the method for manufacturing an organic electroluminescent element according to the invention and the organic electroluminescent element manufactured by the method will be described in detail.

### First Embodiment of the Method for Manufacturing an Organic Electroluminescent Element

The first embodiment of the method for manufacturing an organic electroluminescent element in the invention includes forming a first electrode on a substrate, discharging the composition according to the invention in a pattern onto the surface (film-forming surface) of the substrate having the first electrode thereon by an ink jet apparatus to form an organic compound layer, and forming a second electrode on the organic compound layer. In the following, the method for manufacturing the organic electroluminescent element in this embodiment will be occasionally referred to as “the method (1) for manufacturing an organic EL element”.

In the method (1) for manufacturing an organic EL element according to the invention, because the deterioration of the composition for an organic EL element held in the ink jet apparatus is suppressed by the use of the composition for an organic EL element according to the invention with excellent stability over time, an organic electroluminescent element having high luminous efficiency and luminance and excellent durability can be manufactured stably and easily.

Furthermore, in the method (1) for manufacturing an organic EL element, because the organic compound layer is formed by an ink jet apparatus, highly fine patterning is possible, and the luminescent property of the obtained element, the film properties of the formed organic compound layer, and the like can be controlled easily.

An example of ink jet apparatuses that can be used suitably in the method (1) for manufacturing an organic EL element will be described.

In such an ink jet apparatus, first, information on the pattern to be formed on the film-forming surface is supplied from an information supply source, such as a computer, to the ink jet recording apparatus through a transmission unit, such as a bus.

The ink jet apparatus may be an apparatus that has a head capable of discharging the droplets of the composition for an organic EL element, and a control system that drives the head according to an arbitrary pattern. The composition is provided on the film-forming surface according to the pattern information by discharging the droplets of the composition for an organic EL element from the nozzle opening (discharge opening) of the head of the apparatus moving according to the pattern information, to a prescribed position on the film-forming surface.

The head installed in the ink jet apparatus is equipped with a cavity that is configured to be filled with the composition for an organic EL element. A voltage corresponding to an arbitrary pattern is applied to the piezoelectric element that is configured to be able to cause a volume change of the cavity, so that the inside volume of the cavity is changed; as a result, the composition for an organic EL element stored in the cavity is supplied in the form of minute droplets from the discharge opening onto the film-forming surface in a prescribed pattern, and is adsorbed on the film-forming surface. Thereafter, the solvent and the dispersion medium in the composition for an organic EL element are removed to form an organic compound layer.

In the invention, besides the above-mentioned method, heads using other principles are naturally usable.

Though the embodiment of the method (1) for manufacturing an organic EL element will be described by taking one example, the invention is not limited to the example.

(1) On a substrate (a glass substrate or the like), pixel electrodes (ITO electrodes or the like) are formed in a pattern by photolithography or the like. A partition wall serving both as a light shielding layer and an ink dripping preventing wall is formed between the pixel electrodes by photolithography or the like.

(2) The composition for an organic EL element for forming a desired organic compound layer is discharged in a pattern from the nozzle opening of the ink jet apparatus to deposit the composition for an organic EL element on the film-forming surface. Then, the solvent or the dispersion medium contained in the composition is removed by a heating treatment or the like, to form the organic compound layer. The organic compound layer to be formed may be a single layer including only a luminescent layer, or may have a laminated structure composed of two or more organic compound layers including a luminescent layer.

In the invention, at least one of the organic compound layers is formed by an ink jet method using the composition for an organic EL element according to the invention. When the organic compound layers have a laminated structure, all the layers including the layer formed by using the compound for the organic EL element according to the invention may be formed by an ink jet method, or some (but not all) of the layers may be formed by other methods involving a deposition method or the like.

(3) Counter electrodes are further formed on the organic compound layer by using a deposition method or the like to give an organic EL element.

(An organic EL element manufactured by using the method (1) for manufacturing an organic EL element)

The first embodiment (hereinafter, it will be suitably referred to as “the organic EL element (1)”) of the organic electroluminescent element according to the invention is manufactured by using the above-mentioned method (1) for manufacturing an organic EL element. The organic EL element (1) preferably has two or more organic compound layers including a luminescent layer. At least one of the organic compound layers is formed by using the composition for an organic EL element according to the invention by the method (1) for manufacturing an organic EL element according to the invention.

The organic EL element according to the invention preferably has two or more organic compound layers including a luminescent layer. In the following, the organic EL element (1) will be described in detail.

The organic EL element (1) according to the invention has a cathode and an anode on the substrate, and has organic compound layers, including a luminescent layer, between the both electrodes. In consideration of the property of the luminescent element, at least one of the anode and the cathode is preferably transparent.

As the mode of the lamination of the organic compound layers in the organic EL element (1), a lamination in the order of a hole transport layer, a luminescent layer, and an electron transport layer from the anode side is preferable. The organic EL element (1) may further have a charge block layer or the like between the hole transport layer and the luminescent layer, and/or between the luminescent layer and the electron transport layer. The organic EL element (1) may have a hole injection layer between the anode and the hole transport layer, and/or may have an electron injection layer between the cathode and the electron transport layer. The organic EL element (1) may have only one luminescent layer, or the luminescent layer may be divided, for example into the first luminescent layer, the second luminescent layer, and the third luminescent layer. Furthermore, each layer may be divided into plural sub-layers.

<Luminescent Layer>

When an electric field is applied to the luminescent element, holes injected from the anode, the hole injection layer, or the hole transport layer, and electron injected from the cathode, the electron injection layer, or the electron transport layer recombine in the luminescent layer to emit light. The material constituting the luminescent layer is not particularly limited as long as the material can form a layer having, upon application of an electric field, the function of receiving holes from the anode or the like, the function of receiving electrons from the cathode or the like, the function of moving charges, and the function of offering a field for the recombination of the holes and the electrons to emit light.

The luminescent layer in the organic EL element (1) is preferably formed by using the composition for an organic EL element according to the invention by the above-mentioned manufacturing method (1) according to the invention.

The luminescent layer in the organic EL element (1) preferably contains a metal complex having a tridentate or higher-dentate ligand. Since the metal complex has a function (A) as a luminescent material, a function (B) as a host material (hereinafter occasionally referred to as “the charge transport material”), and the like, embodiments using each function are preferable.

When the above-mentioned metal complex is used as one having the function (A) other luminescent materials than the metal complex may be further used, such as a material that emits light from either a singlet exciton or a triplet exciton. Examples of such additional luminescent materials include benzoxazole, benzimidazole, benzothiazole, styrylbenzene, polyphenyl, dipnenylbutadiene, tetraphenylbutadiene, naphthalimide, coumarin, perylene, perynone, oxadiazole, aldazine, pyralidine, cyclopentadiene, bis-styrylanthracene, quinacridon, pyrrolopyridine, thiadiazolopyridine, styrylamine, aromatic dimethylidyne compounds, metal complexes other than the metal complexes according to the invention (metal complexes of 8-quinolinol derivatives, rare earth complexes, and the like), polymer luminescent materials (polythiophene, polyphenylene, polyphenylene vinylene, and the like), organic silane compounds, transition metal complexes other than the metal complexes according to the invention (iridium trissphenylpyridine complex and the like), and derivatives thereof. Furthermore, cyanine dyes, melocyanine dyes, styryl dyes, dyes of anthracene derivatives, porphyrin derivatives, phthalocyanine derivatives, coumarin, DCM, Nile Red, and the like, laser dyes, and the like, which are other than those mentioned above, can be used.

The content of a luminescent compound in the luminescent layer in the organic EL element (1) is not particularly limited, and is preferably, for example, 0.1 to 70% by mass, and more preferably 1 to 20% by mass. When the content of the luminescent compound is less than 0.1% by mass or over 70% by mass, the effects may be not exhibited sufficiently.

The thickness of the luminescent layer in the organic EL element (1) is preferably from 10 to 200 nm, and more preferably from 20 to 80 nm. When the thickness is over 200 nm, the drive voltage may be increased. On the other hand, when the thickness is less than 10 nm, the organic EL element may be short-circuited.

The drying condition of the thin film can be suitably selected in accordance with the conditions such as the compound and solvent to be used. The drying can be carried out generally under the atmospheric pressure or reduced pressure.

The luminescent layer in the organic EL element (1) may be formed of a single material or of plural materials, as mentioned above. Furthermore, the luminescent layer may be one layer or plural layers. When their are plural luminescent layers, each of the layers may emit light in different color such that white color or the like is emitted. When there are plural luminescent layers, each of the luminescent layers may be formed of a single material, or of plural materials.

Besides the luminescent layer mentioned above, as for other components of the organic EL element (1) such as the substrate, the electrodes, other organic compound layers, and still other layers, for example, those described in [00131] to [0082] of JP-A No. 2004-221068, [0017] to [0091] of JP-A No. 2004-214178, [0024] to [0035] of JP-A No. 2004-146067, [0017] to [0068] of JP-A No. 2004-103577, [0014] to [0062] of JP-A No. 2003-323987, [0015] to [0077] of JP-A No. 2002-305083, [0008] to [0028] of JP-A No. 2001-172284, [0013] to [0075] of JP-A No. 2000-186094, [0016] to [0118] of Japanese Patent Application National Publication (Laid-Open) No. 2003-515897, and the like can be applied in the invention. However, the invention should not be limited to these.

In the hole injection layer and/or the hole transport layer in the organic EL element (1), an electron receiving dopant can be contained. The electron receiving dopant to be introduced into the hole injection layer or the hole transport layer may be an inorganic compound or an organic compound as long as the compound has electron receiving property and is capable of oxidizing organic compounds.

Specific examples of inorganic electron receiving dopants include halogenated metals such as ferric oxide, aluminum chloride, gallium chloride, indium chloride, and antimony pentachloride, and metal oxides such as vanadium pentoxide and molybdenum trioxide.

Specific examples of organic electron receiving dopants include compounds having a nitro group, a halogen, a cyano group, a trifluoromethyl group, or the like as a substituent, quinone compounds, acid anhydride compounds, and fullerene.

Besides these, compounds described in JP-A Nos. 6-212153, 11-111463, 11-251067, 2000-196140, 2000-286054, 2000-315580, 2001-102175, 2001-160493, 2002-252085, 2002-56985, 2003-157981, 2003-217862, 2003-229278, 2004-342614, 2005-72012, 2005-166637, 2005-209643, and the like can be suitably used.

Only one electron receiving dopant may be used, or two or more electron receiving dopants may be used in combination. The amount of the electron receiving dopant to be used varies depending on the kind of the material, and is preferably from 0.01% by mass to 50% by mass relative to the mass of the hole injection layer material or the hole transport layer material, more preferably from 0.05% by mass to 20% by mass, and particularly preferably from 0.1% by mass to 10% by mass.

In the electron injection layer and/or the electron transport layer in the organic EL element (1), an electron-donating dopant can be contained.

A substance that donates an electron and reduces an organic compound may be used as the electron-donating dopant to be introduced into the electron injection layer or the electron transport layer. Preferable examples thereof include alkali metals such as Li, alkaline-earth metals such as Mg, transition metals containing a rare-earth metal, and reducing organic compounds. As the metal, metals having a work function of 4.2 eV or less can be suitably used. Specific examples thereof include Li, Na, K, Be, Mg, Ca, Sr, Ba, Y, Cs, La, Sm, Gd, and Yb. Furthermore, examples of reducing organic compounds include nitrogen-containing compounds, sulfur-containing compounds, and phosphorus-containing compounds.

Besides these, the materials described in JP-A Nos. 6-212153, 2000-196140, 2003-68468, 2003-229278, 2004-342614 and the like, are also usable as electron-donating dopants.

Only one electron-donating dopant may be used, or two or more electron-donating dopants may be used in combination. The amount of the electron-donating dopant to be used varies depending on the kind of the material, and is preferably from 0.1% by mass to 99% by mass relative to the electron injection layer material or the electron transport layer material, more preferably from 1.0% by mass to 80% by mass, and particularly preferably from 2.0% by mass to 70% by mass.

### Second Embodiment of the Method for Manufacturing an Organic Electroluminescent Element According to the Invention

The second embodiment of the method for manufacturing an organic electroluminescent element in the invention includes forming a first electrode on a substrate, superposing a transfer material having an organic compound layer containing a metal complex having a tridentate or higher-dentate ligand provided on a temporary support, on the side of the substrate that has the first electrode thereon, applying heat and/or pressure thereto, peeling away the temporary support so as to transfer the organic compound layer onto the side of the substrate that has the first electrode thereon (the above processes will be occasionally referred to as “transfer process”), and forming a second electrode on the organic compound layer. In the following, the method for manufacturing the organic electroluminescent element in this embodiment will be occasionally referred to as “the method (2) for manufacturing an organic EL element”.

In the method (2) for manufacturing an organic EL element according to the invention, an organic EL element having high luminous efficiency and luminance and excellent durability can be manufactured stably by the formation of an organic compound layer containing a metal complex having a tridentate or higher-dentate ligand by the peel and transfer method using the transfer material.

The metal complex in the invention is a compound that is excellent in stability under heat and/or pressure. Therefore, an organic EL element having excellent performance can be manufactured even when heat and/or pressure is applied at transfer of the organic compound layer onto the film-forming surface of the substrate. Furthermore, the above-mentioned metal complex is a compound that is excellent in stability in a liquid. Therefore, deterioration with time in the manufacturing process is small even when the transfer layer (the organic compound layer) is formed by a wet method, so that an organic EL element having excellent performance can be manufactured.

[Transfer Material]

First, the transfer material used in the method (2) for manufacturing an organic EL element will be described in detail.

The transfer material can be manufactured by forming an organic compound layer on a temporary support.

In the method (2) for manufacturing an organic EL element, the organic compound layer containing a metal complex having a tridentate or higher-dentate ligand is formed by using the transfer material that has the organic compound layer. Other organic compound layers than the organic compound layer containing the metal complex may also be formed by using a transfer material. Detailed description on the transfer will be described later.

The transfer material can be manufactured by appropriately using known methods, such as a deposition method or a wet method. It is preferable to use a wet method from the viewpoint of the productivity.

In an embodiment, separate transfer materials each having an organic compound layer are prepared independently. In another embodiment, organic compound layers are provided sequentially to form a single transfer material. That is, for example, plural organic compound layers including an organic compound layer that contains a metal complex having a tridentate or higher-dentate ligand may be prepared on a single temporary support. When such a transfer material is used, plural organic compound layers can be consecutively formed without the need for exchanging the transfer material.

Further, when a transfer material in which two or more organic compound layers are laminated in advance on a temporary support is used, the plural layers can be laminated on the film-forming surface of the substrate in a single transfer process. For example, plural organic compound layers including an organic compound layer that contains a metal complex having a tridentate or higher-dentate ligand may be laminated on a temporary support. However, when the plural layers are laminated in advance on the temporary support, the interface of each organic compound layer to be laminated should be uniform; otherwise, the movement of holes and electrons becomes nonhomogenous. In order to make the interface of each organic compound layer uniform, the solvent should be selected carefully. Furthermore, an organic compound that is soluble in the solvent for the organic compound layer should be selected.

<Temporary Support>

The temporary support used in the invention is preferably composed of a material that is chemically and thermally stable and flexible. Specifically, preferable examples thereof include thin sheets of fluororesins [for example, tetrafluoroethylene resin (PTFE) and chlorotrifluoroethylene resin (PCTFE)], polyesters [for example, polyethylene terephthalate and polyethylene naphthalate (PEN)], polyallylate, polycarbonate, polyolefin [for example, polyethylene and polypropylene], polyether sulfone, and the like, and lamination of such sheets. The thickness of the temporary support may suitably be from 1 μm to 300 μm, more preferably from 3 μm to 200 μm, and particularly preferably from 3 μm to 50 μm.

<Formation of the Organic Compound Layer on the Temporary Support>

The organic compound layer can be formed on the temporary support by appropriately applying known methods such as deposition methods and wet methods, and is preferably formed by a wet method such as a coating method or a printing method.

When the organic compound layer containing a metal complex according to the invention is formed by a wet method, it is preferable to form the layer by using a liquid containing the metal complex.

The coating method is not particularly limited as long as the method enables formation of an organic compound layer with a uniform dry film thickness of preferably 200 nm or less, and may be selected from spin coat methods, gravure coating methods, dip coating methods, casting methods, die coating methods, roll coating methods, bar coating methods, extrusion coating methods, and inkjet coating methods. Among them, an extrusion coating method with roll-to-roll that achieves high productivity is preferable.

As the printing method, for example, the screen printing methods, the offset printing methods, the letterpress methods, the gravure printing methods, and the like described in JP-A Nos. 2001-52872, 2001-76874, 2001-93668, 2001-155858, 2001-155861, and the like, can be used.

Examples of organic compound layers that can be formed on the temporary support include, specifically, a luminescent layer, an electron transport layer, a hole transport layer, an electron injection layer, and a hole injection layer having unique characteristics.

The organic compound layer containing metal complexes having a tridentate or higher-dentate ligand, which is formed in the invention, may be selected from a luminescent layer, a charge transport layer, and a charge injection layer, and is preferably a luminescent layer.

Furthermore, various layers for improving the coloring property of the organic compound layer can be cited. Specific examples of compounds used in each layer are described, for example, in an extra issue “Organic EL Display” of “Monthly Display” October, 1998 (Techno Times Corp.), and the like.

In the following, each component of the organic compound layers that can be formed on the temporary support will be described in detail.

—Metal Complex Having a Tridentate or Higher-Dentate Ligand —

The metal complex having a tridentate or higher-dentate ligand contained in the organic compound layer is the same as the metal complex having a tridentate or higher-dentate ligand already described in the description of the composition for an organic EL element according to the invention.

The content of the metal complex having a tridentate or higher-dentate ligand in the organic compound layer varies depending on the kind of the layer containing the metal complex. A preferable content is the content described in the description of the each layer.

—Luminescent Layer—

The organic compound layers include at least one luminescent layer. The luminescent layer contains at least one luminescent compound (luminescent material). The metal complex having a tridentate or higher-dentate ligand according to the invention is preferably contained in the luminescent layer as a luminescent compound.

The luminescent compound is not particularly limited, and may be a fluorescent compound or a phosphorescent compound. Further, a fluorescent compound and a phosphorescent compound may be used at the same time. In the invention, it is preferable to use a phosphorescent compound in view of luminance and luminous efficiency. Hereinafter, the term “derivative” means the compound itself and its derivatives.

As luminescent compounds that can be used in the luminescent layer, besides metal complexes having a tridentate or higher-dentate ligand according to the invention, for example, other fluorescent compounds or phosphorescent compounds listed in the following can be used.

Examples of usable fluorescent compounds include benzoxazole derivatives, benzimidazole derivatives, benzothiazole derivatives, styrylbenzene derivatives, polyphenyl derivatives, diphenylbutadiene derivatives, tetraphenylbutadiene derivatives, naphthalimide derivatives, coumarin derivatives, perylene derivatives, perynone derivatives, oxadiazole derivatives, aldazine derivatives, pyralidine derivatives, cyclopentadiene derivatives, bis-styrylanthracene derivatives, quinacridon derivatives, pyrrolopyridine derivatives, thiadiazolopyridine derivatives, styrylamine derivatives, aromatic dimethylidyne compounds, metal complexes other than the metal complexes according to the invention (metal complexes of 8-quinolinol derivatives, rare earth complexes, and the like), polymer luminescent compounds (polythiophene derivatives, polyphenylene derivatives, polyphenylene vinylene derivatives, polyfluorene derivatives, and the like). Only one fluorescent compound may be used, or a mixture of two or more fluorescent materials may be used.

A phosphorescent compound is preferably a compound that can emit light from a triplet exciton, and ortho-metalation complexes and porphyrin complexes are preferable. Only one phosphorescent compound may be used, or two or more phosphorescent materials may be used in combination.

The ortho-metalation complex mentioned in the invention is a generic name for the group of compounds described in “Organometallic Chemistry, Fundamentals and Applications” written by Akio Yamamoto, pp. 150 and 232, Shokabo Corp. (1982), “Photochemistry and Photophysics of Coordination Compounds” written by H. Yersin, pp. 71 to 77 and 135 to 146, Springer-Verlag Corp. (1987), and the like. The ligands that form an ortho-metalation complex are not particularly limited, and are preferably selected from 2-phenylpyridine derivatives, 7,8-benzoquinoline derivatives, 2-(2-thienyl)pyridine derivatives, 2-(1-naphthyl)pyridine derivatives, and 2-phenylquinoline derivatives. These derivatives may have a substituent. Furthermore, these derivatives may have other ligands than the ligands essential for forming the ortho-metalation complexes. As the central metal for forming an ortho-metalation complex, any transition metal can be used. In the invention, rhodium, platinum, gold, iridium, ruthenium, palladium, and the like can be preferably used. An organic thin film layer containing such an ortho-metalation complex is excellent in luminance and luminous efficiency. Specific examples of ortho-metalation complexes are described in JP-A No. 2000-254171.

The ortho-metalation complex used in the invention can be synthesized by the known methods described in literatures such as Inorg. Chem., No. 30, p. 1685 (1991), No. 27, p. 3464 (1988), and No. 33, p. 545 (1994); Inorg. Chim. Acta, No. 181, p. 245 (1991); J. Organomet. Chem., No. 335, p. 293 (1987); and J. Am. Chem. Soc., No. 107, p. 1431 (1985).

The content of the luminescent compound in the luminescent layer is not particularly specified, and is, for example, preferably from 0.1 to 70% by mass, and more preferably from 1 to 20% by mass. When the content of the luminescent compound is less than 0.1% by mass or over 70% by mass, the effect is not exhibited sufficiently in some cases.

In an embodiment, a metal complex having a tridentate or higher-dentate ligand and other luminescent compound are used in combination as luminescent compounds in the luminescent layer.

The luminescent layer may contain a host compound, a hole transport material, an electron transport material, an electrically inert polymer binder, and the like as necessary. A single compound may perform plural functions selected from the functions of these materials. For example, a carbazole derivative functions not only as a host compound, but also functions as a hole transport material.

The host compound is a compound that causes a luminescent compound to emit light through energy transfer from the excited state of the host compound to the luminescent compound. The metal complex according to the invention can be contained as a host compound in the luminescent layer.

Examples of host compounds that can be applied to the invention include, besides the metal complexes according to the invention, carbazole derivatives, triazole derivatives, oxazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, styrylanthracene derivatives, fluorenone derivatives, hydrazone derivatives, stilbene derivatives, silazane derivatives, aromatic tertiary amine compounds, styrylamine compounds, aromatic dimethylidyne compounds, porphyrin compounds, anthraquinodimethane derivatives, anthrone derivatives, diphenylquinone derivatives, thiopyranedioxide derivatives, carbodiimide derivatives, fluorenylidene methane derivatives, distyrylpyrazine derivatives, heterocyclic tetracarboxylic acid anhydrides (such as naphthalene tetracarboxylic acid anhydride and perylene tetracarboxylic acid anhydride), phthalocyanine derivatives, metal complexes of 8-quinolinol derivatives, metal phthalocyanine, metal complexes having benzoxazole, benzothiazole, or the like as a ligand, conductive polymers such as polysilane compounds, poly(N-vinylbarbazole) derivatives, aniline copolymers, thiophene oligomers, and polythiophene, polythiophene derivatives, polyphenylene derivatives, polyphenylene vinylene derivatives, and polyfluorene derivatives. Only a single host compound may be used, or two or more host compounds may be used in combination.

The content of the host compound in the luminescent layer is preferably from 0 to 99.9% by mass, and more preferably from 0 to 99.0% by mass.

The hole transport material is not particularly limited as long as the material has any of: the function of injecting holes from the anode, the function of transporting the holes, and the function of blocking the electrons injected from the cathode. The hole transport material may be a low-molecular material or a high-molecular material. Specific examples thereof include the metal complexes according to the invention, carbazole derivatives, triazole derivatives, oxazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, styrylanthracene derivatives, fluorenone derivatives, hydrazone derivatives, stilbene derivatives, silazane derivatives, aromatic tertiary amine compounds, styrylamine compounds, aromatic dimethylidyne compounds, porphyrin compounds, conductive polymers such as polysilane compounds, poly(N-vinylcarbazole) derivatives, aniline copolymers, thiophene oligomers, and polythiophene, polythiophene derivatives, polyphenylene derivatives, polyphenylene vinylene derivatives, and polyfluorene derivatives. Only a single hole transport material may be used, or two or more hole transport materials may be used. The content of the hole transport material in the luminescent layer is preferably from 0 to 99.9% by mass, and more preferably from 0 to 80.0% by mass.

The electron transport material is not particularly limited as long as the material has any of: the function of injecting electrons from the cathode, the functions of transporting the electrons, and the function of blocking holes injected from the anode. Specific examples thereof include the metal complexes according to the invention, triazole derivatives, oxazole derivatives, oxadiazole derivatives, fluorenone derivatives, anthraquinodimethane derivatives, anthrone derivatives, diphenylquinone derivatives, thiopyranedioxide derivatives, carbodiimide derivatives, fluorenylidene methane derivatives, distyrylpyrazine derivatives, heterocyclic tetracarboxylic acid anhydrides such as naphthalene tetracarboxylic acid and perylene tetracarboxylic acid, phthalocyanine derivatives, metal complexes of 8-quinolinol derivatives, metal phthalocyanine, metal complexes having benzoxazole, benzothiazole, or the like as a ligand, conductive polymers such as aniline copolymers, thiophene oligomers, and polythiophene, polythiophene derivatives, polyphenylene derivatives, polyphenylene vinylene derivatives, and polyfluorene derivatives. Only a single electron transport material may be used, or two or more electron transport materials may be used in combination. The content of the electron transport material in the luminescent layer is preferably from 0 to 99.9% by mass, and more preferably from 0 to 80.0% by mass.

When the luminescent layer is formed by a coating method, the layer preferably contains a polymer binder. Examples of polymers that can be used as a polymer binder include polyvinyl carbazole, polyvinyl chloride, polycarbonate, polystyrene, polymethyl methacrylate, polybutyl methacrylate, polyester, polysulfone, polyphenylene oxide, polybutadiene, hydrocarbon resin, ketone resin, phenoxy resin, polyamide, ethyl cellulose, vinyl acetate, ABS resin, polyurethane, melamine resin, unsaturated polyester, alkyd resin, epoxy resin, silicone resin, polyvinyl butyral, and polyvinyl acetal. Only a single polymer binder may be used, or two or more polymer binders may be used in combination. The luminescent layer having a large area and containing the polymer binder can be easily formed by coating according to a wet film-forming method.

The thickness of the luminescent layer is preferably from 10 to 200 nm, and more preferably from 20 to 80 nm. When the thickness is over 200 nm, the driving voltage may be increased. On the other hand, when the thickness is less than 10 nm, the organic EL element may be short-circuited.

—Hole Transport Layer—

In the invention, it is preferable to provide a hole transport layer comprising the above-mentioned hole transport material, as necessary. The hole transport layer may contain the above-mentioned polymer binder. The thickness of the hole transport layer is preferably from 10 to 200 nm, and more preferably from 20 to 80 nm. When the thickness is over 200 nm, the driving voltage may be increased. When the thickness is less than 10 nm, the organic EL element may be short-circuited.

—Electron Transport Layer—

In the invention, it is preferable to provide an electron transport layer comprising the above-mentioned electron transport material, as necessary. The electron transport layer may contain the above-mentioned polymer binder. The thickness of the electron transport layer is preferably from 10 to 200 nm, and more preferably from 20 to 80 nm. When the thickness is over 200 nm, the driving voltage may be increased. When the thickness is less than 10 nm, the organic electroluminescent element may be short-circuited.

When the organic compound layer is formed by coating according to a liquid phase method, the solvent to be used for preparing the coating liquid through dissolution or dispersion of the material for the organic compound layer is not particularly limited, and may be appropriately selected in consideration of the kind of the component consisting the organic compound layer. Examples of the solvent include water, alcohols such as methanol, ethanol, 1-methoxy-2-propanol, methoxyethanol, and phenoxyethanol, ketones such as acetone, methyl ethyl ketone, diethyl ketone, n-propyl methyl ketone, and cyclohexanone, ethers such as dibutyl ether, tetrahydrofuran, and dioxane, esters such as ethyl acetate, butyl acetate, ethyl 2-ethylhexanoate, methyl propionate, ethyl propionate, γ-butyrolactone, and diethyl carbonate, amides such as formamide, N,N-dimethylformamide (DMF), and N,N-dimethylacetamide, aliphatic hydrocarbons such as hexane, heptane, octane, and cyclohexane, aromatic hydrocarbons such as benzene, toluene, and xylene, halogenated hydrocarbons such as chloroform, carbon tetrachloride, dichloromethane, and 1,2-dichloroethane, organic solvents such as N-methylpyrrolidone (NMP), dimethylimidazoline (DMI), and dimethylsulfoxide (DMSO), inorganic solvents, and a mixture of two or more of the above solvents. A mixture of solvents selected from these solvents is also usable. The solid content in the coating liquid for an organic compound layer is not particularly limited, and the viscosity can also be arbitrarily selected in accordance with the wet film-forming method to be used.

A process using a bar coating method is described as an example of the formation of an organic compound layer containing the metal complex (the metal complex having a tridentate or higher-dentate ligand) according to the invention on the temporary support by a coating method. However, the preparation method is not limited to this particular example.

(1) First, the metal complex according to the invention is dissolved or dispersed in a solvent to prepare a metal complex containing liquid. The metal complex containing liquid may contain the components of the organic compound layer containing the metal complex.

The metal complex containing liquid is not particularly limited, regardless of whether the liquid is in the form of a solution or a dispersion liquid. The metal complex containing liquid is preferably a polymer dispersion liquid containing a polymer for dispersing the metal complex according to the invention. When the metal complex containing liquid is a polymer dispersion liquid, the components of the organic compound layer containing the metal complex according to the invention is preferably dispersed in the polymer. Since the components of the organic compound layer containing the metal complex are dispersed in the polymer, the stability of the components in the dispersion liquid is improved, whereby an organic EL element with further improved luminous efficiency and durability can be obtained. As the polymer to be used for the dispersing operation, for example, polymers described in JP-A Nos. 2001-11568, 2002-25779, 2004-152746, and the like can be used suitably.

The solvent for dissolving or dispersing the metal complex according to the invention is not particularly limited. The solvents described above as examples of the solvent used for preparing the coating liquid through dissolution or dispersion of the material of the organic compound layer can be used for dissolving or dispersing the metal complex. A mixture of two or more of such solvents is also usable.

The optimum solvent is selected based on the molecular weight, the kind of the substituents, the structure and the like of the metal complex according to the invention.

(2) The metal complex containing liquid obtained above is bar-coated on a temporary support that has been washed in advance, by using a bar coating apparatus (for example, #10, manufactured by Matsubo Corporation, and the like), so that a thin film of the organic compound layer is obtained. A thin film having an arbitrary thickness can be obtained by drying the thin film at room temperature or under heating at atmospheric pressure or reduced pressure.

The drying condition of the thin film can be suitably selected according to the conditions such as the compound and solvent to be used. In general, the drying can be carried out under atmospheric pressure or reduced pressure.

When a polymer dispersion liquid is used as the metal complex containing liquid, dispersion liquids with various viscosities can be used. Because the viscosity of the liquid differs depending on the coating method, it is preferable to prepare a liquid having a suitable viscosity for the coating method.

The polymer dispersion liquid can be prepared by dissolving or dispersing a polymer (for example, PVK) and a metal complex according to the invention in a solvent (for example, a mixture of toluene and chloroform in a ratio of 1:1) by stirring, with a dispersing apparatus, the liquid for a necessary time for the dissolution or dispersion. The dispersion apparatus is not particularly limited, and may be a known apparatus.

The glass transition temperature of the organic compound layer itself or the component in the layer is preferably from 40° C. to (the transfer temperature +40° C.), more preferably from 50° C. to (the transfer temperature +20° C.), and particularly preferably from 60° C. to the transfer temperature. The flow starting temperature of the organic compound layer itself in the transfer material or of the component in the layer is preferably from 40° C. to (the transfer temperature +40° C.), more preferably from 50° C. to (the transfer temperature +20° C.), and particularly preferably from 60° C. to the transfer temperature. The glass transition temperature can be measured with a differential scanning calorimeter (DSC). The flow starting temperature can be measured with, for example, flow tester CFT-500 manufactured by Shimadzu Corporation.

[Manufacture of an Organic EL Element]

In the method (2) for manufacturing an organic EL element, the organic EL element is manufactured as follows: the transfer material described above having an organic compound layer on a temporary support is prepared, the transfer material is placed on the substrate having a first electrode formed thereon such that the organic compound layer side contacts the film-forming surface of the substrate (i.e., the surface having the first electrode), heat and/or pressure is applied, and then the temporary support is peeled away so that the organic compound layer is transferred onto the film-forming surface of the substrate (the peel-transfer method), and a second electrode is formed on the organic compound layer.

When plural organic compound layers are formed, other layers than the organic compound layer containing the metal complex according to the invention can be formed by, besides the peel-transfer method, a dry film-forming method such as a deposition method or a sputtering method, a wet method such as dipping, a spin coat method, a dip coating method, a casting method, a die coating method, a roll coating method, a bar coating method, or a gravure coating method, a printing method, or the like.

The peel-transfer method is a method in which the organic compound layer is softened by heating and/or pressurizing the transfer material and is adhered onto the film-forming surface of the substrate, and the temporary support is peeled away to leave only the organic compound layer on the film-forming surface. Furthermore, in the method (2) for manufacturing an organic EL element, the peel-transfer method and the adhesion method may be used together. The adhesion method is a method in which the interfaces of at least two surfaces are bonded to each other by close contact, pressure bonding, fusion bonding, or the like. Specifically, in the method, the organic compound layer transferred onto the film-forming surface, and the substrate having the electrode and/or the organic compound layer formed thereon, are stacked, the organic compound layer is softened by heating and/or pressurizing, and is adhered to the electrode and/or the organic compound layer on the substrate. In the transfer method and the adhesion method used in the invention, heating and pressurizing each may be used alone, or a combination of heat and pressure may be applied.

As a heating device, a generally known method can be used. For example, a laminator, an infrared heater, a roller heater, a laser, a thermal head, and the like can be used. When the transfer of a large area is carried out, a planate heating device is preferable, and a laminator, an infrared heater, a roller heater, and the like are more preferable. The temperature for transfer is not particularly limited, and may be changed according to the material of the organic compound layer and the heating member. In general, the transfer temperature is preferably from 40 to 250° C., more preferably from 50 to 200° C., and particularly preferably from 60 to 180° C. However, the preferable range of the transfer temperature is related to the heat resistance of the heating member, the transfer material, and the substrate, and changes in accordance with the improvement in the heat resistance. The pressurizing device is not particularly limited. When a substrate that is easily destroyed by distortion, such as glass, is used, a device that can apply pressure uniformly is preferred. For example, it is preferable to use a pair of rollers, one or both of which are made of rubber. Specifically, a laminator (trade name: FAST LAMINATOR VA-400 III, manufactured by Taisei Laminator Co., Ltd.) and the like, a heating head for a thermal transfer print, and the like can be used. When pressure is applied, it is preferable that the interfaces uniformly contact with each other. The pressure to be applied is not particularly limited, and, in general, is preferably from 0.1 to 100 MPa, more preferably from 0.1 to 30 MPa, and particularly preferably from 0.1 to 10 MPa.

In the method (2) for manufacturing an organic EL element, the organic EL element can also be formed by laminating plural organic compound layers including the organic compound layer containing at least one metal complex having a tridentate or higher-dentate ligand on the substrate by carrying out repeatedly the processes of transfer and peeling. The plural organic compound layers may have the same composition, or different compositions. When the plural organic compound layers have the same composition, there is an advantage in that omission of the layer caused by transfer defects or peeling defects can be prevented. Furthermore, when different layers are prepared, a design is possible in which the functions are separated and allotted to the different layers, so that the luminous efficiency is improved. For example, in an embodiment, a transparent or opaque conductive layer, a luminescent layer, an electron transport layer, an electron injection layer, and a back electrode are laminated in this order on the film-forming surface by the transfer method. In another embodiment, a transparent conductive layer, a hole injection layer, a hole transport layer, a luminescent layer, an electron transport layer, an electron injection layer, and a transparent or opaque back electrode are laminated in this order on the film-forming surface by the transfer method.

The organic compound layer transferred onto the substrate, or a new organic compound layer transferred onto the previously transferred organic compound layer is preferably reheated as necessary. As a result of the reheating, the organic compound layer adheres more tightly to the substrate or to the previously transferred organic compound layer. At the time of reheating, it is preferable to apply pressure as necessary. The reheating temperature is preferably in a range of the transfer temperature ±50° C.

A surface treatment for improving adhesion strength may be performed on the film-forming surface during the previous transfer process and the next transfer process so that the previous transfer layer is not reversely transferred to the next transfer layer. Examples of such a surface treatment include activation treatments such as the corona discharge treatment, the flame treating, the glow discharge treatment, and the plasma processing. When a surface treatment is conducted, the transfer temperature for the previous transfer material may be lower than the transfer temperature for the next transfer material as long as no reverse transfer occurs.

The manufacturing apparatus used in the transfer method may have an apparatus that feeds a transfer material having an organic compound layer formed on the temporary support, a device that transfers the organic compound layer onto the film-forming surface of the substrate by pushing the transfer material against the film-forming surface of the substrate while heating the transfer material, and a device that peels the temporary support off the organic compound layer after the transfer. The manufacturing apparatus preferably has a device that preheats the transfer material and/or the substrate before supplying them to the transfer device. Furthermore, the apparatus preferably has a cooling device as a stage subsequent to the transfer device.

The apparatus used in the method (2) for manufacturing an organic EL element is not particularly limited. In a preferable example of the apparatus, a glove box whose internal air is replaced with an inert gas such as nitrogen or argon is connected to a deposition device or sputtering device for forming the back electrode, and the formed laminated body can be moved to the next process without exposure to the air.

Furthermore, in the method (2) for manufacturing an organic EL element, each process is preferably conducted in the atmosphere with a moisture content of 100 ppm or less and an oxygen content of 100 ppm or less.

Although suitable embodiments of the method (2) for manufacturing an organic EL element will be described, the embodiments should not be construed as limiting the invention.

First, a coating liquid is prepared by dissolving or dispersing the material of the organic compound layer containing the metal complex according to the invention in a glove box whose internal air has been substituted with an inert gas (nitrogen, argon, or the like) whose moisture content is 100 ppm or less and whose oxygen content is 100 ppm or less. The coating liquid is applied on a temporary support with a spin coater or the like in the glove box, and the resultant organic compound layer is dried to form a transfer material. Furthermore, transfer materials for forming organic compound layers not containing the metal complex according to the invention can be manufactured in a similar manner.

Separately, a substrate support is placed in a vacuum chamber of a deposition device connected to the glove box, and a transparent or opaque electrode is formed on the substrate support. Next, the substrate having a transparent or opaque electrode formed thereon is moved into the glove box. Then, the transfer material is superposed on the substrate such that the organic compound layer side of the transfer material contacts the film-forming surface of the substrate and is heated and/or pressurized, and then the organic compound layer is transferred onto the film-forming surface of the substrate by peeling away the temporary support. Next, in order to form a transparent or opaque back electrode, the substrate is moved into the deposition device connected to the glove box, and a transparent or opaque back electrode is formed. The obtained laminated body is returned to the glove box again, and the electrode and the back electrode each are connected to an aluminum lead wire. Further, sealing is conducted with a sealant, so that an organic EL element is obtained.

(Organic EL Element Manufactured by Using the Method (2) for Manufacturing an Organic EL Element)

The organic electroluminescent element according to the first embodiment of the invention is manufactured by using above-mentioned method (2) for manufacturing an organic EL element (hereinafter occasionally referred to as “the organic EL element (2)”).

[Whole Structure of the Element]

The whole structure of the organic EL element (2) may be a structure having the following layers and electrodes in this order on a substrate support:

a transparent or opaque conductive layer-a luminescent layer-a back electrode,

a transparent conductive layer-a luminescent layer-an electron transport layer-a transparent or opaque back electrode,

a transparent or opaque conductive layer-a hole transport layer-a luminescent layer-an electron transport layer-a transparent or opaque back electrode,

a transparent or opaque conductive layer-a hole transport layer-a luminescent layer-a transparent or opaque back electrode,

a transparent or opaque conductive layer-a luminescent layer-an electron transport layer-an electron injection layer-a transparent or opaque back electrode,

a transparent or opaque conductive layer-a hole injection layer-a hole transport layer-a luminescent layer-an electron transport layer-an electron injection layer-a transparent or opaque back electrode.

Structures in which the above layers are disposed in the reverse order are also usable. In the organic EL element (2), luminescence is usually taken out from the transparent conductive layer.

<Organic Compound Layer>

The description above about the organic compound layers that can be formed on a temporary support is also applicable to the organic compound layers of the organic EL element (2).

—Patterning—

A mask (a fine mask) having openings in a fine pattern may be used for the formation of a finely patterned organic compound layer. The material of the mask is not limited, and is preferably a durable and cheap material, such as metals, glass, ceramics, and heat-resistant resins are preferable. A combination of one or more of these materials is also usable. From the viewpoints of mechanical strength and the transfer accuracy of the organic compound layer, the thickness of the mask is preferably from 2 to 100 μm, and more preferably from 5 to 60 μm.

The openings in the mask are preferably tapered such that the opening is larger at the transfer material side than the substrate side, so as to allow the organic compound layer of the transfer material to adhere accurately to the transparent conductive layer or different organic compound layer on which the organic compound layer is to be formed according to the shape of the openings of the mask.

In another preferable patterning method, the surface of the transfer material on which concave and convex patterns are formed is superposed on a substrate, and the organic compound layer formed in the convex region of the transfer material is transferred onto the substrate. The pattern corresponding to the concavity and convexity of a pushing member can be formed on the surface of the transfer material by pushing the pushing member, having thereon a prescribed pattern of concavity and convexity, against the surface of the organic compound layer provided on the temporary support of the transfer material. Plural transfer materials each having an organic compound layer of a different composition may be formed. Therefore, a patterned organic compound layer having plural organic compound layers with different compositions formed thereon can be manufactured by repeating the transfer onto the substrate, using such plural transfer materials.

[Other Constituent Elements]

Concerning other constituent elements such as the substrate, the electrode, other organic layers, and other layers in the organic EL element according to the invention, besides those already described, for example, those described in [0013] to [0082] of JP-A No. 2004-221068, [0017] to [0091] of JP-A No. 2004-214178, [0024] to [0035] of JP-A No. 2004-146067, [0017] to [0068] of JP-A No. 2004-103577, [0014] to [0062] of JP-A No. 2003-323987, [0015] to [0077] of JP-A No. 2002-305083, [0008] to [0028] of JP-A No. 2001-172284, [0013] to [0075] of JP-A No. 2000-186094, [0016] to [0118] of Japanese Patent Application National Publication (Laid-Open) No. 2003-515897, and the like can be applied similarly in the invention. However, the constituent elements usable in the invention are not limited to these.

In the hole injection layer and/or the hole transport layer in the organic EL element (2), an electron receiving dopant can be contained. The electron receiving dopant to be introduced into the hole injection layer or the hole transport layer may be an inorganic compound or an organic compound as long as the compound has properties of receiving an electron and of oxidizing organic compounds.

Specifically, the inorganic compound may be, for example, a halogenated metal such as ferric oxide, aluminum chloride, gallium chloride, indium chloride, or antimony pentachloride, or a metal oxide such as vanadium pentoxide or molybdenum trioxide.

The organic compound may be, for example, a compound having a nitro group, a halogen, a cyano group, a trifluoromethyl group, or the like as a substituent, a quinone compound, an acid anhydride compound, or a fullerene.

Besides these, compounds described in JP-A Nos. 6-212153, 11-111463, 11-251067, 2000-196140, 2000-286054, 2000-315580, 2001-102175, 2001-160493, 2002-252085, 2002-56985, 2003-157981, 2003-217862, 2003-229278, 2004-342614, 2005-72012, 2005-166637, 2005-209643, and the like can be suitably used.

Only one electron receiving dopant may be used, or two or more electron receiving dopants may be used. The amount of the electron receiving dopant to be used varies depending on the kind of the material, and is preferably from 0.01% by mass to 50% by mass relative to the hole injection layer material or the hole transport layer material, more preferably from 0.05% by mass to 20% by mass, and particularly preferably from 0.1% by mass to 10% by mass.

In the electron injection layer and/or the electron transport layer in the organic EL element (2), an electron-donating dopant can be contained.

The electron-donating dopant introduced into the electron injection layer or the electron transport layer has properties of donating an electron and of reducing organic compounds. The electron-donating dopant is preferably an alkali metal such as Li, an alkaline-earth metal such as Mg, a transition metal (whose scope includes rare-earth metals), a reducing organic compound, or the like. As the metal, metals having a work function of 4.2 eV or less can be suitably used in particular. Specific examples include Li, Na, K, Be, Mg, Ca, Sr, Ba, Y, Cs, La, Sm, Gd, and Yb. Examples of the reducing organic compound include nitrogen-containing compounds, sulfur-containing compounds, and phosphorus-containing compounds.

Besides these, as an electron-donating dopant, materials described in JP-A Nos. 6-212153, 2000-196140, 2003-68468, 2003-229278, 2004-342614, and the like can be used.

Only a single electron-donating dopant may be used, or two or more electron-donating dopants may be used in combination. The amount of the electron-donating dopant to be used varies depending on the kind of the material, and is preferably from 0.1% by mass to 99% by mass relative to the electron injection layer material or the electron transport layer material, more preferably from 1.0% by mass to 80% by mass, and particularly preferably from 2.0% by mass to 70% by mass.

The organic EL elements (1) and (2) emit light when a direct current (, which may include an alternating current component as necessary) voltage (usually from 2 V to 15 V) or direct current is applied between the anode and the cathode.

As for the driving method of the organic EL elements (1) and (2), the driving methods described in JP-A Nos. 2-148687, 6-301355, 5-29080, 7-134558, 8-234685, and 8-241047, Japanese Patent No. 2784615, and U.S. Pat. Nos. 5,828,429 and 6,023,308 can be applied.

The organic EL elements (1) and (2) can be suitably used in display elements, displays, backlights, electrophotography, illumination light sources, light sources for recording, light sources for exposing, light sources for reading, marks, signboards, interiors, optical communication, and the like.

In the following, illustrative embodiments according to the invention will be described.

<1> A composition for an organic electroluminescent element capable of forming a pattern by an ink jet method, comprising at least one metal complex having a tridentate or higher-dentate ligand.

<2> The composition according to <1>, wherein the tridentate or higher ligand is a chain ligand.

<3> The composition according to <1> or <2>, wherein the metal complex having the tridentate or higher-dentate ligand is a compound represented by the following formula (I).

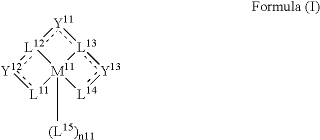

In Formula (I), M¹¹ represents a metal ion; L¹¹ to L¹⁵ each independently represent a ligand coordinated to M¹¹; in no case does an additional atomic group connect L¹¹ and L¹⁴ to form a cyclic ligand; in no case, is L¹⁵ bonded to both L¹¹ and L¹⁴ to form a cyclic ligand; Y¹¹ to Y¹³ each independently represent a connecting group, a single bond, or a double bond; when Y¹¹, Y¹², or Y¹³ represent a connecting group, the bond between L¹¹ and Y¹², the bond between Y¹² and L¹², the bond between L¹² and Y¹¹, the bond between Y¹¹ and L¹³, the bond between L¹³ and Y¹³, and the bond between Y¹³ and L¹⁴ are each independently a single bond or a double bond; and n¹¹ represents an integer of 0 to 4. Each bond connecting M¹¹ and each of L¹¹ to L¹⁵ may be selected from a coordinate bond, an ionic bond and a covalent bond.

<4> The composition according to any one of <1> to <3>, wherein the metal complex having the tridentate or higher-dentate ligand is a compound represented by the following formula (II).

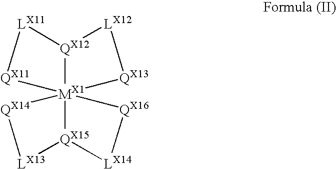

In Formula (II), M^{X1} represents a metal ion. Q^{X11} to Q^{X16} each independently represent an atom coordinating to M^{X1} or an atomic group containing an atom coordinating to M^{X1}. L^{X11} to L^{X14} each independently represent a single bond, a double bond or a connecting group.

Namely, in Formula (II), the atomic group comprising Q^{X11}-L^{X11}-Q^{X12}-L^{X12}-Q^{X13} and the atomic group comprising Q^{X14}-L^{X13}-Q^{X15}-L^{X14}-Q^{X16} each form a tridentate ligand.

In addition, the bond between M^{X1} and each of Q^{X11} to Q^{X16} may be a coordination bond, an ionic bond, or a covalent bond.

<5> The composition according to <1>, wherein the metal complex having the tridentate or higher-dentate ligand is a compound represented by the following formula (III).

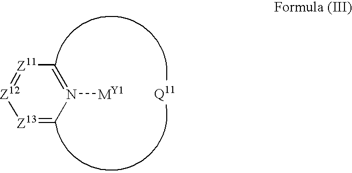

In Formula (III), Q¹¹ represents an atomic group forming a nitrogen-containing heterocycle; Z¹¹, Z¹², and Z¹³ each represent a substituted or unsubstituted carbon or nitrogen atom; and M^{Y1} represents a metal ion that may further have a ligand.

<6> The composition according to any one of <1> to <5>, comprising a polymer dispersion liquid that contains a polymer for dispersing the metal complex having the tridentate or higher-dentate ligand.

<7> A method for manufacturing an organic electroluminescent element, the method comprising forming a first electrode on a substrate, forming an organic compound layer by discharging the composition of any one of <1> to <6> in a pattern onto the side of the substrate that has the first electrode thereon using an ink jet apparatus, and forming a second electrode on the organic compound layer.

<8> A method for manufacturing an organic electroluminescent element, the method comprising forming a first electrode on a substrate, superposing a transfer material having an organic compound layer containing a metal complex having a tridentate or higher-dentate ligand provided on a temporary support, on the side of the substrate that has the first electrode thereon, applying heat and/or pressure thereto, peeling away the temporary support so as to transfer the organic compound layer onto the side of the substrate that has the first electrode thereon, and forming a second electrode on the organic compound layer.

<9> The method for manufacturing an organic electroluminescent element according to <8>, wherein the organic compound layer containing the metal complex having the tridentate or higher-dentate ligand is formed on the temporary support by using a liquid containing the metal complex having the tridentate or higher-dentate ligand.

<10> The method for manufacturing an organic electroluminescent element according to <8> or <9>, wherein the tridentate or higher-dentate ligand is a chain ligand.

<11> The method for manufacturing an organic electroluminescent element according to any one of <8> to <10>, wherein the metal complex having the tridentate or higher-dentate ligand is a compound represented by the following formula (I).

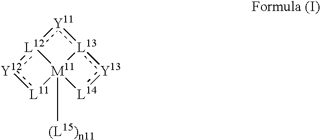

In Formula (I), M¹¹ represents a metal ion; L¹¹ to L¹⁵ each independently represent a ligand coordinated to M¹¹; in no case does an additional atomic group connect L¹¹ and L¹⁴ to form a cyclic ligand; in no case, is L¹⁵ bonded to both L¹¹ and L¹⁴ to form a cyclic ligand; Y¹¹ to Y¹³ each independently represent a connecting group, a single bond, or a double bond; when Y¹¹, Y¹², or Y¹³ represent a connecting group, the bond between L¹¹ and Y¹², the bond between Y¹² and L¹², the bond between L¹² and Y¹¹, the bond between Y¹¹ and L¹³, the bond between L¹³ and Y¹³, and the bond between Y¹³ and L¹⁴ are each independently a single bond or a double bond; and n¹¹ represents an integer of 0 to 4. Each bond connecting M¹¹ and each of L¹¹ to L¹⁵ may be selected from a coordinate bond, an ionic bond and a covalent bond.

<12> The method for manufacturing an organic electroluminescent element according to any one of <8> to <11>, wherein the metal complex having the tridentate or higher-dentate ligand is a compound represented by the following formula (II).

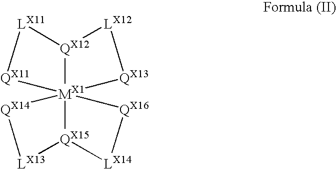

In Formula (II), M^{X1} represents a metal ion. Q^{X11} to Q^{X16} each independently represent an atom coordinating to M^{X1} or an atomic group containing an atom coordinating to M^{X1}. L^{X11} to L^{X14} each independently represent a single bond, a double bond or a connecting group.

Namely, in Formula (II), the atomic group comprising Q^{X11}-L^{X11}-Q^{X12}-L^{X12}-Q^{X13} and the atomic group comprising Q^{X14}-L^{X13}-Q^{X15}-L^{X14}-Q^{X16} each form a tridentate ligand.

In addition, the bond between M^{X1} and each of Q^{X11} to Q^{X16} may be a coordination bond, an ionic bond, or a covalent bond.

<13> The method for manufacturing an organic electroluminescent element according to <8> or <9>, wherein the metal complex having the tridentate or higher-dentate ligand is a compound represented by the following formula (III).

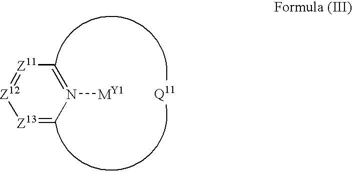

In Formula (III), Q¹¹ represents an atomic group forming a nitrogen-containing heterocycle; Z¹¹, Z¹², and Z¹³ each represent a substituted or unsubstituted carbon or nitrogen atom; and M^{Y1} represents a metal ion that may further have a ligand.

<14> The method for manufacturing an organic electroluminescent element according to any one of <8> to <13>, wherein the liquid containing the metal complex containing the tridentate or higher-dentate ligand is a polymer dispersion liquid that contains a polymer for dispersing the metal complex.

<15> An organic electroluminescent element manufactured by using the method for manufacturing an organic electroluminescence element according to any one of <7> to <14>.

### EXAMPLES

In the following, the present invention will be further described in detail by reference to Examples. However, the Examples should not be construed as limiting the invention.

### Comparative Example 1A

A glass substrate of 25 mm×25 mm×0.7 mm having thereon an ITO film with a thickness of 150 nm (manufactured by Sanyo Vacuum Industries Co., Ltd.) is used as a transparent supporting substrate. This transparent supporting substrate is etched and washed.

After Baytron P (PEDOT-PSS solution (Polyethylene dioxythiophene-polystyrene sulfonate-doped body) manufactured by Bayer AG) for the hole injection and transport layer is spin coated on this ITO glass substrate, the coated layer is dried at 100° C. for one hour under vacuum to form a hole injection and transport layer (about 100 nm in film thickness).

On this layer, a solution for a luminescent layer that contains 0.45% by mass of polyvinyl carbazole (having the structure shown below and a Mn of 25000 to 50000, manufactured by Aldrich Corp.), 0.05% by mass of tris(2-phenylpyridine)iridium complex (ortho-metalation complex), 1% by mass of water, 23.5% by mass of methanol, 60% by mass of DMF, 5% by mass of glycerin, and 10% by mass of diethylene glycol is coated by being discharged from the head of an ink jet printing apparatus, to form a luminescent layer (about 50 nm in film thickness).

Thereafter, Balq and Alq, which are electron transfer materials, are deposited sequentially to thicknesses of 20 nm and 30 nm respectively, so that an electron transport layer is formed.

Furthermore, LiF is deposited to a thickness of about 3 nm in the vacuum of 10⁻³ to 10⁻⁴ Pa with the temperature of the substrate being room temperature.

On this layer, a patterned mask (a mask to give a luminescence area of 2 mm×2 mm) is placed, and then aluminum is deposited to a thickness of about 400 nm, so that an element of Comparative Example 1A is obtained.

The manufactured element is sealed in a dried glove box.

Polyvinyl carbazole

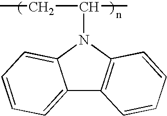

Tris(2-phenylpyridine)iridium complex

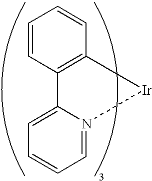

### Example 1A

An element is manufactured in the same manner as in Comparative Example 1A, except for using a compound (Pt-1) having the following structure in place of tris(2-phenylpyridine)iridium complex used in the element of Comparative Example 1A.

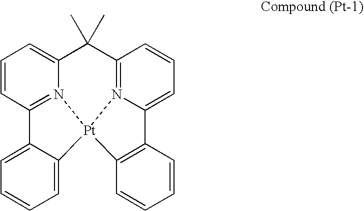

### Comparative Example 2A

An element is manufactured in the same manner as in Comparative Example 1A, except for using a compound (Ir-1) having the following structure in place of tris(2-phenylpyridine)iridium complex used in the element of Comparative Example 1A.

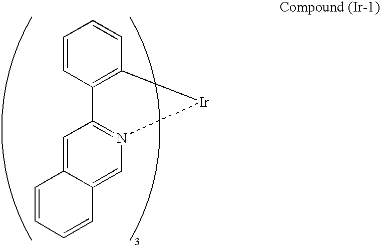

### Example 2A

An element is manufactured in the same manner as in Comparative Example 1A, except for using a compound (Pt-2) having the following structure in place of the compound (Pt-1) used in the element of Example 1A. 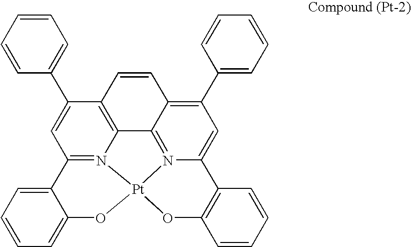
<Evaluation of the Elements>
(1) Luminous Efficiency: External Quantum Efficiency

Using a Source Measure Unit 2400 manufactured by KEITHLEY, a direct current voltage is applied to each element to cause emission of light. The luminance is measured with a luminance meter BM-8, manufactured by Topcon Corporation, and the emission spectrum and the emission wavelength are measured with a spectrum analyzer PMA-11, manufactured by Hamamatsu Photonics KK. Based on these measured values, the external quantum efficiency around the luminance of 1000 cd/m² is calculated according to the luminance conversion method, and is evaluated according to the following criteria.

—Evaluation Criteria—

A: 5% or more

B: 3% or more but less than 5%

C: less than 3%

(2) Driving Durability: Half Life of Luminance

Similarly to (1) above, a direct current voltage is applied to each element to obtain a luminance of 1000 cd/m², and the time until the luminance reduces to 500 cd/m² (the half life of luminance) is measured. The results are evaluated according to the following criteria.

—Evaluation Standard—

A: 2000 hours or more

B: 1000 hours or more but less than 2000 hours

C: less than 1000 hours

Table 1 shows the evaluation results, together with the luminescent color of each element.

TABLE 1

| | | External quantum | Half life of |
|---|---|---|---|
| | Luminescent color | efficiency | luminance |
| Comparative | Green | B | B |
| Example 1A | | | |
| Example 1A | Green | A | A |
| Comparative | Orange-yellow | B | B |
| Example 2A | | | |
| Example 2A | Orange-yellow | A | A |

### Examples 1B and 2B, And Comparative Examples 1B and 2B

Elements of Examples 1B and 2B and Comparative Examples 1B and 2B are manufactured in the same manner as in Examples 1A and 2A and Comparative Examples 1A and 2A, respectively, except that the solution for a luminescent layer is coated by being discharged from the head of the ink jet printing apparatus five hours after the preparation thereof.

<Evaluation of the Elements>

(3) External Quantum Efficiency and Half Life of Luminance in the Case the Solutions Undergo Time Passage.

The external quantum efficiency and the half life of luminance of the elements manufactured as described above are measured by the same methods as the above-mentioned methods (1) and (2), respectively.

Table 2 shows the evaluation results, together with the luminescent color of each element.

TABLE 2

| | | | Half life of |
|---|---|---|---|
| | | External quantum | luminance in the |
| | | efficiency in the case | case the solutions |
| | Luminescent | the solutions undergo | undergo the time |
| | color | the time passage | passage |
| Comparative | Green | C | C |
| Example 1B | | | |
| Example 1B | Green | A | A |
| Comparative | Orange-yellow | C | C |
| Example 2B | | | |
| Example 2B | Orange-yellow | A | A |

### Examples 3A and 3B, And Comparative Examples 3A and 3B

Elements of Examples 3A and 3B are manufactured in the same manner as in Examples 1A and 1B, respectively, except for using a compound (Pt-3) having the following structure in place of the compound (Pt-1) used in the elements of Examples 1A and 1B.

Furthermore, elements of Comparative Examples 3A and 3B are manufactured manufactured in the same manner as in Comparative Examples 1A and 1B, respectively, except for using a compound (Ir-3) having the following structure as a comparative compound in place of tris(2-phenylpyridine)iridium complex used for manufacturing the elements of Comparative Examples 1A and 1B.

The luminescent colors of the elements of Examples 3A and 3B and Comparative Examples 3A and 3B are blue.

As compared with Comparative Examples 3A and 3B, Examples 3A and 3B are excellent in external quantum efficiency and driving durability in the case where the solutions undergo time passage or does not undergo time passage.

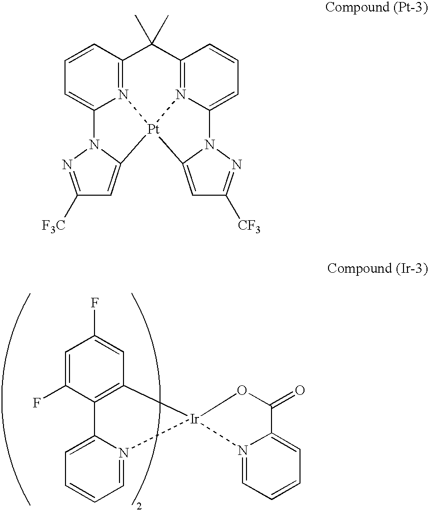

Furthermore, similar elements can be manufactured by using compounds represented by the formula (II) (for example, compound (103), and the like cited above as exemplary compounds) or compounds represented by the formula (III) (for example, compound (64), compound (82), and the like cited above as illustrative compounds) in place of “Pt-1”, “Pt-2”, “Pt-3” used for manufacturing the elements of Examples 1A, 1B, 2A, 2B, 3A, and 3B. Favorable results according to the invention can be achieved also with these elements, similarly to the element of the Examples.

As is apparent from the above results, each of the elements of Examples 1A, 1B, 2A, 2B, 3A, and 3B that are obtained by using the compositions for an organic EL element containing a metal complex having a tridentate or higher-dentate ligand is excellent in luminous efficiency and in driving durability, as compared with the elements of Comparative Examples that are obtained by using a compositions for an organic EL element containing a metal complex having a bidentate ligand. Furthermore, it is understood that the elements manufactured by using a metal complex having a tridentate or higher-dentate ligand are small in deterioration of performance caused by lapse of time after the preparation of the solution, and have suppressed performance variation caused by fluctuation of manufacturing factors, as compared with the elements of Comparative Examples manufactured by using a metal complex having a bidentate ligand.

As described in detail above, according to the invention, it is possible to provide a method for manufacturing an organic electroluminescent element that can stably supply a luminescent element having high luminous efficiency and high driving durability by using a pattern forming method involving an ink jet method.

### Comparative Example 4A

(1) Manufacture of Substrate A

A glass plate with a thickness of 0.5 mm is cut into 2.5 cm square as a substrate support, and the substrate support is introduced into the vacuum chamber of a deposition device. A transparent electrode (an anode) consisting of ITO thin film with a thickness of 0.2 μm is formed on the substrate support by DC magnetron sputtering (conditions: temperature in the substrate support is 100° C., and oxygen pressure is 1×10⁻³ Pa) using an ITO target containing 10% by mass of SnO₂ (indium:tin=95:5 (molar ratio)). The surface resistance of the ITO thin film is 10 Ω/sq.

Next, the glass plate having the transparent electrode formed thereon is moved into a glove box (whose internal air has been substituted with a nitrogen gas containing 30 ppm of moisture and 30 ppm of oxygen) connected to the deposition device. The transparent electrode (ITO) is connected to an aluminum lead wire to form a laminated structure. The glass plate having the transparent electrode is put in a washing vessel, and is washed with isopropyl alcohol (IPA). Thereafter, the glass plate is subjected to an oxygen plasma treatment. An aqueous dispersion liquid of polyethylene dioxythiophene-polystyrene sulfonate (trade name: BAYTON P, manufactured by Bayer AG; solid content of 1.3% by mass) is spin-coated on the surface of the transparent electrode. Then, the glass plate is placed in the vacuum chamber, which is connected to the glove box, and is dried at 150° C. for two hours under vacuum to form a hole transport layer with a thickness of 100 nm.

(2) Manufacture of Transfer Material M

In the glove box, a coating liquid having the following composition for a luminescent layer is applied onto one surface of a temporary support consisting of polyether sulfone (manufactured by Sumitomo Bakelite Co., Ltd.) having a thickness of 188 μm by using a spin coater, and is dried at room temperature to form a luminescent layer having a thickness of 40 nm on the temporary support.

<Composition of the Coating Liquid for a Luminescent Layer>

Polyvinyl carbazole (Mw=63,000, manufactured by Aldrich Corp.): 40 mass parts

Tris(2-phenylpyridine)iridium complex (ortho-metalation complex): 1 mass part

Dichloroethane: 3200 mass parts

(3) Manufacture of an Organic Electroluminescent Element

The substrate A having the hole transport layer formed thereon is returned into the glove box, and the luminescent layer side of the transfer material M is superposed on the upper surface of the hole transport layer of the substrate A. Heat and pressure are applied thereto by using a pair of heating rollers (160° C., 0.3 MPa, and 0.05 m/minute). And then, a substrate MA having a luminescent layer formed on the upper surface of the hole transport layer is manufactured by peeling the temporary support away. It is confirmed with naked eyes that the luminescent layer is formed uniformly when irradiating ultraviolet rays of 254 nm with a handy type UV lamp (trade name: UVGL-25, manufactured by Funakoshi Co., Ltd.).

The substrate MA having the luminescent layer formed thereon is moved to the deposition device connected to the glove box, and compound A having the following structure is deposited as an electron transport material on the luminescent layer at a rate of 1 nm/second, to prepare an electron transport layer 0.036 μm thick. Furthermore, a patterned mask (a mask to give a luminescent area of 5 mm×5 mm) is placed thereon, and then LiF film (the electron injection layer) having a thickness of 3 nm is formed by a deposition method. Furthermore, Al is deposited to a thickness of 0.3 μm to form a back electrode (cathode), to form a laminated structure.

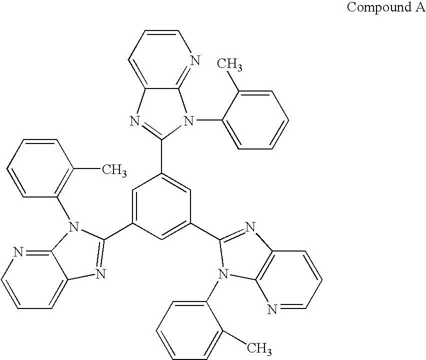

The obtained laminated structure is returned into the glove box connected to the deposition device, and an aluminum lead wire is connected to the back electrode. Furthermore, the laminated structure is sealed in a glass sealing vessel by using an UV-curable adhesive (trade name: XNR5493, manufactured by Nagase Chiba Co., Ltd.) to make an organic EL element of Comparative Example 4A.

### Example 4A

An element is manufactured in the same manner as in Comparative Example 4A, except for using compound (Pt-1) having the following structure in place of tris(2-phenylpyridine)iridium complex used in the element of Comparative Example 4A.

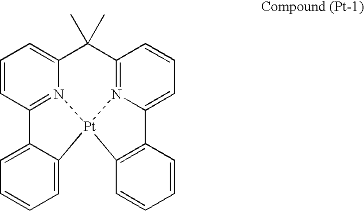

### Comparative Example 5A

An element is manufactured in the same manner as in Comparative Example 4A, except for using compound (Ir-1) having the following structure in place of tris(2-phenylpyridine)iridium complex used in the element of Comparative Example 4A.

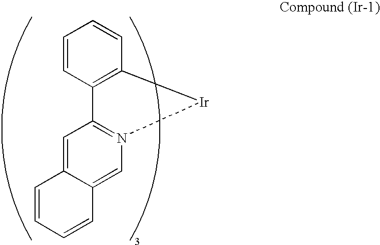

### Example 5A

An element is manufactured in the same manner as in Example 4A, except for using compound (Pt-2) having the following structure in place of compound (Pt-1) used in the element of Example 4A. 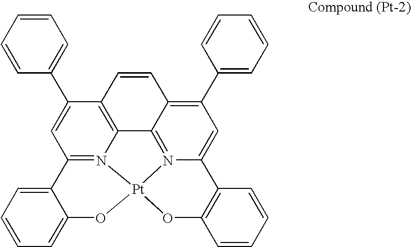
<Evaluation of the Elements>
(1) Luminous Efficiency: External Quantum Efficiency

Using a Source Measure Unit 2400 manufactured by KEITHLEY, a direct current voltage is applied to each element to cause emission of light. The luminance is measured with a luminance meter BM-8, manufactured by Topcon Corporation, and the emission spectrum and the emission wavelength are measured with a spectrum analyzer PMA-11, manufactured by Hamamatsu Photonics KK. Based on these measured values, the external quantum efficiency around the luminance of 1000 cd/m² is calculated according to the luminance conversion method, and is evaluated according to the following criteria.

—Evaluation Criteria—

A: 5% or more

B: 3% or more but less than 5%

C: less than 3%

(2) Driving Durability: Half Life of Luminance

A direct current voltage is applied to each element to obtain a luminance of 1000 cd/m², and the time until the luminance reduces to 500 cd/m² (the half life of luminance) is measured. The results are evaluated according to the following criteria.

—Evaluation Standard—

A: 2000 hours or more

B: 1000 hours or more but less than 2000 hours

C: less than 1000 hours

Table 3 shows the evaluation results, together with the luminescent color of each element.

TABLE 3

| | | External quantum | Half life of |
|---|---|---|---|
| | Luminescent color | efficiency | luminance |
| Comparative | Green | B | B |
| Example 4A | | | |
| Example 4A | Green | A | A |
| Comparative | Orange-yellow | B | B |
| Example 5A | | | |
| Example 5A | Orange-yellow | A | A |

### Examples 4B and 5B, And Comparative Examples 4B and 5B

Elements of Examples 4B and 5B and Comparative Examples 4B and 5B are manufactured in the same manner as in Examples 4A and 5A and Comparative Examples 4A and 5A, respectively, except that the solution for a luminescent layer is spin-coated five hours after the preparation thereof.

<Evaluation of the Elements>

(3) External Quantum Efficiency and Half Life of Luminance in the Case the Solutions Undergo Time Passage.

The external quantum efficiency and the half life of luminance of the elements manufactured as described above are measured by the same methods as the methods (1) and (2), respectively.

Table 4 shows the evaluation results, together with the luminescent color of each element.

TABLE 4

| | | External quantum | |
|---|---|---|---|
| | | efficiency | Half life of |
| | | in the case the | luminance in the case |
| | Luminescent | solutions undergo | the solutions undergo |
| | color | the time passage | the time passage |
| Comparative | Green | C | C |
| Example 4B | | | |
| Example 4B | Green | A | A |
| Comparative | Orange-yellow | C | C |
| Example 5B | | | |
| Example 5B | Orange-yellow | A | A |

### Examples 6A and 6B, And Comparative Examples 6A and 6B

Elements of Examples 6A and 6B are manufactured in the same manner as in Examples 4A and 4B, respectively, except for using compound (Pt-3) having the following structure in place of compound (Pt-1) used in the elements of Examples 4A and 4B.

Furthermore, elements of Comparative Examples 6A and 6B are manufactured in the same manner as in Comparative Examples 4A and 4B, except for using compound (Ir-3) having the following structure as a comparative compound in place of tris(2-phenylpyridine)iridium complex used in the elements of Comparative Examples 4A and 4B.

The luminescent colors of the elements of Examples 6A and 6B and Comparative Examples 6A and 6B are blue.

As compared with Comparative Examples 6A and 6B, Examples 6A and 6B are excellent in external quantum efficiency and driving durability in the case where the solutions undergo time passage or does not undergo time passage.

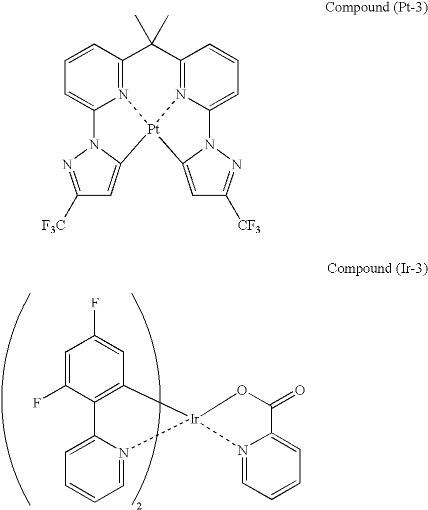

### Examples 7A and 7B

(1) Manufacture of Substrate B

Polyimide sheets (trade name: UPILEX 50S, 50 μm in thickness, manufactured by Ube Industries, Ltd.) are laminated on both sides of aluminum foil having a thickness of 30 μm by using an adhesive. Then the aluminum foil is put in a washing vessel in a glove box (whose internal air has been substituted with nitrogen gas containing 30 ppm of moisture and 30 ppm of oxygen), and is washed with isopropyl alcohol (IPA). Thereafter, the aluminum foil is subjected to an oxygen plasma treatment. Then, the substrate (i.e., aluminum foil) is moved to a deposition device connected to the glove box. A patterned mask (a mask to give a luminescence area of 5 mm×5 mm) for deposition is placed on one side of the substrate that has been treated with oxygen plasma, and Al is deposited in a reduced-pressure atmosphere of about 0.1 mPa to form a back electrode (cathode) having a thickness of 0.3 μm. Further, as an electron injection layer, LiF is deposited to a thickness of 3 nm in the same pattern as the Al layer. The substrate having the electrode and the electron injection layer formed thereon is moved to the glove box, and an aluminum lead wire is connected to the Al electrode. The substrate is moved again into the deposition device, and the compound A shown above is deposited as an electron transport material on the LiF layer at a rate of 1 nm/second to prepare an electron transport layer having a thickness of 0.036 μm.

(2) Manufacture of Substrate MA

The substrate MA is manufactured by forming a luminescent layer in the same manner as in Examples 4A and 4B.

(3) Manufacture of an Organic Electroluminescent Element

The substrate MA and the substrate B are stacked in the glove box such that the film-forming surface of the substrate MA having the transferred luminescent layer contacts the electron transport layer of the substrate B. The substrate MA and the substrate B are bonded to each other by heat and pressure (160° C., 0.3 MPa) using a pair of heating rollers (0.05 m/minute). Then, an aluminum lead wire is connected to the back electrode to make a laminated structure. Then, the laminated structure is sealed in a glass sealing vessel with an UV-curable adhesive (trade name: XNR5493, manufactured by Nagase Chiba Co., Ltd.), so that organic EL elements of Example 6A and 6B are obtained.

<Evaluation of the Elements>

The obtained elements are evaluated in the same manner as in Examples 4A and 4B. As a result, excellent results similar to Examples 4A and 4B are obtained.

As clearly seen from the above results, each of the elements of Examples 3A, 3B, 4A, 4B, 5A, 5B, 6A, 6B, 7A, and 7B in which metal complexes having a tridentate or higher-dentate ligand are used is excellent in luminous efficiency and driving durability, as compared with the elements of Comparative Examples in which metal complexes having a bidentate ligand are used. Furthermore, it is understood that the performance of the elements of Comparative Examples in which conventional metal complexes having a bidentate ligand is deteriorated with lapse of time in the solution state, while each of the elements of Examples exhibits smaller deterioration of performance after time passage in the solution state and can suppress the variation of performance caused by fluctuation of manufacturing factors.

Furthermore, similar elements can be manufactured by using compounds represented by the formula (II) (for example, compound (103), and the like cited above as exemplary compounds) or compounds represented by the formula (III) (for example, compound (64), compound (82), and the like cited above as illustrative compounds) in place of “Pt-1”, “Pt-2”, “Pt-3” used for manufacturing the elements of Examples 4A, 4B, 5A, 5B, 6A, 6B, 7A, and 7B. Favorable results according to the invention can be achieved also with these elements, similarly to the element of the above Examples.

As described in detail above, according to the invention, a method for manufacturing an organic electroluminescent element is provided which can stably supply a luminescent element having high luminous efficiency and high driving durability by using a simple liquid phase method. Furthermore, the organic electroluminescent element can be manufactured at high productivity and low cost by the use of the peel-transfer method (or, the peel-transfer method and the adhesion method). Because the organic layer is formed by using a transfer material in an aspect of the invention, even if there exist defects and the like (physical defects such as defects in surface smoothness) in the substrate and the organic layer, the influence from the defects can be reduced, and sheet luminescence can be improved. Furthermore, when the adhesion method is used, an organic EL element with fewer defects and excellent durability can be obtained in which layers are tightly bonded.

According to the invention, a composition for an organic electroluminescent element excellent in storability can be provided.

Further, a method for manufacturing an organic electroluminescent element can be provided which can stably and easily manufacture an organic electroluminescent element having high luminous efficiency, high luminance, and excellent durability.

Furthermore, an organic electroluminescent element can be provided which has high luminous efficiency, high luminance, and excellent durability.

All publications, patent applications, and technical standards mentioned in this specification are herein incorporated by reference to the same extent as if each individual publication, patent application, or technical standard is specifically and individually indicated to be incorporated by reference.

What is claimed is:

1. A composition for an organic electroluminescent element capable of forming a pattern by an ink jet method, comprising at least one metal complex having a tridentate or higher-dentate ligand.

2. The composition according to claim 1, wherein the tridentate or higher ligand is a chain ligand.

3. The composition according to claim 1, wherein the metal complex having a tridentate or higher-dentate ligand is a compound represented by the following formula (I): 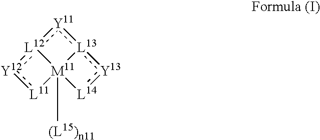
wherein in Formula (I), M¹¹ represents a metal ion; L¹¹ to L¹⁵ each independently represent a ligand coordinated to M¹¹; in no case does an additional atomic group connect L¹¹ and L¹⁴ to form a cyclic ligand; in no case, is L¹⁵ bonded to both L¹¹ and L¹⁴ to form a cyclic ligand; Y¹¹ to Y¹³ each independently represent a connecting group, a single bond, or a double bond; when Y¹¹, Y¹², or Y¹³ represent a connecting group, the bond between L¹¹ and Y¹², the bond between Y¹² and L¹², the bond between L¹² and Y¹¹, the bond between Y¹¹ and L¹³, the bond between L¹³ and Y¹³, and the bond between Y¹³ and L¹⁴ are each independently a single bond or a double bond; n¹¹ represents an integer of 0 to 4; and each bond connecting M¹¹ and each of L¹¹ to L¹⁵ is selected from a coordinate bond, an ionic bond and a covalent bond.

4. The composition according to claim 1, wherein the metal complex having a tridentate or higher-dentate ligand is a compound represented by the following formula (II): 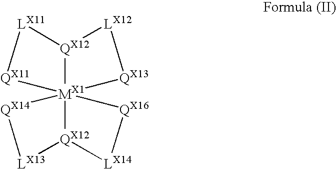
wherein in Formula (II), M^{X1} represents a metal ion; Q^{X11} to Q^{X16} each independently represent an atom coordinating to M^{X1} or an atomic group containing an atom coordinating to M^{X1}; L^{X11} to L^{X14} each independently represent a single bond, a double bond or a connecting group; and the bond between M^{X1} and each of Q^{X11} to Q^{X16} is a coordination bond, an ionic bond, or a covalent bond.

5. The composition according to claim 1, wherein the metal complex having a tridentate or higher-dentate ligand is a compound represented by the following formula (III): 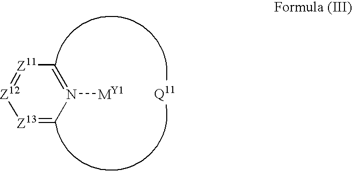
wherein in Formula (III), Q¹¹ represents an atomic group forming a nitrogen-containing heterocycle; Z¹¹, Z¹², and Z¹³ each represent a substituted or unsubstituted carbon or nitrogen atom; and M^{Y1} represents a metal ion that may further have a ligand.

6. The composition according to claim 1, comprising a polymer dispersion liquid that contains a polymer for dispersing the metal complex having a tridentate or higher-dentate ligand.

7. A method for manufacturing an organic electroluminescent element, the method comprising forming a first electrode on a substrate, forming an organic compound layer by discharging the composition of claim 1 in a pattern onto a side of the substrate that has the first electrode thereon using an ink jet apparatus, and forming a second electrode on the organic compound layer.

8. A method for manufacturing an organic electroluminescent element, the method comprising forming a first electrode on a substrate, superposing a transfer material having an organic compound layer containing a metal complex having a tridentate or higher-dentate ligand provided on a temporary support, on a side of the substrate that has the first electrode thereon, applying heat and/or pressure thereto, peeling away the temporary support so as to transfer the organic compound layer onto the side of the substrate that has the first electrode thereon, and forming a second electrode on the organic compound layer.

9. The method for manufacturing an organic electroluminescent element according to claim 8, wherein the organic compound layer containing the metal complex having a tridentate or higher-dentate ligand is formed on the temporary support by using a liquid containing the metal complex having a tridentate or higher-dentate ligand.

10. The method for manufacturing an organic electroluminescent element according to claim 8, wherein the tridentate or higher-dentate ligand is a chain ligand.

11. The method for manufacturing an organic electroluminescent element according to claim 8, wherein the metal complex having a tridentate or higher-dentate ligand is a compound represented by the following formula (I): 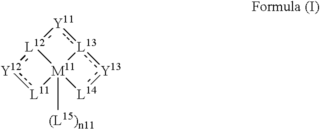
wherein in Formula (I), M¹¹ represents a metal ion; L¹¹ to L¹⁵ each independently represent a ligand coordinated to M¹¹; in no case does an additional atomic group connect L¹¹ and L¹⁴ to form a cyclic ligand; in no case, is L¹⁵ bonded to both L¹¹ and L¹⁴ to form a cyclic ligand; Y¹¹ to Y¹³ each independently represent a connecting group, a single bond, or a double bond; when Y¹¹, Y¹², or Y¹³ represent a connecting group, the bond between L¹¹ and Y¹², the bond between Y¹² and L¹², the bond between L¹² and Y¹¹, the bond between Y¹¹ and L¹³, the bond between L¹³ and Y¹³, and the bond between Y¹³ and L¹⁴ are each independently a single bond or a double bond; n¹¹ represents an integer of 0 to 4; and each bond connecting M¹¹ and each of L¹¹ to L¹⁵ is selected from a coordinate bond, an ionic bond and a covalent bond.

12. The method for manufacturing an organic electroluminescent element according to claim 8, wherein the metal complex having a tridentate or higher-dentate ligand is a compound represented by the following formula (II): 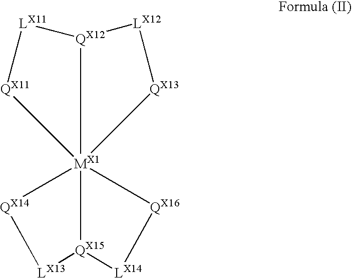
wherein in Formula (II), M^{X1} represents a metal ion; Q^{X11} to Q^{X16} each independently represent an atom coordinating to M^{X1} or an atomic group containing an atom coordinating to M^{X1}; L^{X11} to L^{X14} each independently represent a single bond, a double bond or a connecting group; and the bond between M^{X1} and each of Q^{X11} to Q^{X16} is a coordination bond, an ionic bond, or a covalent bond.

13. The method for manufacturing an organic electroluminescent element according to claim 8, wherein the metal complex having a tridentate or higher-dentate ligand is a compound represented by the following formula (III): 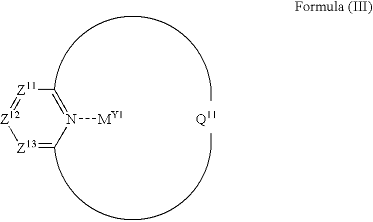
wherein in Formula (III), Q¹¹ represents an atomic group forming a nitrogen-containing heterocycle; Z¹¹, Z¹², and Z¹³ each represent a substituted or unsubstituted carbon or nitrogen atom; and M^{Y1} represents a metal ion that may further have a ligand.

14. The method for manufacturing an organic electroluminescent element according to claim 9, wherein the liquid containing the metal complex containing a tridentate or higher-dentate ligand is a polymer dispersion liquid that contains a polymer for dispersing the metal complex.

15. An organic electroluminescent element manufactured by using the method of claim 7.

16. An organic electroluminescent element manufactured by using the method of claim 8.
